(19) United States
(12) Patent Application Publication
(10) Pub. No.: US 2025/0376620 A1
(43) Pub. Date: Dec. 11, 2025

(54) COMPOSITION, DEPOSITION SOURCE, ORGANIC ELECTROLUMINESCENT DEVICE INCLUDING SAME, AND MANUFACTURING METHOD THEREFOR

(71) Applicant: LG CHEM, LTD., Seoul (KR)

(72) Inventors: Jae Seung HA, Daejeon (KR); Ji Young CHOI, Daejeon (KR); Wanpyo HONG, Daejeon (KR); Woochul LEE, Daejeon (KR); Joo Ho KIM, Daejeon (KR); Hoon Jun KIM, Daejeon (KR)

(21) Appl. No.: 19/301,721

(22) Filed: Aug. 15, 2025

Related U.S. Application Data
(62) Division of application No. 17/637,613, filed on Feb. 23, 2022.

(30) Foreign Application Priority Data
Jun. 1, 2020 (KR) 10-2020-0065928

(51) Int. Cl. C09K 11/02; C09K 11/06; H10K 50/11; H10K 85/60

(52) U.S. Cl. CPC C09K 11/02; C09K 11/06; H10K 85/615; H10K 85/626; H10K 85/658; C09K 2211/1007; C09K 2211/1011; C09K 2211/1014; C09K 2211/1022; H10K 50/11

(57) ABSTRACT

A method for manufacturing an organic electroluminescent device, the method including forming one or more organic material layers using a composition that includes a compound of Chemical Formula 1 and a compound of Chemical Formula 2, at least one of which includes at least one deuterium:

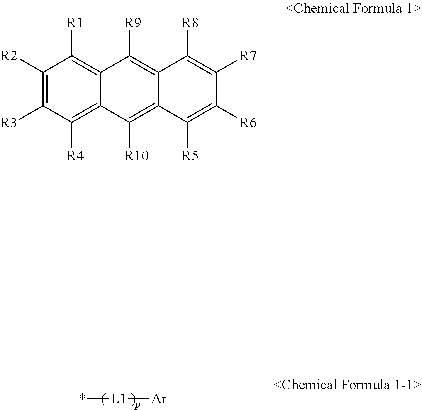

wherein at least one of R1 to R10 bonds to a * site of Chemical Formula 1-1, and Ar is a substituted or unsubstituted aryl group;

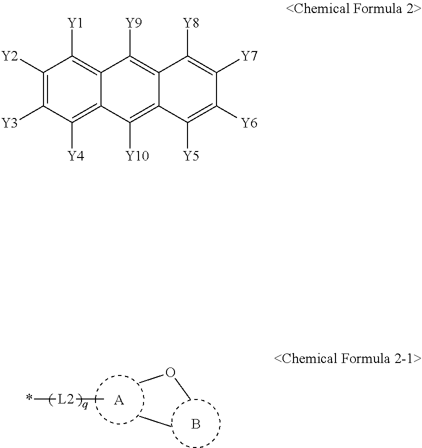

wherein at least one of Y1 to Y10 bonds to a * site of Chemical Formula 2-1, and A and B are each independently a substituted or unsubstituted aromatic hydrocarbon ring or a substituted or unsubstituted aromatic heteroring; and the other substituents are defined in the specification; and an organic electroluminescent device prepared by the method.

### CROSS-REFERENCE TO RELATED APPLICATIONS

This application is a divisional of co-pending U.S. patent application Ser. No. 17/637,613, filed Feb. 23, 2022, which is a National Stage Application of International Application No. PCT/KR2021/006821 filed on Jun. 1, 2021, which claims priority to and the benefits of Korean Patent Application No. 10-2020-0065928, filed with the Korean Intellectual Property Office on Jun. 1, 2020, the entire contents of which are incorporated herein by reference.

### TECHNICAL FIELD

The present specification relates to a composition, a deposition source, an organic electroluminescent device including the same, and a method for manufacturing an organic electroluminescent device.

### BACKGROUND

An organic electroluminescent device has a structure disposing an organic thin film between two electrodes. When a voltage is applied to an organic electroluminescent device having such a structure, electrons and holes injected from the two electrodes bind and pair in the organic thin film, and light emits as these annihilate. The organic thin film can be formed in a single layer or a multilayer as necessary.

Materials used in an organic electroluminescent device are mostly pure organic materials or complex compounds in which organic materials and metals form complexes, and can be divided into hole injection materials, hole transfer materials, light emitting materials, electron transfer materials, electron injection materials and the like depending on the application. Herein, as the hole injection material or the hole transfer material, organic materials having a p-type property, that is, organic materials readily oxidized and having an electrochemically stable state when oxidized, are generally used. Meanwhile, as the electron injection material or the electron transfer material, organic materials having an n-type property, that is, organic materials readily reduced and having an electrochemically stable state when reduced, are generally used. As the light emitting layer material, materials having both a p-type property and an n-type property, that is, materials having a stable form in both oxidized and reduced states, are preferred, and materials having high light emission efficiency converting, when excitons produced by holes and electrons recombining in a light emitting layer are formed, the excitons to light are preferred.

Development of an organic thin film material has been continuously required for enhancing performance, lifetime or efficiency of an organic electroluminescent device.

### BRIEF DESCRIPTION

### Technical Problem

The present specification is directed to providing a material for an organic electroluminescent device having high stability and exhibiting excellent properties when used in the device.

### Technical Solution

One embodiment of the present specification provides a composition including a compound of the following Chemical Formula 1 and a compound of the following Chemical Formula 2, wherein at least one of the compound of the following Chemical Formula 1 and the compound of the following Chemical Formula 2 includes at least one deuterium:

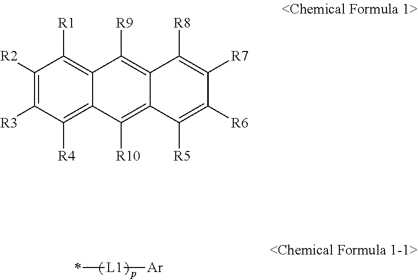

wherein in Chemical Formula 1:
at least one of R1 to R10 bonds to a * site of Chemical Formula 1-1 and the rest are the same as or different from each other, and each independently is hydrogen, deuterium, a halogen group, a cyano group, a nitro group, a hydroxyl group, a substituted or unsubstituted alkyl group, a substituted or unsubstituted aryl group, a substituted or unsubstituted cycloalkyl group, a substituted or unsubstituted heteroaryl group, or a substituted or unsubstituted silyl group;
L1 is a direct bond, a substituted or unsubstituted arylene group, or a substituted or unsubstituted heteroarylene group;
Ar is a substituted or unsubstituted aryl group; and
p is an integer of 1 to 5;

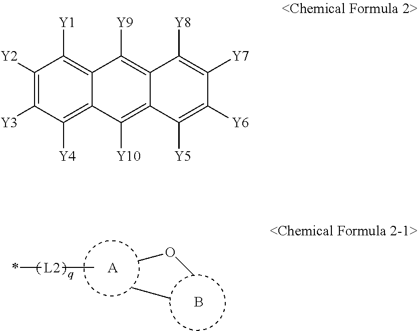

wherein in Chemical Formula 2:
at least one of Y1 to Y10 bonds to a * site of Chemical Formula 2-1, and the rest are the same as or different from each other, and each independently is hydrogen, deuterium, a halogen group, a cyano group, a nitro group, a hydroxyl group, a substituted or unsubstituted alkyl group, a substituted or unsubstituted aryl group, a substituted or unsubstituted cycloalkyl group, a substituted or unsubstituted heteroaryl group, or a substituted or unsubstituted silyl group;
A and B are the same as or different from each other, and each independently is a substituted or unsubstituted aromatic hydrocarbon ring or a substituted or unsubstituted aromatic heteroring;
L2 is a direct bond, a substituted or unsubstituted arylene group, or a substituted or unsubstituted heteroarylene group; and
q is an integer of 1 to 5.

One embodiment of the present specification provides a deposition source prepared using the composition.

In addition, one embodiment of the present specification provides an organic electroluminescent device including a cathode, an anode, and a light emitting layer provided between the cathode and the anode, wherein the light emitting layer includes the composition.

Lastly, one embodiment of the present specification provides a method for manufacturing an organic electroluminescent device, the method including preparing the composition; preparing a substrate; forming a first electrode on the substrate; forming one or more organic material layers on the first electrode; and forming a second electrode on the organic material layer, wherein the forming of one or more organic material layers includes forming one or more organic material layers using the composition.

### Advantageous Effects

A composition according to embodiments described in the present specification has very superior stability, and when used in an organic electroluminescent device, excellent efficiency properties, driving voltage properties and lifetime properties are obtained in the device.

### DESCRIPTION OF THE DRAWINGS

FIG. 1 and FIG. 3 each illustrate an organic electroluminescent device according to one embodiment of the present specification.

FIG. 2 is a TLC-MS graph for calculating a deuterium substitution rate.

FIG. 4 shows a schematic representation of HPLC analysis of three replicates of deposited substrate film samples of a sublimation mixture composition containing Compound 6 and Compound J.

FIG. 5 shows a schematic representation of HPLC analysis of three replicates of deposited substrate film samples of a sublimation mixture composition containing Compound B and Compound 24.

### FIGURE REFERENCES AND NUMERALS

10: Organic Electroluminescent Device
20: Substrate
30: Anode
40: Light Emitting Layer
50: Cathode
60: Hole Injection Layer
70: Hole Transfer Layer
80: Hole Control Layer
90: Electron Control Layer
100: Electron Transfer Layer
110: Electron Injection Layer
120: Capping Layer
ref: mixture composition before sublimation
R1: mixture composition after sublimation (sublimation mixture composition)
boat: composition remaining after preparing sublimation mixture composition
films 1 to 3: films prepared using sublimation mixture composition
crucible: composition remaining after preparing film by loading sublimation mixture composition on deposition source

### DETAILED DESCRIPTION

Hereinafter, the present specification will be described in detail.

A composition according to one embodiment of the present specification is a composition including a compound of Chemical Formula 1 and a compound of Chemical Formula 2, and at least one of the compound of Chemical Formula 1 and the compound of Chemical Formula 2 includes at least one deuterium. When manufacturing an organic electroluminescent device including the composition, a device having a significantly improved lifetime while maintaining excellent efficiency can be obtained.

Anthracene derivatives such as Chemical Formula 1 and Chemical Formula 2 show stable performance when used as a host of an organic electroluminescent device, and have been commercialized to date. However, a single host has opposite effects of lifetime and efficiency, and it has been quite difficult to satisfy both. A mixed host has been used as an alternative, but such has not been able to achieve beyond a basic performance range of an organic compound, and it has been difficult to improve performance of a manufactured blue device.

Accordingly, deuteration of an anthracene-based host has been sought as a way to maintain a lifetime while maximizing efficiency of a light emitting layer, and the present specification has significantly improved a lifetime problem while maintaining efficiency of an organic electroluminescent device by introducing an anthracene derivative substituted with deuterium as a mixed host.

A light emitting layer of an organic electroluminescent device is a region having a direct influence of emitting light, and is a section with a large molecular loss by energy. A carbon-deuterium bond is stronger than a carbon-hydrogen bond, and deuterium has high bond energy by having a high mass value and thereby lowering zero point energy with carbon, and therefore, bond energy of a molecule increases by replacing carbon-hydrogen bonds included in the molecules of the compound of Chemical Formula 1 and/or the compound of Chemical Formula 2 with carbon-deuterium bonds. Accordingly, when manufacturing a device including the compound of Chemical Formula 1 including deuterium and/or the compound of Chemical Formula 2 including deuterium, effects of improving a lifetime of the device are obtained.

$$Zero point energy = \sqrt{\frac{{m}_{C} + {m}_{H}}{{m}_{C} {m}_{H}}}$$

In the present specification, a description of a certain part “including” certain constituents means capable of further including other constituents, and does not exclude other constituents unless particularly stated on the contrary.

In the present specification, “deuteration” or deuterated” means hydrogen at a substitutable position of a compound being substituted with deuterium.

In the present specification, “X % deuterated”, “degree of deuteration of X %” or “deuterium substitution rate of X %” means X % of hydrogens at a substitutable position in the corresponding structure being substituted with deuterium. For example, when the corresponding structure is dibenzofuran, the dibenzofuran being “25% deuterated”, “degree of deuteration of 25%” of the dibenzofuran, or “deuterium substitution rate of 25%” of the dibenzofuran means two of eight hydrogens at a substitutable position in the dibenzofuran being substituted with deuterium.

In the present specification, the “degree of deuteration” or “deuterium substitution rate” can be identified using known methods such as nuclear magnetic resonance (1H NMR), TLC/MS (thin-layer chromatography/mass spectrometry) or GC/MS (gas chromatography/mass spectrometry).

Specifically, when analyzing the “degree of deuteration” or “deuterium substitution rate” using nuclear magnetic resonance (1H NMR), the degree of deuteration or deuterium substitution rate can be calculated from the integrated quantity of total peaks through the integration ratio in 1H NMR after adding DMF (dimethylformamide) as an internal standard.

In addition, when analyzing the “degree of deuteration” or “deuterium substitution rate” through TLC/MS (thin-layer chromatography/mass spectrometry), the substitution rate can be calculated based on the maximum value (median value) of distribution that molecular weights form at the end of the reaction. For example, in the analysis of the degree of deuteration of the following Compound A, when the following starting material has a molecular weight of 506 and the following Compound A has a molecular weight maximum value (median value) of 527 in the MS graph of FIG. 2, 21 of 26 hydrogens at a substitutable position of the following starting material are substituted with deuterium, and therefore, it can be calculated that approximately 81% of hydrogens are deuterated:

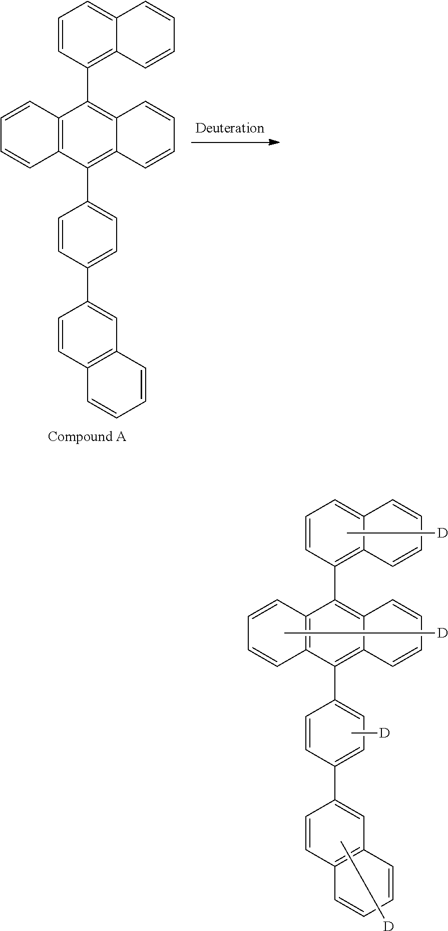

In the present specification, D means deuterium.

Examples of substituents in the present specification are described below, however, the substituents are not limited thereto.

The term “substitution” means a hydrogen atom bonding to a carbon atom of a compound being changed to another substituent, and the position of substitution is not limited as long as it is a position at which the hydrogen atom is substituted, that is, a position at which a substituent can substitute, and when two or more substituents substitute, the two or more substituents can be the same as or different from each other.

In the present specification, a term “substituted or unsubstituted” means being substituted with one, two or more substituents selected from the group consisting of deuterium, a halogen group, a nitrile group, a nitro group, an imide group, an amide group, a carbonyl group, an ester group, a hydroxyl group, a substituted or unsubstituted alkyl group, a substituted or unsubstituted cycloalkyl group, a substituted or unsubstituted heterocycloalkyl group, a substituted or unsubstituted alkoxy group, a substituted or unsubstituted aryloxy group, a substituted or unsubstituted alkylthioxy group, a substituted or unsubstituted arylthioxy group, a substituted or unsubstituted alkylsulfoxy group, a substituted or unsubstituted arylsulfoxy group, a substituted or unsubstituted alkenyl group, a substituted or unsubstituted silyl group, a substituted or unsubstituted boron group, a substituted or unsubstituted amine group, a substituted or unsubstituted arylphosphine group, a substituted or unsubstituted phosphine oxide group, a substituted or unsubstituted aryl group, and a substituted or unsubstituted heterocyclic group, or being substituted with a substituent linking two or more substituents among the substituents illustrated above, or having no substituents. For example, the “substituent linking two or more substituents” can be a heteroaryl group substituted with an aryl group, or an aryl group substituted with a heteroaryl group. In addition, a biphenyl group can be an aryl group, or can be interpreted as a substituent linking two phenyl groups.

In the present specification, the halogen group can be fluorine, chlorine, bromine or iodine.

In the present specification, the alkyl group can be linear or branched, and although not particularly limited thereto, the number of carbon atoms is preferably from 1 to 30. Specific examples thereof can include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, 5-methylhexyl and the like, but are not limited thereto.

In the present specification, the cycloalkyl group is not particularly limited, but preferably has 3 to 30 carbon atoms. Specific examples thereof can include cyclopropyl, cyclobutyl, cyclopentyl, cycloheptyl, cyclooctyl and the like, but are not limited thereto.

In the present specification, the alkoxy group can be linear, branched or cyclic. The number of carbon atoms of the alkoxy group is not particularly limited, but is preferably from 1 to 30. Specific examples thereof can include methoxy, ethoxy, n-propoxy, isopropoxy, n-butoxy, isobutoxy, tert-butoxy, sec-butoxy, n-pentyloxy, neopentyloxy, isopentyloxy, n-hexyloxy, 3,3-dimethylbutyloxy, 2-ethylbutyloxy, n-octyloxy, n-nonyloxy, n-decyloxy and the like, but are not limited thereto.

In the present specification, the amine group can be selected from the group consisting of —NH₂, an alkylamine group, an N-alkylarylamine group, an arylamine group, an N-arylheteroarylamine group, an N-alkylheteroarylamine group, and a heteroarylamine group, and although not particularly limited thereto, the number of carbon atoms is preferably from 0 to 30. Specific examples of the amine group can include a methylamine group, a dimethylamine group, an ethylamine group, a diethylamine group, a phenylamine group, a naphthylamine group, a biphenylamine group, an anthracenylamine group, a 9-methyl-anthracenylamine group, a diphenylamine group, an N-phenylnaphthylamine group, a ditolylamine group, an N-phenyltolylamine group, a triphenylamine group, an N-phenylbiphenylamine group, an N-phenylnaphthylamine group, an N-biphenylnaphthylamine group, an N-naphthylfluorenylamine group, an N-phenylphenanthrenyl-amine group, an N-biphenylphenanthrenylamine group, an N-phenylfluorenylamine group, an N-phenylterphenylamine group, an N-phenanthrenylfluorenylamine group, an N-biphenyl-fluorenylamine group and the like, but are not limited thereto.

In the present specification, the N-alkylarylamine group means an amine group in which N of the amine group is substituted with an alkyl group and an aryl group.

In the present specification, the N-arylheteroarylamine group means an amine group in which N of the amine group is substituted with an aryl group and a heteroaryl group.

In the present specification, the N-alkylheteroarylamine group means an amine group in which N of the amine group is substituted with an alkyl group and a heteroaryl group.

In the present specification, the alkyl group in the alkylamine group, the N-arylalkylamine group, the alkylthioxy group, the alkylsulfoxy group and the N-alkylheteroarylamine group is the same as the examples of the alkyl group described above.

The number of carbon atoms of the alkylthioxy group is not particularly limited, but is preferably from 1 to 30. Specific examples thereof can include a methylthioxy group, an ethylthioxy group, a tert-butylthioxy group, a hexylthioxy group, an octylthioxy group and the like, and examples of the alkylsulfoxy group can include mesyl, an ethylsulfoxy group, a propylsulfoxy group, a butylsulfoxy group and the like, but are not limited thereto.

In the present specification, the alkenyl group can be linear or branched, and although not particularly limited thereto, the number of carbon atoms is preferably from 2 to 30. Specific examples thereof can include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenyl-vinyl-1-yl, 2-phenyl-2-(naphthyl-1-yl) vinyl-1-yl, 2,2-bis-(diphenyl-1-yl) vinyl-1-yl and the like, but are not limited thereto.

In the present specification, the alkynyl group can be linear or branched, and although not particularly limited thereto, the number of carbon atoms is preferably from 2 to 20. Specific examples thereof can include ethynyl, propynyl, butynyl, pentynyl, hexynyl, heptynyl, octynyl, nonynyl and the like, but are not limited thereto.

In the present specification, the silyl group can be an alkylsilyl group or an arylsilyl group, and furthermore, can be a trialkylsilyl group or a triarylsilyl group. The number of carbon atoms of the silyl group is not particularly limited, but is preferably from 1 to 30, and the number of carbon atoms of the alkylsilyl group can be from 1 to 30 and the number of carbon atoms of the arylsilyl group can be from 5 to 30. Specific examples thereof can include a trimethylsilyl group, a triethylsilyl group, a tert-butyldimethylsilyl group, a vinyldimethylsilyl group, a propyldimethylsilyl group, a triphenylsilyl group, a diphenylsilyl group, a phenylsilyl group and the like, but are not limited thereto.

In the present specification, the boron group can be —BR₁₀₀R₁₀₁. R₁₀₀ and R₁₀₁ are the same as or different from each other, and can be each independently selected from the group consisting of hydrogen; deuterium; halogen; a nitrile group; a substituted or unsubstituted monocyclic or polycyclic cycloalkyl group having 3 to 30 carbon atoms; a substituted or unsubstituted linear or branched alkyl group having 1 to 30 carbon atoms; a substituted or unsubstituted monocyclic or polycyclic aryl group having 6 to 30 carbon atoms; and a substituted or unsubstituted monocyclic or polycyclic heteroaryl group having 2 to 30 carbon atoms.

In the present specification, specific examples of the phosphine oxide group can include a diphenylphosphine oxide group, a dinaphthylphosphine oxide group and the like, but are not limited thereto.

In the present specification, the aryl group is not particularly limited, but preferably has 6 to 30 carbon atoms, and the aryl group can be monocyclic or polycyclic.

When the aryl group is a monocyclic aryl group, the number of carbon atoms is not particularly limited, but is preferably from 6 to 30. Specific examples of the monocyclic aryl group can include a phenyl group, a biphenyl group, a terphenyl group and the like, but are not limited thereto.

When the aryl group is a polycyclic aryl group, the number of carbon atoms is not particularly limited, but is preferably from 10 to 30. Specific examples of the polycyclic aryl group can include a naphthyl group, an anthracenyl group, a phenanthrenyl group, a triphenylenyl group, a pyrenyl group, a phenalenyl group, a perylenyl group, a chrysenyl group, a fluorenyl group, a fluoranthenyl group and the like, but are not limited thereto.

In the present specification, the fluorenyl group can be substituted, and adjacent groups can bond to each other to form a ring.

When the fluorenyl group is substituted,

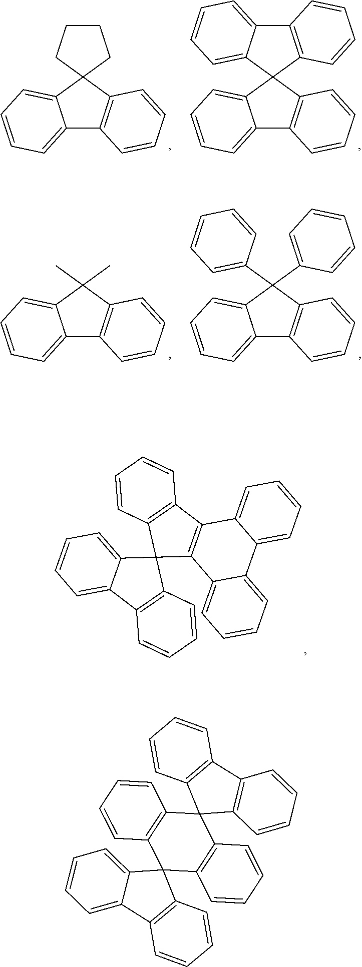

and the like can be included, however, the structure is not limited thereto.

In the present specification, the aryl group in the aryloxy group, the arylthioxy group, the arylsulfoxy group, the N-arylalkylamine group, the N-arylheteroarylamine group and the arylphosphine group is the same as the examples of the aryl group described above.

The number of carbon atoms of the aryloxy group is not particularly limited, but is preferably from 6 to 30. Specific examples thereof can include a phenoxy group, a p-tolyloxy group, an m-tolyloxy group, a 3,5-dimethyl-phenoxy group, a 2,4,6-trimethylphenoxy group, a p-tert-butylphenoxy group, a 3-biphenyloxy group, a 4-biphenyloxy group, a 1-naphthyloxy group, a 2-naphthyloxy group, a 4-methyl-1-naphthyloxy group, a 5-methyl-2-naphthyloxy group, a 1-anthryloxy group, a 2-anthryloxy group, a 9-anthryloxy group, a 1-phenanthryloxy group, a 3-phenanthryloxy group, a 9-phenanthryloxy group and the like.

The number of carbon atoms of the arylthioxy group is not particularly limited, but is preferably from 5 to 30, and furthermore, from 6 to 30. Specific examples of the arylthioxy group can include a phenylthioxy group, a 2-methylphenylthioxy group, a 4-tert-butylphenylthioxy group and the like, and specific examples of the arylsulfoxy group can include a benzenesulfoxy group, a p-toluenesulfoxy and the like, however, the arylthioxy group and the arylsulfoxy group are not limited thereto.

In the present specification, examples of the arylamine group include a substituted or unsubstituted monoarylamine group, or a substituted or unsubstituted diarylamine group. The aryl group in the arylamine group can be a monocyclic aryl group or a polycyclic aryl group. The arylamine group including two or more aryl groups can include monocyclic aryl groups, polycyclic aryl groups, or both monocyclic aryl groups and polycyclic aryl groups. For example, the aryl group in the arylamine group can be selected from among the examples of the aryl group described above.

In the present specification, the heterocyclic group is a group including one or more atoms that are not carbon, that is, heteroatoms, and specifically, the heteroatom can include one or more atoms selected from the group consisting of O, N, S, P and the like. Although not particularly limited thereto, the number of carbon atoms is preferably from 2 to 50, and furthermore, from 2 to 30, and the heterocyclic group can be monocyclic or polycyclic. The heterocyclic group can be an aromatic ring, an aliphatic ring and a fused ring thereof. Examples of the heterocyclic group can include a thiophene group, a furanyl group, a pyrrole group, an imidazolyl group, a thiazolyl group, an oxazolyl group, an oxadiazolyl group, a pyridyl group, a bipyridyl group, a pyrimidyl group, a triazinyl group, a triazolyl group, an acridyl group, a pyridazinyl group, a pyrazinyl group, a quinolyl group, a quinazolyl group, a quinoxalyl group, a phthalazinyl group, a pyridopyrimidyl group, a pyridopyrazinyl group, a pyrazinopyrazinyl group, an isoquinolyl group, an indolyl group, a carbazolyl group, a benzoxazolyl group, a benzimidazolyl group, a benzothiazolyl group, a benzocarbazolyl group, a benzothiophene group, a dibenzothiophene group, a benzofuranyl group, a phenanthrolinyl group, an isoxazolyl group, a thiadiazolyl group, a phenothiazinyl group, a dibenzofuranyl group and the like, but are not limited thereto.

The heteroaryl group means a monovalent aromatic heterocyclic group, and the heteroarylene group means a divalent aromatic heterocyclic group. The descriptions on the heterocyclic group provided above can be applied to the heteroaryl group and the heteroarylene group except that these are an aromatic heterocyclic group.

In the present specification, examples of the heteroarylamine group include a substituted or unsubstituted monoheteroarylamine group, or a substituted or unsubstituted diheteroarylamine group. The heteroarylamine group including two or more heteroaryl groups can include monocyclic heteroaryl groups, polycyclic heteroaryl groups, or both monocyclic heteroaryl groups and polycyclic heteroaryl groups. For example, the heteroaryl group in the heteroarylamine group can be selected from among the examples of the heteroaryl group described above.

In the present specification, examples of the heteroaryl group in the N-arylheteroarylamine group and the N-alkylheteroarylamine group are the same as the examples of the heteroaryl group described above.

Hereinafter, Chemical Formula 1 will be described.

According to one embodiment of the present specification, one to three of R1 to R10 bond to the * site of Chemical Formula 1-1, and the rest are hydrogen, deuterium, a halogen group, a cyano group, a nitro group, a hydroxyl group, a substituted or unsubstituted alkyl group, a substituted or unsubstituted aryl group, a substituted or unsubstituted cycloalkyl group, a substituted or unsubstituted heteroaryl group, or a substituted or unsubstituted silyl group.

According to another embodiment, one to three of R1 to R10 bond to the * site of Chemical Formula 1-1, and the rest are hydrogen, deuterium, a halogen group, a cyano group, a nitro group, a hydroxyl group, a substituted or unsubstituted alkyl group having 1 to 20 carbon atoms, a substituted or unsubstituted aryl group having 6 to 60 carbon atoms, a substituted or unsubstituted cycloalkyl group having 3 to 60 carbon atoms, a substituted or unsubstituted heteroaryl group having 2 to 60 carbon atoms, or a substituted or unsubstituted silyl group.

In another embodiment, R9 and R10 bond to the * site of Chemical Formula 1-1, and the rest are hydrogen, deuterium, a halogen group, a cyano group, a nitro group, a hydroxyl group, a substituted or unsubstituted alkyl group, a substituted or unsubstituted aryl group, a substituted or unsubstituted cycloalkyl group, a substituted or unsubstituted heteroaryl group, or a substituted or unsubstituted silyl group.

According to another embodiment, R9, R10 and R8 bond to the * site of Chemical Formula 1-1, and the rest are hydrogen, deuterium, a halogen group, a cyano group, a nitro group, a hydroxyl group, a substituted or unsubstituted alkyl group, a substituted or unsubstituted aryl group, a substituted or unsubstituted cycloalkyl group, a substituted or unsubstituted heteroaryl group, or a substituted or unsubstituted silyl group.

In another embodiment, R9, R10 and R7 bond to the * site of Chemical Formula 1-1, and the rest are hydrogen, deuterium, a halogen group, a cyano group, a nitro group, a hydroxyl group, a substituted or unsubstituted alkyl group, a substituted or unsubstituted aryl group, a substituted or unsubstituted cycloalkyl group, a substituted or unsubstituted heteroaryl group, or a substituted or unsubstituted silyl group.

According to one embodiment of the present specification, substituents not bonding to Chemical Formula 1-1 among R1 to R10 are the same as or different from each other, and each independently is hydrogen, deuterium or a dibenzofuranyl group.

According to one embodiment of the present specification, p is an integer of 1 to 5, and when p is 2 or greater, the two or more L1s are the same as or different from each other.

In another embodiment, p is an integer of 1 to 3, and when p is 2 or greater, the two or more L1s are the same as or different from each other.

According to one embodiment of the present specification, Chemical Formula 1 is any one of the following Chemical Formulae 1-A to 1-C:

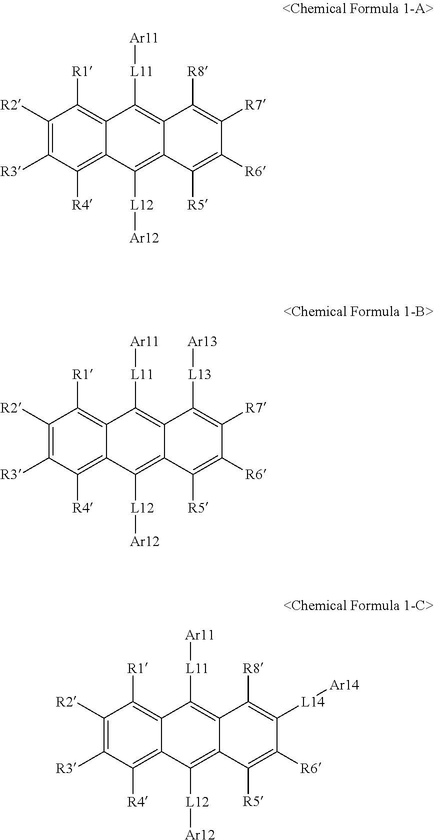

wherein in Chemical Formulae 1-A to 1-C:
R1′ to R8′ are the same as or different from each other, and each independently is hydrogen, deuterium, a halogen group, a cyano group, a nitro group, a hydroxyl group, a substituted or unsubstituted alkyl group, a substituted or unsubstituted aryl group, a substituted or unsubstituted cycloalkyl group, a substituted or unsubstituted heteroaryl group, or a substituted or unsubstituted silyl group;
L11 to L14 are the same as or different from each other, and each independently is a direct bond, a substituted or unsubstituted arylene group, or a substituted or unsubstituted heteroarylene group; and
Ar11 to Ar14 are the same as or different from each other, and each independently is a substituted or unsubstituted aryl group.

According to one embodiment of the present specification, R1′ to R8′ are hydrogen, deuterium, a halogen group, a cyano group, a nitro group, a hydroxyl group, a substituted or unsubstituted alkyl group having 1 to 20 carbon atoms, a substituted or unsubstituted aryl group having 6 to 60 carbon atoms, a substituted or unsubstituted cycloalkyl group having 3 to 60 carbon atoms, a substituted or unsubstituted heteroaryl group having 2 to 60 carbon atoms, or a substituted or unsubstituted silyl group.

According to one embodiment of the present specification, R1′ to R8′ are the same as or different from each other, and each independently is hydrogen, deuterium or a dibenzofuranyl group.

According to one embodiment of the present specification, L1 is a direct bond, a substituted or unsubstituted arylene group having 6 to 60 carbon atoms, or a substituted or unsubstituted heteroarylene group having 2 to 60 carbon atoms. L1 can be substituted with deuterium.

In another embodiment, L1 is a direct bond, a substituted or unsubstituted arylene group having 6 to 30 carbon atoms, or a substituted or unsubstituted heteroarylene group having 2 to 30 carbon atoms.

According to another embodiment, L1 is a direct bond, a substituted or unsubstituted phenylene group, a substituted or unsubstituted biphenylylene group, a substituted or unsubstituted naphthylene group, a substituted or unsubstituted phenanthrenylene group, or a substituted or unsubstituted triphenylenylene group.

In another embodiment, L1 is a direct bond, a phenylene group unsubstituted or substituted with deuterium, a biphenylylene group unsubstituted or substituted with deuterium, a naphthylene group unsubstituted or substituted with deuterium, a phenanthrenylene group unsubstituted or substituted with deuterium, or a triphenylenylene group unsubstituted or substituted with deuterium.

According to one embodiment of the present specification, Ar is a substituted or unsubstituted aryl group having 6 to 60 carbon atoms. Ar can be substituted with deuterium.

In another embodiment, Ar is a substituted or unsubstituted aryl group having 6 to 30 carbon atoms.

According to another embodiment, Ar is a substituted or unsubstituted phenyl group, a substituted or unsubstituted biphenyl group, a substituted or unsubstituted terphenyl group, a substituted or unsubstituted naphthyl group, a substituted or unsubstituted phenanthrenyl group, or a substituted or unsubstituted triphenylenyl group.

In another embodiment, Ar is a phenyl group unsubstituted or substituted with deuterium, a biphenyl group unsubstituted or substituted with deuterium, a terphenyl group unsubstituted or substituted with deuterium, a naphthyl group unsubstituted or substituted with deuterium, a phenanthrenyl group unsubstituted or substituted with deuterium, or a triphenylenyl group unsubstituted or substituted with deuterium.

According to one embodiment of the present specification, L11 to L14 are the same as or different from each other, and each independently is a direct bond, a substituted or unsubstituted arylene group having 6 to 60 carbon atoms, or a substituted or unsubstituted heteroarylene group having 2 to 60 carbon atoms. L11 to L14 can be substituted with deuterium.

In another embodiment, L11 to L14 are the same as or different from each other, and each independently is a direct bond, a substituted or unsubstituted arylene group having 6 to 30 carbon atoms, or a substituted or unsubstituted heteroarylene group having 2 to 30 carbon atoms.

According to another embodiment, L11 to L14 are the same as or different from each other, and each independently is a direct bond, a substituted or unsubstituted phenylene group, a substituted or unsubstituted biphenylylene group, a substituted or unsubstituted naphthylene group, a substituted or unsubstituted phenanthrenylene group, or a substituted or unsubstituted triphenylenylene group.

In another embodiment, L11 to L14 are the same as or different from each other, and each independently is a direct bond, a phenylene group unsubstituted or substituted with deuterium, a biphenylylene group unsubstituted or substituted with deuterium, a naphthylene group unsubstituted or substituted with deuterium, a phenanthrenylene group unsubstituted or substituted with deuterium, or a triphenylenylene group unsubstituted or substituted with deuterium.

According to one embodiment of the present specification, Ar11 to Ar14 are the same as or different from each other, and each independently is a substituted or unsubstituted aryl group having 6 to 60 carbon atoms. Ar11 to Ar14 can be substituted with deuterium.

In another embodiment, Ar11 to Ar14 are the same as or different from each other, and each independently is a substituted or unsubstituted aryl group having 6 to 30 carbon atoms.

According to another embodiment, Ar11 to Ar14 are the same as or different from each other, and each independently is a substituted or unsubstituted phenyl group, a substituted or unsubstituted biphenyl group, a substituted or unsubstituted naphthyl group, a substituted or unsubstituted terphenyl group, a substituted or unsubstituted phenanthrenyl group, a substituted or unsubstituted triphenylenyl group.

In another embodiment, Ar11 to Ar14 are the same as or different from each other, and each independently is a phenyl group unsubstituted or substituted with deuterium, a biphenyl group unsubstituted or substituted with deuterium, a naphthyl group unsubstituted or substituted with deuterium, a terphenyl group unsubstituted or substituted with deuterium, a phenanthrenyl group unsubstituted or substituted with deuterium, or a triphenylenyl group unsubstituted or substituted with deuterium.

In one embodiment of the present specification, Chemical Formula 1 can be selected from among the following structural formulae, but is not limited thereto, and the bonding position of deuterium is not limited. In addition, when Chemical Formula 1 does not include deuterium, it can be a structure excluding deuterium (-D) from the following structural formulae, however, the structure is not limited thereto.

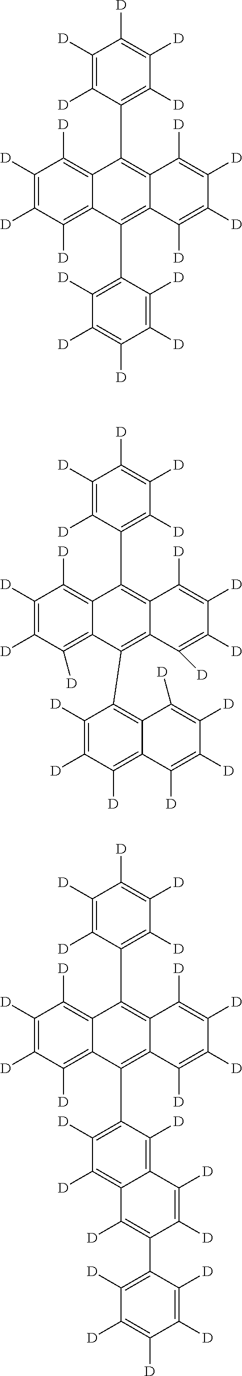

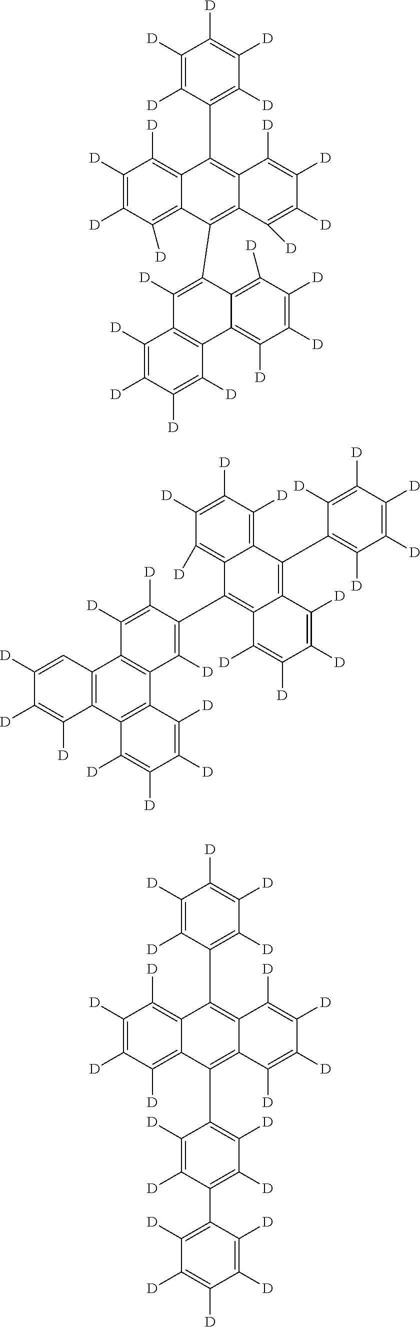

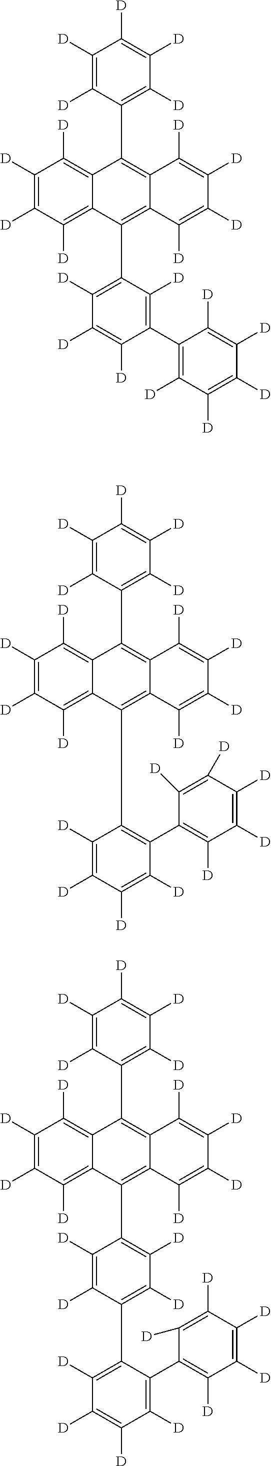

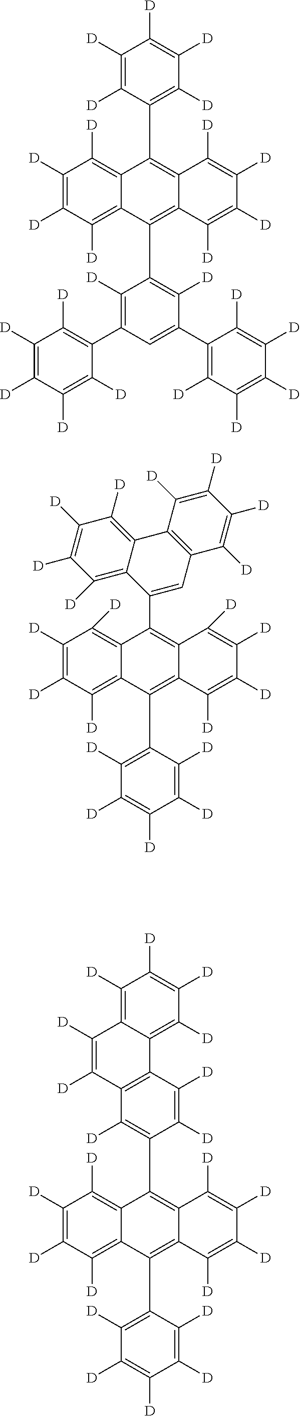

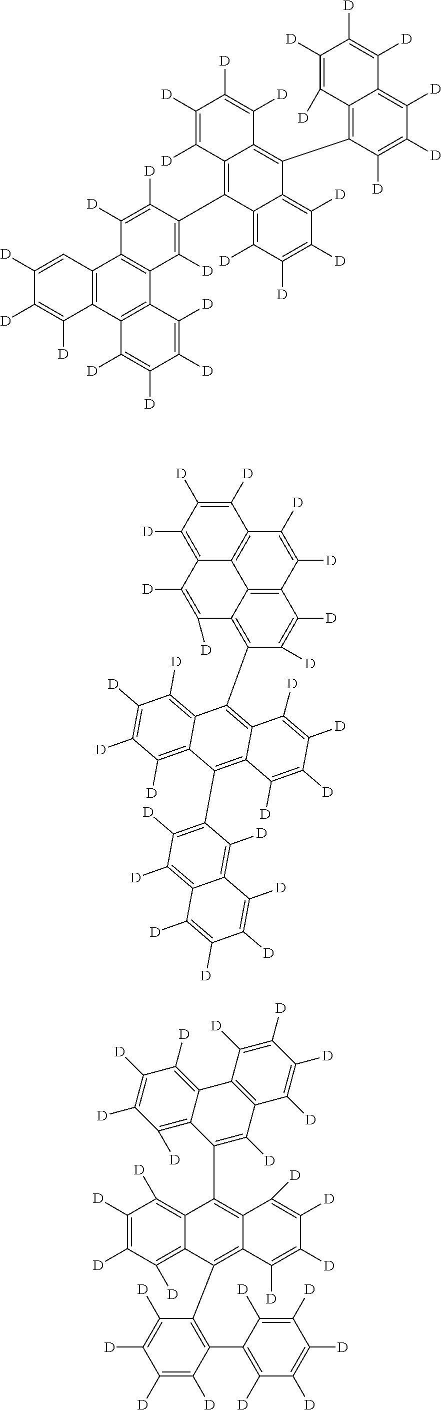

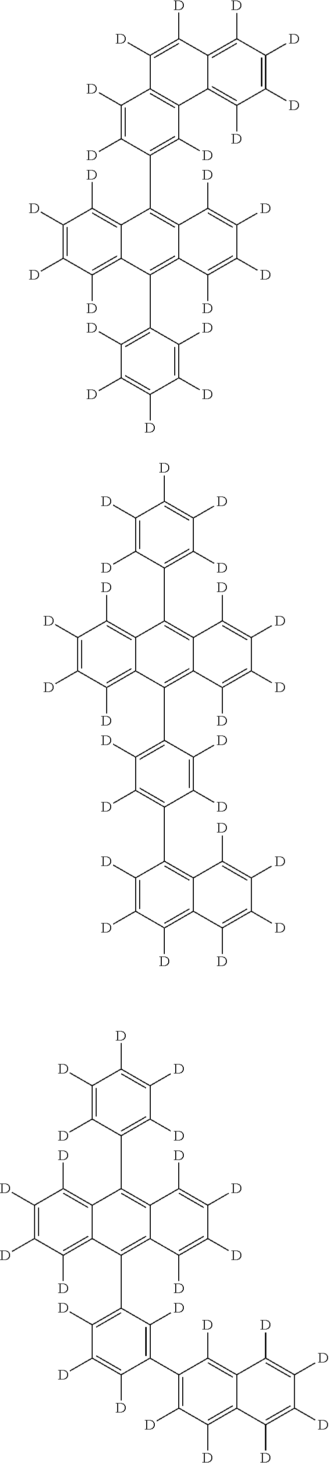

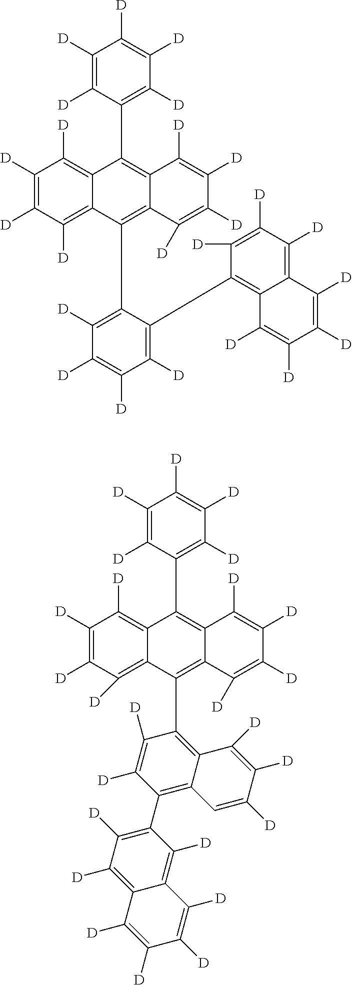 [SMILES: [2H]c1c([2H])c([2H])c(-c2c3c([2H])c([2H])c([2H])c([2H])c3c(-c3c([2H])c([2H])c([2H])c([2H])c3-c3c([2H])c([2H])c([2H])c4c([2H])c([2H])c([2H])c([2H])c34)c3c([2H])c([2H])c([2H])c([2H])c23)c([2H])c1[2H] ; [2H]c1cc2c(-c3c([2H])c([2H])c4c([2H])c([2H])c([2H])c([2H])c4c3[2H])c([2H])c([2H])c(-c3c4c([2H])c([2H])c([2H])c([2H])c4c(-c4c([2H])c([2H])c([2H])c([2H])c4[2H])c4c([2H])c([2H])c([2H])c([2H])c34)c2c([2H])c1[2H]]

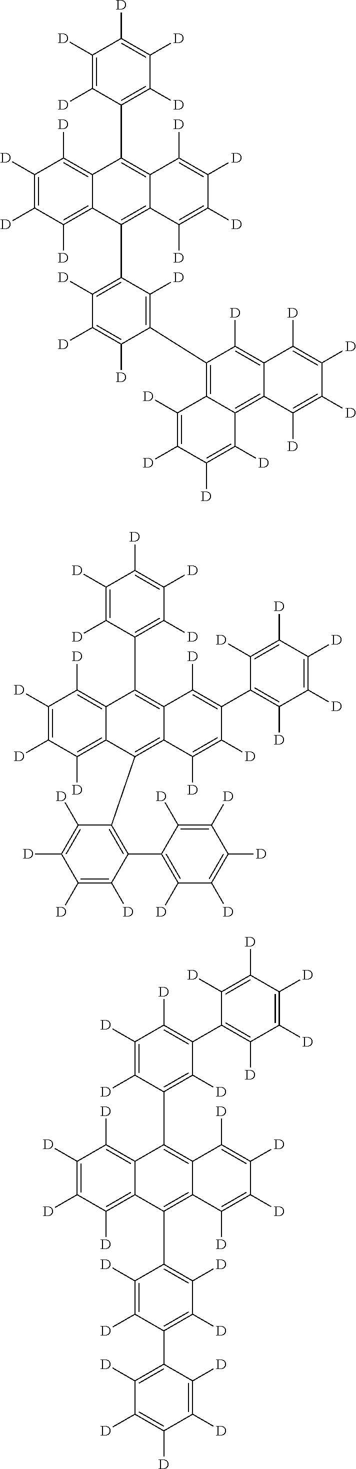

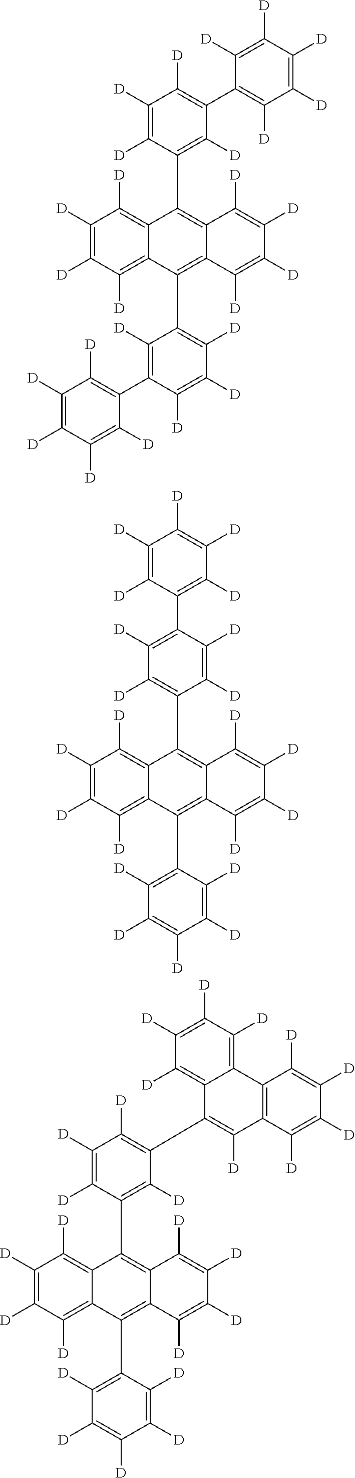

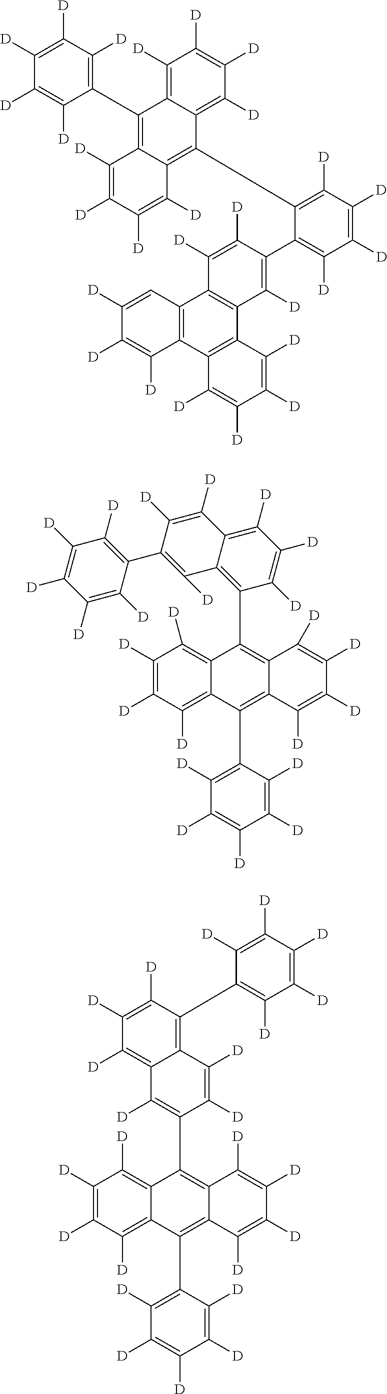

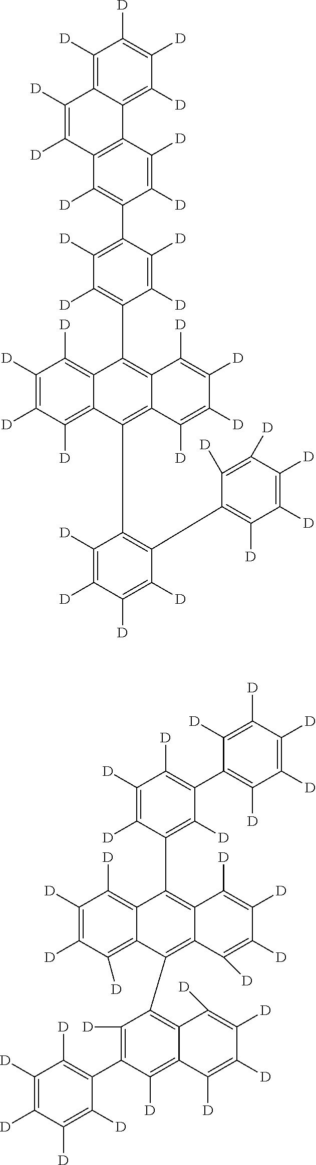 [SMILES: [2H]c1c([2H])c([2H])c(-c2c([2H])c([2H])c([2H])c([2H])c2-c2c3c([2H])c([2H])c([2H])c([2H])c3c(-c3c([2H])c([2H])c(-c4c([2H])c([2H])c5c(c4[2H])c([2H])c([2H])c4c([2H])c([2H])c([2H])c([2H])c45)c([2H])c3[2H])c3c([2H])c([2H])c([2H])c([2H])c23)c([2H])c1[2H] ; [2H]c1c([2H])c([2H])c(-c2c([2H])c([2H])c([2H])c(-c3c4c([2H])c([2H])c([2H])c([2H])c4c(-c4c([2H])c(-c5c([2H])c([2H])c([2H])c([2H])c5[2H])c([2H])c5c([2H])c([2H])c([2H])c([2H])c45)c4c([2H])c([2H])c([2H])c([2H])c34)c2[2H])c([2H])c1[2H]]

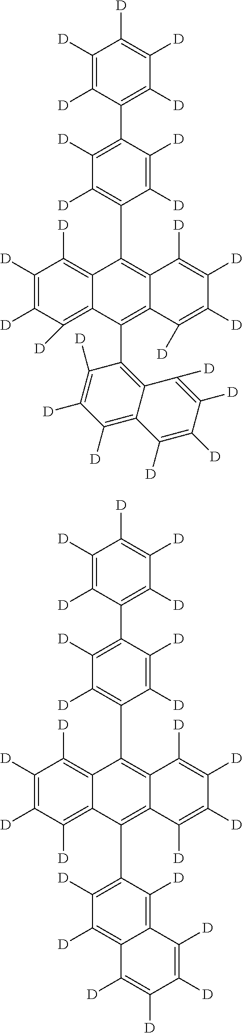

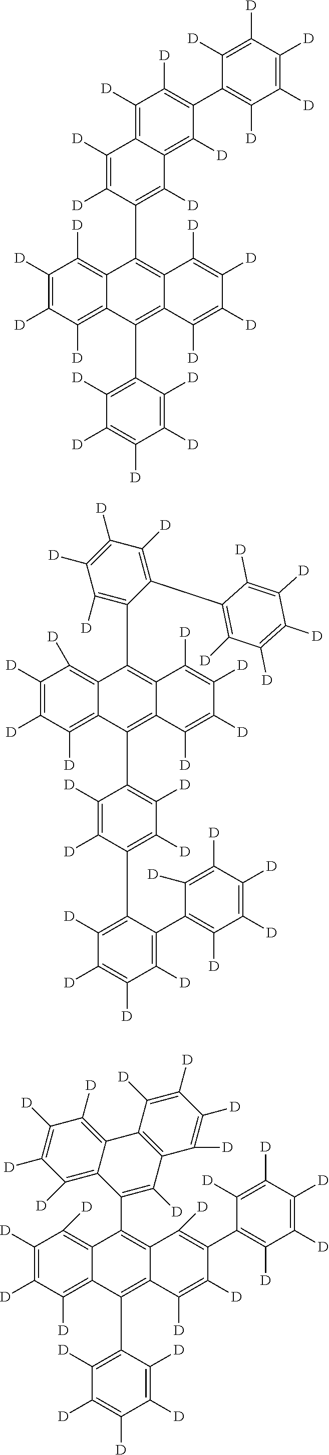

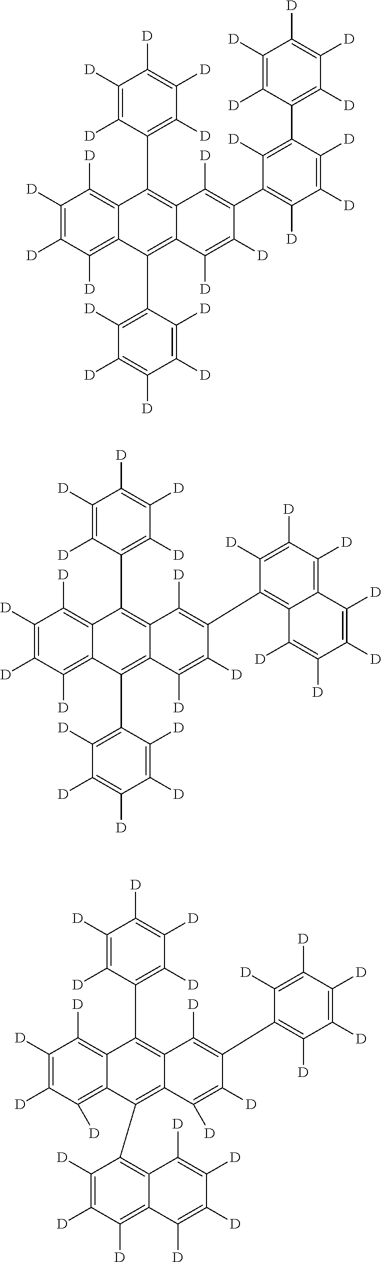

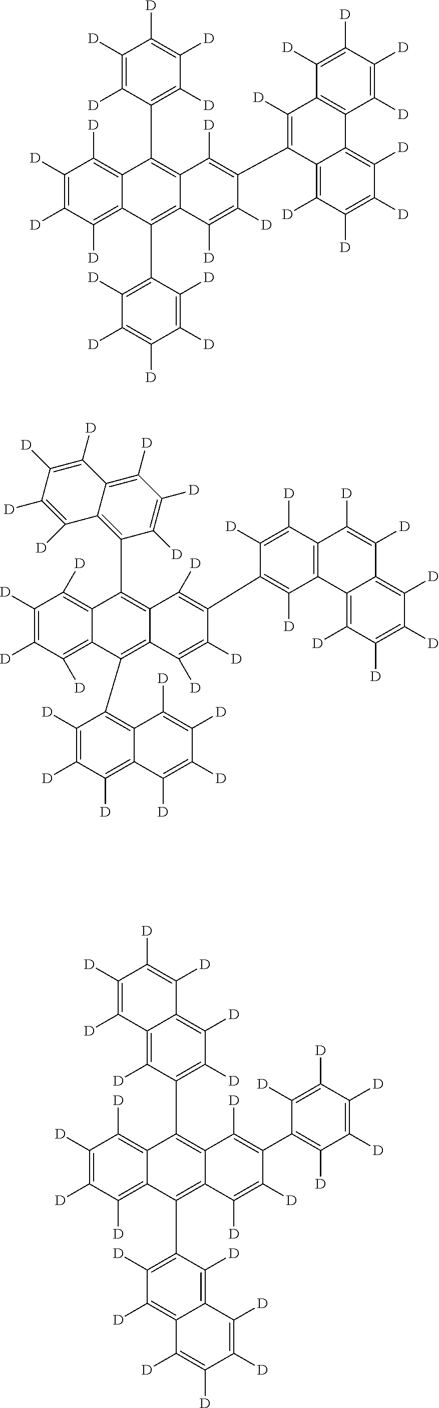

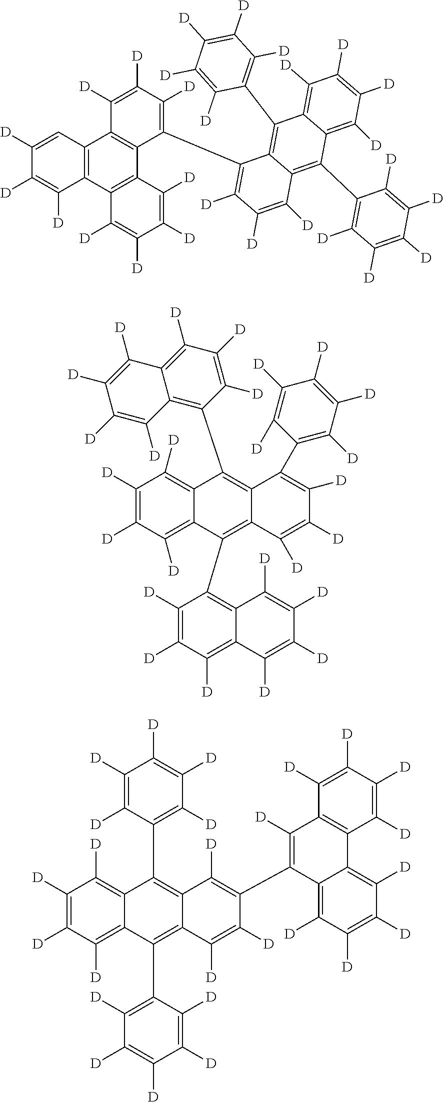

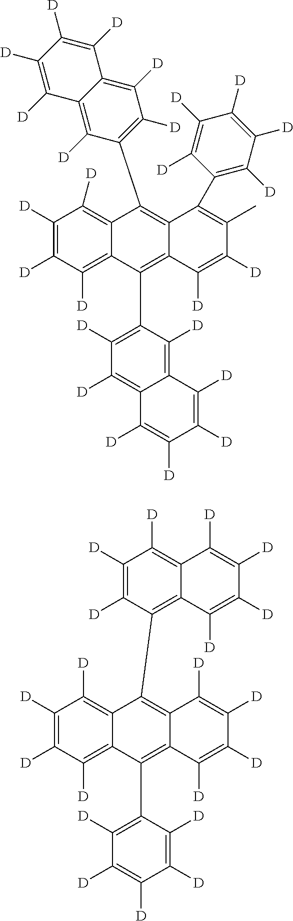

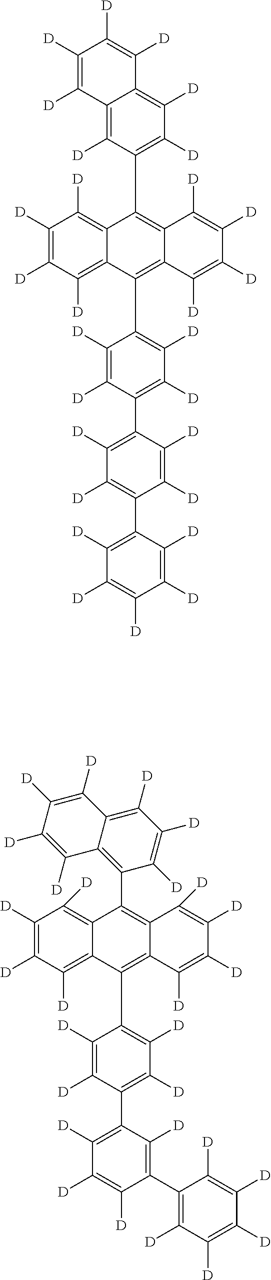 [SMILES: [2H]c1c([2H])c([2H])c(-c2c([2H])c([2H])c(-c3c([2H])c([2H])c(-c4c5c([2H])c([2H])c([2H])c([2H])c5c(-c5c([2H])c([2H])c6c([2H])c([2H])c([2H])c([2H])c6c5[2H])c5c([2H])c([2H])c([2H])c([2H])c45)c([2H])c3[2H])c([2H])c2[2H])c([2H])c1[2H] ; [2H]c1c([2H])c([2H])c(-c2c([2H])c([2H])c([2H])c(-c3c([2H])c([2H])c(-c4c5c([2H])c([2H])c([2H])c([2H])c5c(-c5c([2H])c([2H])c([2H])c6c([2H])c([2H])c([2H])c([2H])c56)c5c([2H])c([2H])c([2H])c([2H])c45)c([2H])c3[2H])c2[2H])c([2H])c1[2H]]

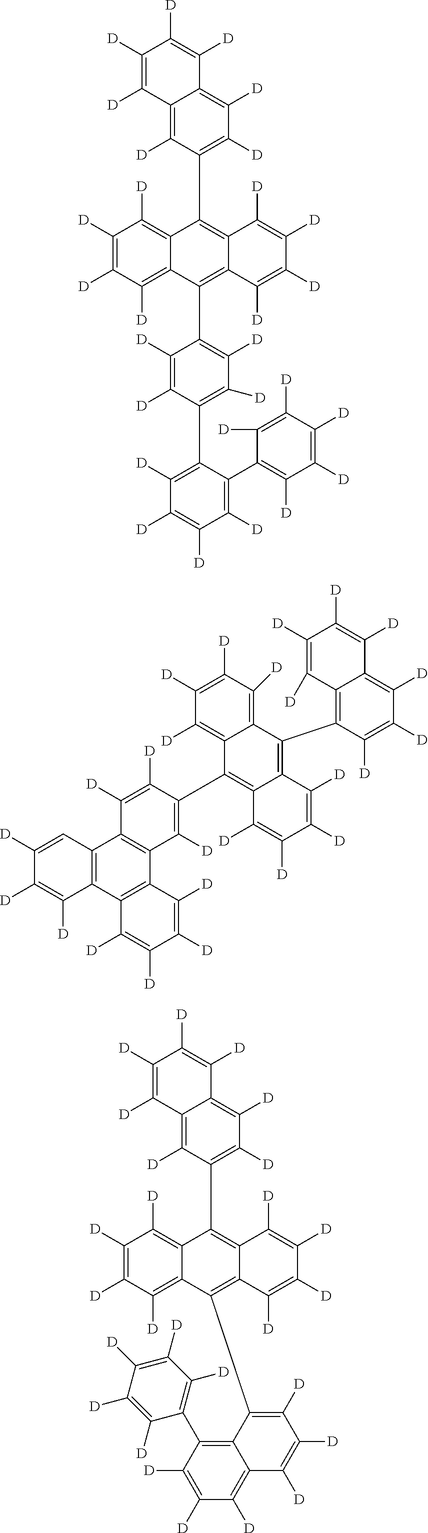

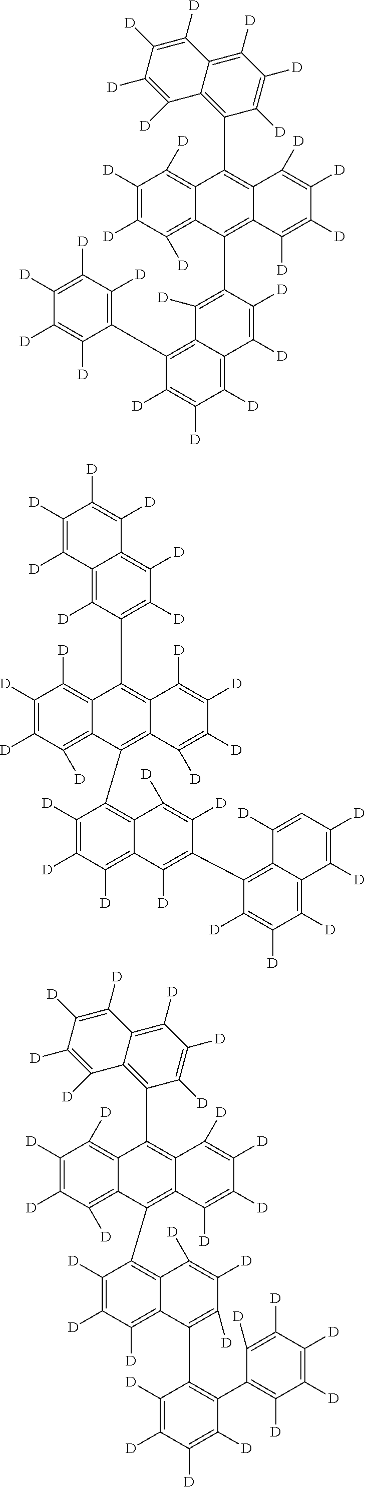

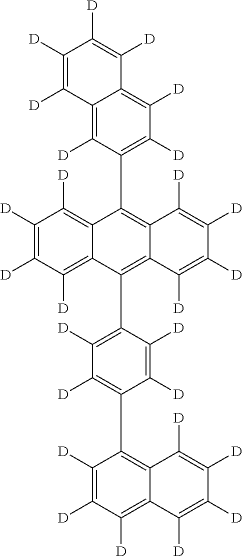 [SMILES: [2H]c1c([2H])c(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c([2H])c([2H])c1-c1c([2H])c([2H])c([2H])c2c([2H])c([2H])c([2H])c([2H])c12]

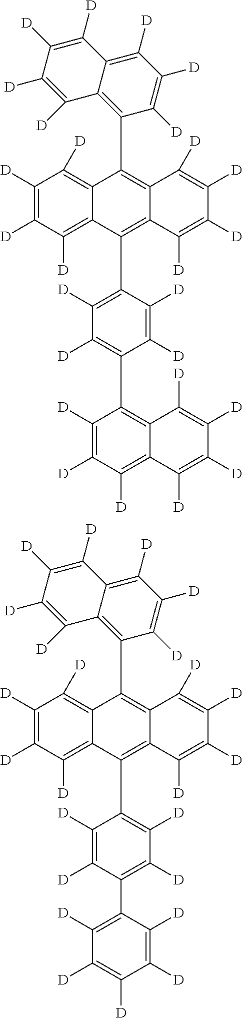

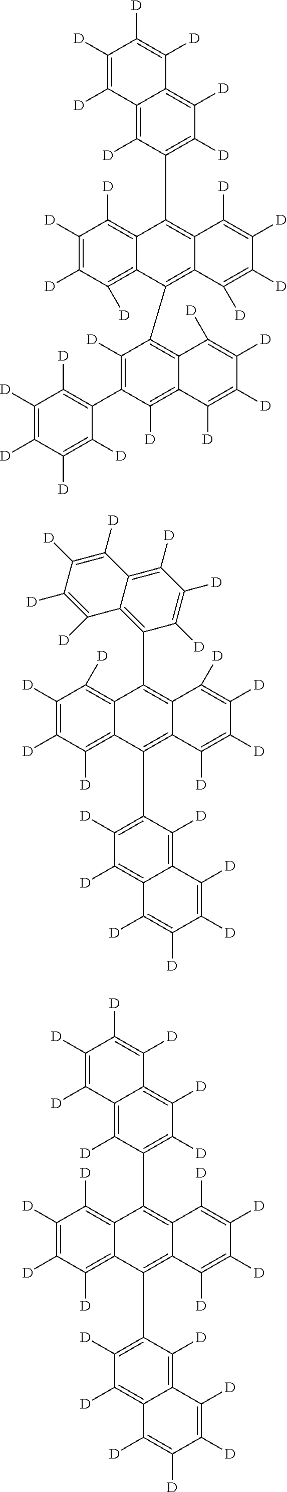

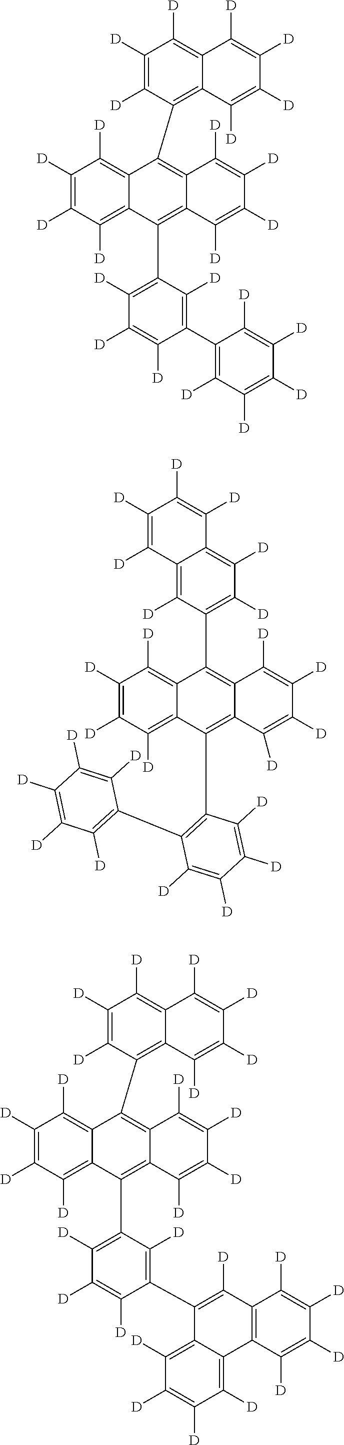

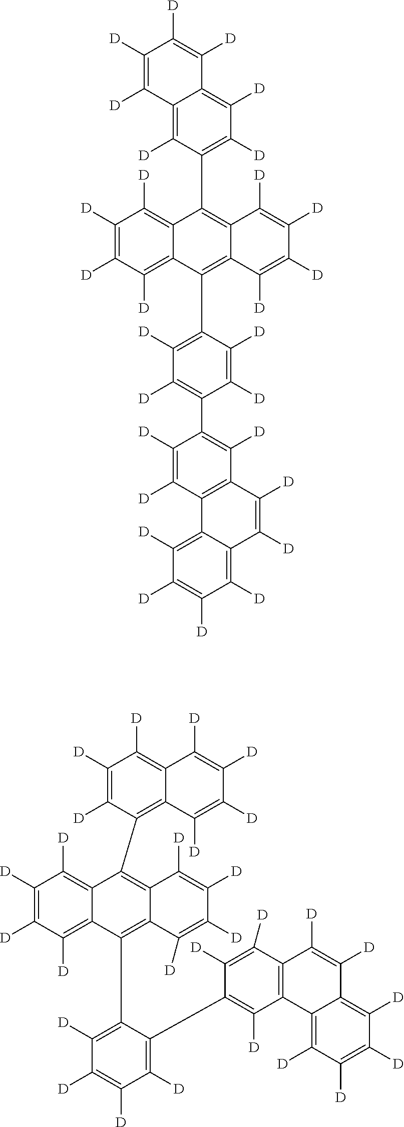 [SMILES: [2H]c1c([2H])c(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c([2H])c([2H])c1-c1c([2H])c([2H])c2c(c1[2H])c([2H])c([2H])c1c([2H])c([2H])c([2H])c([2H])c12 ; [2H]c1c([2H])c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c(-c2c([2H])c([2H])c3c([2H])c([2H])c4c([2H])c([2H])c([2H])c([2H])c4c3c2[2H])c1[2H]]

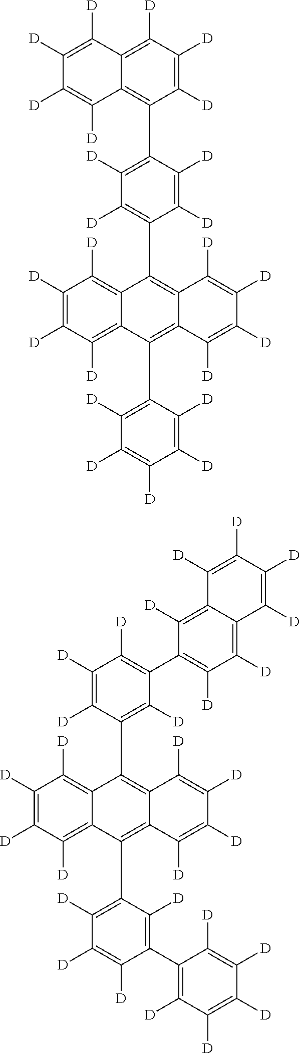 [SMILES: [2H]c1c([2H])c([2H])c(-c2c3c([2H])c([2H])c([2H])c([2H])c3c(-c3c([2H])c([2H])c(-c4c([2H])c([2H])c([2H])c5c([2H])c([2H])c([2H])c([2H])c45)c([2H])c3[2H])c3c([2H])c([2H])c([2H])c([2H])c23)c([2H])c1[2H] ; [2H]c1c([2H])c([2H])c(-c2c([2H])c([2H])c([2H])c(-c3c4c([2H])c([2H])c([2H])c([2H])c4c(-c4c([2H])c([2H])c([2H])c(-c5c([2H])c([2H])c6c([2H])c([2H])c([2H])c([2H])c6c5[2H])c4[2H])c4c([2H])c([2H])c([2H])c([2H])c34)c2[2H])c([2H])c1[2H]]

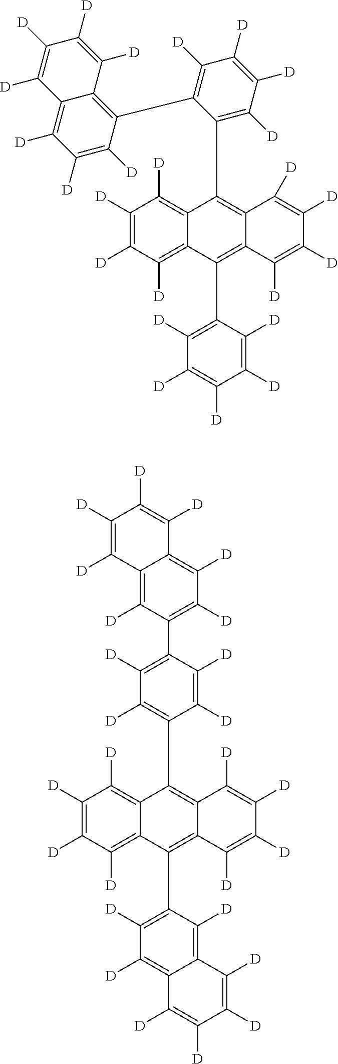 [SMILES: [2H]c1c([2H])c([2H])c(-c2c3c([2H])c([2H])c([2H])c([2H])c3c(-c3c([2H])c([2H])c([2H])c([2H])c3-c3c([2H])c([2H])c([2H])c4c([2H])c([2H])c([2H])c([2H])c34)c3c([2H])c([2H])c([2H])c([2H])c23)c([2H])c1[2H] ; [2H]c1c([2H])c(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c([2H])c([2H])c1-c1c([2H])c([2H])c2c([2H])c([2H])c([2H])c([2H])c2c1[2H]]

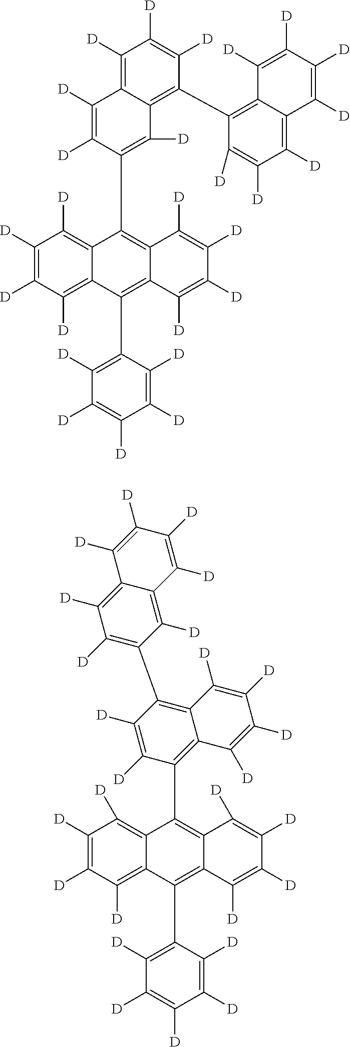

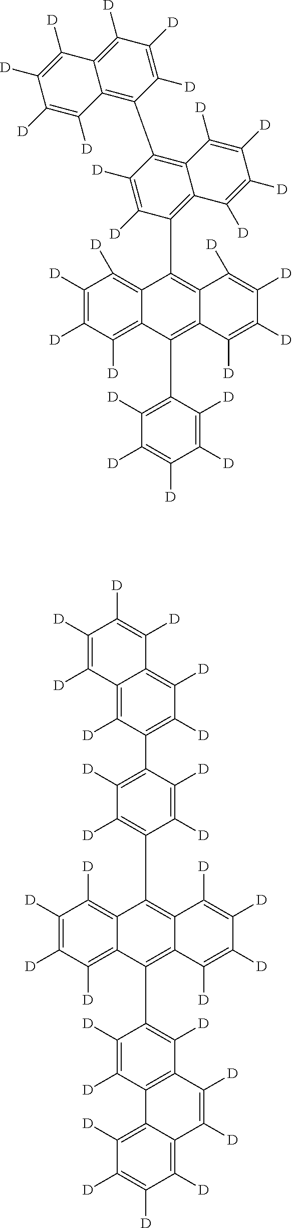 [SMILES: [2H]c1c([2H])c([2H])c(-c2c3c([2H])c([2H])c([2H])c([2H])c3c(-c3c([2H])c([2H])c(-c4c([2H])c([2H])c([2H])c5c([2H])c([2H])c([2H])c([2H])c45)c4c([2H])c([2H])c([2H])c([2H])c34)c3c([2H])c([2H])c([2H])c([2H])c23)c([2H])c1[2H] ; [2H]c1c([2H])c(-c2c3c([2H])c([2H])c([2H])c([2H])c3c(-c3c([2H])c([2H])c4c(c3[2H])c([2H])c([2H])c3c([2H])c([2H])c([2H])c([2H])c34)c3c([2H])c([2H])c([2H])c([2H])c23)c([2H])c([2H])c1-c1c([2H])c([2H])c2c([2H])c([2H])c([2H])c([2H])c2c1[2H]]

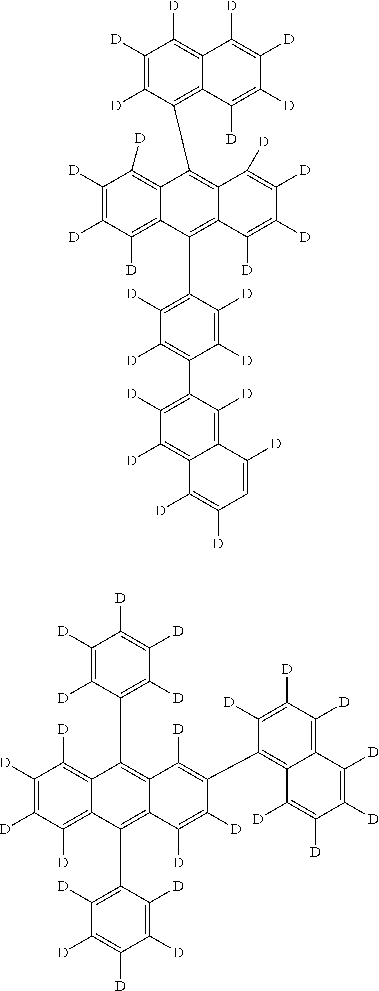 [SMILES: [2H]c1cc([2H])c2c([2H])c(-c3c([2H])c([2H])c(-c4c5c([2H])c([2H])c([2H])c([2H])c5c(-c5c([2H])c([2H])c([2H])c6c([2H])c([2H])c([2H])c([2H])c56)c5c([2H])c([2H])c([2H])c([2H])c45)c([2H])c3[2H])c([2H])c([2H])c2c1[2H] ; [2H]c1c([2H])c([2H])c(-c2c3c([2H])c([2H])c([2H])c([2H])c3c(-c3c([2H])c([2H])c([2H])c([2H])c3[2H])c3c([2H])c(-c4c([2H])c([2H])c([2H])c5c([2H])c([2H])c([2H])c([2H])c45)c([2H])c([2H])c23)c([2H])c1[2H]]

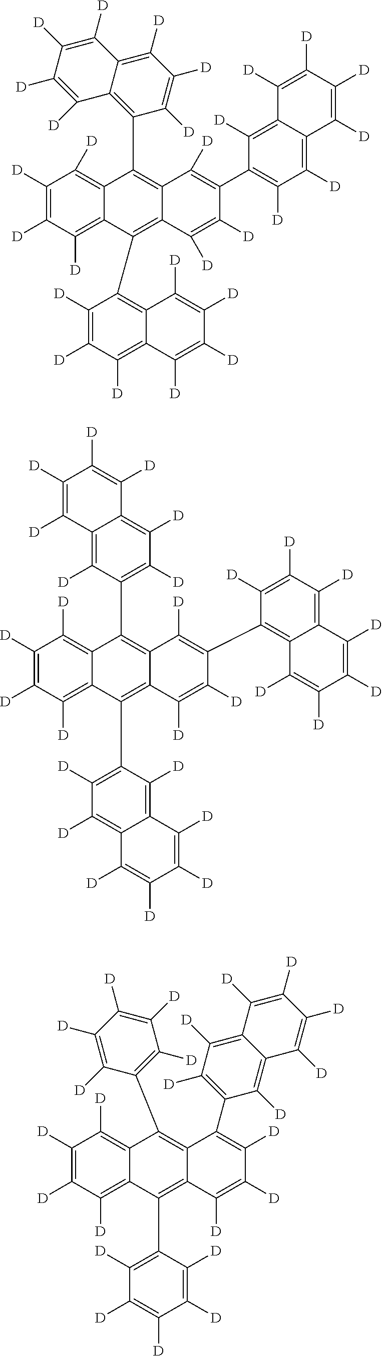

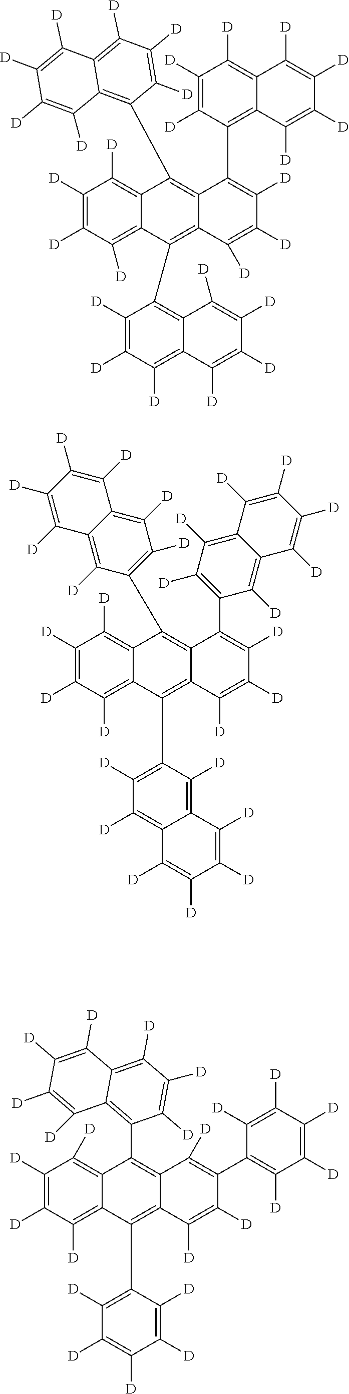

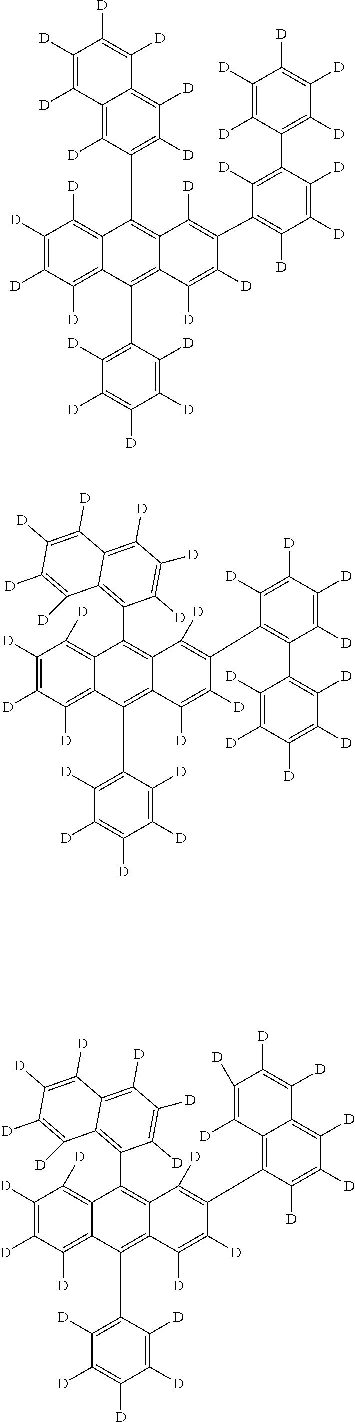

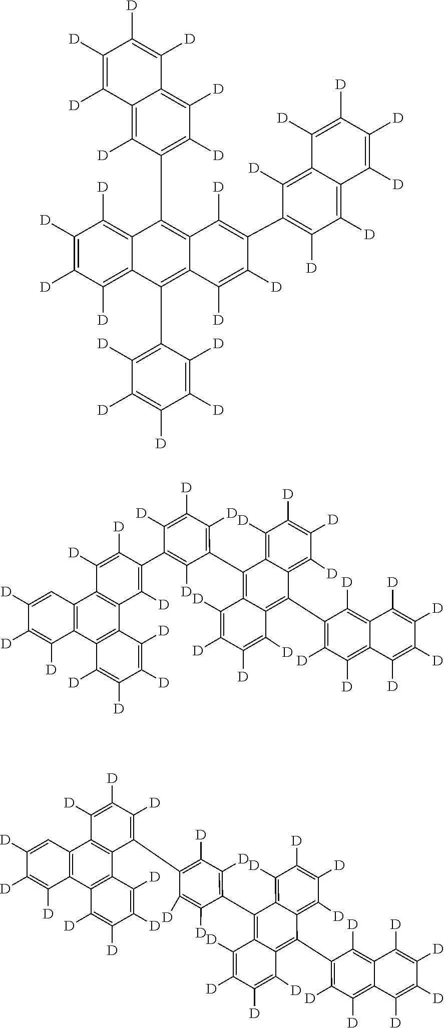

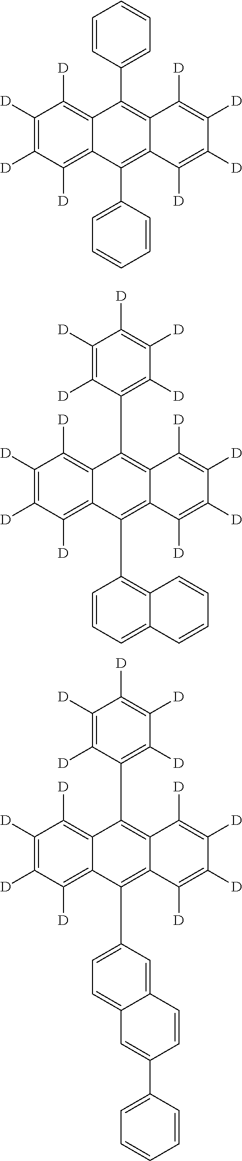

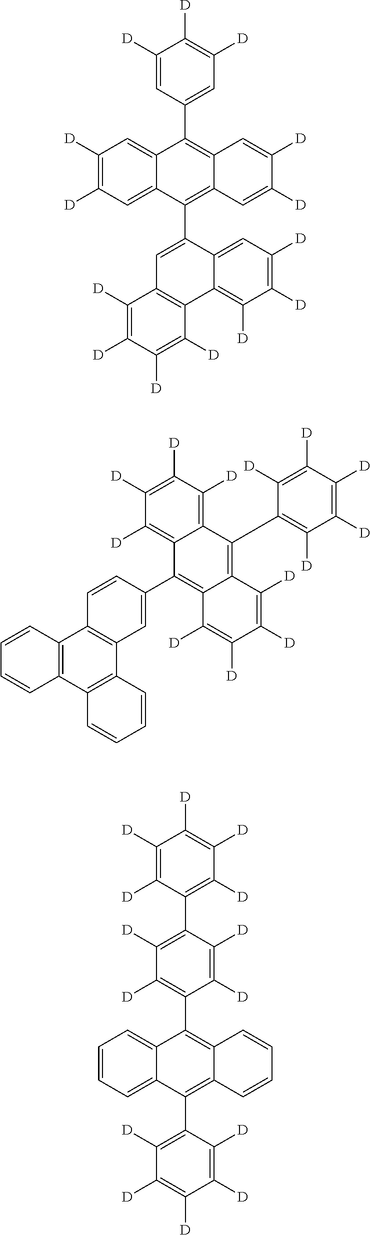 [SMILES: [2H]c1cc2c(-c3cc([2H])c([2H])c([2H])c3)c3cc([2H])c([2H])cc3c(-c3cc4c([2H])c([2H])c([2H])c([2H])c4c4c([2H])c([2H])c([2H])cc34)c2cc1[2H] ; [2H]c1c([2H])c([2H])c(-c2c3c([2H])c([2H])c([2H])c([2H])c3c(-c3ccc4c5ccccc5c5ccccc5c4c3)c3c([2H])c([2H])c([2H])c([2H])c23)c([2H])c1[2H] ; [2H]c1c([2H])c([2H])c(-c2c([2H])c([2H])c(-c3c4ccccc4c(-c4c([2H])c([2H])c([2H])c([2H])c4[2H])c4ccccc34)c([2H])c2[2H])c([2H])c1[2H]]

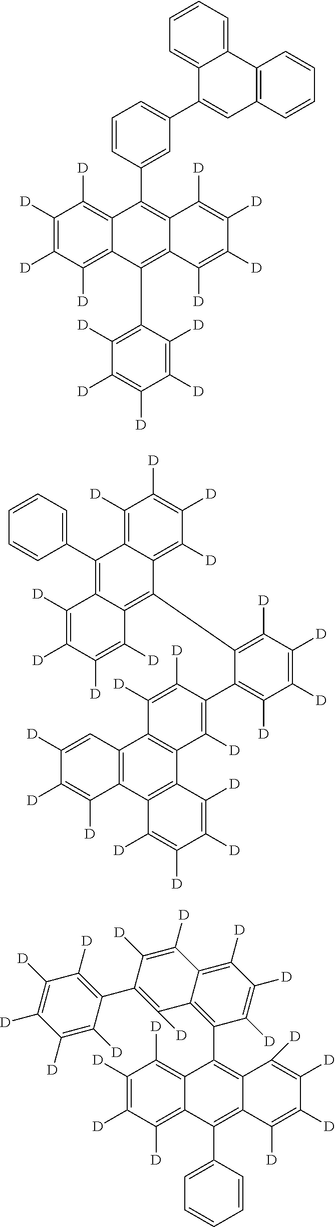

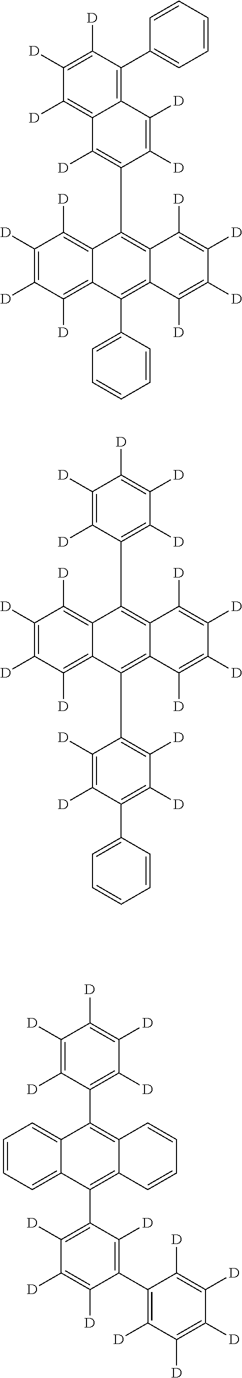

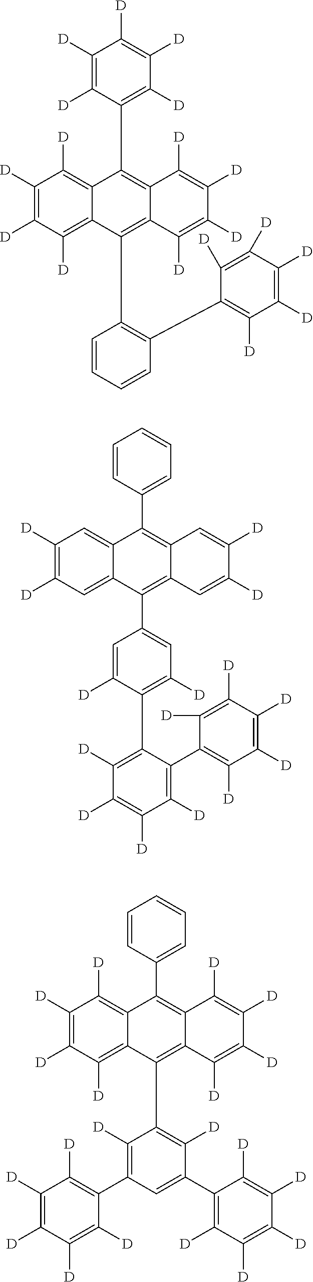

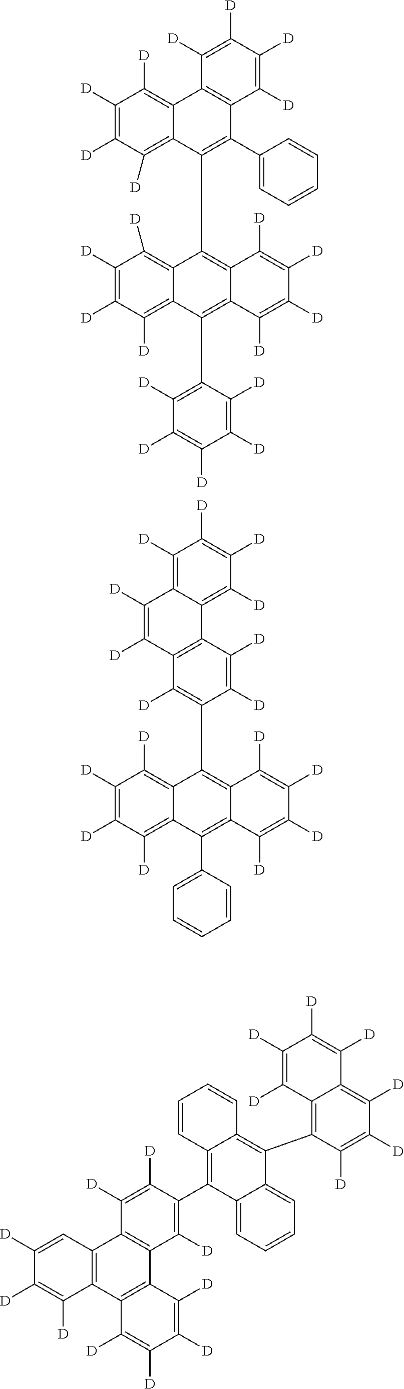

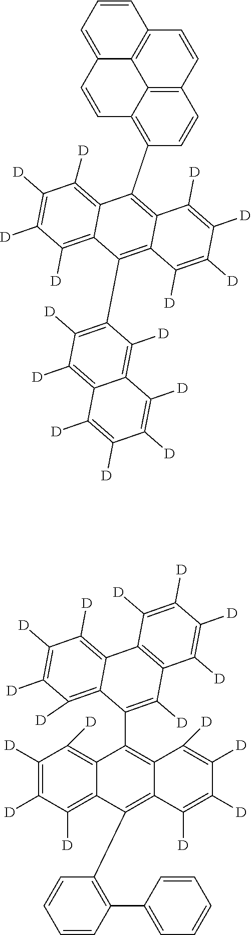 [SMILES: [2H]c1c([2H])c([2H])c2c([2H])c(-c3c4c([2H])c([2H])c([2H])c([2H])c4c(-c4ccc5ccc6cccc7ccc4c5c67)c4c([2H])c([2H])c([2H])c([2H])c34)c([2H])c([2H])c2c1[2H] ; [2H]c1c([2H])c([2H])c2c(-c3c([2H])c4c([2H])c([2H])c([2H])c([2H])c4c4c([2H])c([2H])c([2H])c([2H])c34)c3c([2H])c([2H])c([2H])c([2H])c3c(-c3ccccc3-c3ccccc3)c2c1[2H]]

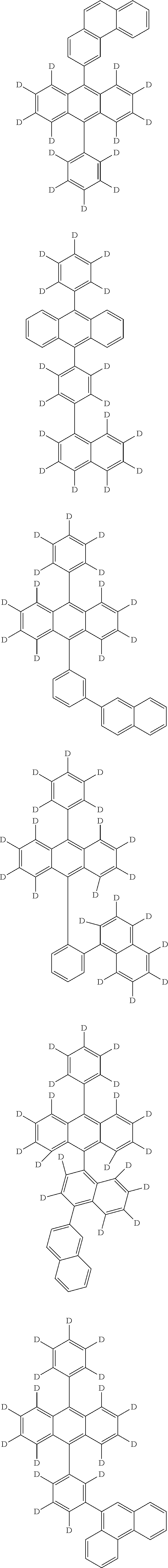

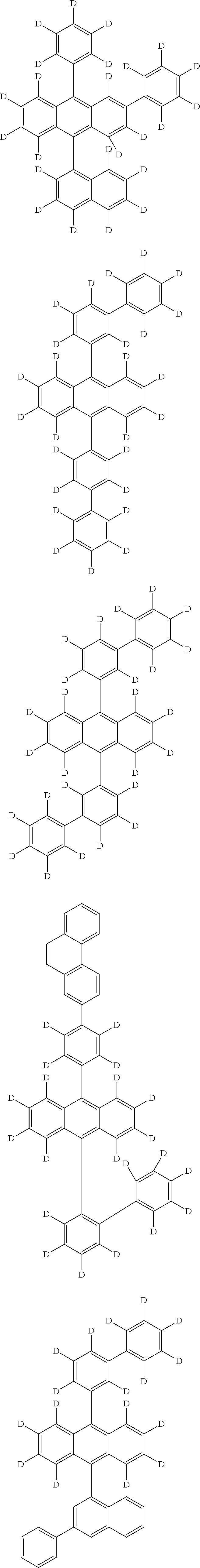

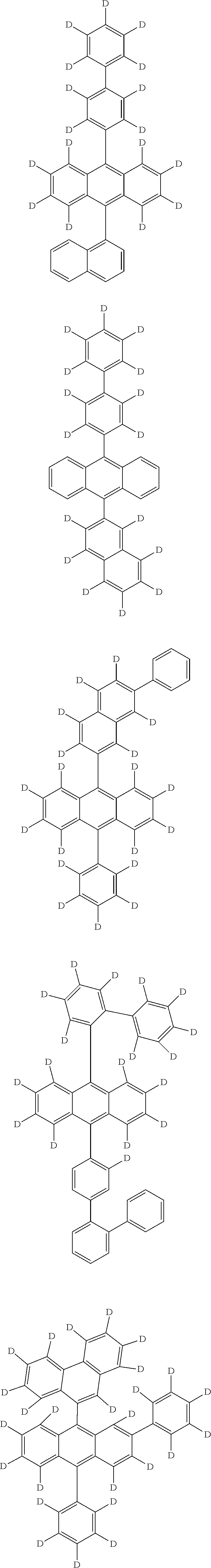

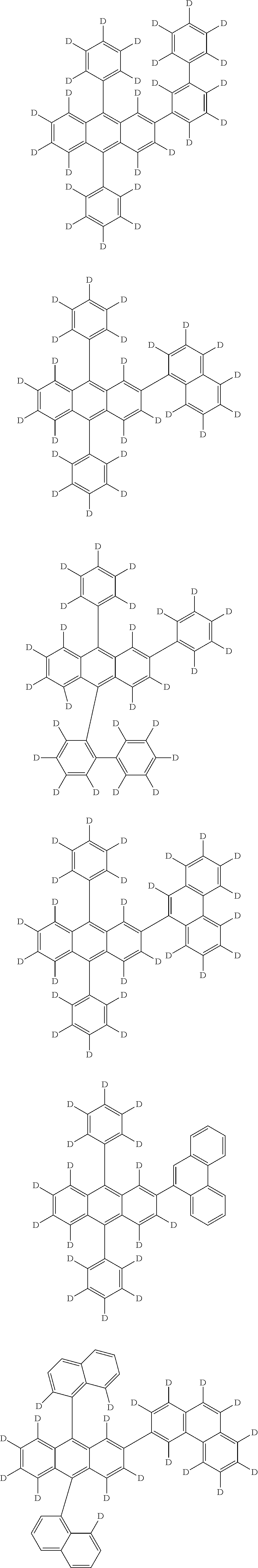

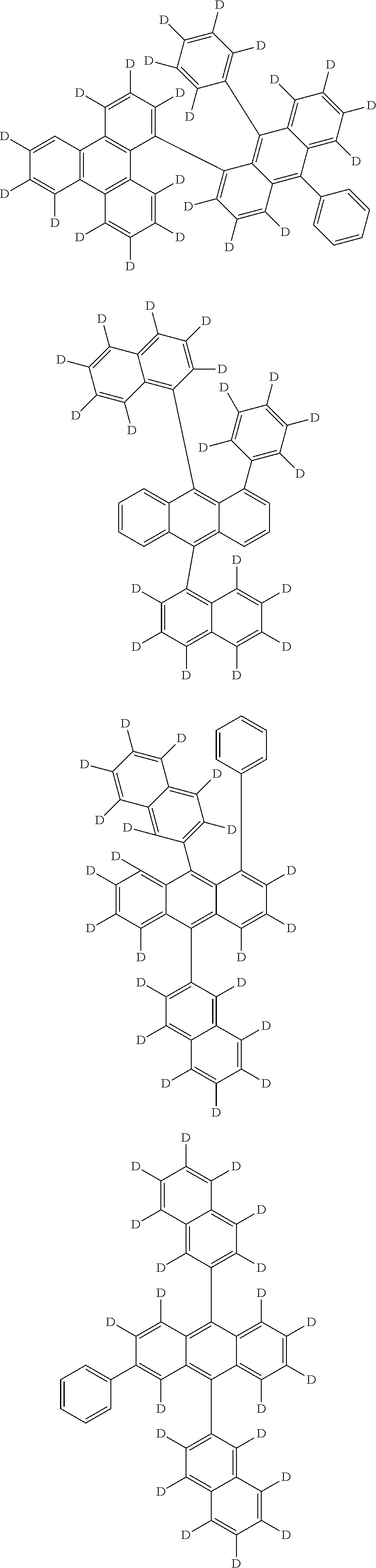

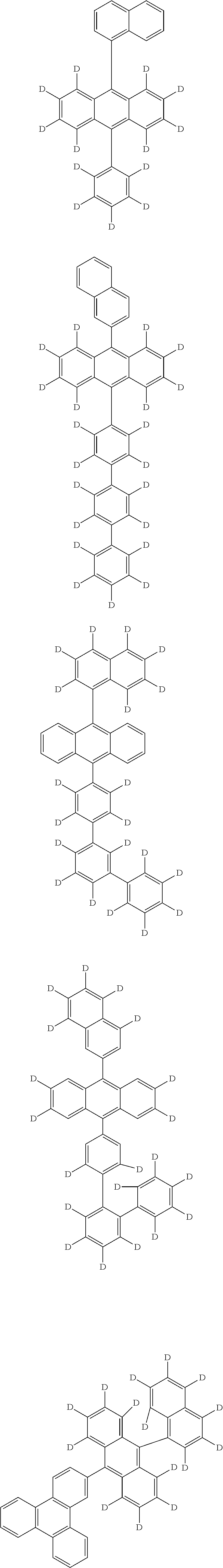

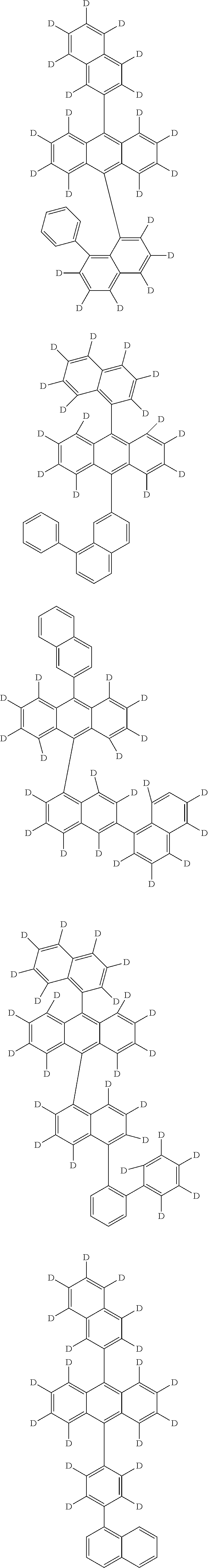

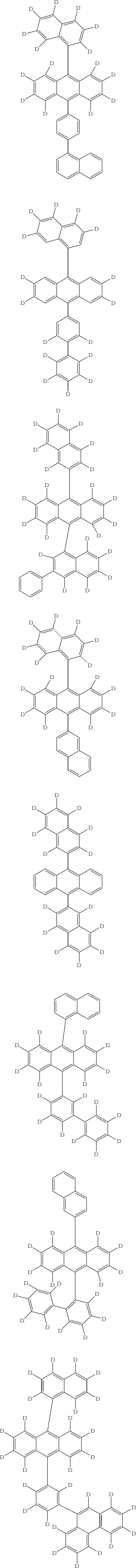

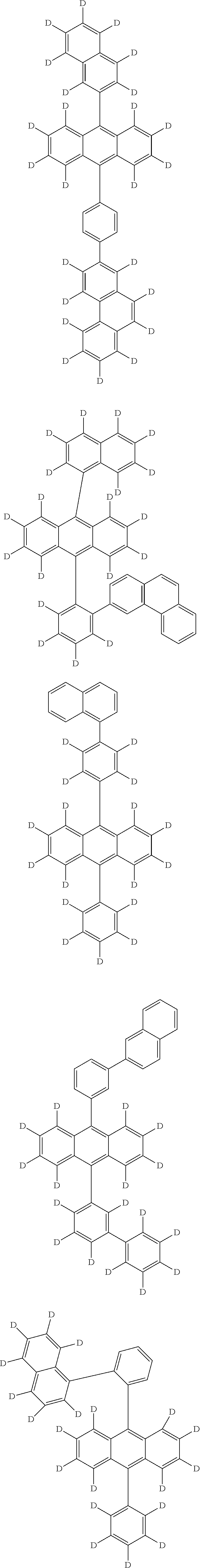

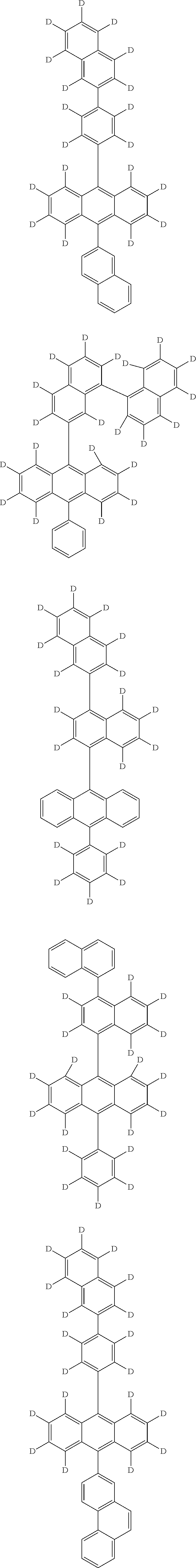

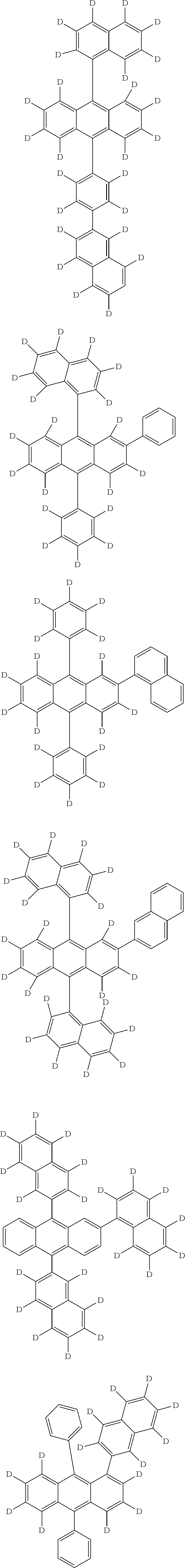

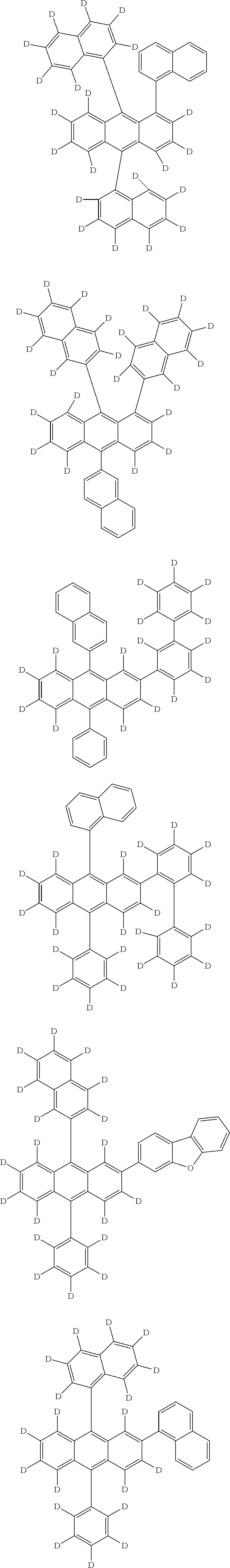

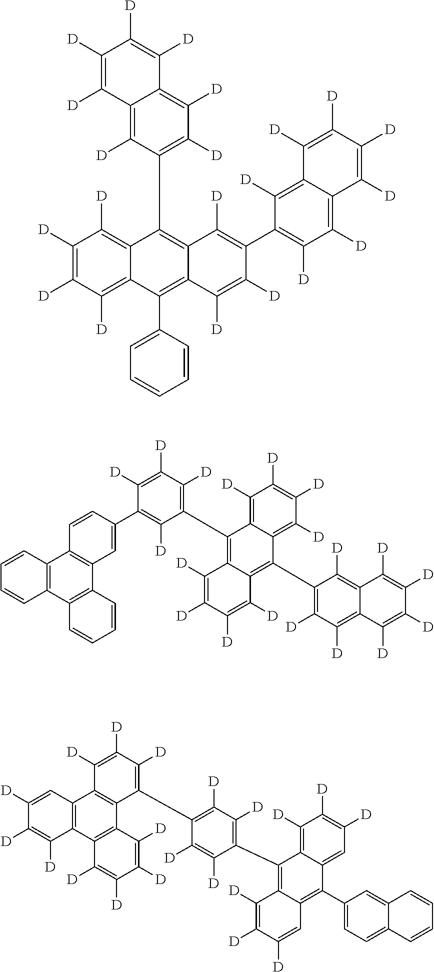

Hereinafter, Chemical Formula 2 will be described.

According to one embodiment of the present specification, at least one of Y1 to Y10 bonds to the * site of Chemical Formula 2-1, and the rest are hydrogen, deuterium, or a substituted or unsubstituted aryl group having 6 to 60 carbon atoms.

According to one embodiment of the present specification, one to three of Y1 to Y10 bond to the * site of Chemical Formula 2-1, and the rest are hydrogen, deuterium, a halogen group, a cyano group, a nitro group, a hydroxyl group, a substituted or unsubstituted alkyl group, a substituted or unsubstituted aryl group, a substituted or unsubstituted cycloalkyl group, a substituted or unsubstituted heteroaryl group, or a substituted or unsubstituted silyl group.

In one embodiment of the present specification, one to three of Y1 to Y10 bond to the * site of Chemical Formula 2-1, and the rest are hydrogen, deuterium, a halogen group, a cyano group, a nitro group, a hydroxyl group, a substituted or unsubstituted alkyl group having 1 to 20 carbon atoms, a substituted or unsubstituted aryl group having 6 to 60 carbon atoms, a substituted or unsubstituted cycloalkyl group having 3 to 60 carbon atoms, a substituted or unsubstituted heteroaryl group having 2 to 60 carbon atoms, or a substituted or unsubstituted silyl group.

In another embodiment, Y7, Y8 or Y9 bonds to the * site of Chemical Formula 2-1, and the rest are hydrogen, deuterium, a halogen group, a cyano group, a nitro group, a hydroxyl group, a substituted or unsubstituted alkyl group, a substituted or unsubstituted aryl group, a substituted or unsubstituted cycloalkyl group, a substituted or unsubstituted heteroaryl group, or a substituted or unsubstituted silyl group.

According to another embodiment, Y7 and Y9 bond to the * site of Chemical Formula 2-1, and the rest are hydrogen, deuterium, a halogen group, a cyano group, a nitro group, a hydroxyl group, a substituted or unsubstituted alkyl group, a substituted or unsubstituted aryl group, a substituted or unsubstituted cycloalkyl group, a substituted or unsubstituted heteroaryl group, or a substituted or unsubstituted silyl group.

According to another embodiment, Y9 and Y10 bond to the * site of Chemical Formula 2-1, and the rest are hydrogen, deuterium, a halogen group, a cyano group, a nitro group, a hydroxyl group, a substituted or unsubstituted alkyl group, a substituted or unsubstituted aryl group, a substituted or unsubstituted cycloalkyl group, a substituted or unsubstituted heteroaryl group, or a substituted or unsubstituted silyl group.

According to one embodiment of the present specification, substituents not bonding to Chemical Formula 2-1 among Y1 to Y10 are the same as or different from each other, and each independently is hydrogen, deuterium, or a substituted or unsubstituted aryl group having 6 to 30 carbon atoms. The substituents not bonding to Chemical Formula 2-1 among Y1 to Y10 can be substituted with deuterium.

According to another embodiment, substituents not bonding to Chemical Formula 2-1 among Y1 to Y10 are the same as or different from each other, and each independently is hydrogen, deuterium, a substituted or unsubstituted phenyl group, a substituted or unsubstituted biphenyl group, a substituted or unsubstituted terphenyl group, a substituted or unsubstituted naphthyl group, a substituted or unsubstituted phenanthrenyl group, or a substituted or unsubstituted triphenylenyl group, and the substituents can be further substituted with deuterium, a phenyl group unsubstituted or substituted with deuterium, a biphenyl group unsubstituted or substituted with deuterium, a terphenyl group unsubstituted or substituted with deuterium, a naphthyl group unsubstituted or substituted with deuterium, a phenanthrenyl unsubstituted or substituted with group deuterium, or a triphenylenyl group unsubstituted or substituted with deuterium.

According to one embodiment of the present specification, q is an integer of 1 to 5, and when q is 2 or greater, the two or more L2s are the same as or different from each other.

In another embodiment, q is an integer of 1 to 3, and when q is 2 or greater, the two or more L2s are the same as or different from each other.

According to one embodiment of the present specification, Chemical Formula 2 is the following Chemical Formulae 2-A to 2-E:

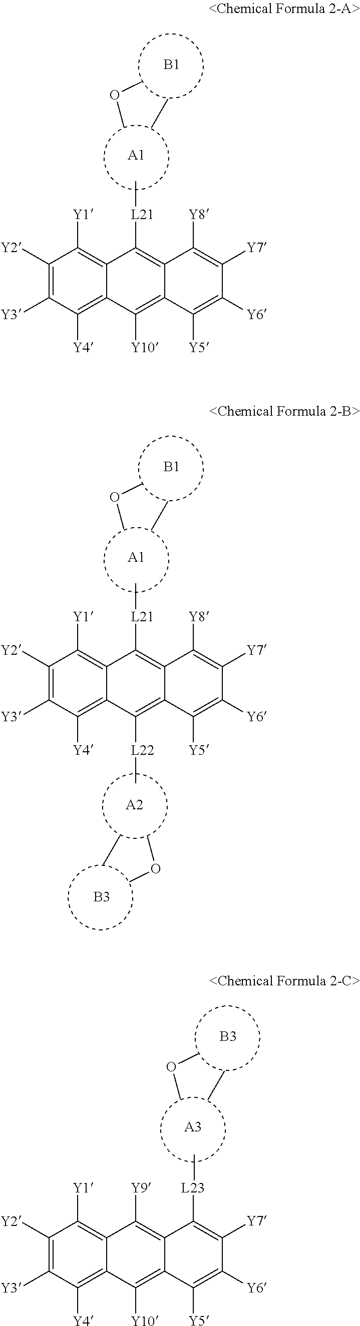

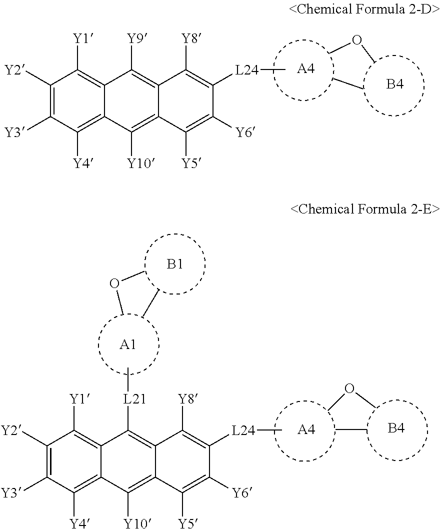

wherein in Chemical Formulae 2-A to 2-E:
A1 to A4 and B1 to B4 are the same as or different from each other, and each independently is a substituted or unsubstituted aromatic hydrocarbon ring; or a substituted or unsubstituted aromatic heteroring;
Y1′ to Y10′ are the same as or different from each other, and each independently is hydrogen, deuterium, a halogen group, a cyano group, a nitro group, a hydroxyl group, a substituted or unsubstituted alkyl group, a substituted or unsubstituted aryl group, a substituted or unsubstituted cycloalkyl group, a substituted or unsubstituted heteroaryl group, or a substituted or unsubstituted silyl group; and
L21 to L24 are the same as or different from each other, and each independently is a direct bond, a substituted or unsubstituted arylene group, or a substituted or unsubstituted heteroarylene group.

According to one embodiment of the present specification, L2 is a direct bond, a substituted or unsubstituted arylene group having 6 to 60 carbon atoms, or a substituted or unsubstituted heteroarylene group having 2 to 60 carbon atoms. L2 can be substituted with deuterium.

In another embodiment, L2 is a direct bond, a substituted or unsubstituted arylene group having 6 to 30 carbon atoms, or a substituted or unsubstituted heteroarylene group having 2 to 30 carbon atoms.

According to another embodiment, L2 is a direct bond, a substituted or unsubstituted phenylene group, a substituted or unsubstituted biphenylylene group, a substituted or unsubstituted naphthylene group, a substituted or unsubstituted phenanthrenylene group, or a substituted or unsubstituted triphenylenylene group.

In another embodiment, L2 is a direct bond, a phenylene group unsubstituted or substituted with deuterium, a biphenylylene group unsubstituted or substituted with deuterium, a naphthylene group unsubstituted or substituted with deuterium, a phenanthrenylene group unsubstituted or substituted with deuterium, or a triphenylenylene group unsubstituted or substituted with deuterium.

According to one embodiment of the present specification, A and B are the same as or different from each other, and each independently is a substituted or unsubstituted aromatic hydrocarbon ring having 6 to 60 carbon atoms, or a substituted or unsubstituted aromatic heteroring having 2 to 60 carbon atoms.

In one embodiment of the present specification, A and B are the same as or different from each other, and each independently is an aromatic hydrocarbon ring having 6 to 60 carbon atoms that is unsubstituted or substituted with one or more substituents selected from the group consisting of deuterium and an aryl that group is unsubstituted or substituted with deuterium; or an aromatic heteroring having 2 to 60 carbon atoms that is unsubstituted or substituted with one or more substituents selected from the group consisting of deuterium and an aryl group that is unsubstituted or substituted with deuterium.

According to another embodiment, A and B are the same as or different from each other, and each independently is an aromatic hydrocarbon ring having 6 to 60 carbon atoms that is unsubstituted or substituted with one or more substituents selected from the group consisting of deuterium and an aryl group having 6 to 30 carbon atoms that is unsubstituted or substituted with deuterium; or an aromatic heteroring having 2 to 60 carbon atoms that it unsubstituted or substituted with one or more substituents selected from the group consisting of deuterium and an aryl group having 6 to 30 carbon atoms that is unsubstituted or substituted with deuterium.

In another embodiment, A and B are the same as or different from each other, and each independently is a substituted or unsubstituted benzene, substituted or unsubstituted naphthalene, substituted or unsubstituted phenanthrene, substituted or unsubstituted triphenylene, or substituted or unsubstituted dibenzofuran.

According to another embodiment, A and B are the same as or different from each other, and each independently is a benzene that is unsubstituted or substituted with one or more substituents selected from the group consisting of deuterium and an aryl group having 6 to 30 carbon atoms that is unsubstituted or substituted with deuterium; naphthalene that is unsubstituted or substituted with one or more substituents selected from the group consisting of deuterium and an aryl group having 6 to 30 carbon atoms that is unsubstituted or substituted with deuterium; phenanthrene that is unsubstituted or substituted with one or more substituents selected from the group consisting of deuterium and an aryl group having 6 to 30 carbon atoms that is unsubstituted or substituted with deuterium; triphenylene that is unsubstituted or substituted with one or more substituents selected from the group consisting of deuterium and an aryl group having 6 to 30 carbon atoms that is unsubstituted or substituted with deuterium; or dibenzofuran that is unsubstituted or substituted with one or more substituents selected from the group consisting of deuterium and an aryl group having 6 to 30 carbon atoms that is unsubstituted or substituted with deuterium.

According to one embodiment of the present specification, L21 to L24 are the same as or different from each other, and each independently is a direct bond, a substituted or unsubstituted arylene group having 6 to 60 carbon atoms, or a substituted or unsubstituted heteroarylene group having 2 to 60 carbon atoms. L21 to L24 can be substituted with deuterium.

In another embodiment, L21 to L24 are the same as or different from each other, and each independently is a direct bond, a substituted or unsubstituted arylene group having 6 to 30 carbon atoms, or a substituted or unsubstituted heteroarylene group having 2 to 30 carbon atoms.

According to another embodiment, L21 to L24 are the same as or different from each other, and each independently is a direct bond, a substituted or unsubstituted phenylene group, a substituted or unsubstituted biphenylylene group, a substituted or unsubstituted naphthylene group, a substituted or unsubstituted phenanthrenylene group, or a substituted or unsubstituted triphenylenylene group.

In another embodiment, L21 to L24 are the same as or different from each other, and each independently is a direct bond, a phenylene group that is unsubstituted or substituted with deuterium, a biphenylylene group that is unsubstituted or substituted with deuterium, a naphthylene group that is unsubstituted or substituted with deuterium, a phenanthrenylene group that is unsubstituted or substituted with deuterium, or a triphenylenylene group that is unsubstituted or substituted with deuterium.

According to one embodiment of the present specification, A1 to A4 and B1 to B4 are the same as or different from each other, and each independently is a substituted or unsubstituted aromatic hydrocarbon ring having 6 to 60 carbon atoms, or a substituted or unsubstituted aromatic heteroring having 2 to 60 carbon atoms.

In one embodiment of the present specification, A1 to A4 and B1 to B4 are the same as or different from each other, and each independently is an aromatic hydrocarbon ring having 6 to 60 carbon atoms that is unsubstituted or substituted with one or more substituents selected from the group consisting of deuterium and an aryl group that is unsubstituted or substituted with deuterium; or an aromatic heteroring having 2 to 60 carbon atoms that is unsubstituted or substituted with one or more substituents selected from the group consisting of deuterium and an aryl group that is unsubstituted or substituted with deuterium.

According to another embodiment, A1 to A4 and B1 to B4 are the same as or different from each other, and each independently is an aromatic hydrocarbon ring having 6 to 60 carbon atoms that is unsubstituted or substituted with one or more substituents selected from the group consisting of deuterium and an aryl group having 6 to 30 carbon atoms that is unsubstituted or substituted with deuterium; or an aromatic heteroring having 2 to 60 carbon atoms that is unsubstituted or substituted with one or more substituents selected from the group consisting of deuterium and an aryl group having 6 to 30 carbon atoms that is unsubstituted or substituted with deuterium.

In another embodiment, A1 to A4 and B1 to B4 are the same as or different from each other, and each independently is a substituted or unsubstituted benzene, substituted or unsubstituted naphthalene, substituted or unsubstituted phenanthrene, substituted or unsubstituted triphenylene, or substituted or unsubstituted dibenzofuran.

According to another embodiment, A1 to A4 and B1 to B4 are the same as or different from each other, and each independently is a benzene that is unsubstituted or substituted with one or more substituents selected from the group consisting of deuterium and an aryl group having 6 to 30 carbon atoms that is unsubstituted or substituted with deuterium; naphthalene that is unsubstituted or substituted with one or more substituents selected from the group consisting of deuterium and an aryl group having 6 to 30 carbon atoms that is unsubstituted or substituted with deuterium; phenanthrene that is unsubstituted or substituted with one or more substituents selected from the group consisting of deuterium and an aryl group having 6 to 30 carbon atoms that is unsubstituted or substituted with deuterium; triphenylene that is unsubstituted or substituted with one or more substituents selected from the group consisting of deuterium and an aryl group having 6 to 30 carbon atoms that is unsubstituted or substituted with deuterium; or dibenzofuran that is unsubstituted or substituted with one or more substituents selected from the group consisting of deuterium and an aryl group having 6 to 30 carbon atoms that is unsubstituted or substituted with deuterium.

According to one embodiment of the present specification, Y1′ to Y10′ are the same as or different from each other, and each independently is hydrogen, deuterium, or a substituted or unsubstituted aryl group having 6 to 60 carbon atoms. Y1′ to Y10′ can be substituted with deuterium.

According to another embodiment, Y1′ to Y10′ are the same as or different from each other, and each independently is hydrogen, deuterium, a substituted or unsubstituted phenyl group, a substituted or unsubstituted biphenyl group, a substituted or unsubstituted terphenyl group, a substituted or unsubstituted naphthyl group, a substituted or unsubstituted phenanthrenyl group or a substituted or unsubstituted triphenylenyl group, and the substituents can be further substituted with deuterium, a phenyl group that is unsubstituted or substituted with deuterium, a biphenyl group that is unsubstituted or substituted with deuterium, a terphenyl group that is unsubstituted or substituted with deuterium, a naphthyl group that is unsubstituted or substituted with deuterium, a phenanthrenyl group that is unsubstituted or substituted with deuterium, or a triphenylenyl group that is unsubstituted or substituted with deuterium.

In one embodiment of the present specification, Chemical Formula 2 can be selected from among the following compounds, but is not limited thereto, and the bonding position of deuterium is not limited. In addition, when Chemical Formula 2 does not include deuterium, it can be a structure excluding deuterium (-D) from the following compounds, however, the structure is not limited thereto:

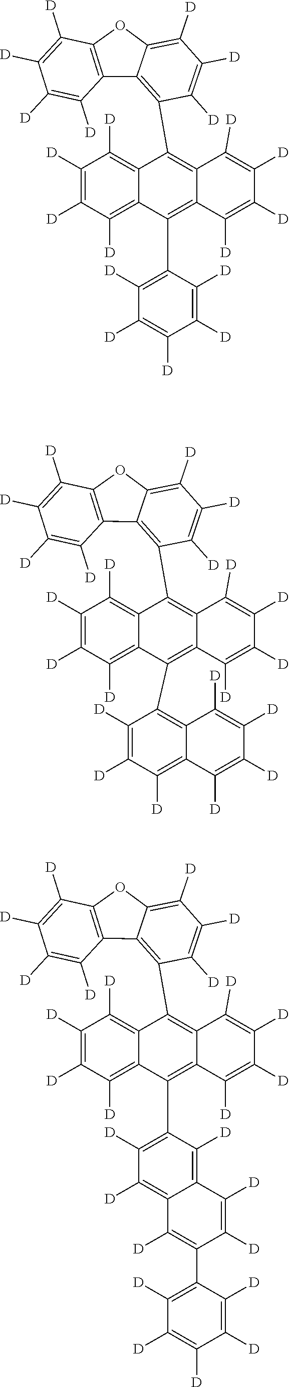

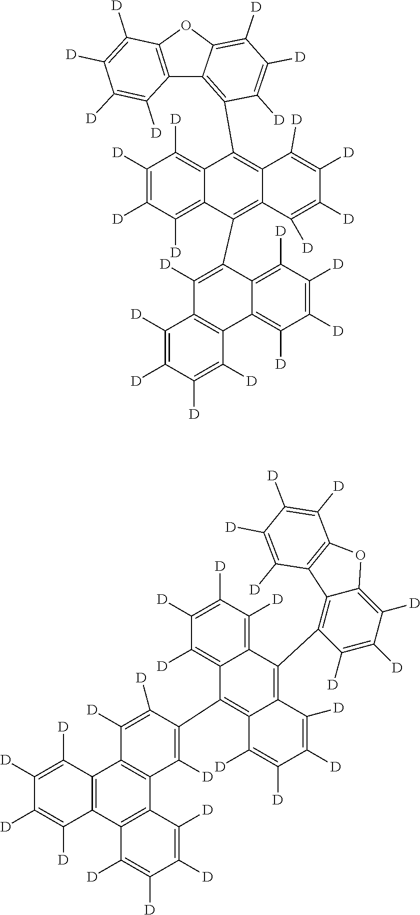 [SMILES: [2H]c1c([2H])c([2H])c2c(oc3c([2H])c([2H])c([2H])c(-c4c5c([2H])c([2H])c([2H])c([2H])c5c(-c5c([2H])c6c([2H])c([2H])c([2H])c([2H])c6c6c([2H])c([2H])c([2H])c([2H])c56)c5c([2H])c([2H])c([2H])c([2H])c45)c32)c1[2H] ; [2H]c1c([2H])c([2H])c2c(oc3c([2H])c([2H])c([2H])c(-c4c5c([2H])c([2H])c([2H])c([2H])c5c(-c5c([2H])c([2H])c6c7c([2H])c([2H])c([2H])c([2H])c7c7c([2H])c([2H])c([2H])c([2H])c7c6c5[2H])c5c([2H])c([2H])c([2H])c([2H])c45)c32)c1[2H]]

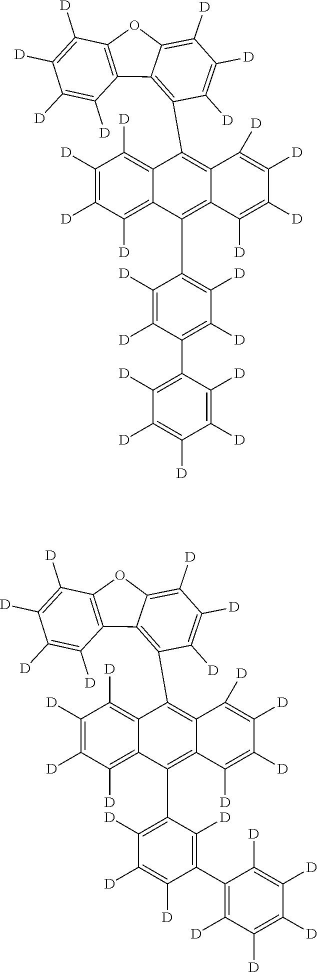 [SMILES: [2H]c1c([2H])c([2H])c(-c2c([2H])c([2H])c(-c3c4c([2H])c([2H])c([2H])c([2H])c4c(-c4c([2H])c([2H])c([2H])c5oc6c([2H])c([2H])c([2H])c([2H])c6c45)c4c([2H])c([2H])c([2H])c([2H])c34)c([2H])c2[2H])c([2H])c1[2H] ; [2H]c1c([2H])c([2H])c(-c2c([2H])c([2H])c([2H])c(-c3c4c([2H])c([2H])c([2H])c([2H])c4c(-c4c([2H])c([2H])c([2H])c5oc6c([2H])c([2H])c([2H])c([2H])c6c45)c4c([2H])c([2H])c([2H])c([2H])c34)c2[2H])c([2H])c1[2H]]

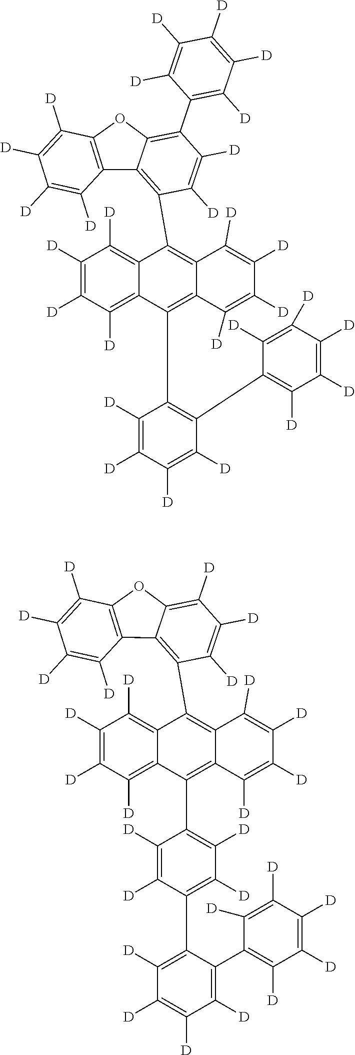 [SMILES: [2H]c1c([2H])c([2H])c(-c2c([2H])c([2H])c([2H])c([2H])c2-c2c3c([2H])c([2H])c([2H])c([2H])c3c(-c3c([2H])c([2H])c(-c4c([2H])c([2H])c([2H])c([2H])c4[2H])c4oc5c([2H])c([2H])c([2H])c([2H])c5c34)c3c([2H])c([2H])c([2H])c([2H])c23)c([2H])c1[2H] ; [2H]c1c([2H])c([2H])c(-c2c([2H])c([2H])c([2H])c([2H])c2-c2c([2H])c([2H])c(-c3c4c([2H])c([2H])c([2H])c([2H])c4c(-c4c([2H])c([2H])c([2H])c5oc6c([2H])c([2H])c([2H])c([2H])c6c45)c4c([2H])c([2H])c([2H])c([2H])c34)c([2H])c2[2H])c([2H])c1[2H]]

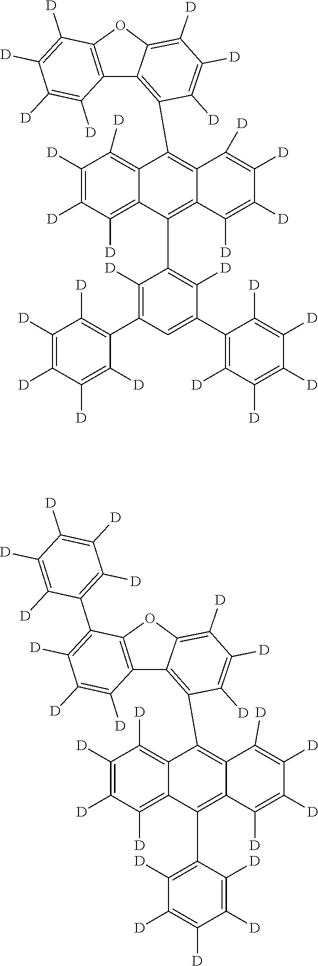 [SMILES: [2H]c1c([2H])c([2H])c(-c2cc(-c3c([2H])c([2H])c([2H])c([2H])c3[2H])c([2H])c(-c3c4c([2H])c([2H])c([2H])c([2H])c4c(-c4c([2H])c([2H])c([2H])c5oc6c([2H])c([2H])c([2H])c([2H])c6c45)c4c([2H])c([2H])c([2H])c([2H])c34)c2[2H])c([2H])c1[2H] ; [2H]c1c([2H])c([2H])c(-c2c([2H])c([2H])c([2H])c3c2oc2c([2H])c([2H])c([2H])c(-c4c5c([2H])c([2H])c([2H])c([2H])c5c(-c5c([2H])c([2H])c([2H])c([2H])c5[2H])c5c([2H])c([2H])c([2H])c([2H])c45)c23)c([2H])c1[2H]]

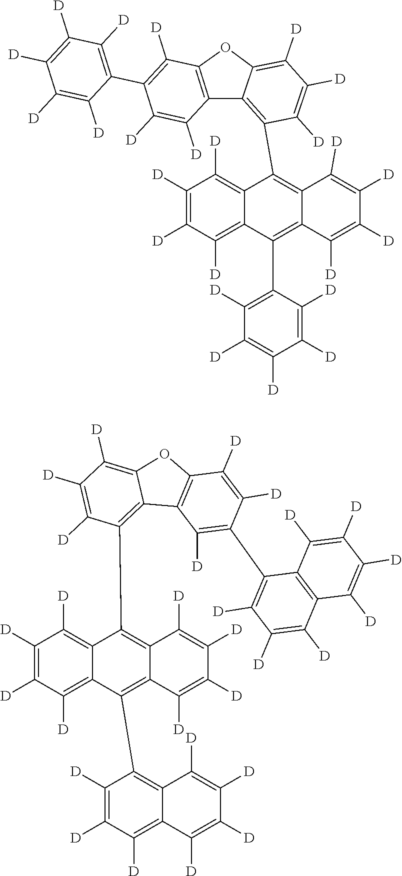 [SMILES: [2H]c1c([2H])c([2H])c(-c2c([2H])c([2H])c3c(oc4c([2H])c([2H])c([2H])c(-c5c6c([2H])c([2H])c([2H])c([2H])c6c(-c6c([2H])c([2H])c([2H])c([2H])c6[2H])c6c([2H])c([2H])c([2H])c([2H])c56)c43)c2[2H])c([2H])c1[2H] ; [2H]c1c(-c2c([2H])c([2H])c([2H])c3c([2H])c([2H])c([2H])c([2H])c23)c([2H])c2c(oc3c([2H])c([2H])c([2H])c(-c4c5c([2H])c([2H])c([2H])c([2H])c5c(-c5c([2H])c([2H])c([2H])c6c([2H])c([2H])c([2H])c([2H])c56)c5c([2H])c([2H])c([2H])c([2H])c45)c32)c1[2H]]

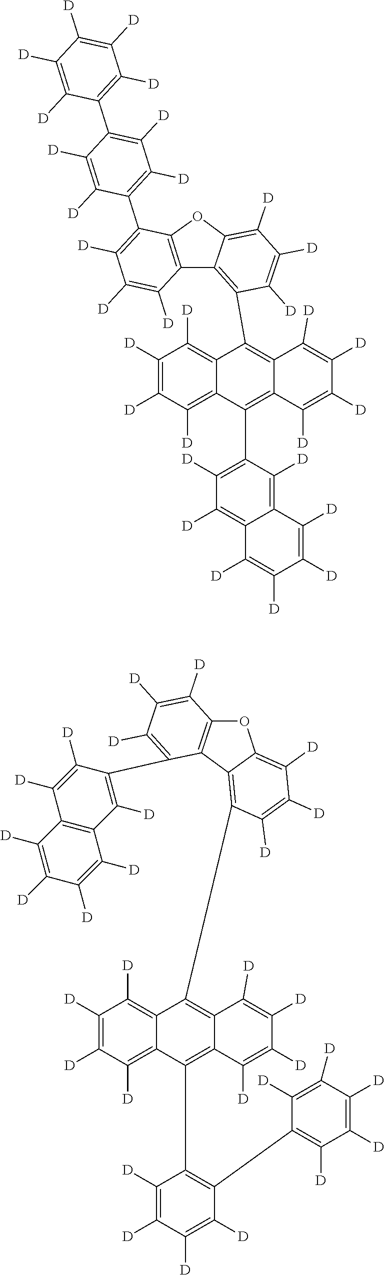

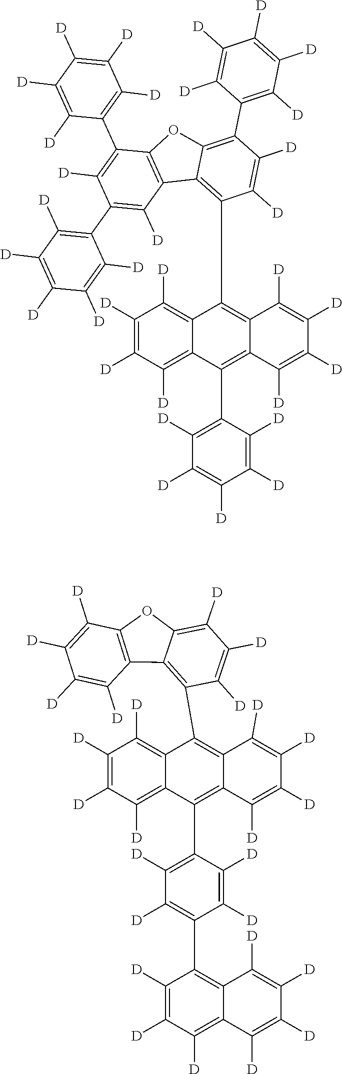 [SMILES: [2H]c1c([2H])c([2H])c(-c2c([2H])c(-c3c([2H])c([2H])c([2H])c([2H])c3[2H])c3oc4c(-c5c([2H])c([2H])c([2H])c([2H])c5[2H])c([2H])c([2H])c(-c5c6c([2H])c([2H])c([2H])c([2H])c6c(-c6c([2H])c([2H])c([2H])c([2H])c6[2H])c6c([2H])c([2H])c([2H])c([2H])c56)c4c3c2[2H])c([2H])c1[2H] ; [2H]c1c([2H])c(-c2c3c([2H])c([2H])c([2H])c([2H])c3c(-c3c([2H])c([2H])c([2H])c4oc5c([2H])c([2H])c([2H])c([2H])c5c34)c3c([2H])c([2H])c([2H])c([2H])c23)c([2H])c([2H])c1-c1c([2H])c([2H])c([2H])c2c([2H])c([2H])c([2H])c([2H])c12]

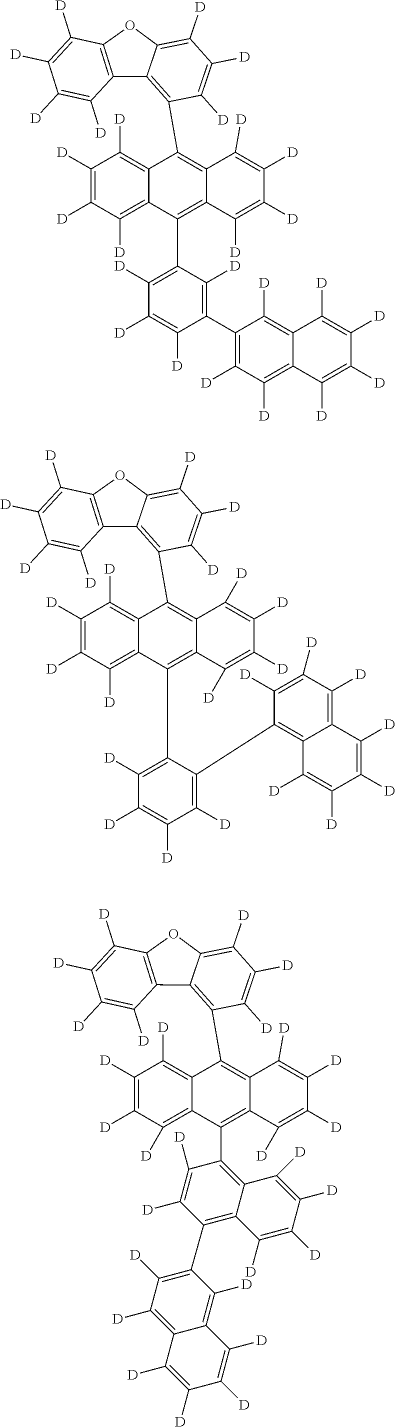

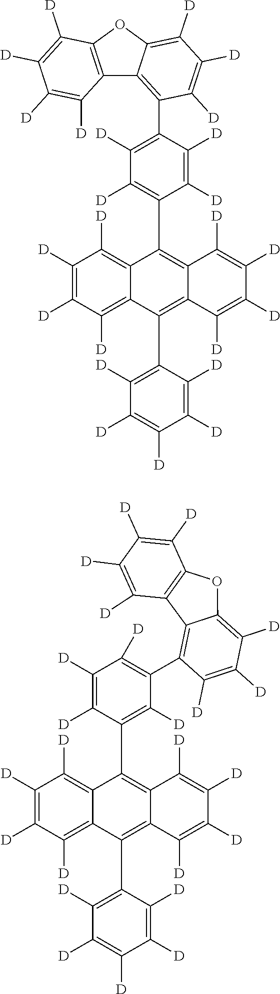 [SMILES: [2H]c1c([2H])c([2H])c(-c2c3c([2H])c([2H])c([2H])c([2H])c3c(-c3c([2H])c([2H])c(-c4c([2H])c([2H])c([2H])c5oc6c([2H])c([2H])c([2H])c([2H])c6c45)c([2H])c3[2H])c3c([2H])c([2H])c([2H])c([2H])c23)c([2H])c1[2H] ; [2H]c1c([2H])c([2H])c(-c2c3c([2H])c([2H])c([2H])c([2H])c3c(-c3c([2H])c([2H])c([2H])c(-c4c([2H])c([2H])c([2H])c5oc6c([2H])c([2H])c([2H])c([2H])c6c45)c3[2H])c3c([2H])c([2H])c([2H])c([2H])c23)c([2H])c1[2H]]

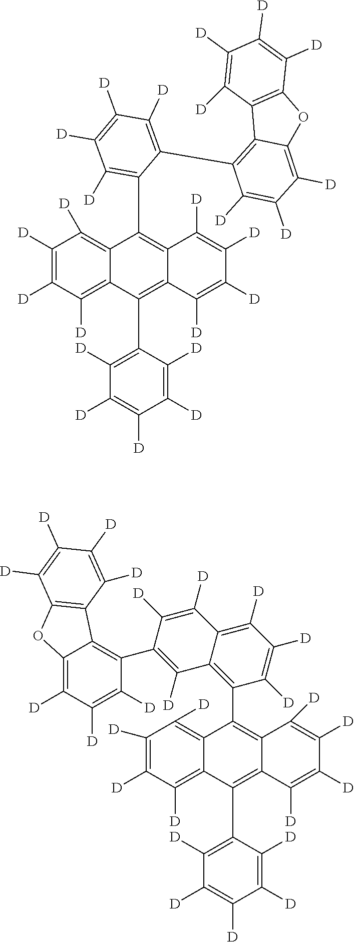 [SMILES: [2H]c1c([2H])c([2H])c(-c2c3c([2H])c([2H])c([2H])c([2H])c3c(-c3c([2H])c([2H])c([2H])c([2H])c3-c3c([2H])c([2H])c([2H])c4oc5c([2H])c([2H])c([2H])c([2H])c5c34)c3c([2H])c([2H])c([2H])c([2H])c23)c([2H])c1[2H] ; [2H]c1c([2H])c([2H])c(-c2c3c([2H])c([2H])c([2H])c([2H])c3c(-c3c([2H])c([2H])c([2H])c4c([2H])c([2H])c(-c5c([2H])c([2H])c([2H])c6oc7c([2H])c([2H])c([2H])c([2H])c7c56)c([2H])c34)c3c([2H])c([2H])c([2H])c([2H])c23)c([2H])c1[2H]]

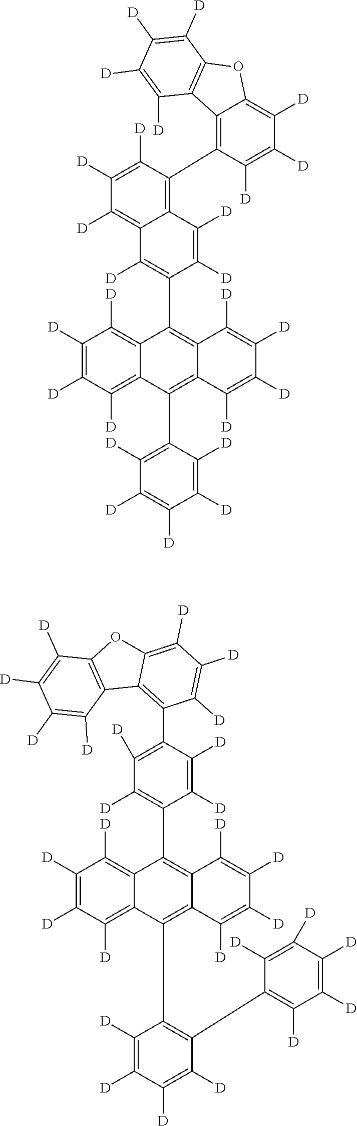 [SMILES: [2H]c1c([2H])c([2H])c(-c2c3c([2H])c([2H])c([2H])c([2H])c3c(-c3c([2H])c([2H])c4c(-c5c([2H])c([2H])c([2H])c6oc7c([2H])c([2H])c([2H])c([2H])c7c56)c([2H])c([2H])c([2H])c4c3[2H])c3c([2H])c([2H])c([2H])c([2H])c23)c([2H])c1[2H] ; [2H]c1c([2H])c([2H])c(-c2c([2H])c([2H])c([2H])c([2H])c2-c2c3c([2H])c([2H])c([2H])c([2H])c3c(-c3c([2H])c([2H])c(-c4c([2H])c([2H])c([2H])c5oc6c([2H])c([2H])c([2H])c([2H])c6c45)c([2H])c3[2H])c3c([2H])c([2H])c([2H])c([2H])c23)c([2H])c1[2H]]

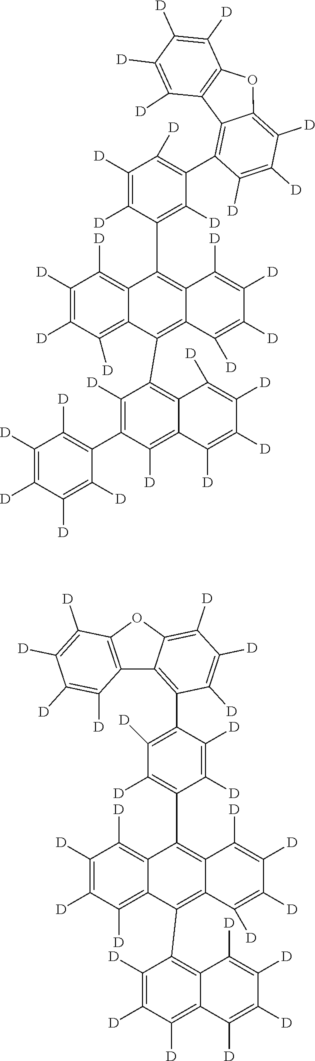 [SMILES: [2H]c1c([2H])c([2H])c(-c2c([2H])c(-c3c4c([2H])c([2H])c([2H])c([2H])c4c(-c4c([2H])c([2H])c([2H])c(-c5c([2H])c([2H])c([2H])c6oc7c([2H])c([2H])c([2H])c([2H])c7c56)c4[2H])c4c([2H])c([2H])c([2H])c([2H])c34)c3c([2H])c([2H])c([2H])c([2H])c3c2[2H])c([2H])c1[2H] ; [2H]c1c([2H])c(-c2c([2H])c([2H])c([2H])c3oc4c([2H])c([2H])c([2H])c([2H])c4c23)c([2H])c([2H])c1-c1c2c([2H])c([2H])c([2H])c([2H])c2c(-c2c([2H])c([2H])c([2H])c3c([2H])c([2H])c([2H])c([2H])c23)c2c([2H])c([2H])c([2H])c([2H])c12]

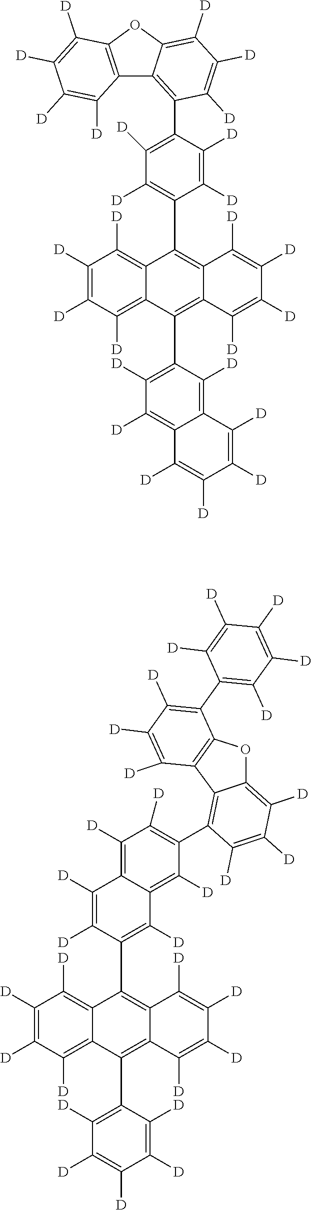 [SMILES: [2H]c1c([2H])c(-c2c([2H])c([2H])c([2H])c3oc4c([2H])c([2H])c([2H])c([2H])c4c23)c([2H])c([2H])c1-c1c2c([2H])c([2H])c([2H])c([2H])c2c(-c2c([2H])c([2H])c3c([2H])c([2H])c([2H])c([2H])c3c2[2H])c2c([2H])c([2H])c([2H])c([2H])c12 ; [2H]c1c([2H])c([2H])c(-c2c([2H])c([2H])c([2H])c3c2oc2c([2H])c([2H])c([2H])c(-c4c([2H])c([2H])c5c([2H])c([2H])c(-c6c7c([2H])c([2H])c([2H])c([2H])c7c(-c7c([2H])c([2H])c([2H])c([2H])c7[2H])c7c([2H])c([2H])c([2H])c([2H])c67)c([2H])c5c4[2H])c23)c([2H])c1[2H]]

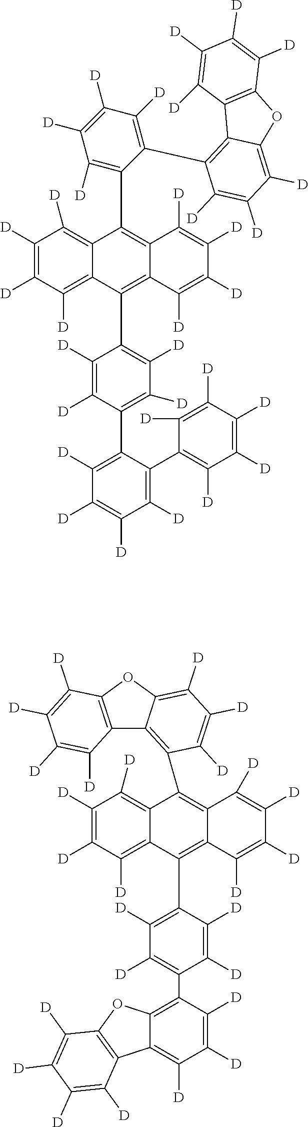 [SMILES: [2H]c1c([2H])c([2H])c(-c2c([2H])c([2H])c([2H])c([2H])c2-c2c([2H])c([2H])c(-c3c4c([2H])c([2H])c([2H])c([2H])c4c(-c4c([2H])c([2H])c([2H])c([2H])c4-c4c([2H])c([2H])c([2H])c5oc6c([2H])c([2H])c([2H])c([2H])c6c45)c4c([2H])c([2H])c([2H])c([2H])c34)c([2H])c2[2H])c([2H])c1[2H] ; [2H]c1c([2H])c(-c2c3c([2H])c([2H])c([2H])c([2H])c3c(-c3c([2H])c([2H])c([2H])c4oc5c([2H])c([2H])c([2H])c([2H])c5c34)c3c([2H])c([2H])c([2H])c([2H])c23)c([2H])c([2H])c1-c1c([2H])c([2H])c([2H])c2c1oc1c([2H])c([2H])c([2H])c([2H])c12]

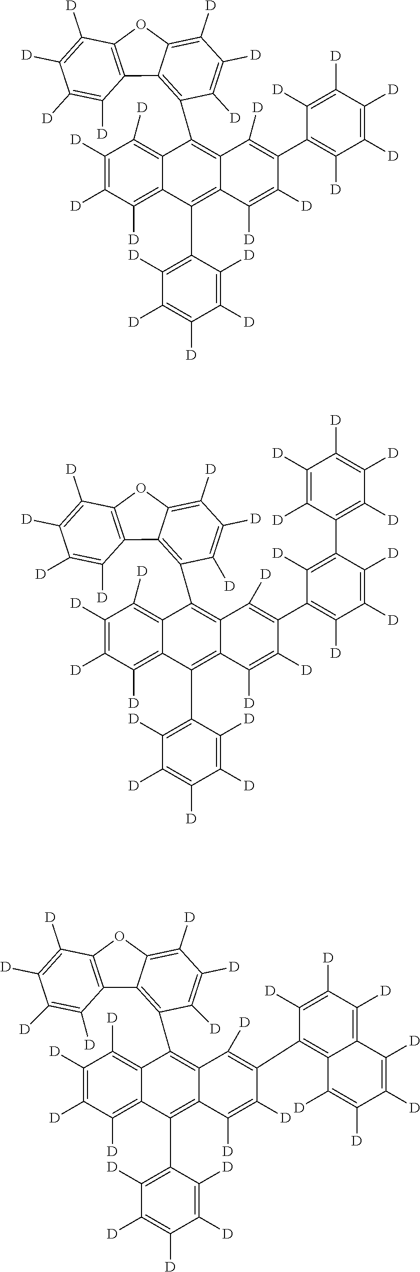

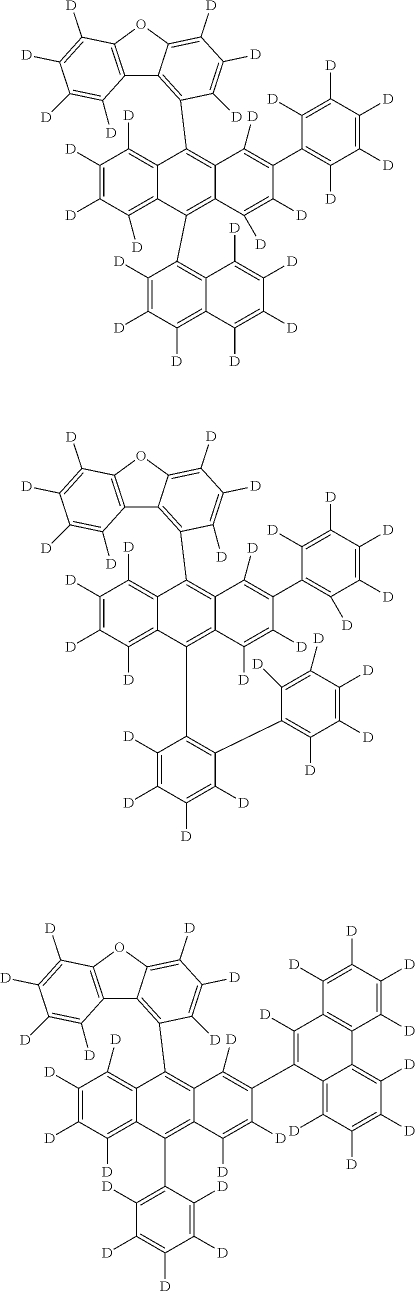

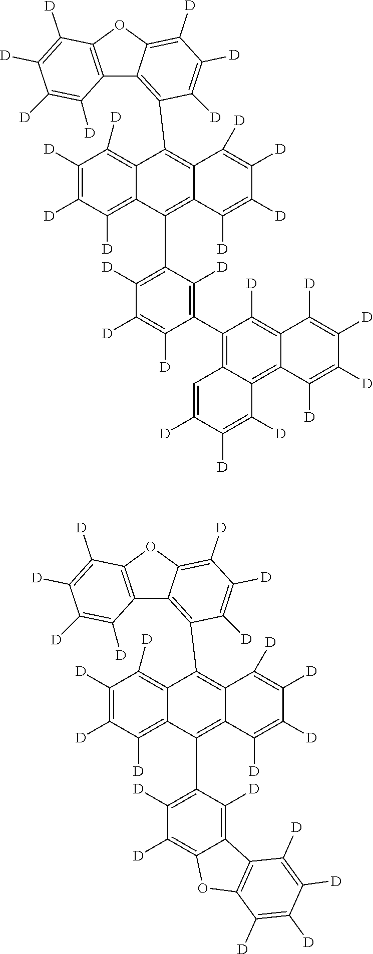 [SMILES: [2H]c1cc2c(-c3c([2H])c([2H])c([2H])c(-c4c5c([2H])c([2H])c([2H])c([2H])c5c(-c5c([2H])c([2H])c([2H])c6oc7c([2H])c([2H])c([2H])c([2H])c7c56)c5c([2H])c([2H])c([2H])c([2H])c45)c3[2H])c([2H])c3c([2H])c([2H])c([2H])c([2H])c3c2c([2H])c1[2H] ; [2H]c1c([2H])c([2H])c2c(oc3c([2H])c([2H])c(-c4c5c([2H])c([2H])c([2H])c([2H])c5c(-c5c([2H])c([2H])c([2H])c6oc7c([2H])c([2H])c([2H])c([2H])c7c56)c5c([2H])c([2H])c([2H])c([2H])c45)c([2H])c32)c1[2H]]

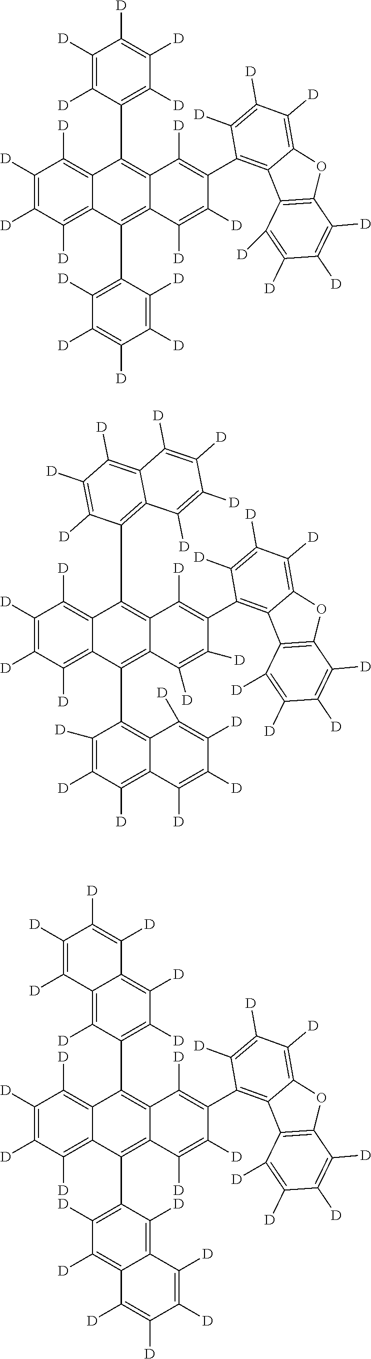

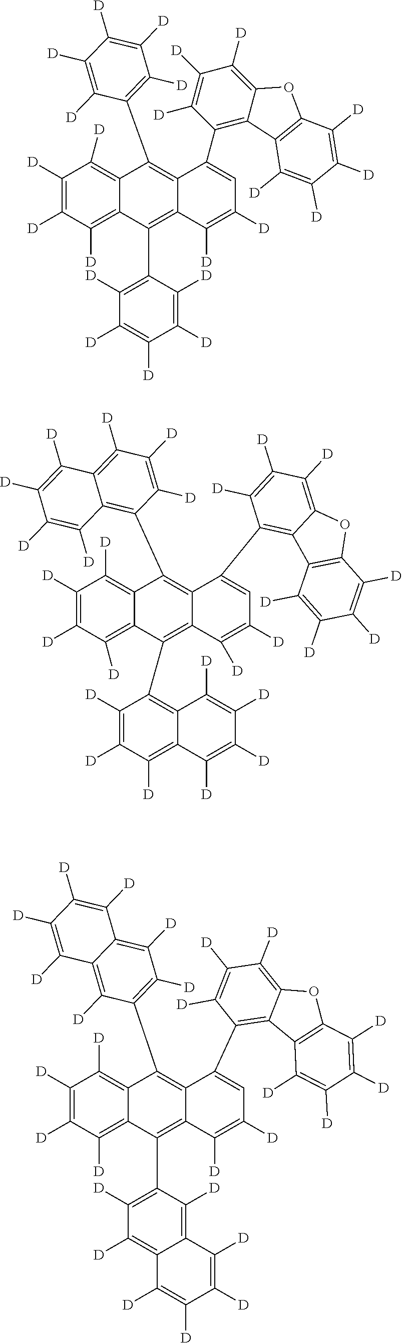

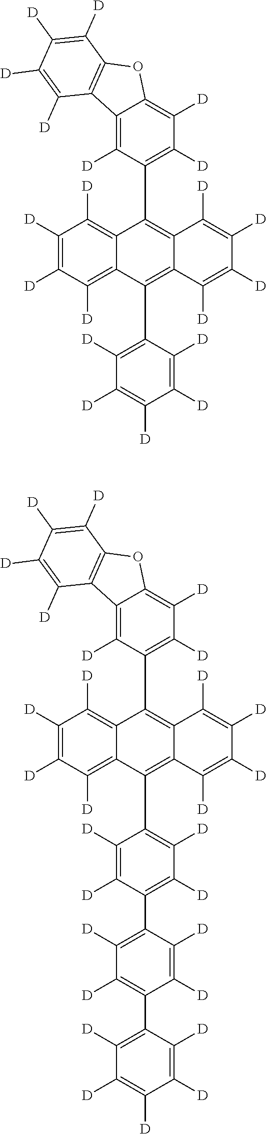 [SMILES: [2H]c1c([2H])c([2H])c(-c2c3c([2H])c([2H])c([2H])c([2H])c3c(-c3c([2H])c([2H])c4oc5c([2H])c([2H])c([2H])c([2H])c5c4c3[2H])c3c([2H])c([2H])c([2H])c([2H])c23)c([2H])c1[2H] ; [2H]c1c([2H])c([2H])c(-c2c([2H])c([2H])c(-c3c([2H])c([2H])c(-c4c5c([2H])c([2H])c([2H])c([2H])c5c(-c5c([2H])c([2H])c6oc7c([2H])c([2H])c([2H])c([2H])c7c6c5[2H])c5c([2H])c([2H])c([2H])c([2H])c45)c([2H])c3[2H])c([2H])c2[2H])c([2H])c1[2H]]

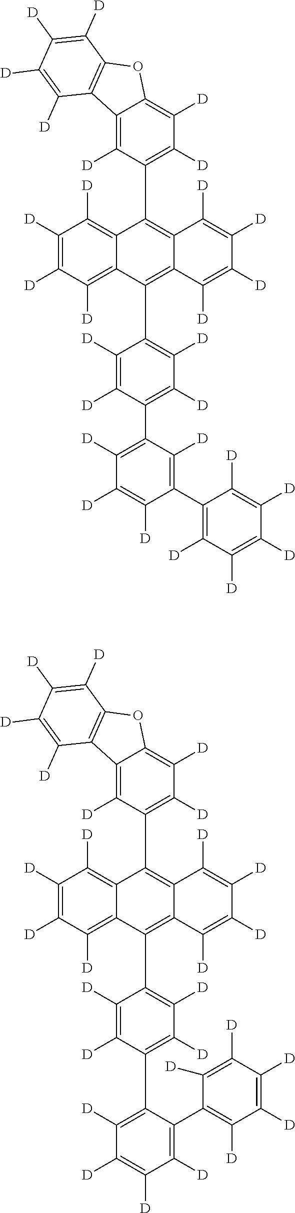 [SMILES: [2H]c1c([2H])c([2H])c(-c2c([2H])c([2H])c([2H])c(-c3c([2H])c([2H])c(-c4c5c([2H])c([2H])c([2H])c([2H])c5c(-c5c([2H])c([2H])c6oc7c([2H])c([2H])c([2H])c([2H])c7c6c5[2H])c5c([2H])c([2H])c([2H])c([2H])c45)c([2H])c3[2H])c2[2H])c([2H])c1[2H] ; [2H]c1c([2H])c([2H])c(-c2c([2H])c([2H])c([2H])c([2H])c2-c2c([2H])c([2H])c(-c3c4c([2H])c([2H])c([2H])c([2H])c4c(-c4c([2H])c([2H])c5oc6c([2H])c([2H])c([2H])c([2H])c6c5c4[2H])c4c([2H])c([2H])c([2H])c([2H])c34)c([2H])c2[2H])c([2H])c1[2H]]

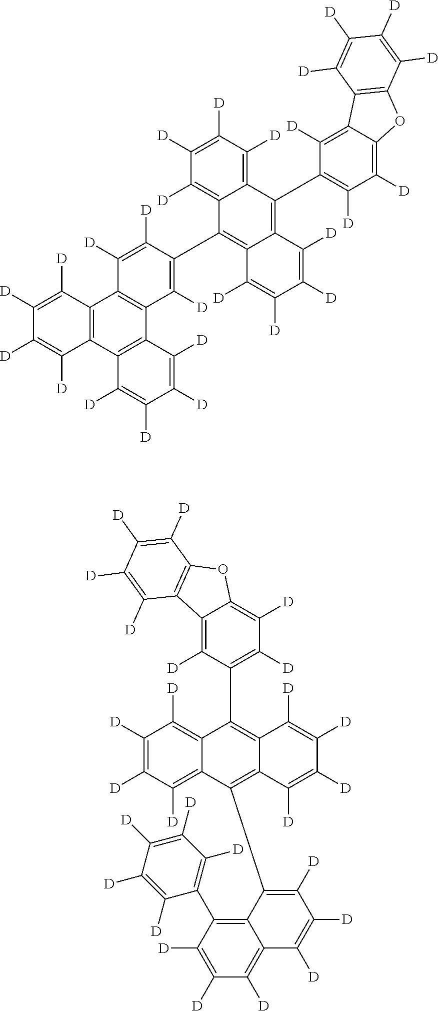 [SMILES: [2H]c1c([2H])c([2H])c2c(oc3c([2H])c([2H])c(-c4c5c([2H])c([2H])c([2H])c([2H])c5c(-c5c([2H])c([2H])c6c7c([2H])c([2H])c([2H])c([2H])c7c7c([2H])c([2H])c([2H])c([2H])c7c6c5[2H])c5c([2H])c([2H])c([2H])c([2H])c45)c([2H])c32)c1[2H] ; [2H]c1c([2H])c([2H])c(-c2c([2H])c([2H])c([2H])c3c([2H])c([2H])c([2H])c(-c4c5c([2H])c([2H])c([2H])c([2H])c5c(-c5c([2H])c([2H])c6oc7c([2H])c([2H])c([2H])c([2H])c7c6c5[2H])c5c([2H])c([2H])c([2H])c([2H])c45)c23)c([2H])c1[2H]]

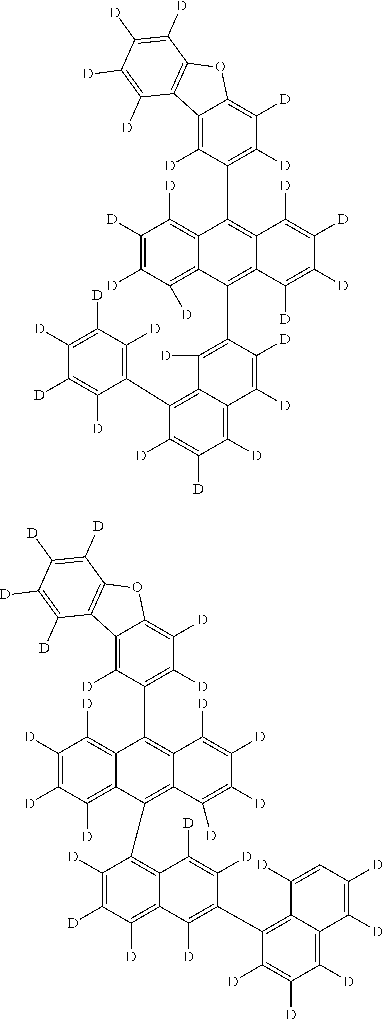 [SMILES: [2H]c1c([2H])c([2H])c(-c2c([2H])c([2H])c([2H])c3c([2H])c([2H])c(-c4c5c([2H])c([2H])c([2H])c([2H])c5c(-c5c([2H])c([2H])c6oc7c([2H])c([2H])c([2H])c([2H])c7c6c5[2H])c5c([2H])c([2H])c([2H])c([2H])c45)c([2H])c23)c([2H])c1[2H] ; [2H]c1cc([2H])c2c(-c3c([2H])c([2H])c4c(-c5c6c([2H])c([2H])c([2H])c([2H])c6c(-c6c([2H])c([2H])c7oc8c([2H])c([2H])c([2H])c([2H])c8c7c6[2H])c6c([2H])c([2H])c([2H])c([2H])c56)c([2H])c([2H])c([2H])c4c3[2H])c([2H])c([2H])c([2H])c2c1[2H]]

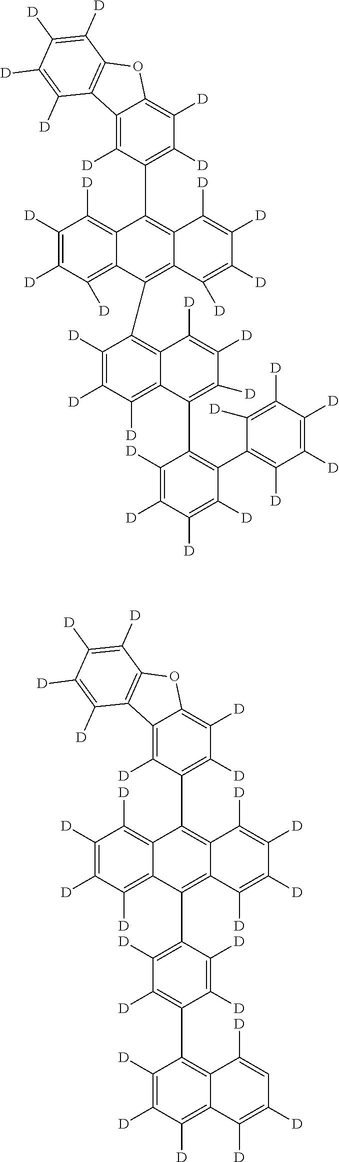 [SMILES: [2H]c1c([2H])c([2H])c(-c2c([2H])c([2H])c([2H])c([2H])c2-c2c([2H])c([2H])c([2H])c3c(-c4c5c([2H])c([2H])c([2H])c([2H])c5c(-c5c([2H])c([2H])c6oc7c([2H])c([2H])c([2H])c([2H])c7c6c5[2H])c5c([2H])c([2H])c([2H])c([2H])c45)c([2H])c([2H])c([2H])c23)c([2H])c1[2H] ; [2H]c1cc([2H])c2c(-c3c([2H])c([2H])c(-c4c5c([2H])c([2H])c([2H])c([2H])c5c(-c5c([2H])c([2H])c6oc7c([2H])c([2H])c([2H])c([2H])c7c6c5[2H])c5c([2H])c([2H])c([2H])c([2H])c45)c([2H])c3[2H])c([2H])c([2H])c([2H])c2c1[2H]]

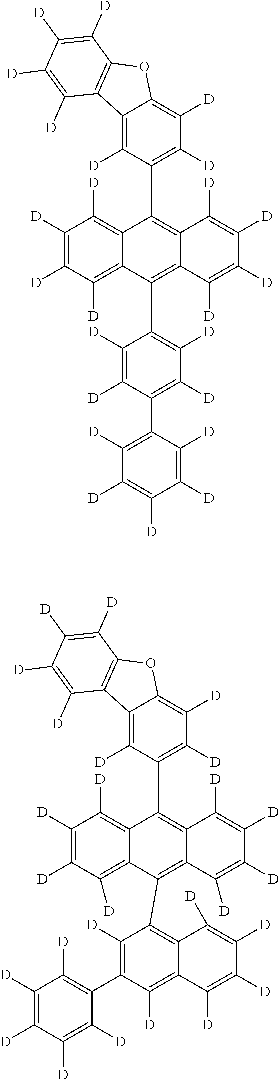 [SMILES: [2H]c1c([2H])c([2H])c(-c2c([2H])c([2H])c(-c3c4c([2H])c([2H])c([2H])c([2H])c4c(-c4c([2H])c([2H])c5oc6c([2H])c([2H])c([2H])c([2H])c6c5c4[2H])c4c([2H])c([2H])c([2H])c([2H])c34)c([2H])c2[2H])c([2H])c1[2H] ; [2H]c1c([2H])c([2H])c(-c2c([2H])c(-c3c4c([2H])c([2H])c([2H])c([2H])c4c(-c4c([2H])c([2H])c5oc6c([2H])c([2H])c([2H])c([2H])c6c5c4[2H])c4c([2H])c([2H])c([2H])c([2H])c34)c3c([2H])c([2H])c([2H])c([2H])c3c2[2H])c([2H])c1[2H]]

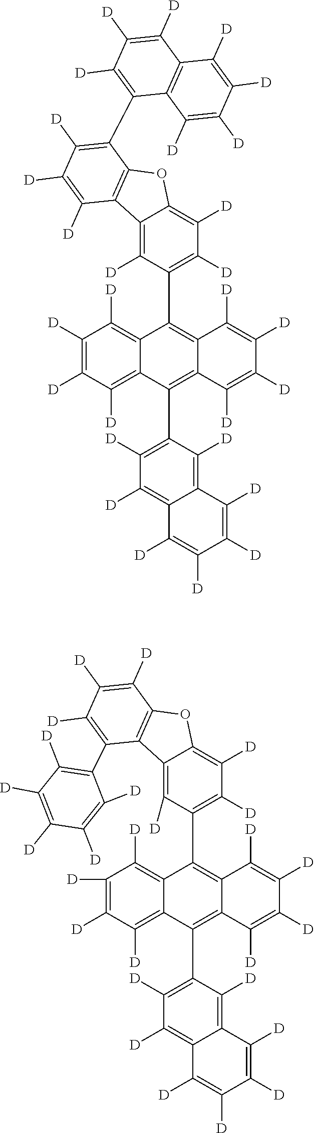 [SMILES: [2H]c1c(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c([2H])c2c(oc3c(-c4c([2H])c([2H])c([2H])c5c([2H])c([2H])c([2H])c([2H])c45)c([2H])c([2H])c([2H])c32)c1[2H] ; [2H]c1c([2H])c([2H])c(-c2c([2H])c([2H])c([2H])c3oc4c([2H])c([2H])c(-c5c6c([2H])c([2H])c([2H])c([2H])c6c(-c6c([2H])c([2H])c7c([2H])c([2H])c([2H])c([2H])c7c6[2H])c6c([2H])c([2H])c([2H])c([2H])c56)c([2H])c4c23)c([2H])c1[2H]]

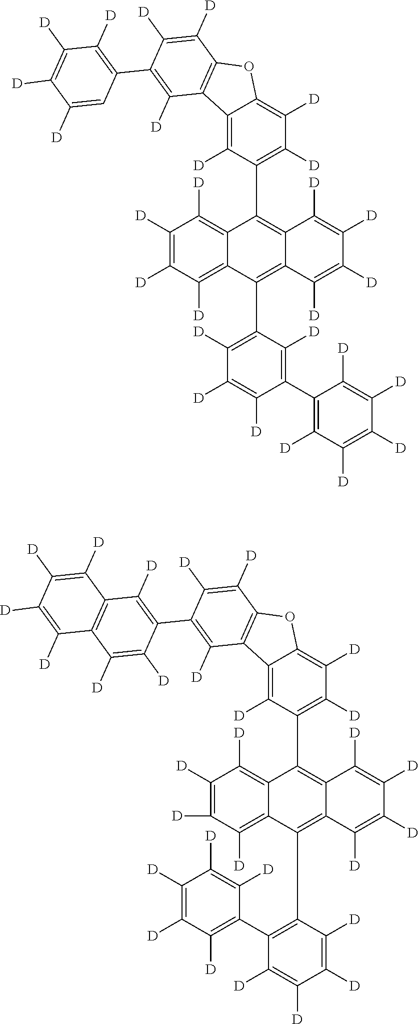 [SMILES: [2H]c1cc(-c2c([2H])c([2H])c3oc4c([2H])c([2H])c(-c5c6c([2H])c([2H])c([2H])c([2H])c6c(-c6c([2H])c([2H])c([2H])c(-c7c([2H])c([2H])c([2H])c([2H])c7[2H])c6[2H])c6c([2H])c([2H])c([2H])c([2H])c56)c([2H])c4c3c2[2H])c([2H])c([2H])c1[2H] ; [2H]c1c([2H])c([2H])c(-c2c([2H])c([2H])c([2H])c([2H])c2-c2c3c([2H])c([2H])c([2H])c([2H])c3c(-c3c([2H])c([2H])c4oc5c([2H])c([2H])c(-c6c([2H])c([2H])c7c([2H])c([2H])c([2H])c([2H])c7c6[2H])c([2H])c5c4c3[2H])c3c([2H])c([2H])c([2H])c([2H])c23)c([2H])c1[2H]]

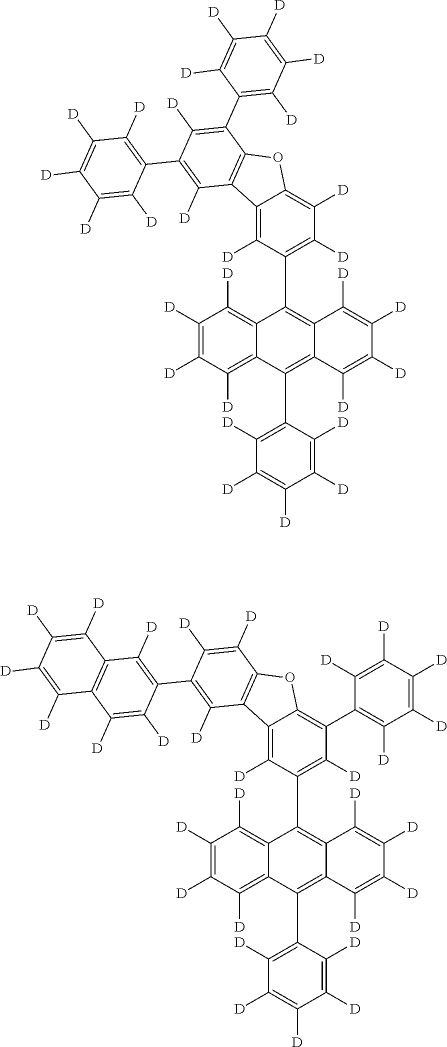 [SMILES: [2H]c1c([2H])c([2H])c(-c2c([2H])c(-c3c([2H])c([2H])c([2H])c([2H])c3[2H])c3oc4c([2H])c([2H])c(-c5c6c([2H])c([2H])c([2H])c([2H])c6c(-c6c([2H])c([2H])c([2H])c([2H])c6[2H])c6c([2H])c([2H])c([2H])c([2H])c56)c([2H])c4c3c2[2H])c([2H])c1[2H] ; [2H]c1c([2H])c([2H])c(-c2c([2H])c(-c3c4c([2H])c([2H])c([2H])c([2H])c4c(-c4c([2H])c([2H])c([2H])c([2H])c4[2H])c4c([2H])c([2H])c([2H])c([2H])c34)c([2H])c3c2oc2c([2H])c([2H])c(-c4c([2H])c([2H])c5c([2H])c([2H])c([2H])c([2H])c5c4[2H])c([2H])c23)c([2H])c1[2H]]

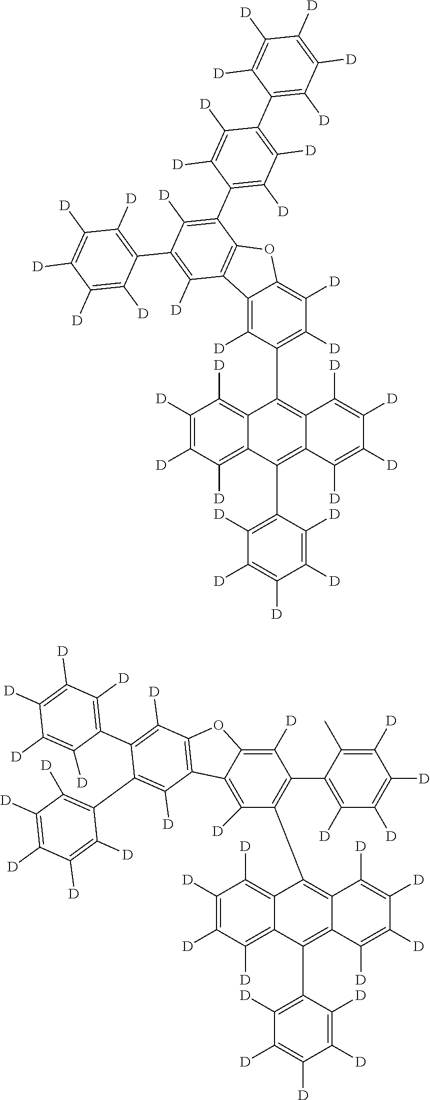

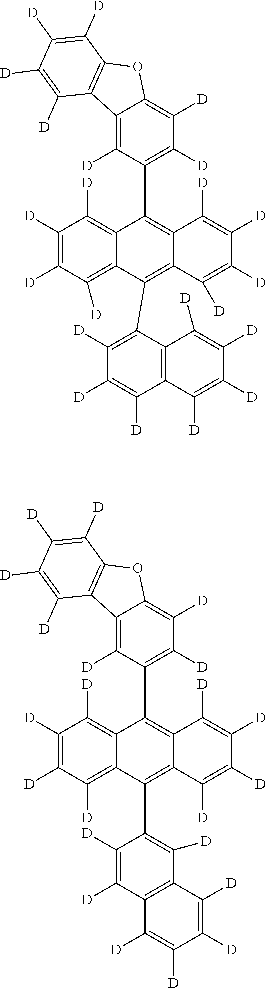 [SMILES: [2H]c1c([2H])c([2H])c2c(oc3c([2H])c([2H])c(-c4c5c([2H])c([2H])c([2H])c([2H])c5c(-c5c([2H])c([2H])c([2H])c6c([2H])c([2H])c([2H])c([2H])c56)c5c([2H])c([2H])c([2H])c([2H])c45)c([2H])c32)c1[2H] ; [2H]c1c([2H])c([2H])c2c(oc3c([2H])c([2H])c(-c4c5c([2H])c([2H])c([2H])c([2H])c5c(-c5c([2H])c([2H])c6c([2H])c([2H])c([2H])c([2H])c6c5[2H])c5c([2H])c([2H])c([2H])c([2H])c45)c([2H])c32)c1[2H]]

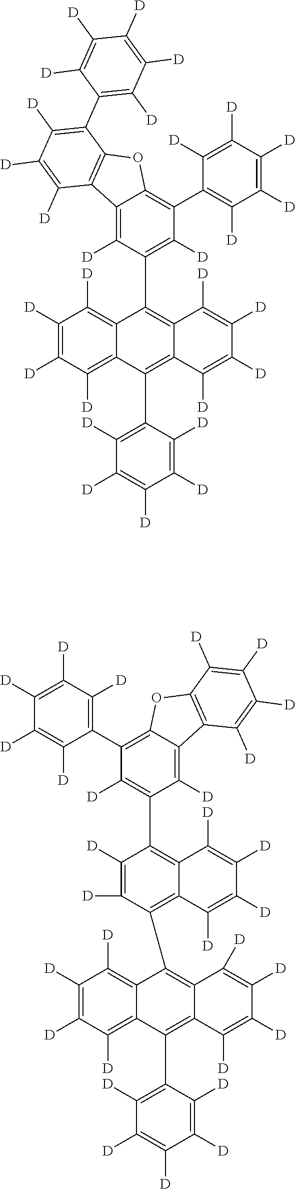 [SMILES: [2H]c1c([2H])c([2H])c(-c2c([2H])c([2H])c([2H])c3c2oc2c(-c4c([2H])c([2H])c([2H])c([2H])c4[2H])c([2H])c(-c4c5c([2H])c([2H])c([2H])c([2H])c5c(-c5c([2H])c([2H])c([2H])c([2H])c5[2H])c5c([2H])c([2H])c([2H])c([2H])c45)c([2H])c23)c([2H])c1[2H] ; [2H]c1c([2H])c([2H])c(-c2c([2H])c(-c3c([2H])c([2H])c(-c4c5c([2H])c([2H])c([2H])c([2H])c5c(-c5c([2H])c([2H])c([2H])c([2H])c5[2H])c5c([2H])c([2H])c([2H])c([2H])c45)c4c([2H])c([2H])c([2H])c([2H])c34)c([2H])c3c2oc2c([2H])c([2H])c([2H])c([2H])c23)c([2H])c1[2H]]

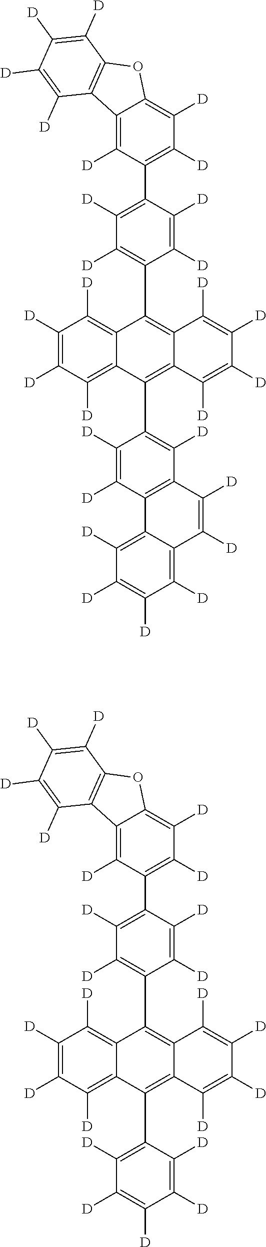 [SMILES: [2H]c1c([2H])c(-c2c3c([2H])c([2H])c([2H])c([2H])c3c(-c3c([2H])c([2H])c4c(c3[2H])c([2H])c([2H])c3c([2H])c([2H])c([2H])c([2H])c34)c3c([2H])c([2H])c([2H])c([2H])c23)c([2H])c([2H])c1-c1c([2H])c([2H])c2oc3c([2H])c([2H])c([2H])c([2H])c3c2c1[2H] ; [2H]c1c([2H])c([2H])c(-c2c3c([2H])c([2H])c([2H])c([2H])c3c(-c3c([2H])c([2H])c(-c4c([2H])c([2H])c5oc6c([2H])c([2H])c([2H])c([2H])c6c5c4[2H])c([2H])c3[2H])c3c([2H])c([2H])c([2H])c([2H])c23)c([2H])c1[2H]]

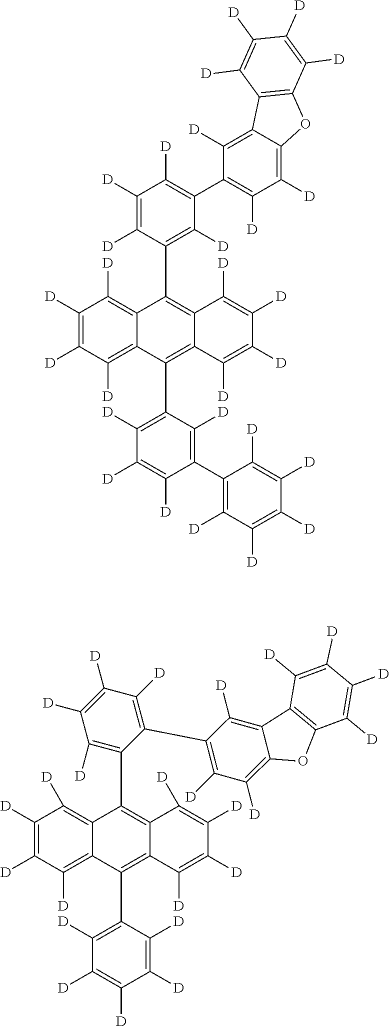 [SMILES: [2H]c1c([2H])c([2H])c(-c2c([2H])c([2H])c([2H])c(-c3c4c([2H])c([2H])c([2H])c([2H])c4c(-c4c([2H])c([2H])c([2H])c(-c5c([2H])c([2H])c6oc7c([2H])c([2H])c([2H])c([2H])c7c6c5[2H])c4[2H])c4c([2H])c([2H])c([2H])c([2H])c34)c2[2H])c([2H])c1[2H] ; [2H]c1c([2H])c([2H])c(-c2c3c([2H])c([2H])c([2H])c([2H])c3c(-c3c([2H])c([2H])c([2H])c([2H])c3-c3c([2H])c([2H])c4oc5c([2H])c([2H])c([2H])c([2H])c5c4c3[2H])c3c([2H])c([2H])c([2H])c([2H])c23)c([2H])c1[2H]]

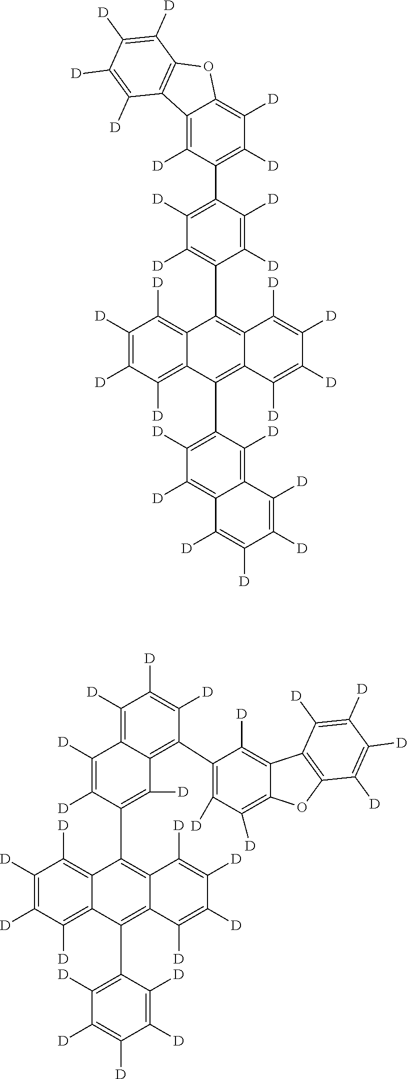 [SMILES: [2H]c1c([2H])c(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c([2H])c([2H])c1-c1c([2H])c([2H])c2oc3c([2H])c([2H])c([2H])c([2H])c3c2c1[2H] ; [2H]c1c([2H])c([2H])c(-c2c3c([2H])c([2H])c([2H])c([2H])c3c(-c3c([2H])c([2H])c4c([2H])c([2H])c([2H])c(-c5c([2H])c([2H])c6oc7c([2H])c([2H])c([2H])c([2H])c7c6c5[2H])c4c3[2H])c3c([2H])c([2H])c([2H])c([2H])c23)c([2H])c1[2H]]

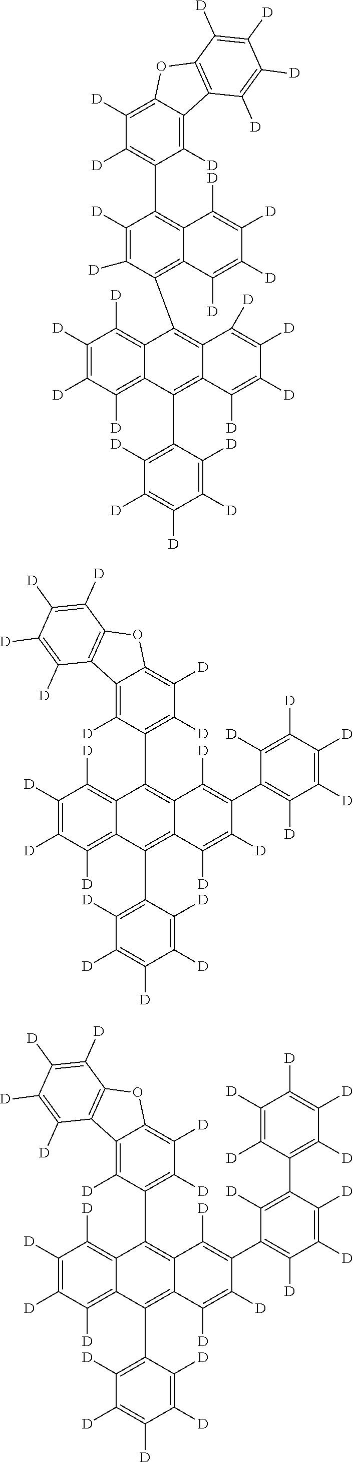

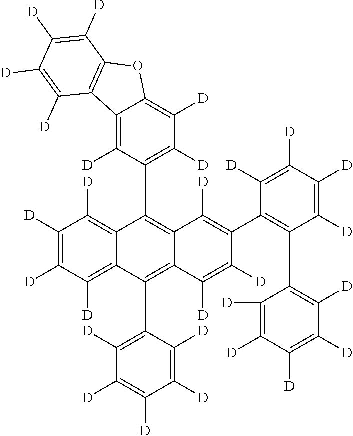 [SMILES: [2H]c1c([2H])c([2H])c(-c2c([2H])c([2H])c([2H])c([2H])c2-c2c([2H])c([2H])c3c(-c4c([2H])c([2H])c([2H])c([2H])c4[2H])c4c([2H])c([2H])c([2H])c([2H])c4c(-c4c([2H])c([2H])c5oc6c([2H])c([2H])c([2H])c([2H])c6c5c4[2H])c3c2[2H])c([2H])c1[2H]]

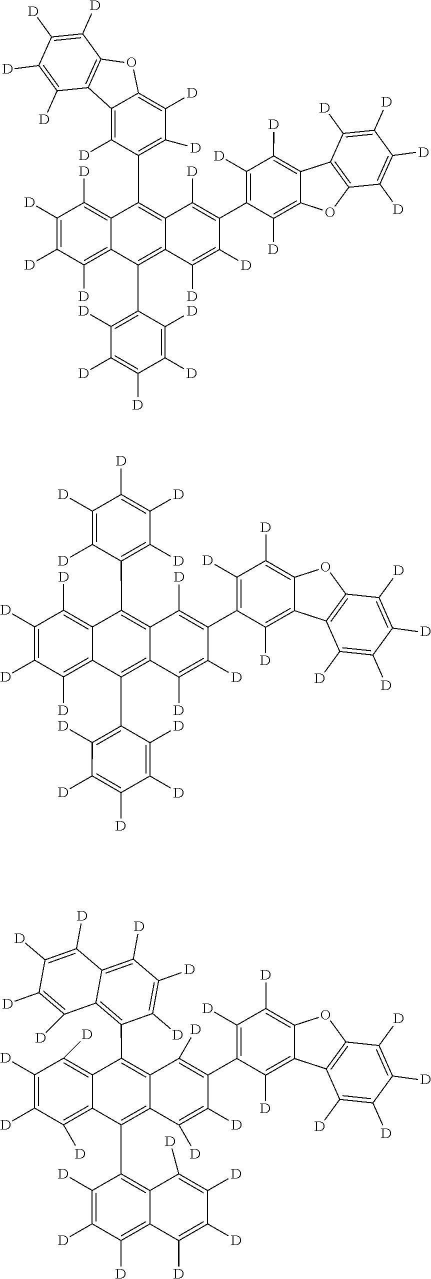

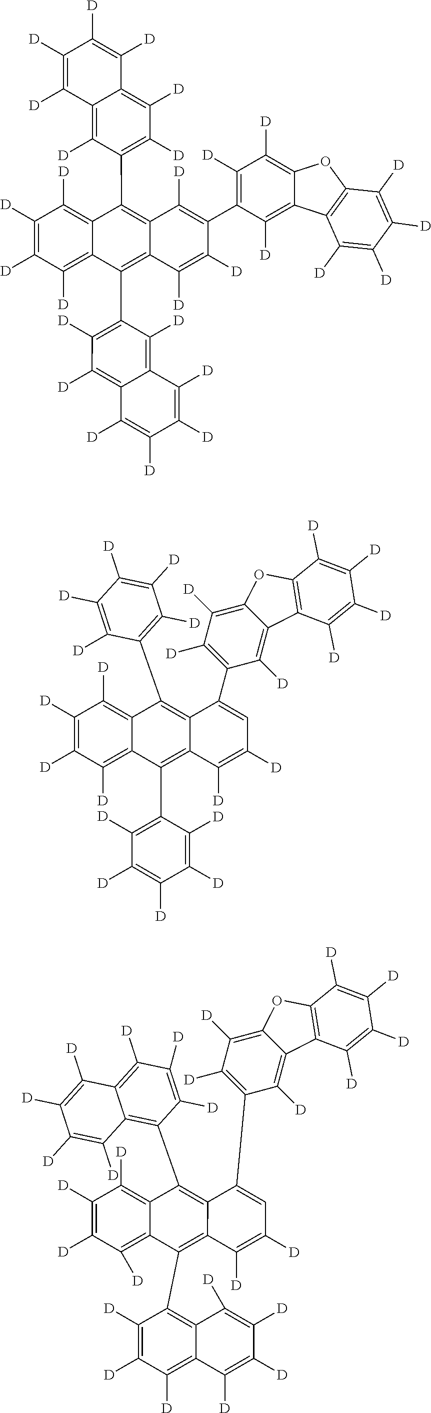

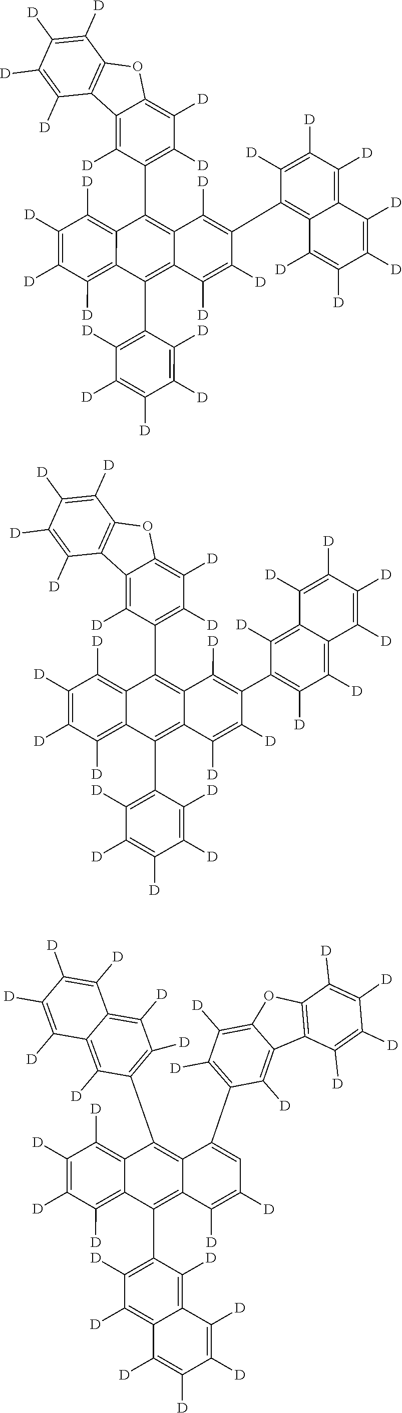

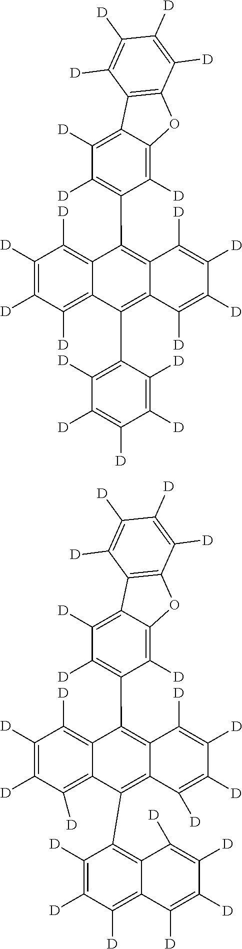

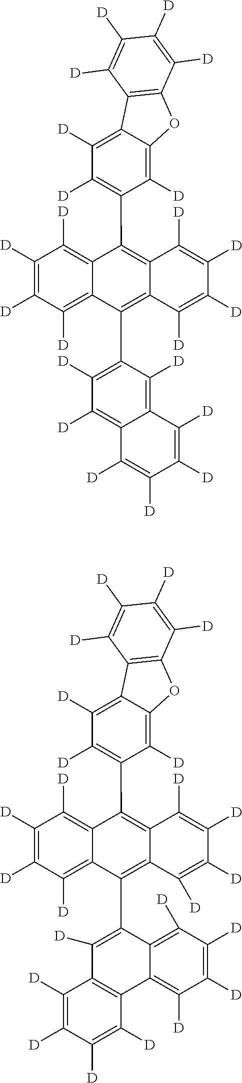 [SMILES: [2H]c1c([2H])c([2H])c2c(oc3c([2H])c(-c4c5c([2H])c([2H])c([2H])c([2H])c5c(-c5c([2H])c([2H])c6c([2H])c([2H])c([2H])c([2H])c6c5[2H])c5c([2H])c([2H])c([2H])c([2H])c45)c([2H])c([2H])c32)c1[2H] ; [2H]c1c([2H])c([2H])c2c(oc3c([2H])c(-c4c5c([2H])c([2H])c([2H])c([2H])c5c(-c5c([2H])c6c([2H])c([2H])c([2H])c([2H])c6c6c([2H])c([2H])c([2H])c([2H])c56)c5c([2H])c([2H])c([2H])c([2H])c45)c([2H])c([2H])c32)c1[2H]]

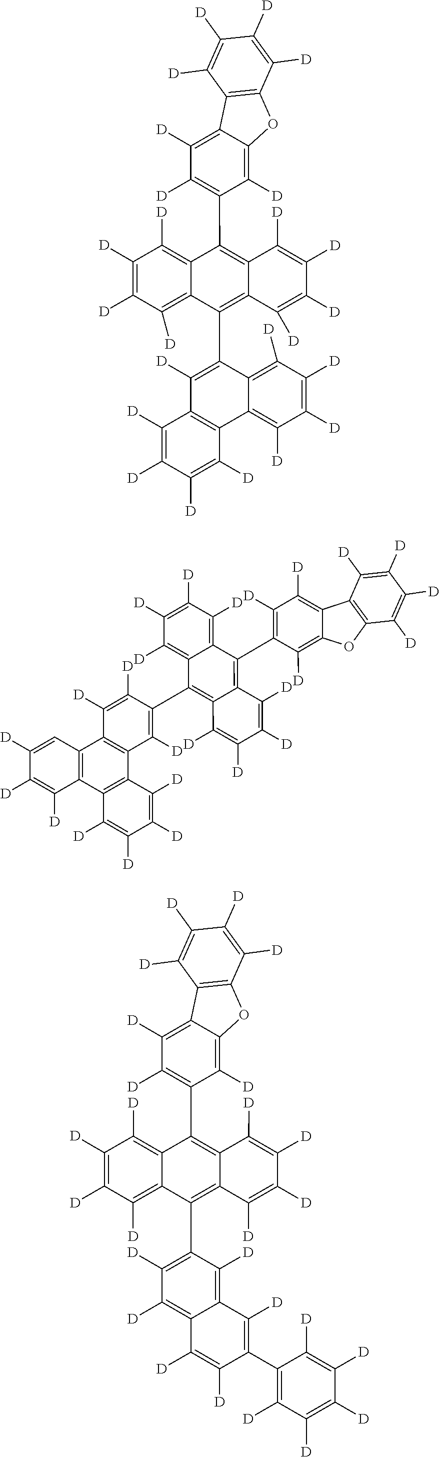

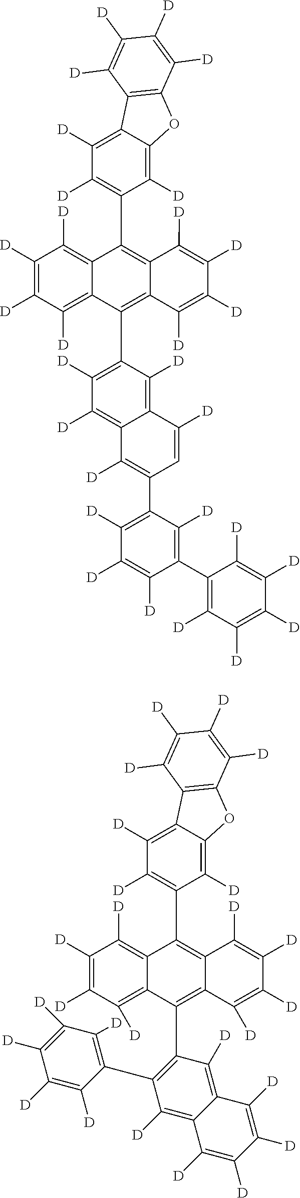

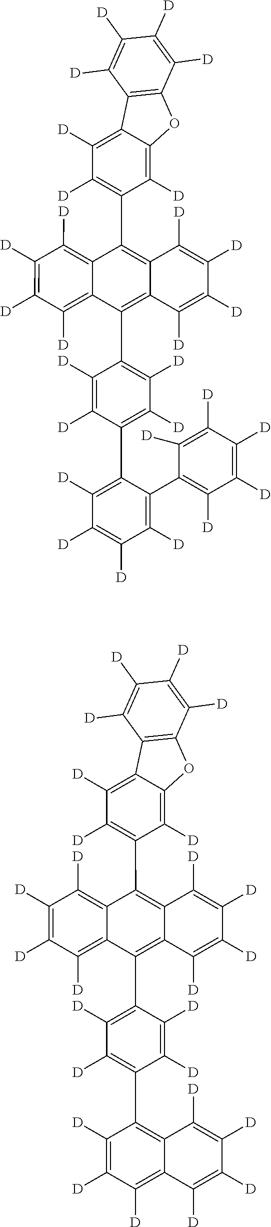 [SMILES: [2H]c1c([2H])c([2H])c(-c2c([2H])c([2H])c([2H])c([2H])c2-c2c([2H])c([2H])c(-c3c4c([2H])c([2H])c([2H])c([2H])c4c(-c4c([2H])c([2H])c5c(oc6c([2H])c([2H])c([2H])c([2H])c65)c4[2H])c4c([2H])c([2H])c([2H])c([2H])c34)c([2H])c2[2H])c([2H])c1[2H] ; [2H]c1c([2H])c(-c2c3c([2H])c([2H])c([2H])c([2H])c3c(-c3c([2H])c([2H])c4c(oc5c([2H])c([2H])c([2H])c([2H])c54)c3[2H])c3c([2H])c([2H])c([2H])c([2H])c23)c([2H])c([2H])c1-c1c([2H])c([2H])c([2H])c2c([2H])c([2H])c([2H])c([2H])c12]

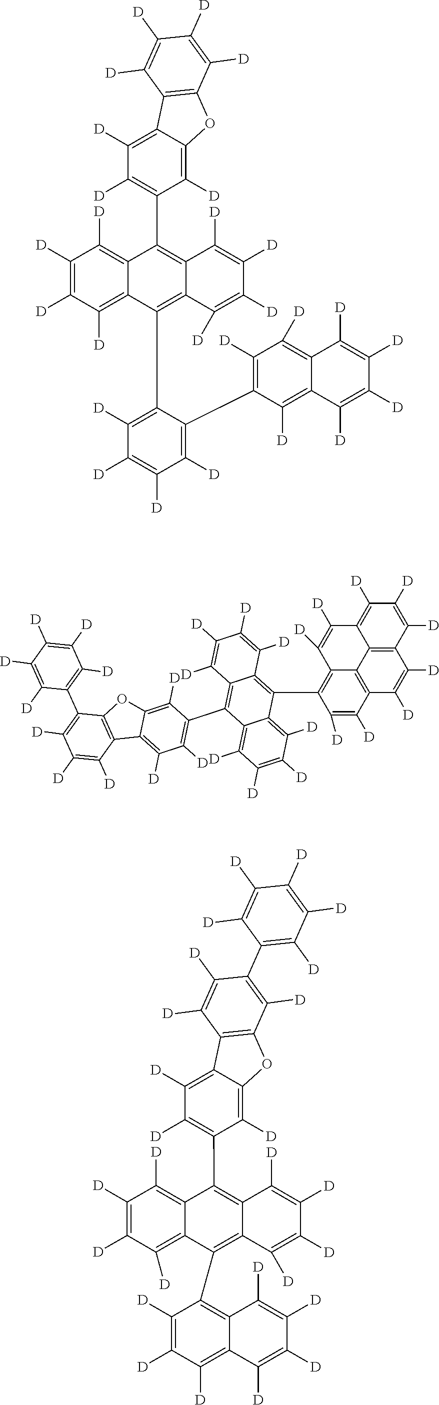

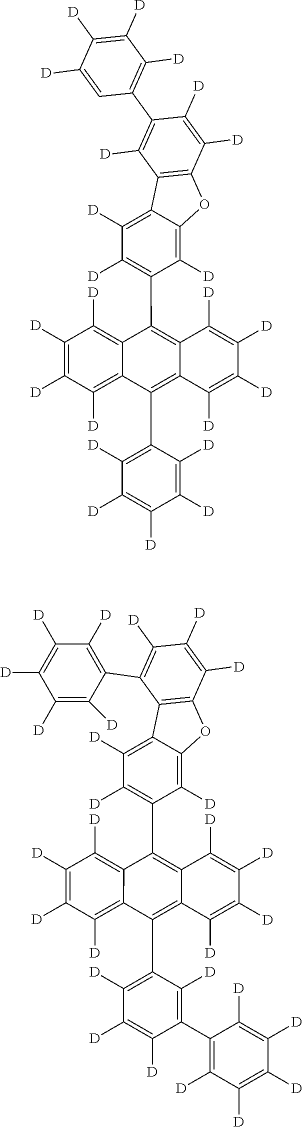 [SMILES: [2H]c1cc(-c2c([2H])c([2H])c3oc4c([2H])c(-c5c6c([2H])c([2H])c([2H])c([2H])c6c(-c6c([2H])c([2H])c([2H])c([2H])c6[2H])c6c([2H])c([2H])c([2H])c([2H])c56)c([2H])c([2H])c4c3c2[2H])c([2H])c([2H])c1[2H] ; [2H]c1c([2H])c([2H])c(-c2c([2H])c([2H])c([2H])c(-c3c4c([2H])c([2H])c([2H])c([2H])c4c(-c4c([2H])c([2H])c5c(oc6c([2H])c([2H])c([2H])c(-c7c([2H])c([2H])c([2H])c([2H])c7[2H])c65)c4[2H])c4c([2H])c([2H])c([2H])c([2H])c34)c2[2H])c([2H])c1[2H]]

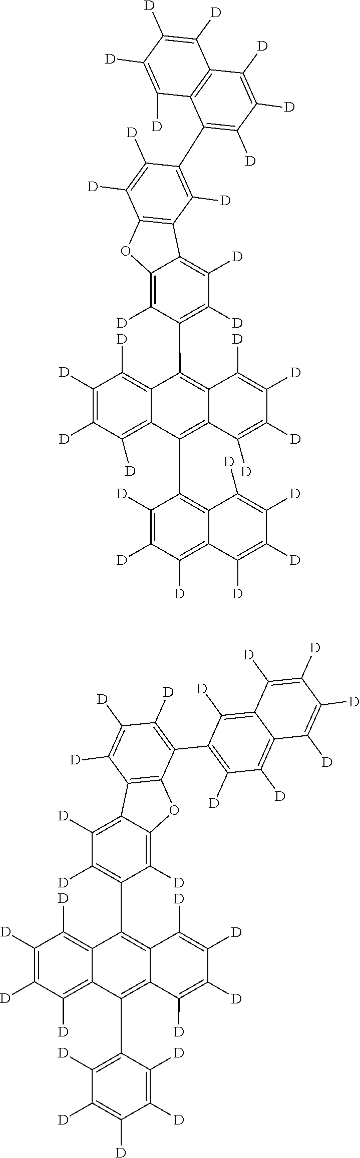 [SMILES: [2H]c1c(-c2c([2H])c([2H])c([2H])c3c([2H])c([2H])c([2H])c([2H])c23)c([2H])c2c(oc3c([2H])c(-c4c5c([2H])c([2H])c([2H])c([2H])c5c(-c5c([2H])c([2H])c([2H])c6c([2H])c([2H])c([2H])c([2H])c56)c5c([2H])c([2H])c([2H])c([2H])c45)c([2H])c([2H])c32)c1[2H] ; [2H]c1c([2H])c([2H])c(-c2c3c([2H])c([2H])c([2H])c([2H])c3c(-c3c([2H])c([2H])c4c(oc5c(-c6c([2H])c([2H])c7c([2H])c([2H])c([2H])c([2H])c7c6[2H])c([2H])c([2H])c([2H])c54)c3[2H])c3c([2H])c([2H])c([2H])c([2H])c23)c([2H])c1[2H]]

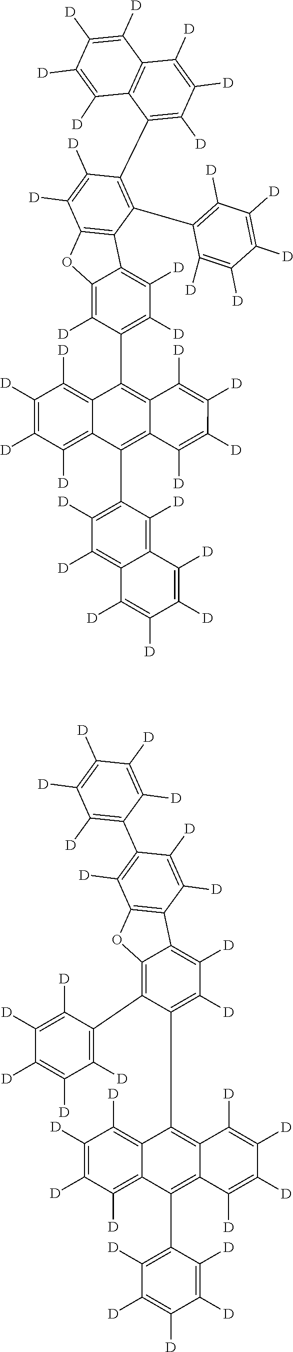

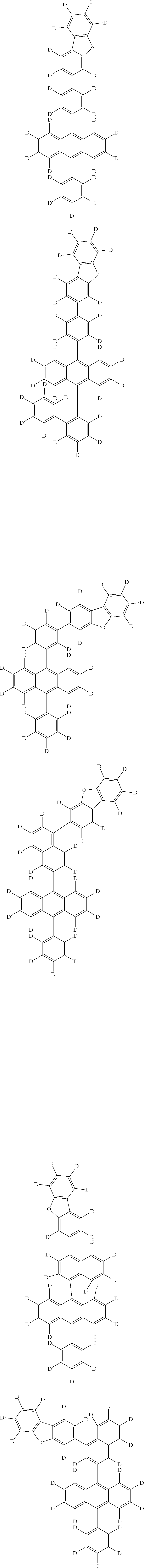

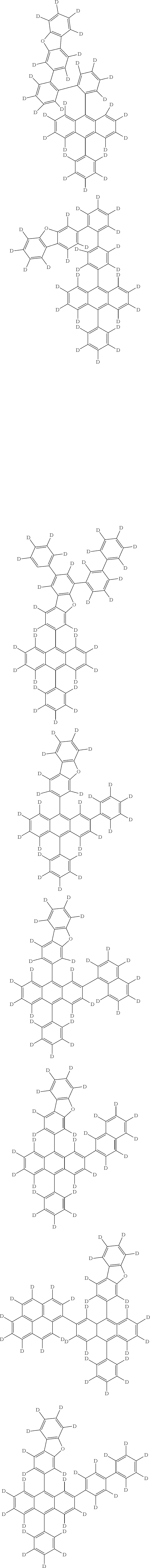

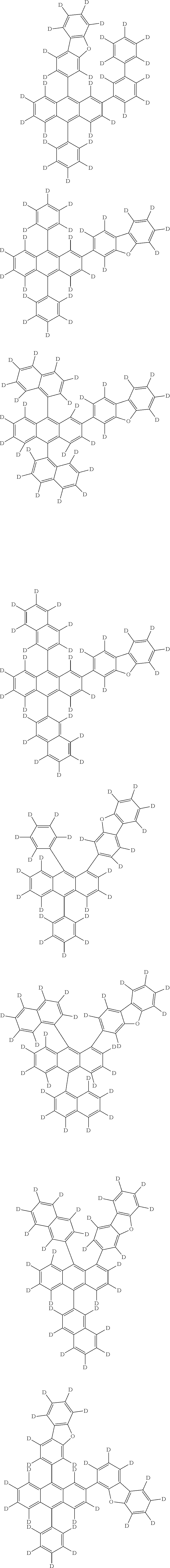

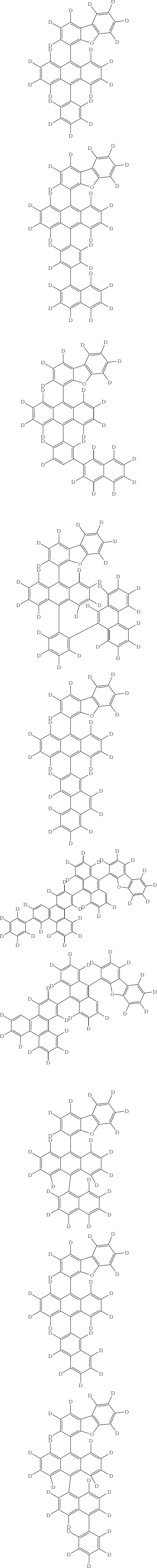

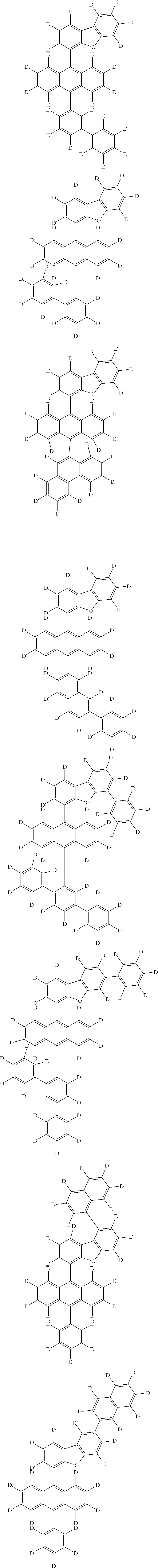

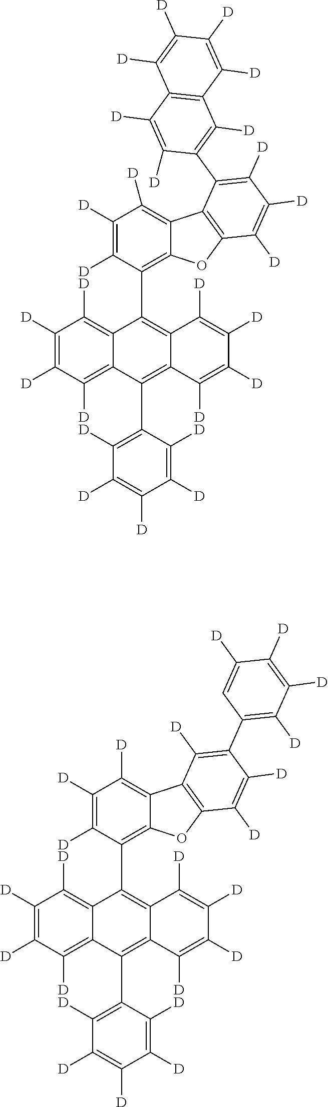 [SMILES: [2H]c1c([2H])c([2H])c(-c2c3c([2H])c([2H])c([2H])c([2H])c3c(-c3c([2H])c([2H])c([2H])c4c3oc3c([2H])c([2H])c([2H])c(-c5c([2H])c([2H])c6c([2H])c([2H])c([2H])c([2H])c6c5[2H])c34)c3c([2H])c([2H])c([2H])c([2H])c23)c([2H])c1[2H] ; [2H]c1cc(-c2c([2H])c([2H])c3oc4c(-c5c6c([2H])c([2H])c([2H])c([2H])c6c(-c6c([2H])c([2H])c([2H])c([2H])c6[2H])c6c([2H])c([2H])c([2H])c([2H])c56)c([2H])c([2H])c([2H])c4c3c2[2H])c([2H])c([2H])c1[2H]]

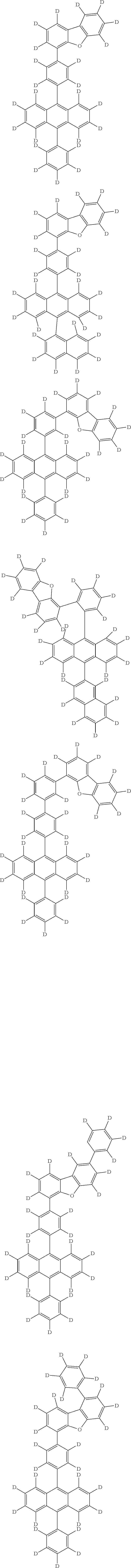

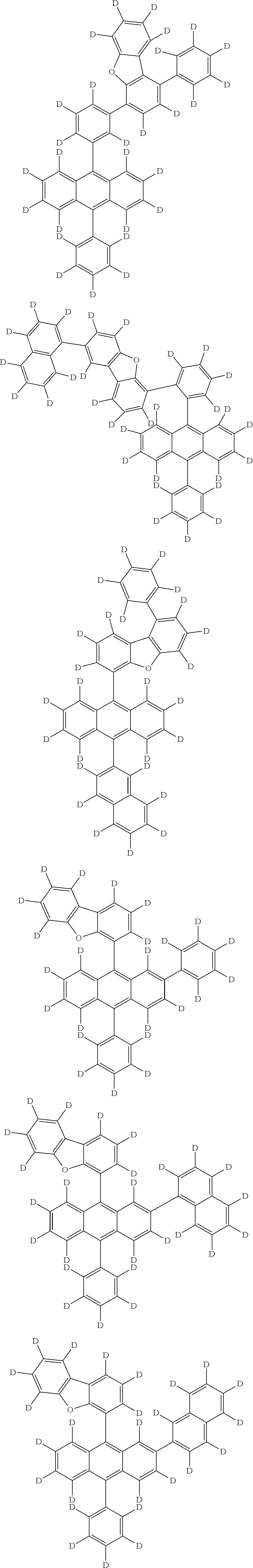

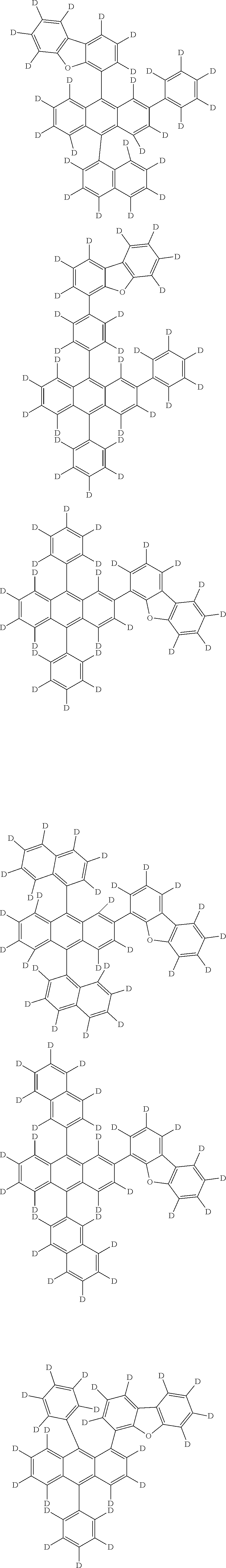

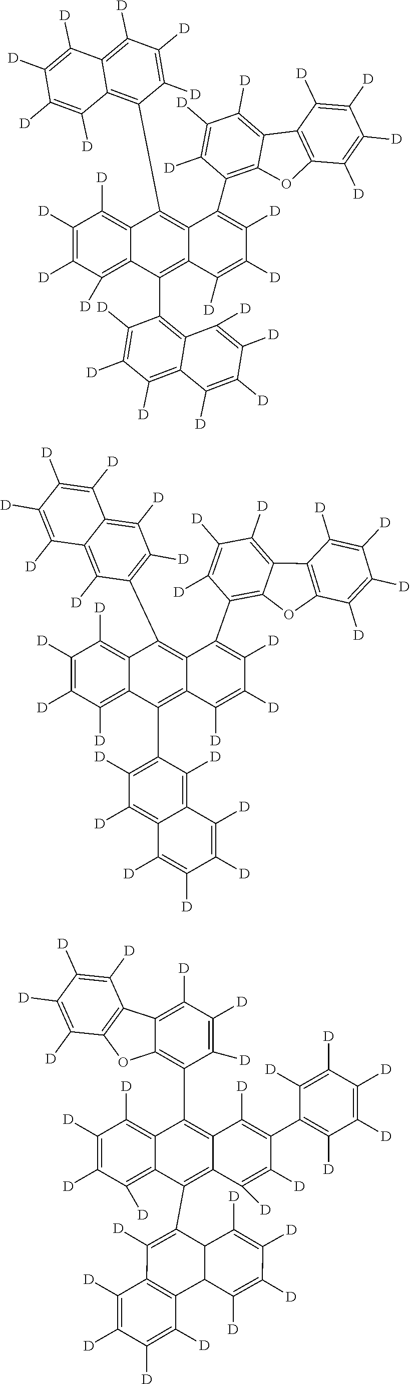

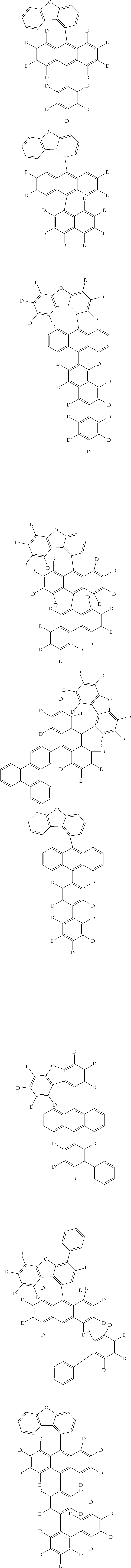

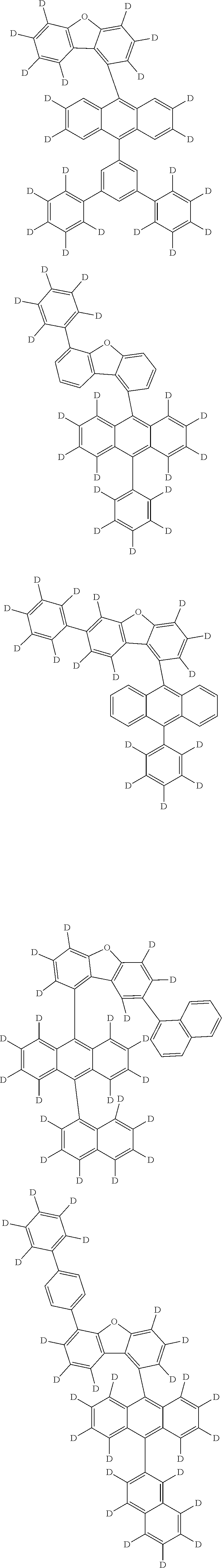

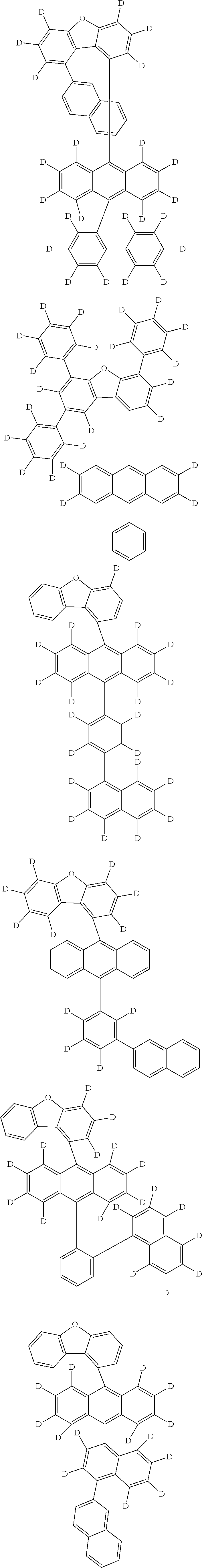

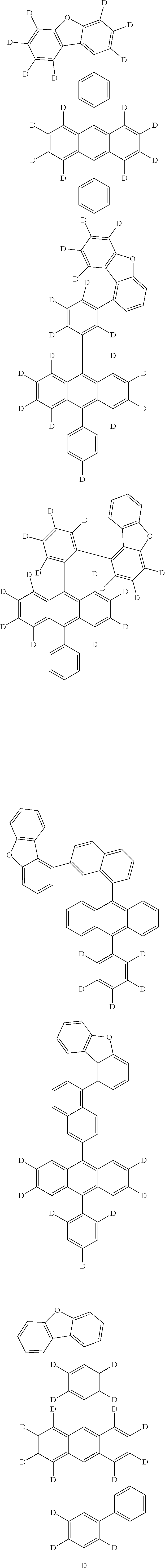

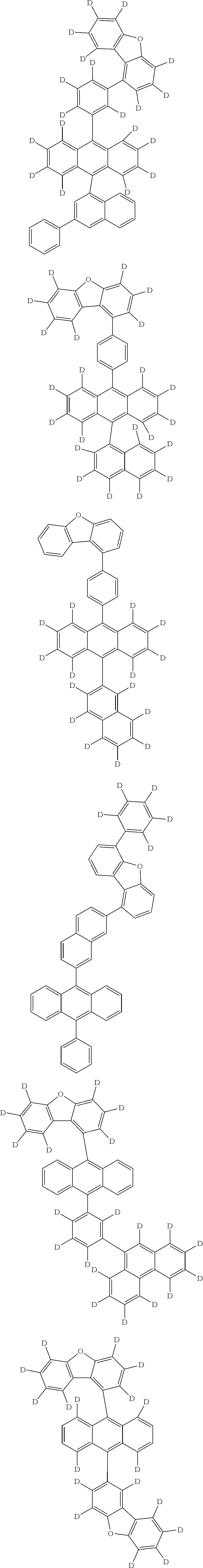

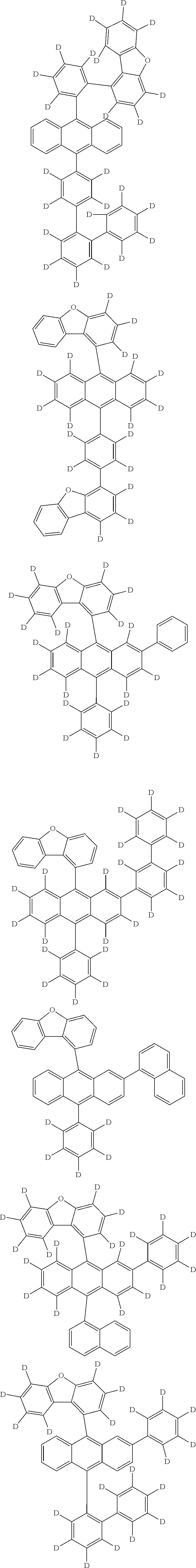

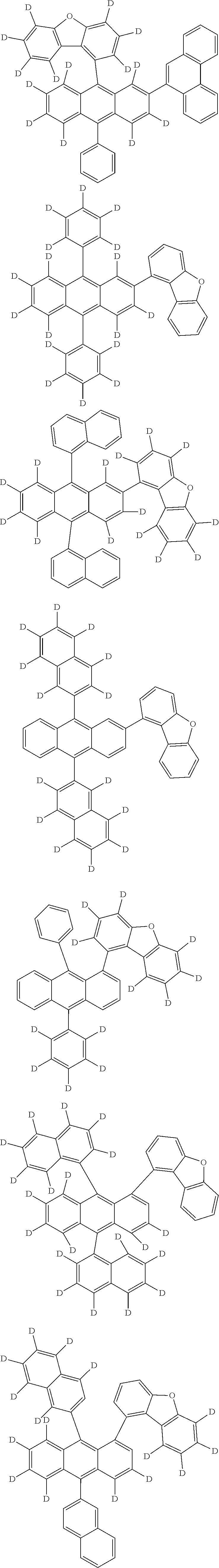

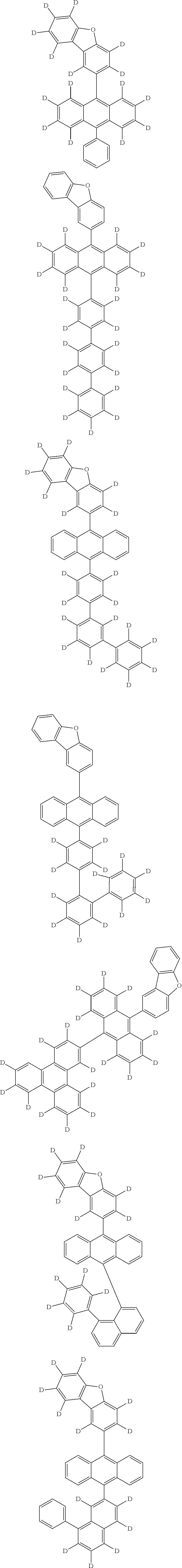

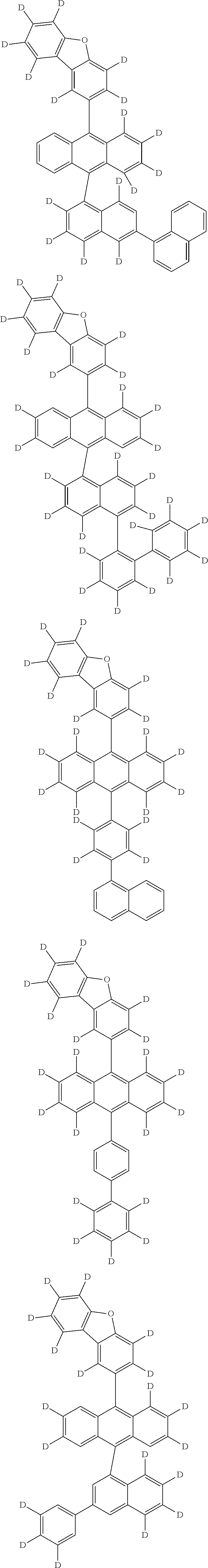

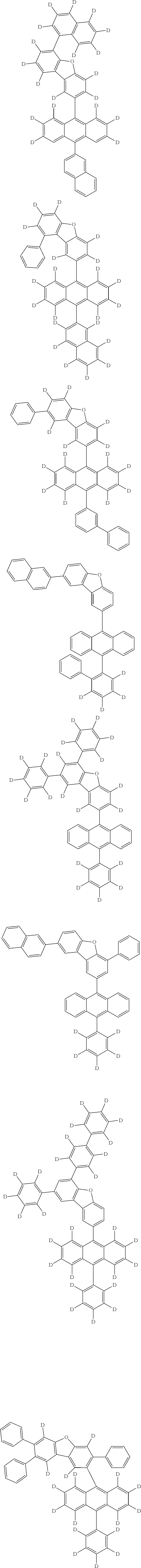

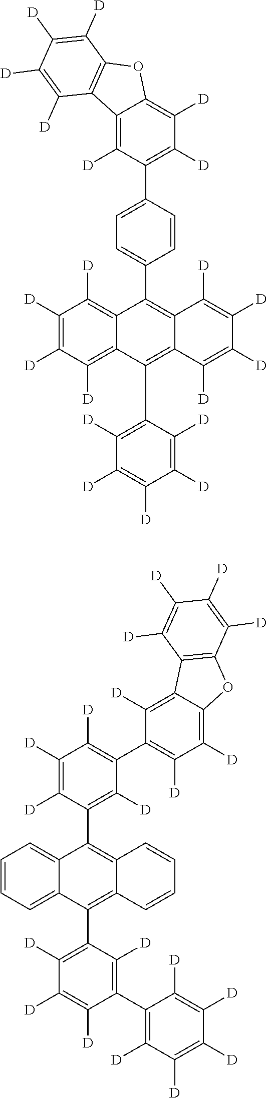 [SMILES: [2H]c1c([2H])c([2H])c(-c2c3c([2H])c([2H])c([2H])c([2H])c3c(-c3ccc(-c4c([2H])c([2H])c5oc6c([2H])c([2H])c([2H])c([2H])c6c5c4[2H])cc3)c3c([2H])c([2H])c([2H])c([2H])c23)c([2H])c1[2H] ; [2H]c1c([2H])c([2H])c(-c2c([2H])c([2H])c([2H])c(-c3c4ccccc4c(-c4c([2H])c([2H])c([2H])c(-c5c([2H])c([2H])c6oc7c([2H])c([2H])c([2H])c([2H])c7c6c5[2H])c4[2H])c4ccccc34)c2[2H])c([2H])c1[2H]]

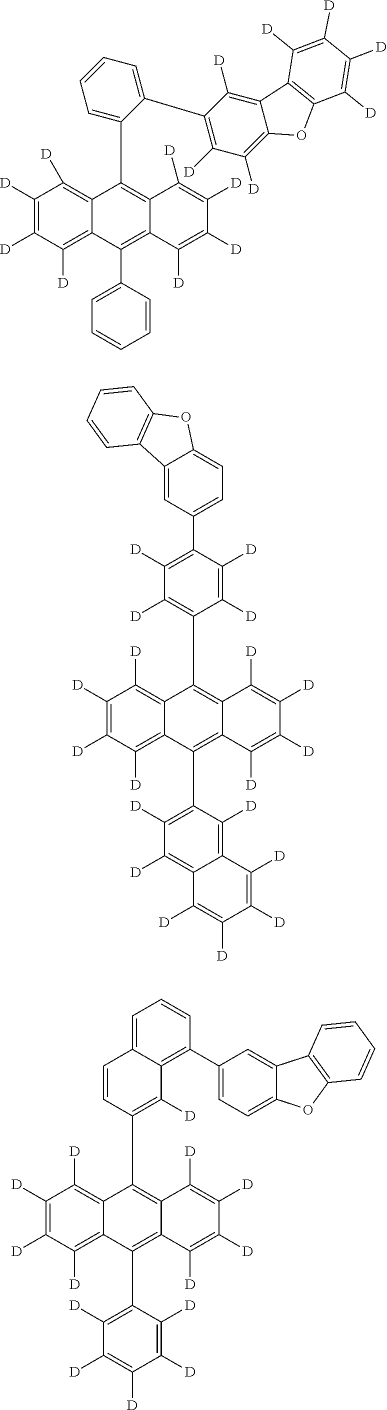

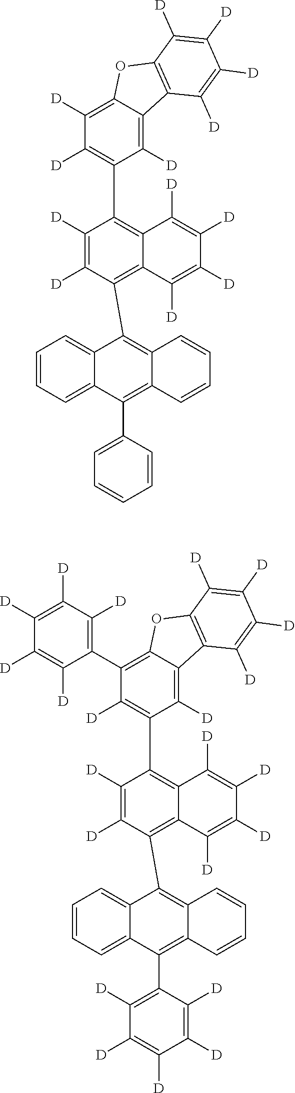 [SMILES: [2H]c1c([2H])c([2H])c2c(oc3c([2H])c([2H])c(-c4c([2H])c([2H])c(-c5c6ccccc6c(-c6ccccc6)c6ccccc56)c5c([2H])c([2H])c([2H])c([2H])c45)c([2H])c32)c1[2H] ; [2H]c1c([2H])c([2H])c(-c2c3ccccc3c(-c3c([2H])c([2H])c(-c4c([2H])c(-c5c([2H])c([2H])c([2H])c([2H])c5[2H])c5oc6c([2H])c([2H])c([2H])c([2H])c6c5c4[2H])c4c([2H])c([2H])c([2H])c([2H])c34)c3ccccc23)c([2H])c1[2H]]

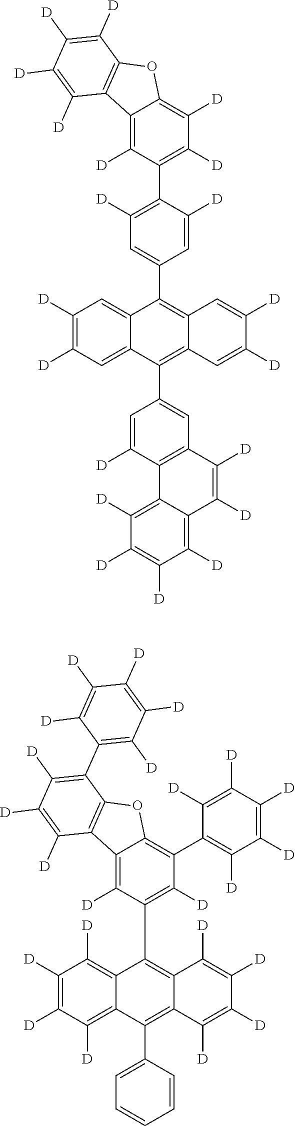 [SMILES: [2H]c1cc2c(-c3cc([2H])c(-c4c([2H])c([2H])c5oc6c([2H])c([2H])c([2H])c([2H])c6c5c4[2H])c([2H])c3)c3cc([2H])c([2H])cc3c(-c3cc([2H])c4c(c3)c([2H])c([2H])c3c([2H])c([2H])c([2H])c([2H])c34)c2cc1[2H] ; [2H]c1c([2H])c([2H])c(-c2c([2H])c([2H])c([2H])c3c2oc2c(-c4c([2H])c([2H])c([2H])c([2H])c4[2H])c([2H])c(-c4c5c([2H])c([2H])c([2H])c([2H])c5c(-c5ccccc5)c5c([2H])c([2H])c([2H])c([2H])c45)c([2H])c23)c([2H])c1[2H]]

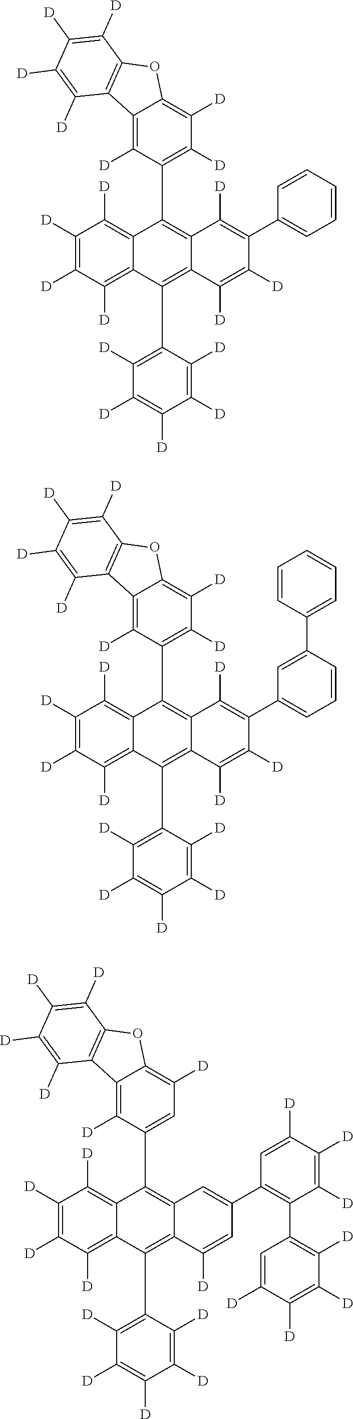

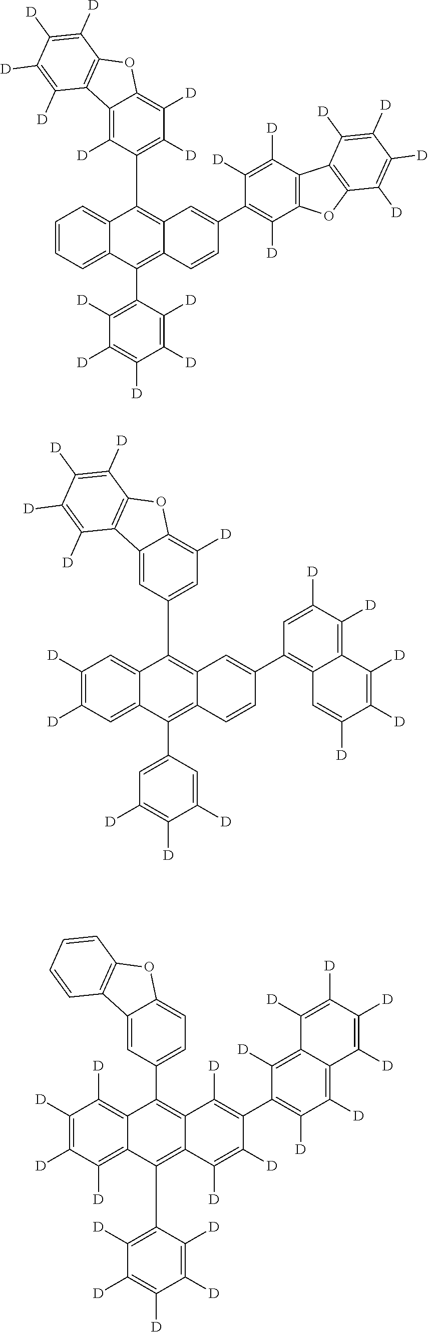

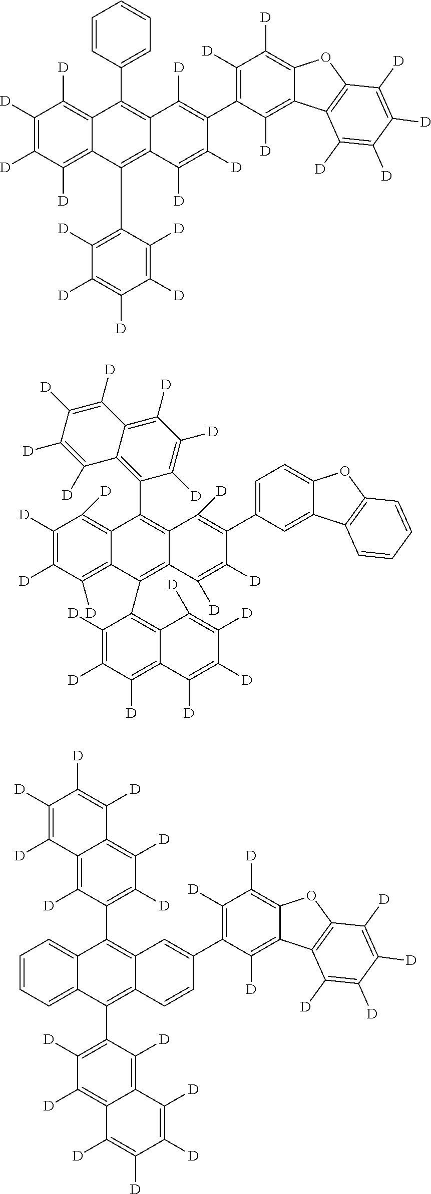

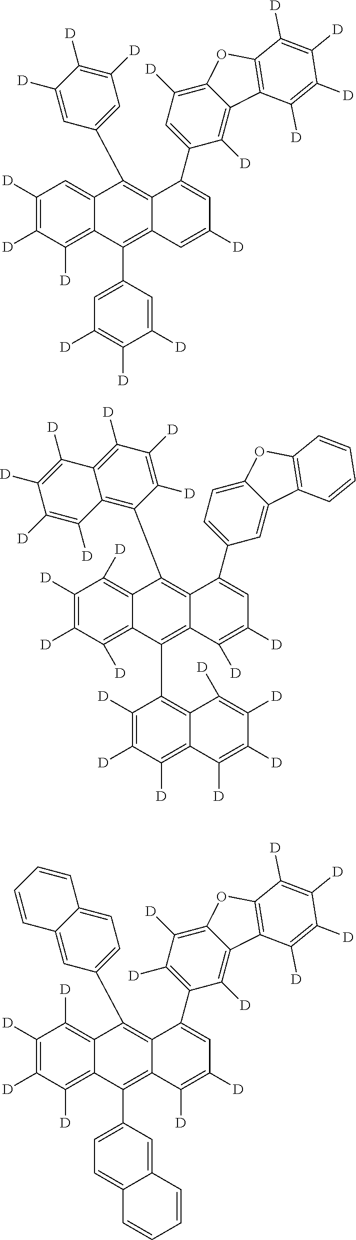

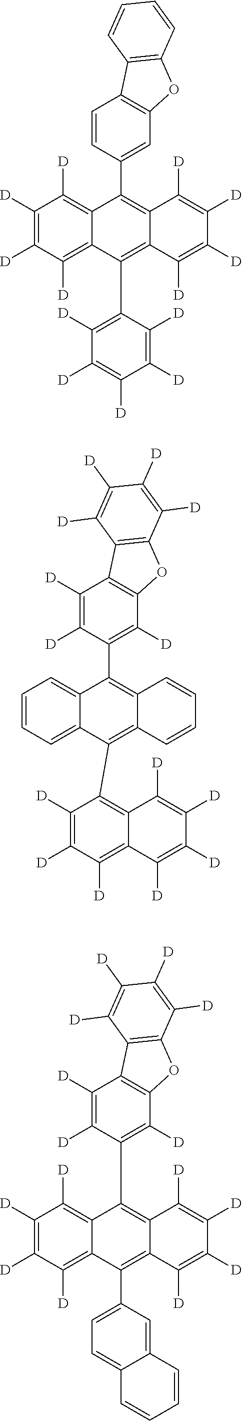 [SMILES: [2H]c1c([2H])c([2H])c(-c2c3c([2H])c([2H])c([2H])c([2H])c3c(-c3ccc4c(c3)oc3ccccc34)c3c([2H])c([2H])c([2H])c([2H])c23)c([2H])c1[2H] ; [2H]c1c([2H])c([2H])c2c(oc3c([2H])c(-c4c5ccccc5c(-c5c([2H])c([2H])c([2H])c6c([2H])c([2H])c([2H])c([2H])c56)c5ccccc45)c([2H])c([2H])c32)c1[2H] ; [2H]c1c([2H])c([2H])c2c(oc3c([2H])c(-c4c5c([2H])c([2H])c([2H])c([2H])c5c(-c5ccc6ccccc6c5)c5c([2H])c([2H])c([2H])c([2H])c45)c([2H])c([2H])c32)c1[2H]]

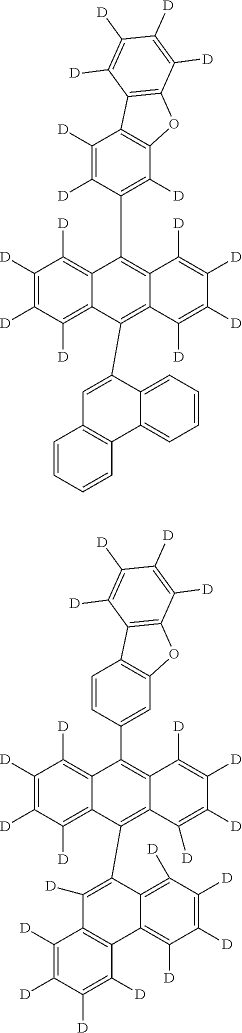 [SMILES: [2H]c1c([2H])c([2H])c2c(oc3c([2H])c(-c4c5c([2H])c([2H])c([2H])c([2H])c5c(-c5cc6ccccc6c6ccccc56)c5c([2H])c([2H])c([2H])c([2H])c45)c([2H])c([2H])c32)c1[2H] ; [2H]c1c([2H])c([2H])c2c(oc3cc(-c4c5c([2H])c([2H])c([2H])c([2H])c5c(-c5c([2H])c6c([2H])c([2H])c([2H])c([2H])c6c6c([2H])c([2H])c([2H])c([2H])c56)c5c([2H])c([2H])c([2H])c([2H])c45)ccc32)c1[2H]]

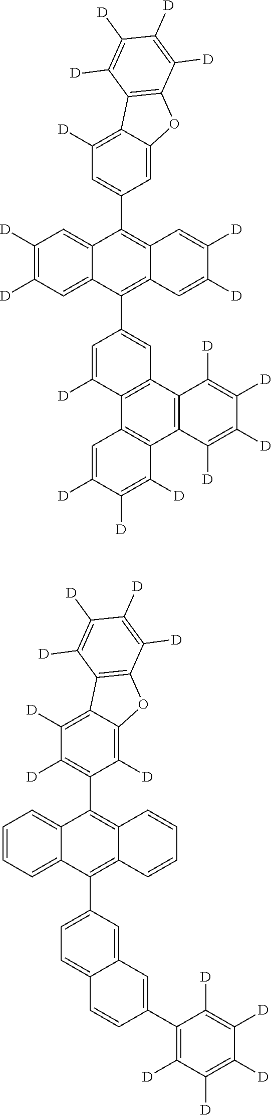 [SMILES: [2H]c1cc2c(-c3cc([2H])c4c(c3)oc3c([2H])c([2H])c([2H])c([2H])c34)c3cc([2H])c([2H])cc3c(-c3cc([2H])c4c5cc([2H])c([2H])c([2H])c5c5c([2H])c([2H])c([2H])c([2H])c5c4c3)c2cc1[2H] ; [2H]c1c([2H])c([2H])c(-c2ccc3ccc(-c4c5ccccc5c(-c5c([2H])c([2H])c6c(oc7c([2H])c([2H])c([2H])c([2H])c76)c5[2H])c5ccccc45)cc3c2)c([2H])c1[2H]]

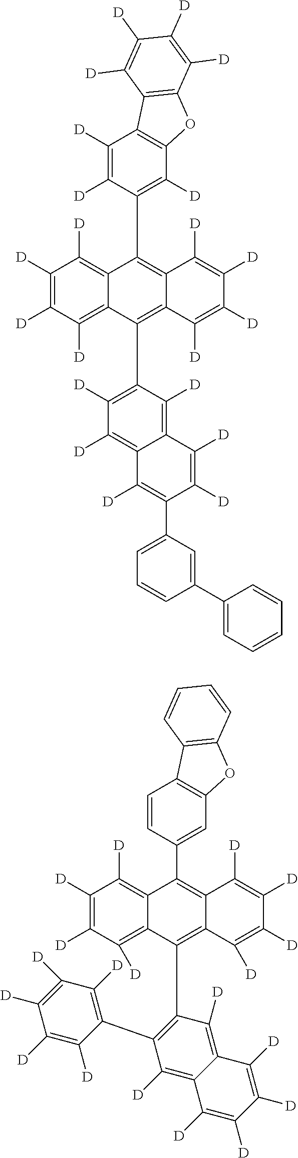 [SMILES: [2H]c1c([2H])c([2H])c2c(oc3c([2H])c(-c4c5c([2H])c([2H])c([2H])c([2H])c5c(-c5c([2H])c([2H])c6c([2H])c(-c7cccc(-c8ccccc8)c7)c([2H])c([2H])c6c5[2H])c5c([2H])c([2H])c([2H])c([2H])c45)c([2H])c([2H])c32)c1[2H] ; [2H]c1c([2H])c([2H])c(-c2c(-c3c4c([2H])c([2H])c([2H])c([2H])c4c(-c4ccc5c(c4)oc4ccccc45)c4c([2H])c([2H])c([2H])c([2H])c34)c([2H])c3c([2H])c([2H])c([2H])c([2H])c3c2[2H])c([2H])c1[2H]]

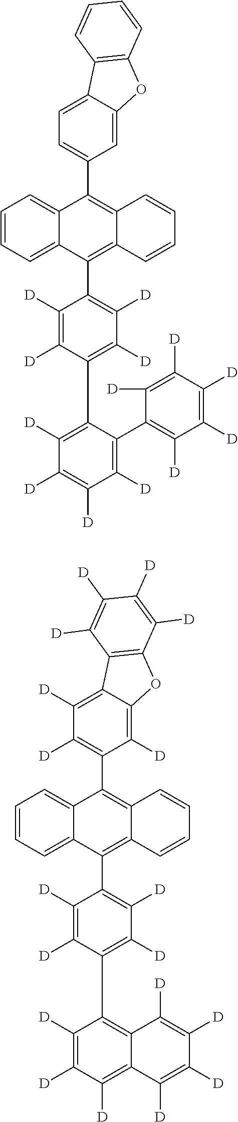 [SMILES: [2H]c1c([2H])c([2H])c(-c2c([2H])c([2H])c([2H])c([2H])c2-c2c([2H])c([2H])c(-c3c4ccccc4c(-c4ccc5c(c4)oc4ccccc45)c4ccccc34)c([2H])c2[2H])c([2H])c1[2H] ; [2H]c1c([2H])c(-c2c([2H])c([2H])c([2H])c3c([2H])c([2H])c([2H])c([2H])c23)c([2H])c([2H])c1-c1c2ccccc2c(-c2c([2H])c([2H])c3c(oc4c([2H])c([2H])c([2H])c([2H])c43)c2[2H])c2ccccc12]

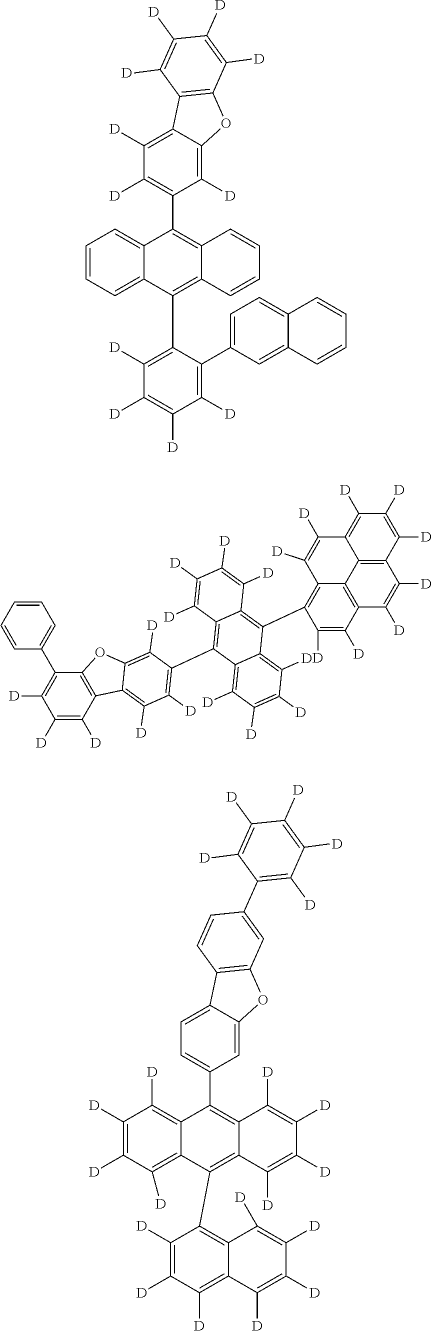

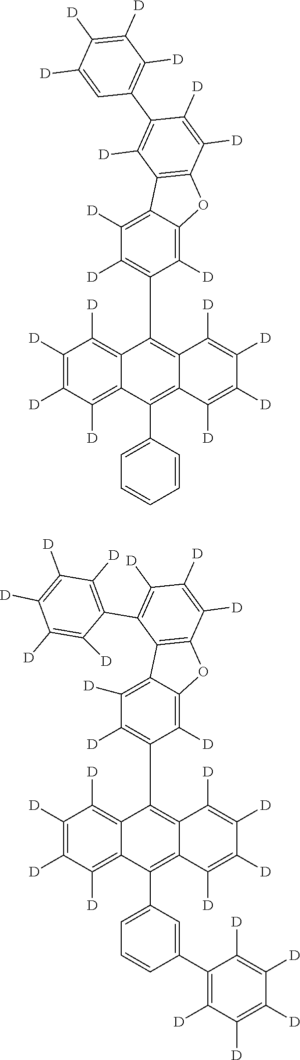 [SMILES: [2H]c1cc(-c2c([2H])c([2H])c3oc4c([2H])c(-c5c6c([2H])c([2H])c([2H])c([2H])c6c(-c6ccccc6)c6c([2H])c([2H])c([2H])c([2H])c56)c([2H])c([2H])c4c3c2[2H])c([2H])c([2H])c1[2H] ; [2H]c1c([2H])c([2H])c(-c2cccc(-c3c4c([2H])c([2H])c([2H])c([2H])c4c(-c4c([2H])c([2H])c5c(oc6c([2H])c([2H])c([2H])c(-c7c([2H])c([2H])c([2H])c([2H])c7[2H])c65)c4[2H])c4c([2H])c([2H])c([2H])c([2H])c34)c2)c([2H])c1[2H]]

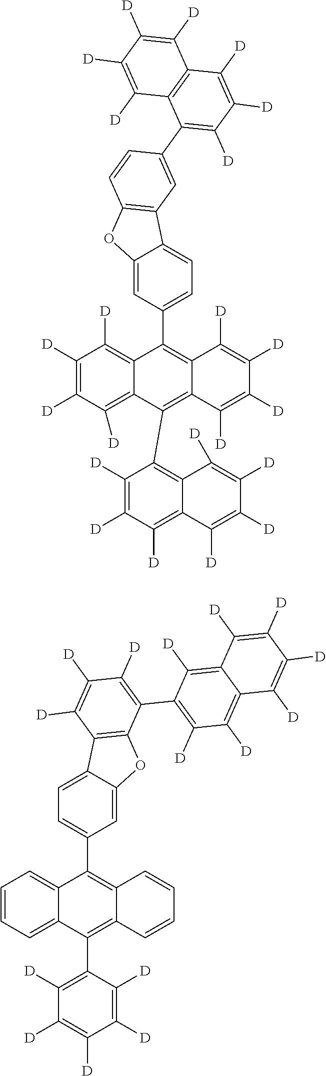 [SMILES: [2H]c1c([2H])c([2H])c2c(-c3ccc4oc5cc(-c6c7c([2H])c([2H])c([2H])c([2H])c7c(-c7c([2H])c([2H])c([2H])c8c([2H])c([2H])c([2H])c([2H])c78)c7c([2H])c([2H])c([2H])c([2H])c67)ccc5c4c3)c([2H])c([2H])c([2H])c2c1[2H] ; [2H]c1c([2H])c([2H])c(-c2c3ccccc3c(-c3ccc4c(c3)oc3c(-c5c([2H])c([2H])c6c([2H])c([2H])c([2H])c([2H])c6c5[2H])c([2H])c([2H])c([2H])c34)c3ccccc23)c([2H])c1[2H]]

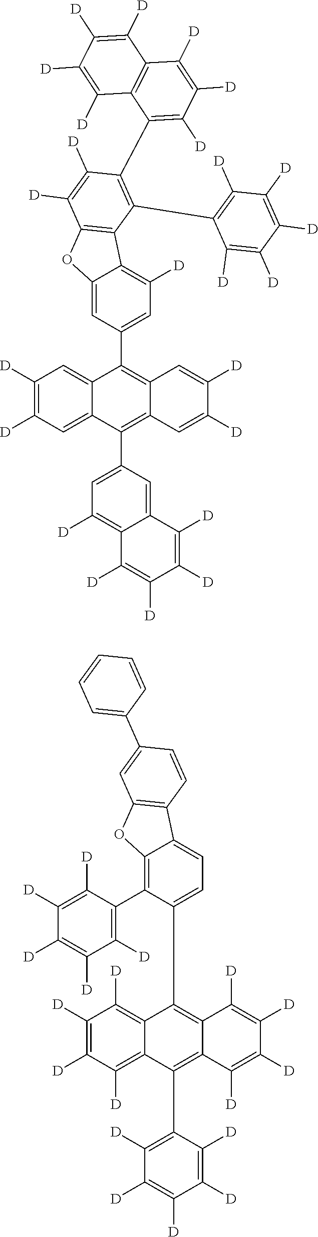 [SMILES: [2H]c1cc2c(-c3cc([2H])c4c(c3)oc3c([2H])c([2H])c(-c5c([2H])c([2H])c([2H])c6c([2H])c([2H])c([2H])c([2H])c56)c(-c5c([2H])c([2H])c([2H])c([2H])c5[2H])c34)c3cc([2H])c([2H])cc3c(-c3cc([2H])c4c([2H])c([2H])c([2H])c([2H])c4c3)c2cc1[2H] ; [2H]c1c([2H])c([2H])c(-c2c(-c3c4c([2H])c([2H])c([2H])c([2H])c4c(-c4c([2H])c([2H])c([2H])c([2H])c4[2H])c4c([2H])c([2H])c([2H])c([2H])c34)ccc3c2oc2cc(-c4ccccc4)ccc23)c([2H])c1[2H]]

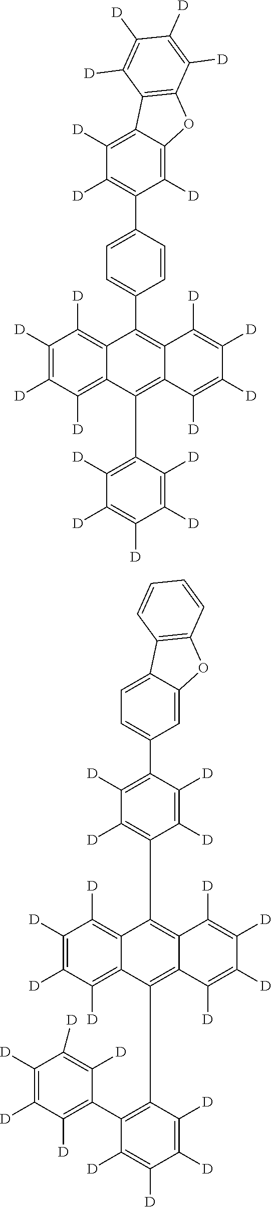

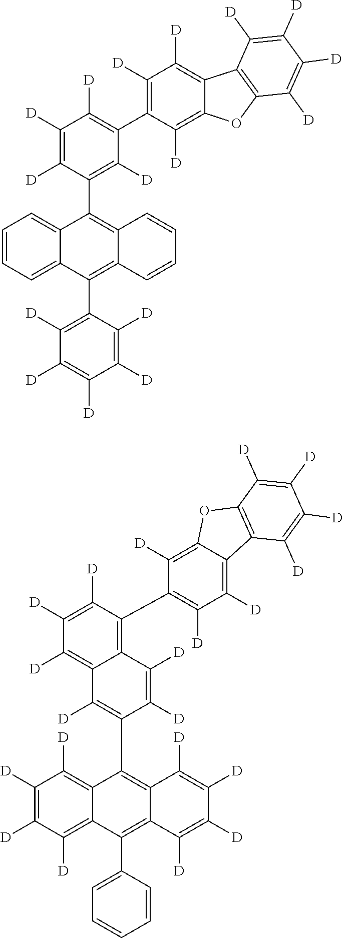 [SMILES: [2H]c1c([2H])c([2H])c(-c2c3ccccc3c(-c3c([2H])c([2H])c([2H])c(-c4c([2H])c([2H])c5c(oc6c([2H])c([2H])c([2H])c([2H])c65)c4[2H])c3[2H])c3ccccc23)c([2H])c1[2H] ; [2H]c1c([2H])c([2H])c2c(oc3c([2H])c(-c4c([2H])c([2H])c([2H])c5c([2H])c(-c6c7c([2H])c([2H])c([2H])c([2H])c7c(-c7ccccc7)c7c([2H])c([2H])c([2H])c([2H])c67)c([2H])c([2H])c45)c([2H])c([2H])c32)c1[2H]]

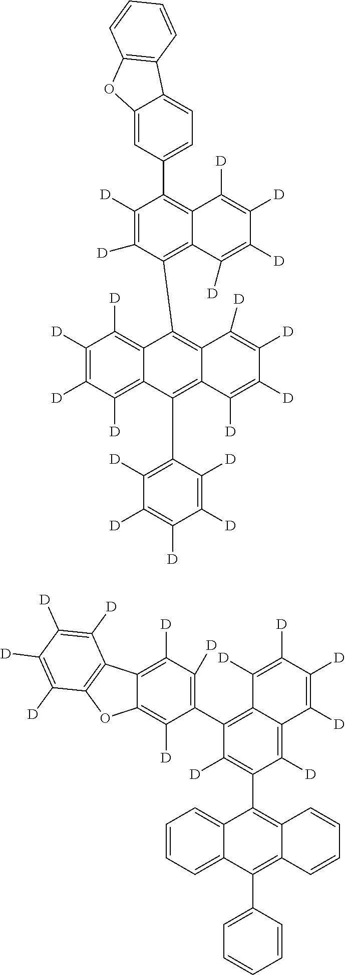 [SMILES: [2H]c1c([2H])c([2H])c(-c2c3c([2H])c([2H])c([2H])c([2H])c3c(-c3c([2H])c([2H])c(-c4ccc5c(c4)oc4ccccc45)c4c([2H])c([2H])c([2H])c([2H])c34)c3c([2H])c([2H])c([2H])c([2H])c23)c([2H])c1[2H] ; [2H]c1c([2H])c([2H])c2c(oc3c([2H])c(-c4c([2H])c(-c5c6ccccc6c(-c6ccccc6)c6ccccc56)c([2H])c5c([2H])c([2H])c([2H])c([2H])c45)c([2H])c([2H])c32)c1[2H]]

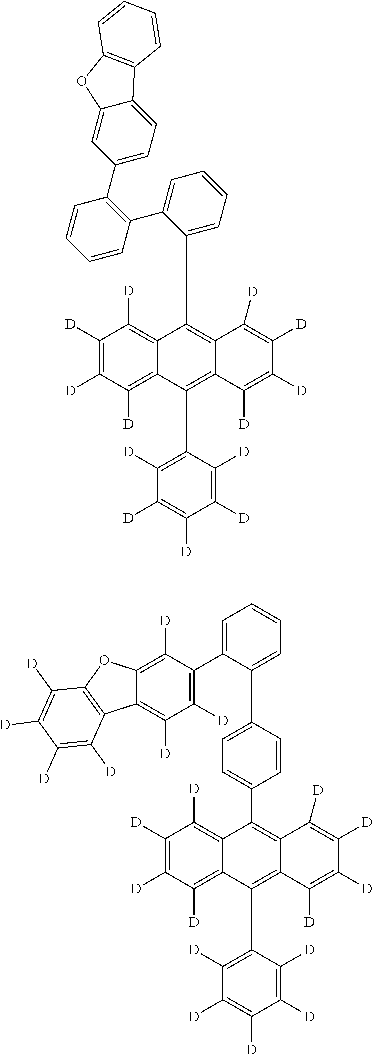 [SMILES: [2H]c1c([2H])c([2H])c(-c2c3c([2H])c([2H])c([2H])c([2H])c3c(-c3ccccc3-c3ccccc3-c3ccc4c(c3)oc3ccccc34)c3c([2H])c([2H])c([2H])c([2H])c23)c([2H])c1[2H] ; [2H]c1c([2H])c([2H])c(-c2c3c([2H])c([2H])c([2H])c([2H])c3c(-c3ccc(-c4ccccc4-c4c([2H])c([2H])c5c(oc6c([2H])c([2H])c([2H])c([2H])c65)c4[2H])cc3)c3c([2H])c([2H])c([2H])c([2H])c23)c([2H])c1[2H]]

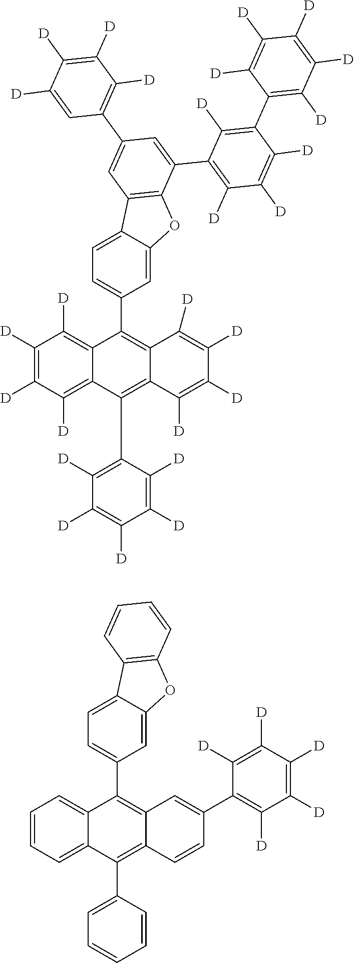 [SMILES: [2H]c1cc(-c2cc(-c3c([2H])c([2H])c([2H])c(-c4c([2H])c([2H])c([2H])c([2H])c4[2H])c3[2H])c3oc4cc(-c5c6c([2H])c([2H])c([2H])c([2H])c6c(-c6c([2H])c([2H])c([2H])c([2H])c6[2H])c6c([2H])c([2H])c([2H])c([2H])c56)ccc4c3c2)c([2H])c([2H])c1[2H] ; [2H]c1c([2H])c([2H])c(-c2ccc3c(-c4ccccc4)c4ccccc4c(-c4ccc5c(c4)oc4ccccc45)c3c2)c([2H])c1[2H]]

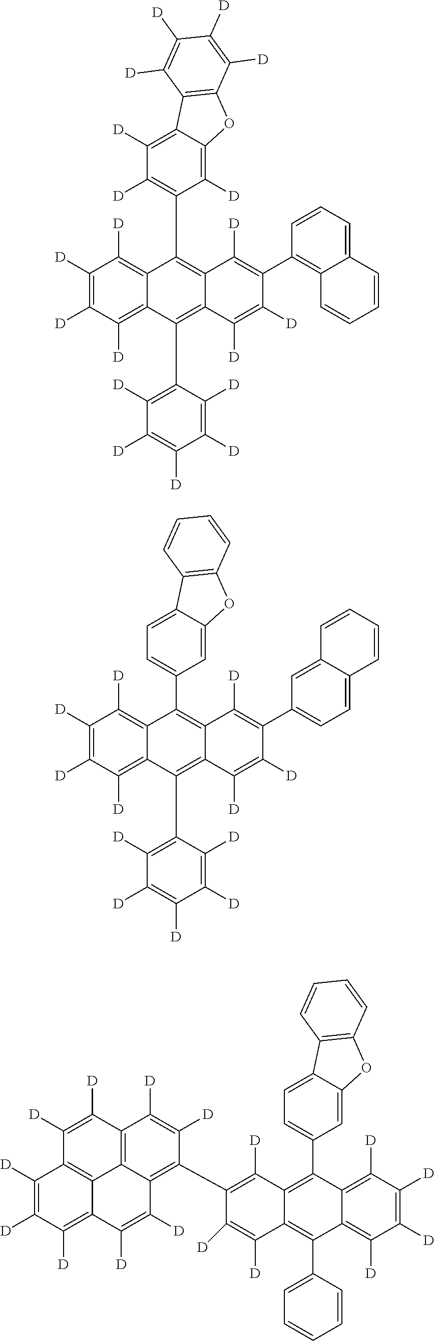

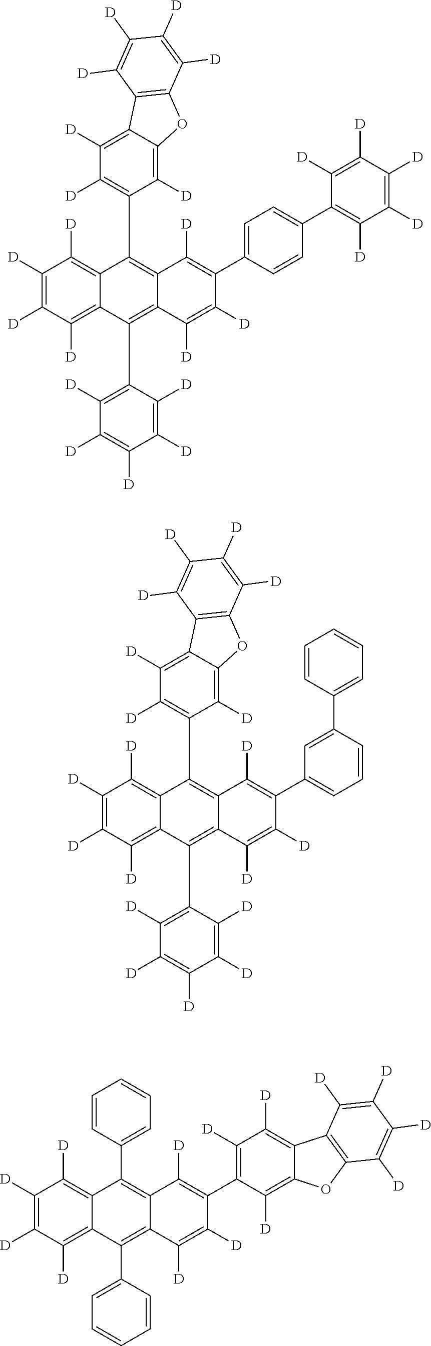

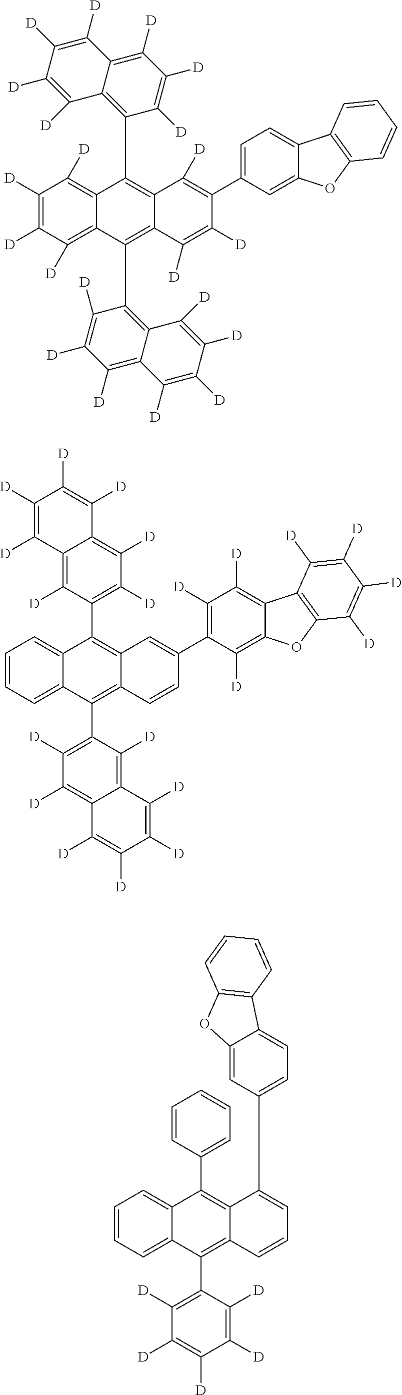 [SMILES: [2H]c1c([2H])c([2H])c2c(-c3c4c([2H])c([2H])c([2H])c([2H])c4c(-c4c([2H])c([2H])c([2H])c5c([2H])c([2H])c([2H])c([2H])c45)c4c([2H])c(-c5ccc6c(c5)oc5ccccc56)c([2H])c([2H])c34)c([2H])c([2H])c([2H])c2c1[2H] ; [2H]c1c([2H])c([2H])c2c(oc3c([2H])c(-c4ccc5c(-c6c([2H])c([2H])c7c([2H])c([2H])c([2H])c([2H])c7c6[2H])c6ccccc6c(-c6c([2H])c([2H])c7c([2H])c([2H])c([2H])c([2H])c7c6[2H])c5c4)c([2H])c([2H])c32)c1[2H] ; [2H]c1c([2H])c([2H])c(-c2c3ccccc3c(-c3ccccc3)c3c(-c4ccc5c(c4)oc4ccccc45)cccc23)c([2H])c1[2H]]

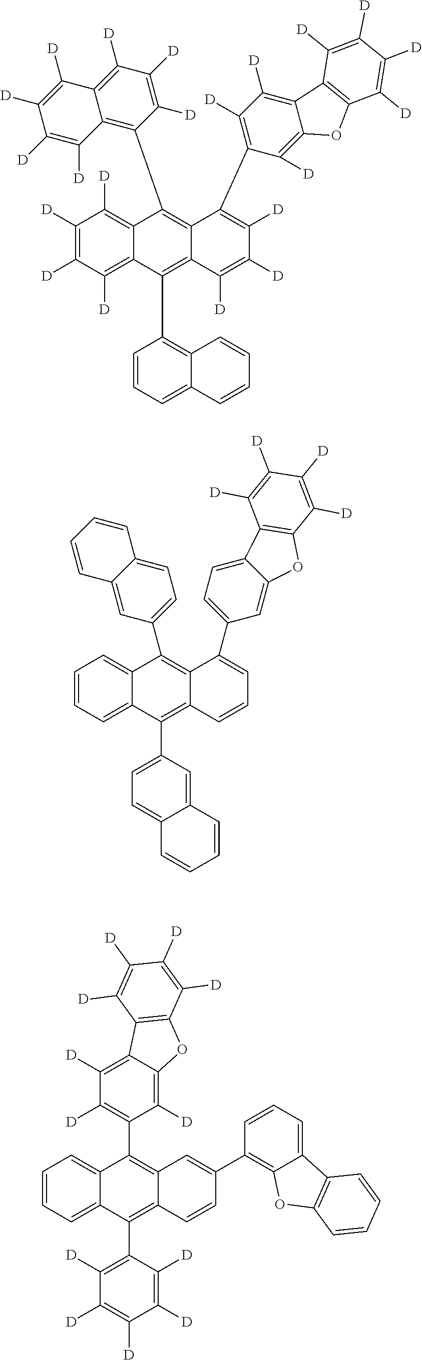 [SMILES: [2H]c1c([2H])c([2H])c2c(oc3c([2H])c(-c4c([2H])c([2H])c([2H])c5c(-c6cccc7ccccc67)c6c([2H])c([2H])c([2H])c([2H])c6c(-c6c([2H])c([2H])c([2H])c7c([2H])c([2H])c([2H])c([2H])c67)c45)c([2H])c([2H])c32)c1[2H] ; [2H]c1c([2H])c([2H])c2c(oc3cc(-c4cccc5c(-c6ccc7ccccc7c6)c6ccccc6c(-c6ccc7ccccc7c6)c45)ccc32)c1[2H] ; [2H]c1c([2H])c([2H])c(-c2c3ccccc3c(-c3c([2H])c([2H])c4c(oc5c([2H])c([2H])c([2H])c([2H])c54)c3[2H])c3cc(-c4cccc5c4oc4ccccc45)ccc23)c([2H])c1[2H]]

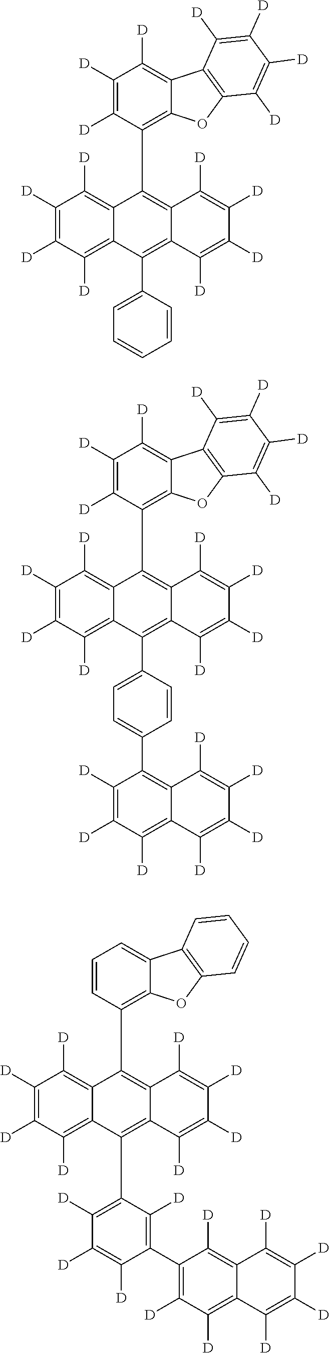

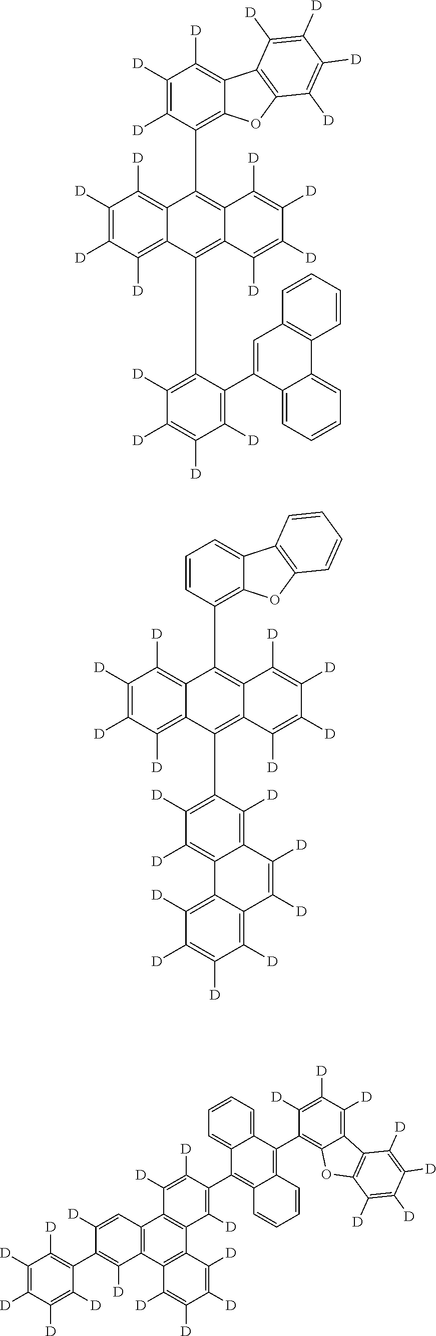

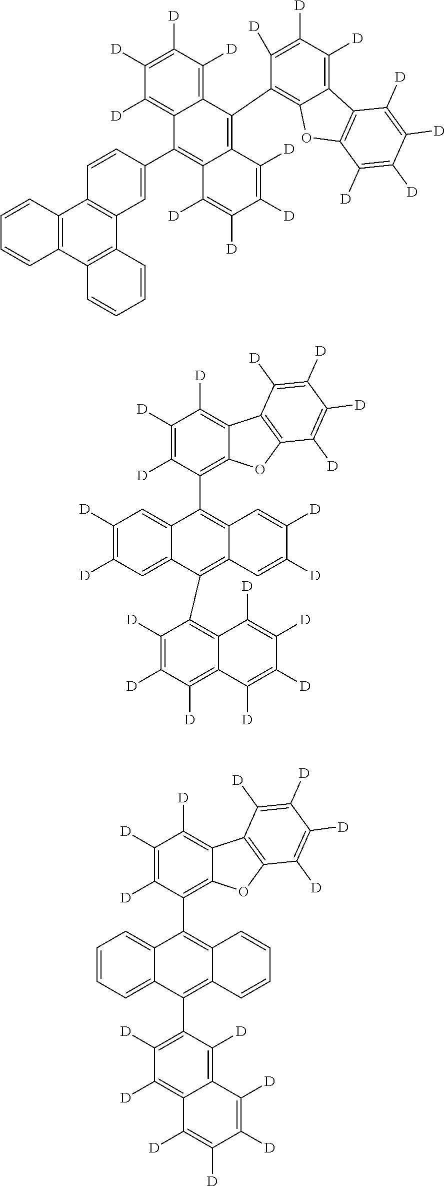 [SMILES: [2H]c1c([2H])c([2H])c2c(oc3c(-c4c5c([2H])c([2H])c([2H])c([2H])c5c(-c5ccc6c7ccccc7c7ccccc7c6c5)c5c([2H])c([2H])c([2H])c([2H])c45)c([2H])c([2H])c([2H])c32)c1[2H] ; [2H]c1cc2c(-c3c([2H])c([2H])c([2H])c4c3oc3c([2H])c([2H])c([2H])c([2H])c34)c3cc([2H])c([2H])cc3c(-c3c([2H])c([2H])c([2H])c4c([2H])c([2H])c([2H])c([2H])c34)c2cc1[2H] ; [2H]c1c([2H])c([2H])c2c(oc3c(-c4c5ccccc5c(-c5c([2H])c([2H])c6c([2H])c([2H])c([2H])c([2H])c6c5[2H])c5ccccc45)c([2H])c([2H])c([2H])c32)c1[2H]]

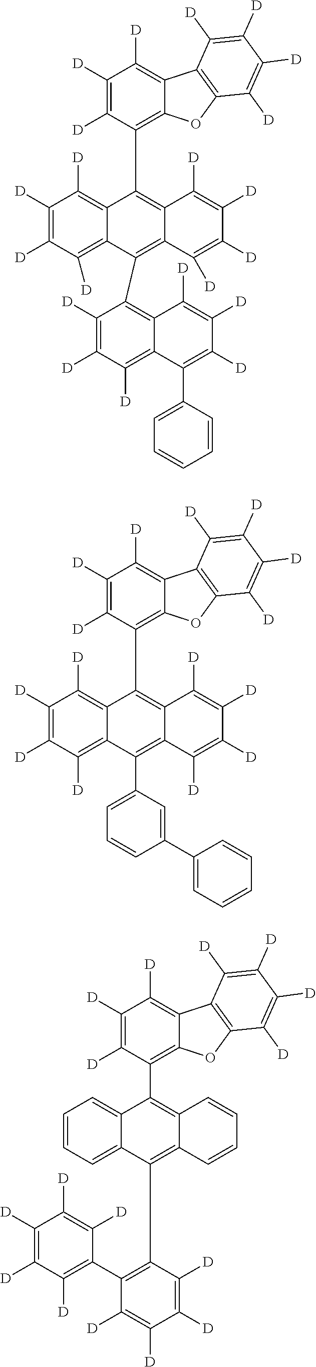

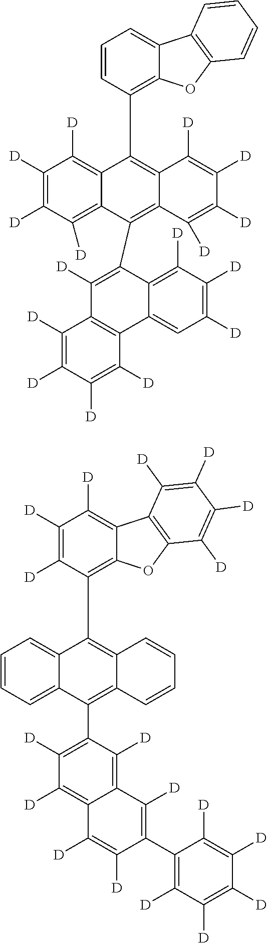 [SMILES: [2H]c1cc2c(c([2H])c1[2H])c(-c1c3c([2H])c([2H])c([2H])c([2H])c3c(-c3cccc4c3oc3ccccc34)c3c([2H])c([2H])c([2H])c([2H])c13)c([2H])c1c([2H])c([2H])c([2H])c([2H])c12 ; [2H]c1c([2H])c([2H])c(-c2c([2H])c([2H])c3c([2H])c([2H])c(-c4c5ccccc5c(-c5c([2H])c([2H])c([2H])c6c5oc5c([2H])c([2H])c([2H])c([2H])c56)c5ccccc45)c([2H])c3c2[2H])c([2H])c1[2H]]

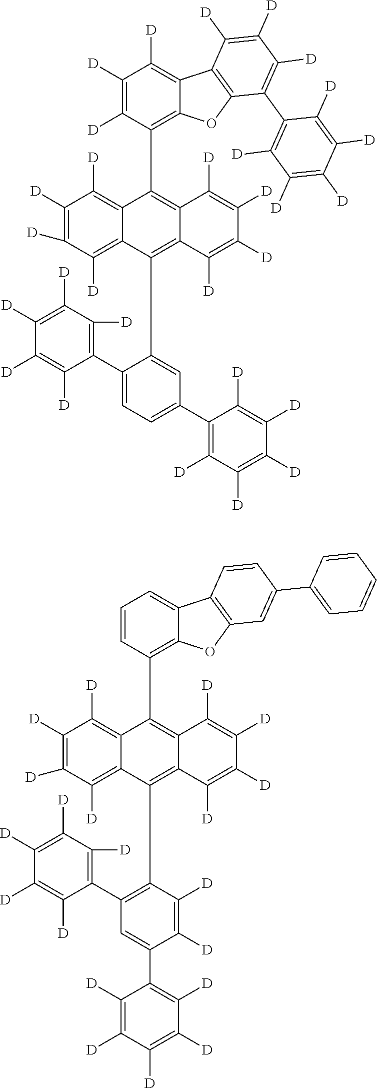 [SMILES: [2H]c1c([2H])c([2H])c(-c2ccc(-c3c([2H])c([2H])c([2H])c([2H])c3[2H])c(-c3c4c([2H])c([2H])c([2H])c([2H])c4c(-c4c([2H])c([2H])c([2H])c5c4oc4c(-c6c([2H])c([2H])c([2H])c([2H])c6[2H])c([2H])c([2H])c([2H])c45)c4c([2H])c([2H])c([2H])c([2H])c34)c2)c([2H])c1[2H] ; [2H]c1c(-c2c([2H])c([2H])c([2H])c([2H])c2[2H])cc(-c2c([2H])c([2H])c([2H])c([2H])c2[2H])c(-c2c3c([2H])c([2H])c([2H])c([2H])c3c(-c3cccc4c3oc3cc(-c5ccccc5)ccc34)c3c([2H])c([2H])c([2H])c([2H])c23)c1[2H]]

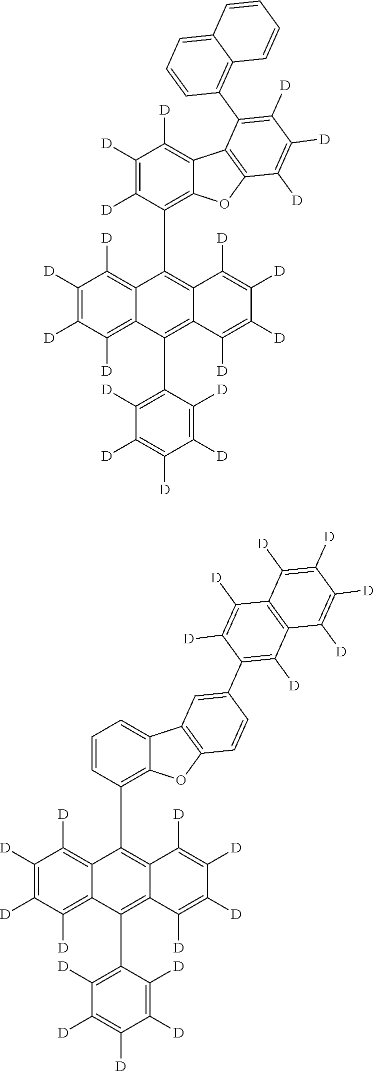 [SMILES: [2H]c1c([2H])c([2H])c(-c2c3c([2H])c([2H])c([2H])c([2H])c3c(-c3c([2H])c([2H])c([2H])c4c3oc3c([2H])c([2H])c([2H])c(-c5cccc6ccccc56)c34)c3c([2H])c([2H])c([2H])c([2H])c23)c([2H])c1[2H] ; [2H]c1c([2H])c([2H])c(-c2c3c([2H])c([2H])c([2H])c([2H])c3c(-c3cccc4c3oc3ccc(-c5c([2H])c([2H])c6c([2H])c([2H])c([2H])c([2H])c6c5[2H])cc34)c3c([2H])c([2H])c([2H])c([2H])c23)c([2H])c1[2H]]

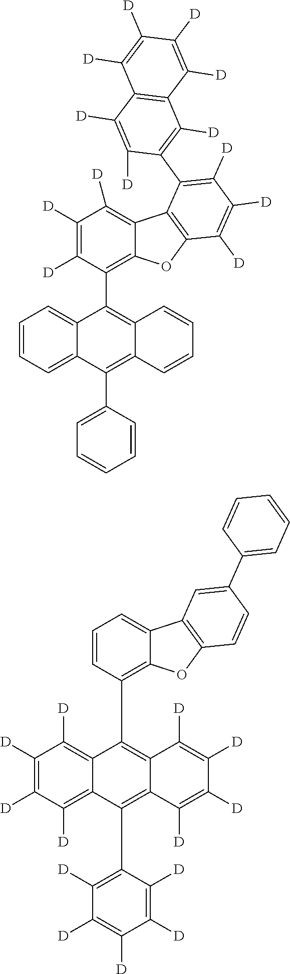 [SMILES: [2H]c1c([2H])c(-c2c([2H])c([2H])c3c([2H])c([2H])c([2H])c([2H])c3c2[2H])c2c(oc3c(-c4c5ccccc5c(-c5ccccc5)c5ccccc45)c([2H])c([2H])c([2H])c32)c1[2H] ; [2H]c1c([2H])c([2H])c(-c2c3c([2H])c([2H])c([2H])c([2H])c3c(-c3cccc4c3oc3ccc(-c5ccccc5)cc34)c3c([2H])c([2H])c([2H])c([2H])c23)c([2H])c1[2H]]

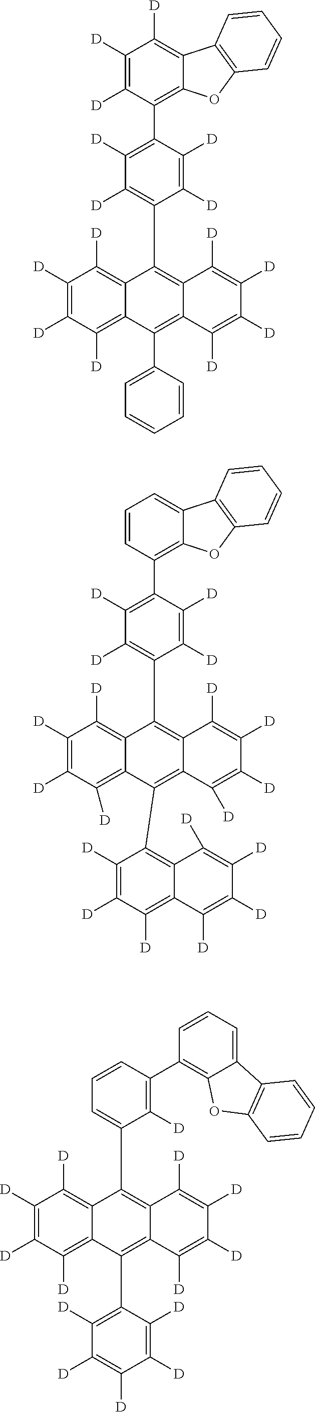 [SMILES: [2H]c1c([2H])c(-c2c3c([2H])c([2H])c([2H])c([2H])c3c(-c3ccccc3)c3c([2H])c([2H])c([2H])c([2H])c23)c([2H])c([2H])c1-c1c([2H])c([2H])c([2H])c2c1oc1ccccc12 ; [2H]c1c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c([2H])c([2H])c1-c1cccc2c1oc1ccccc12 ; [2H]c1c(-c2cccc3c2oc2ccccc23)cccc1-c1c2c([2H])c([2H])c([2H])c([2H])c2c(-c2c([2H])c([2H])c([2H])c([2H])c2[2H])c2c([2H])c([2H])c([2H])c([2H])c12]

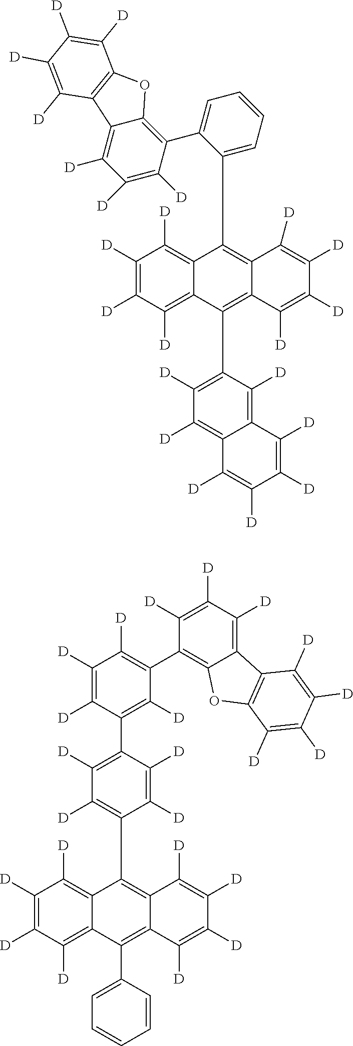 [SMILES: [2H]c1c([2H])c([2H])c2c(oc3c(-c4ccccc4-c4c5c([2H])c([2H])c([2H])c([2H])c5c(-c5c([2H])c([2H])c6c([2H])c([2H])c([2H])c([2H])c6c5[2H])c5c([2H])c([2H])c([2H])c([2H])c45)c([2H])c([2H])c([2H])c32)c1[2H] ; [2H]c1c([2H])c(-c2c([2H])c([2H])c(-c3c4c([2H])c([2H])c([2H])c([2H])c4c(-c4ccccc4)c4c([2H])c([2H])c([2H])c([2H])c34)c([2H])c2[2H])c([2H])c(-c2c([2H])c([2H])c([2H])c3c2oc2c([2H])c([2H])c([2H])c([2H])c23)c1[2H]]

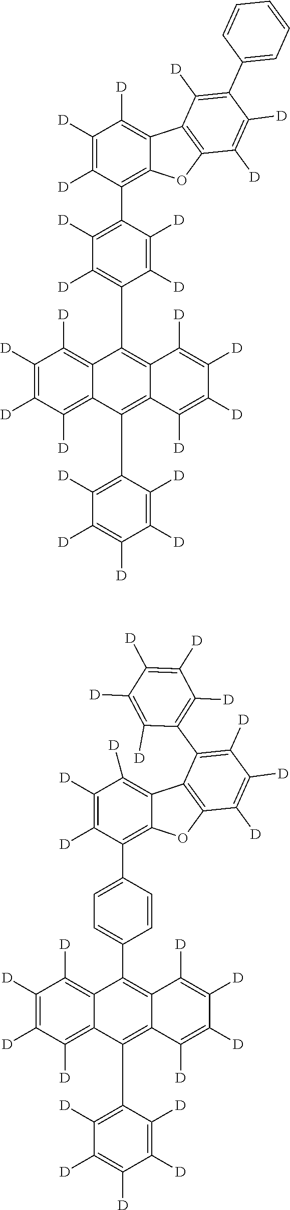 [SMILES: [2H]c1c([2H])c([2H])c(-c2c3c([2H])c([2H])c([2H])c([2H])c3c(-c3c([2H])c([2H])c(-c4c([2H])c([2H])c([2H])c5c4oc4c([2H])c([2H])c(-c6ccccc6)c([2H])c45)c([2H])c3[2H])c3c([2H])c([2H])c([2H])c([2H])c23)c([2H])c1[2H] ; [2H]c1c([2H])c([2H])c(-c2c3c([2H])c([2H])c([2H])c([2H])c3c(-c3ccc(-c4c([2H])c([2H])c([2H])c5c4oc4c([2H])c([2H])c([2H])c(-c6c([2H])c([2H])c([2H])c([2H])c6[2H])c45)cc3)c3c([2H])c([2H])c([2H])c([2H])c23)c([2H])c1[2H]]

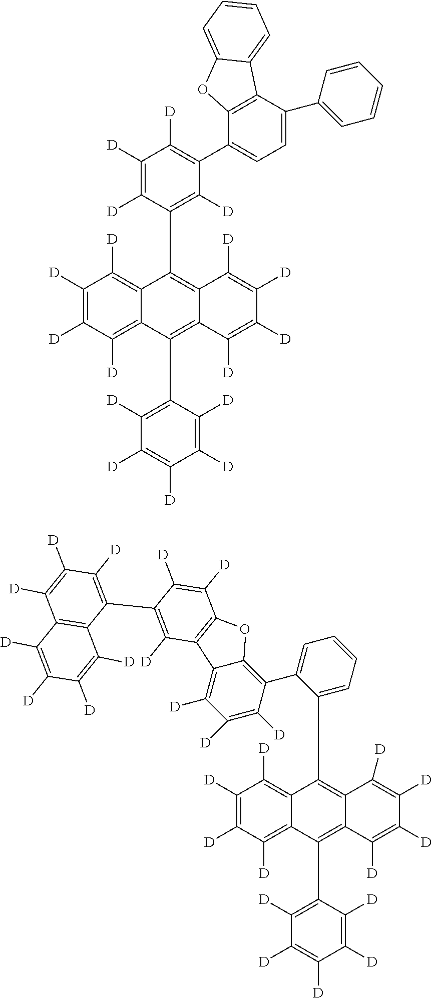 [SMILES: [2H]c1c([2H])c([2H])c(-c2c3c([2H])c([2H])c([2H])c([2H])c3c(-c3c([2H])c([2H])c([2H])c(-c4ccc(-c5ccccc5)c5c4oc4ccccc45)c3[2H])c3c([2H])c([2H])c([2H])c([2H])c23)c([2H])c1[2H] ; [2H]c1c([2H])c([2H])c(-c2c3c([2H])c([2H])c([2H])c([2H])c3c(-c3ccccc3-c3c([2H])c([2H])c([2H])c4c3oc3c([2H])c([2H])c(-c5c([2H])c([2H])c([2H])c6c([2H])c([2H])c([2H])c([2H])c56)c([2H])c34)c3c([2H])c([2H])c([2H])c([2H])c23)c([2H])c1[2H]]

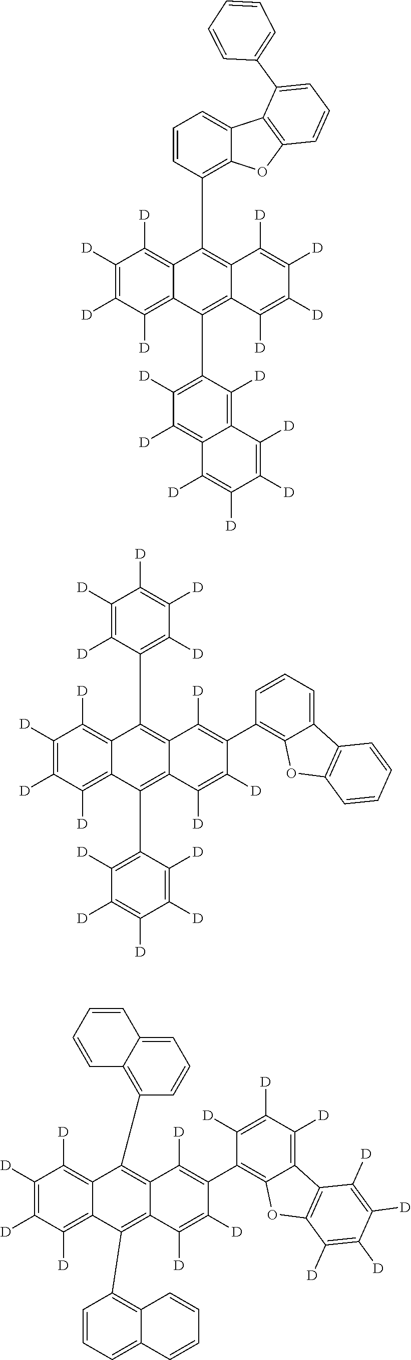 [SMILES: [2H]c1c([2H])c([2H])c2c([2H])c(-c3c4c([2H])c([2H])c([2H])c([2H])c4c(-c4cccc5c4oc4cccc(-c6ccccc6)c45)c4c([2H])c([2H])c([2H])c([2H])c34)c([2H])c([2H])c2c1[2H] ; [2H]c1c([2H])c([2H])c(-c2c3c([2H])c([2H])c([2H])c([2H])c3c(-c3c([2H])c([2H])c([2H])c([2H])c3[2H])c3c([2H])c(-c4cccc5c4oc4ccccc45)c([2H])c([2H])c23)c([2H])c1[2H] ; [2H]c1c([2H])c([2H])c2c(oc3c(-c4c([2H])c([2H])c5c(-c6cccc7ccccc67)c6c([2H])c([2H])c([2H])c([2H])c6c(-c6cccc7ccccc67)c5c4[2H])c([2H])c([2H])c([2H])c32)c1[2H]]

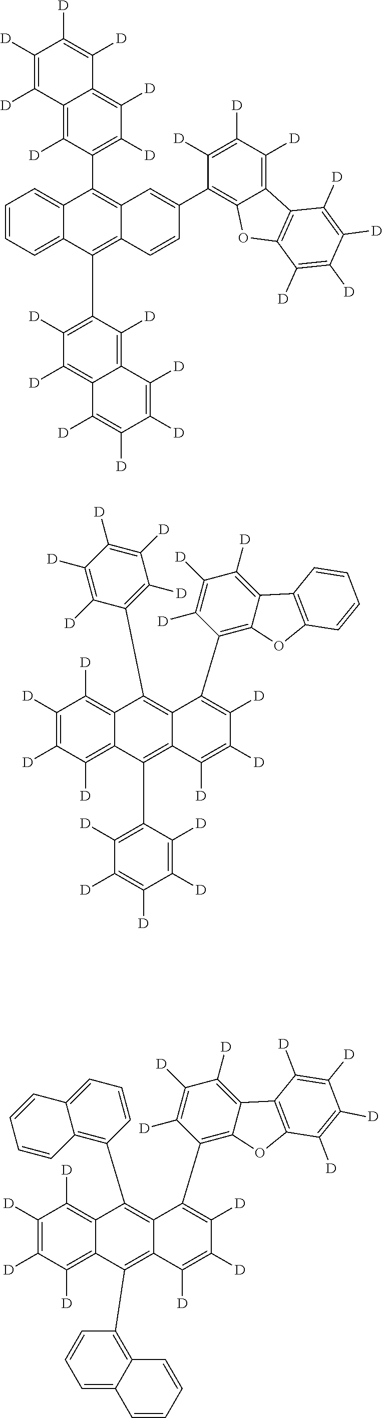

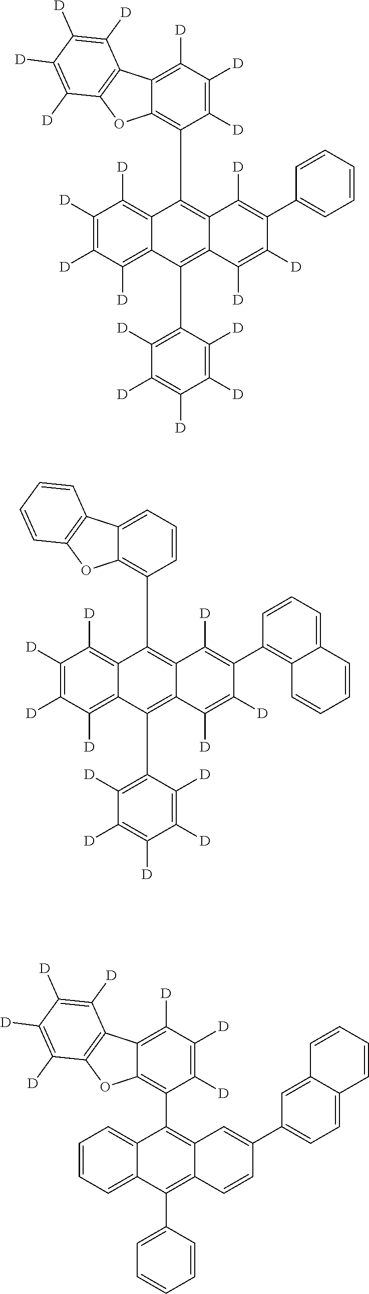 [SMILES: [2H]c1c([2H])c([2H])c(-c2c3c([2H])c([2H])c([2H])c([2H])c3c(-c3c([2H])c([2H])c([2H])c4c3oc3c([2H])c([2H])c([2H])c([2H])c34)c3c([2H])c(-c4ccccc4)c([2H])c([2H])c23)c([2H])c1[2H] ; [2H]c1c([2H])c([2H])c(-c2c3c([2H])c([2H])c([2H])c([2H])c3c(-c3cccc4c3oc3ccccc34)c3c([2H])c(-c4cccc5ccccc45)c([2H])c([2H])c23)c([2H])c1[2H] ; [2H]c1c([2H])c([2H])c2c(oc3c(-c4c5ccccc5c(-c5ccccc5)c5ccc(-c6ccc7ccccc7c6)cc45)c([2H])c([2H])c([2H])c32)c1[2H]]

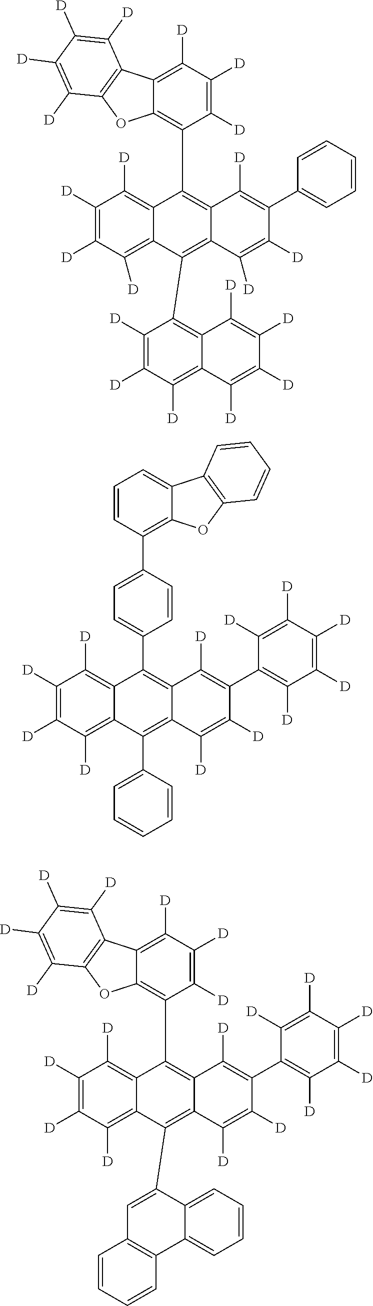

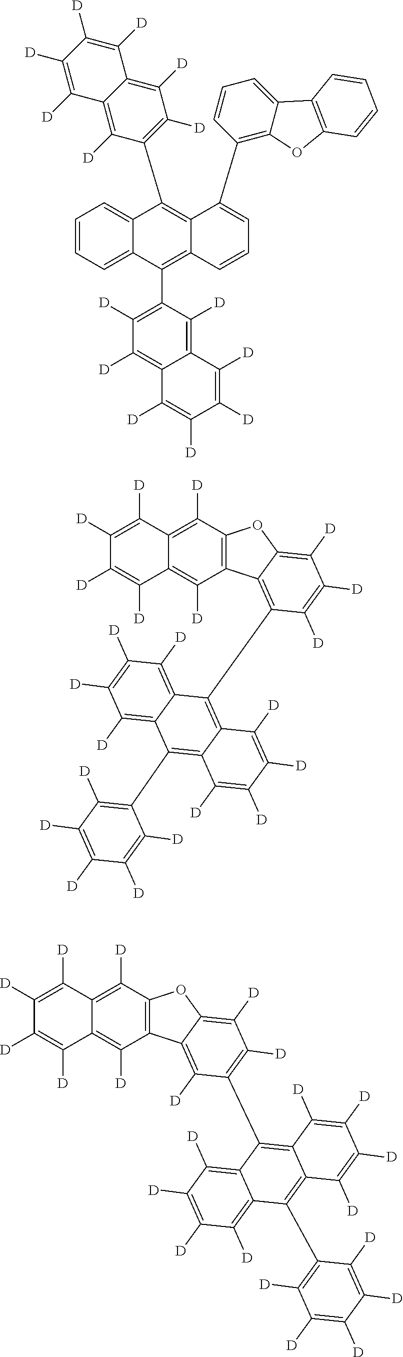

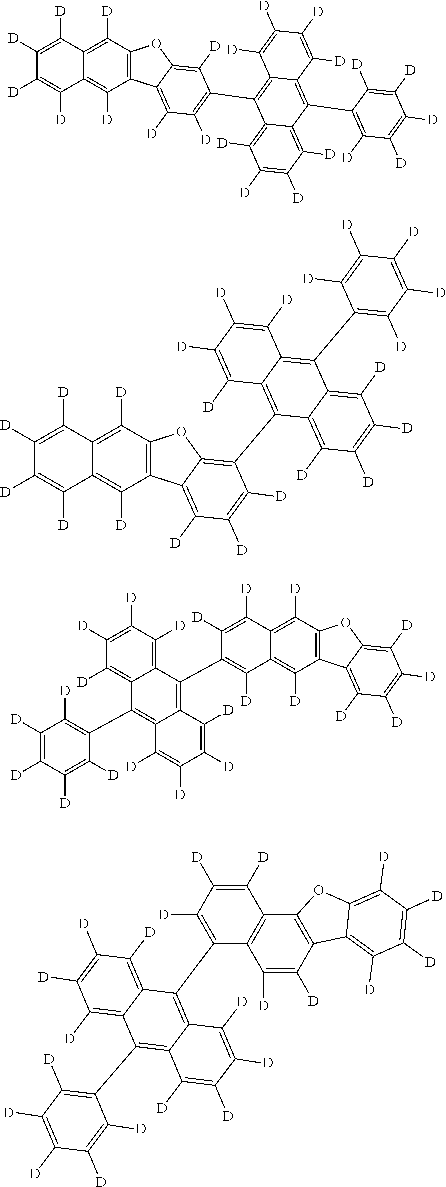

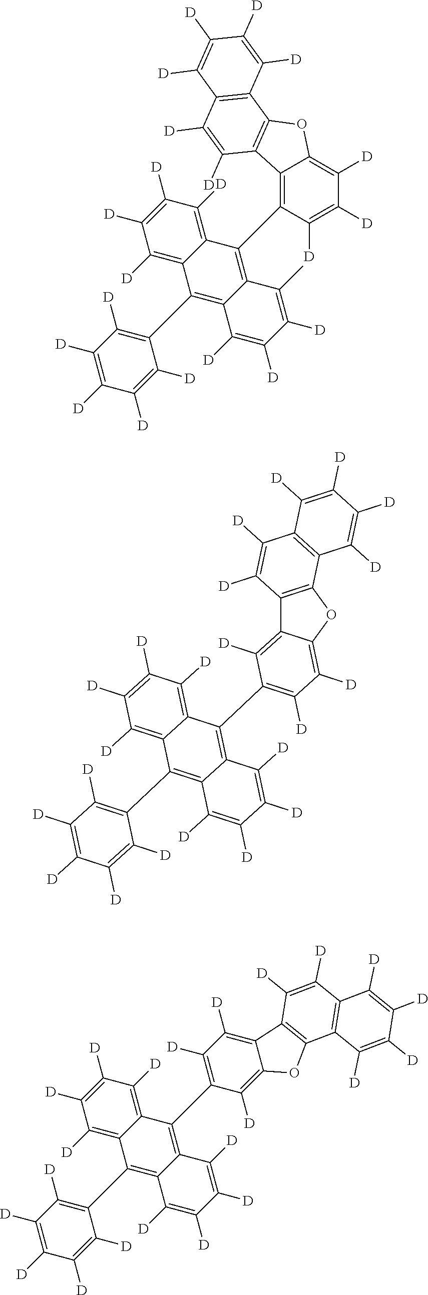

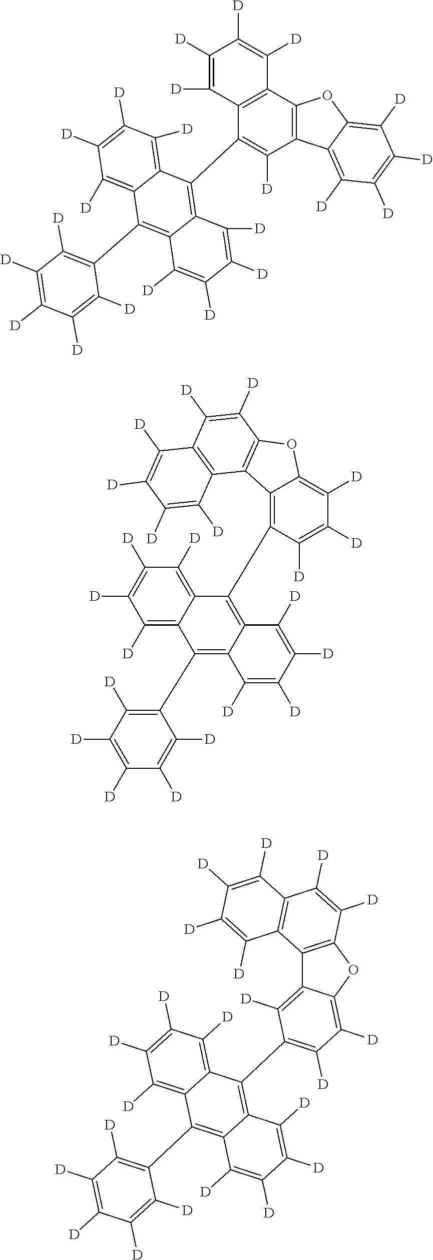

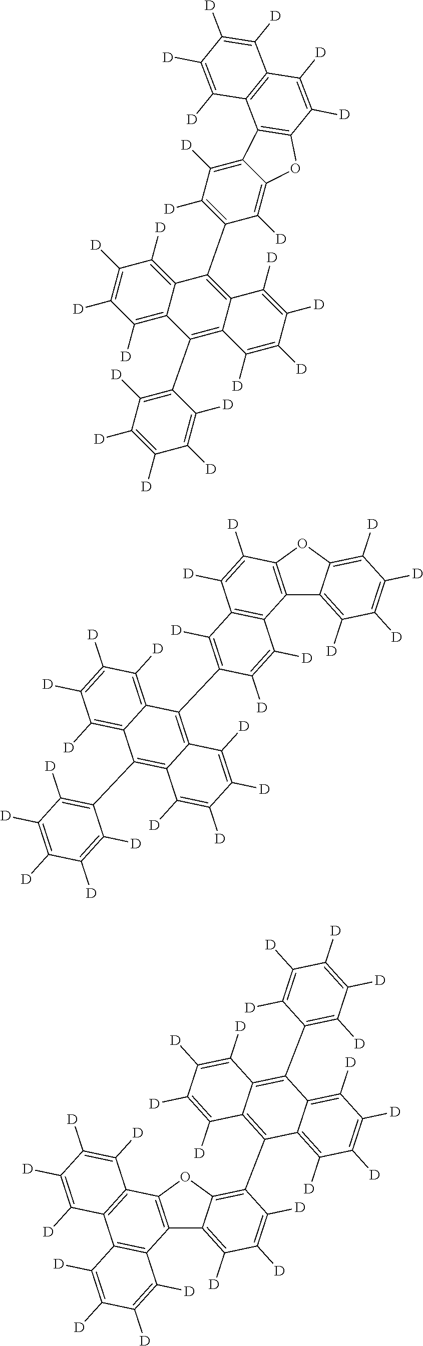

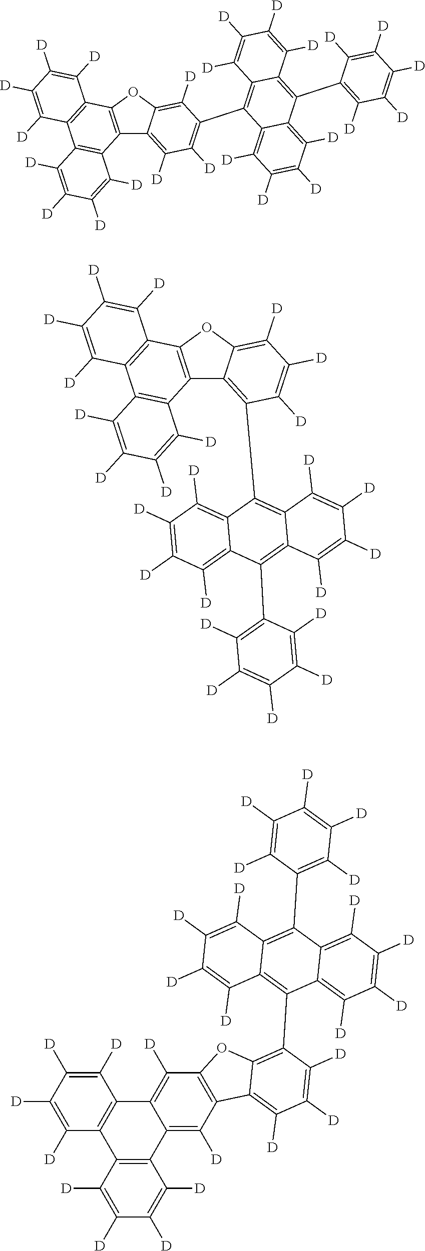

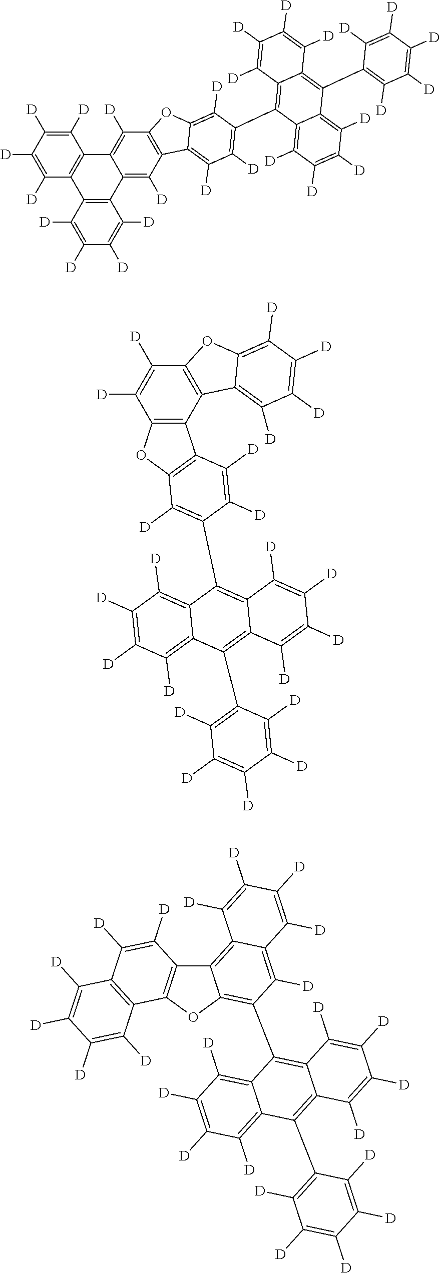

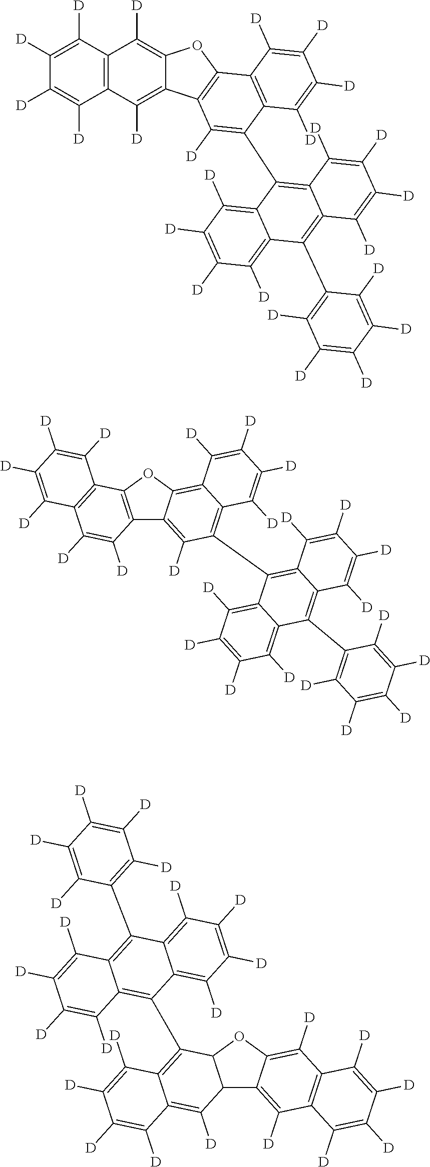

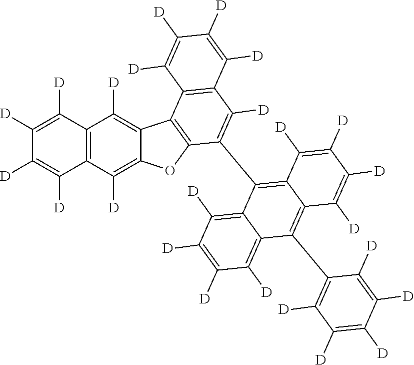 [SMILES: [2H]c1c([2H])c([2H])c(-c2c3c([2H])c([2H])c([2H])c([2H])c3c(-c3c([2H])c4c([2H])c([2H])c([2H])c([2H])c4c4c3oc3c([2H])c5c([2H])c([2H])c([2H])c([2H])c5c([2H])c34)c3c([2H])c([2H])c([2H])c([2H])c23)c([2H])c1[2H]]

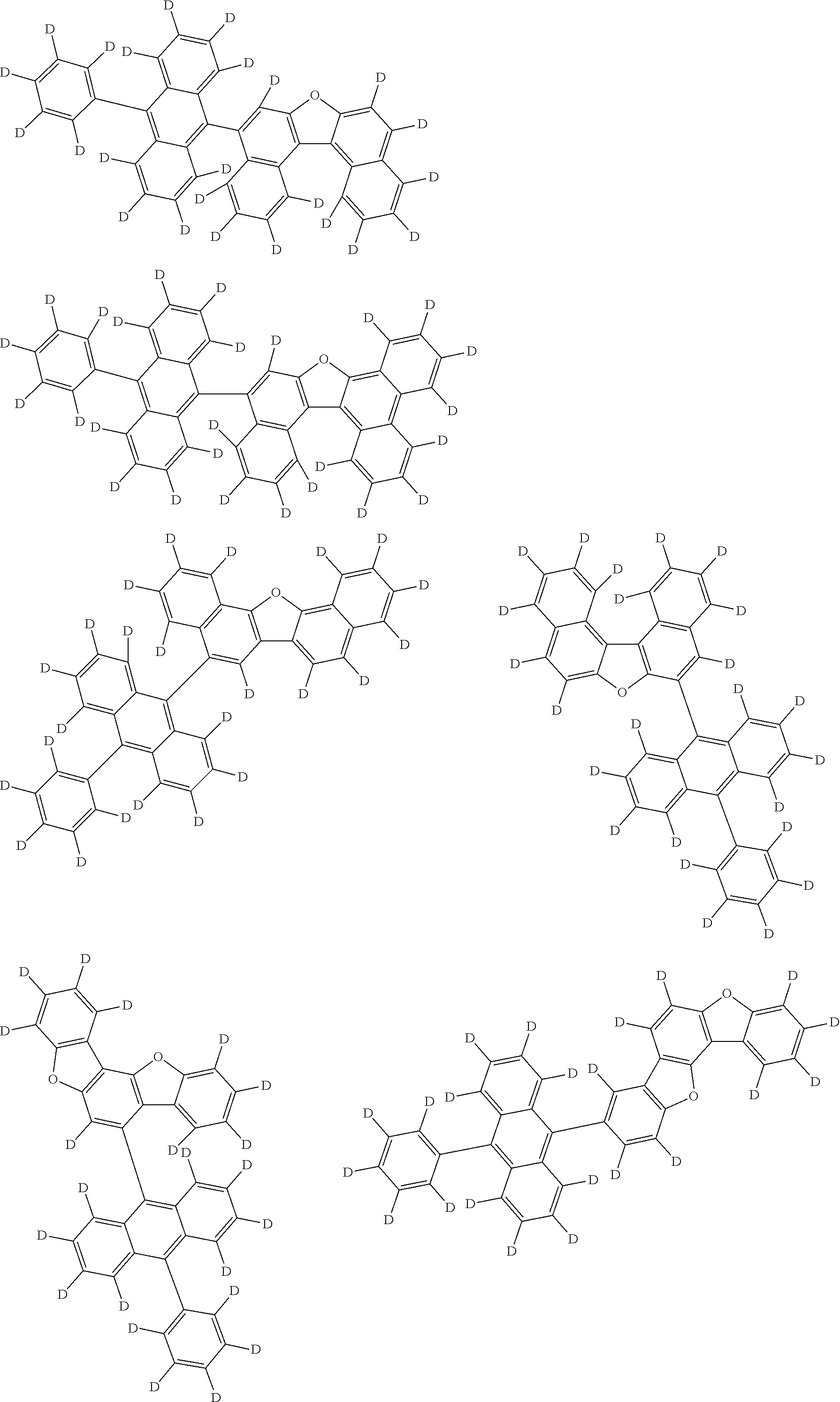

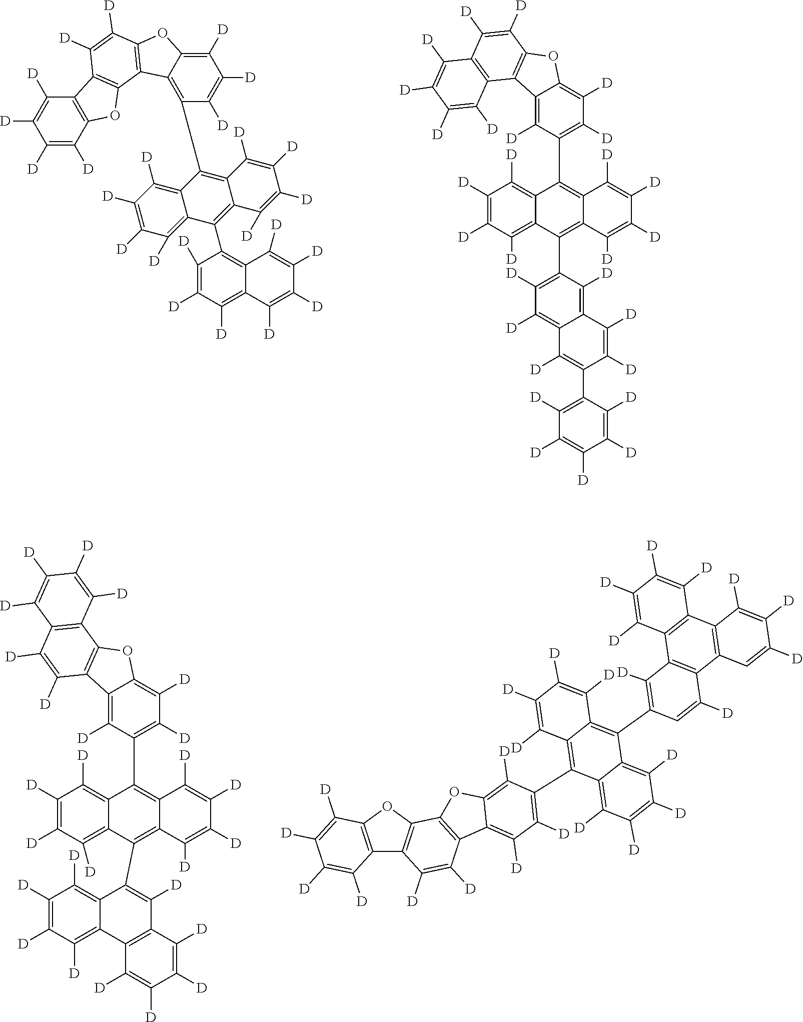

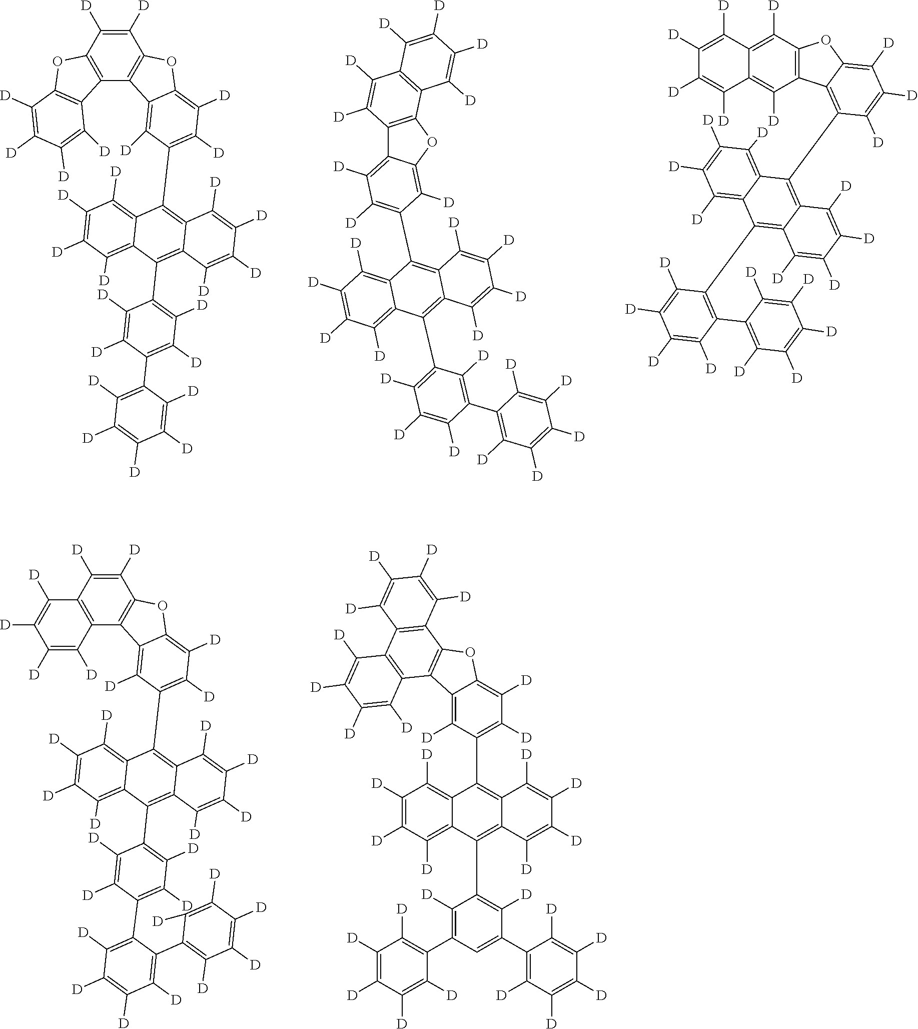

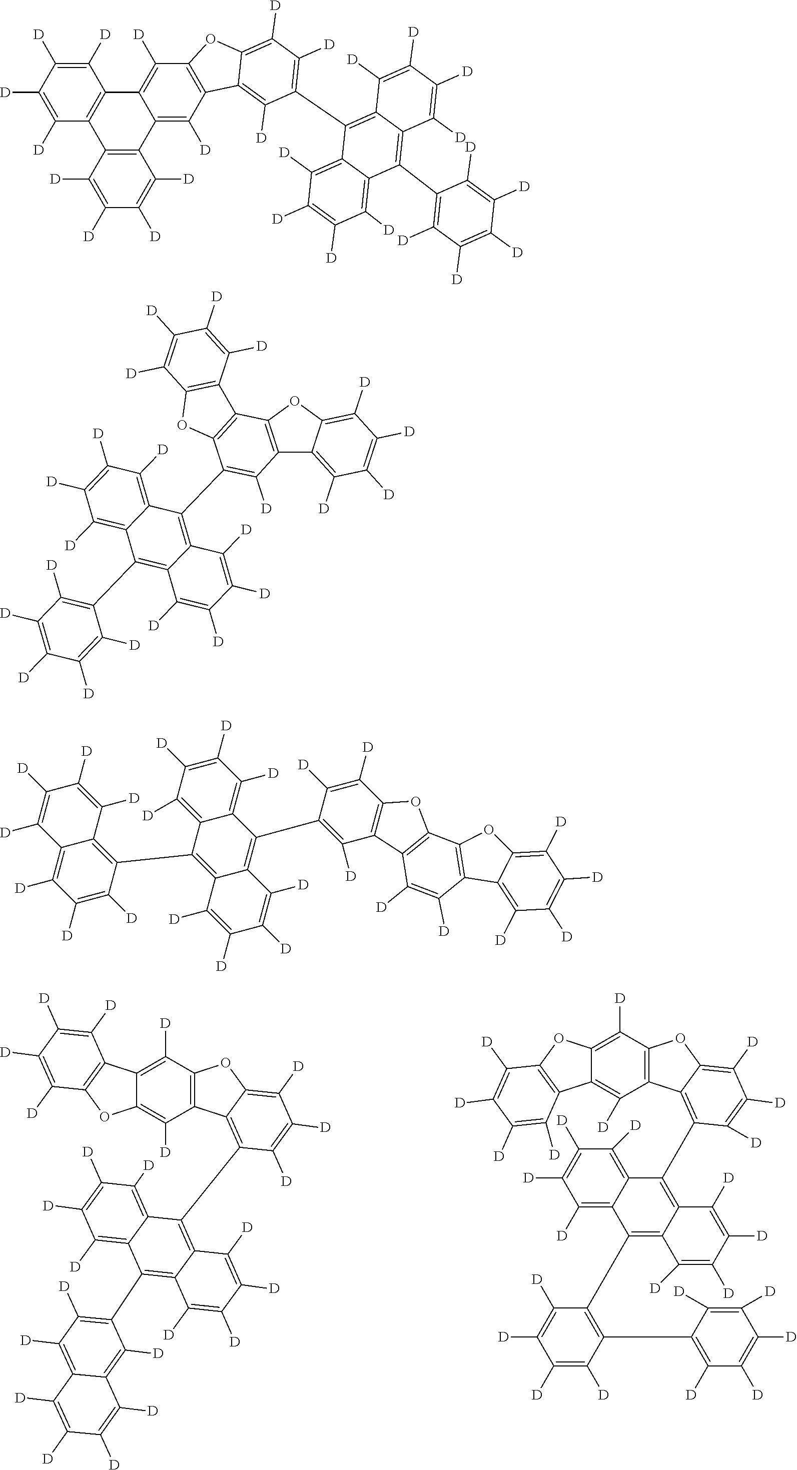

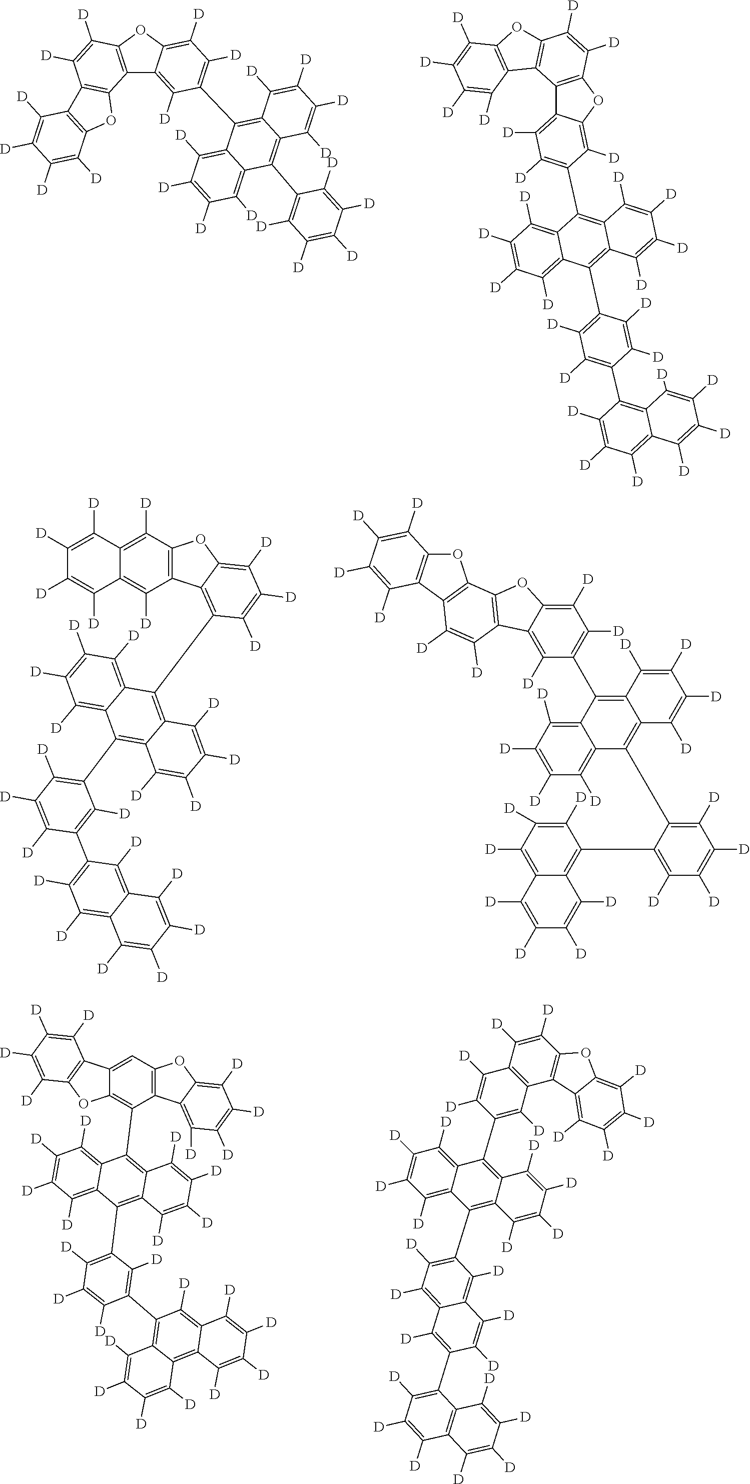

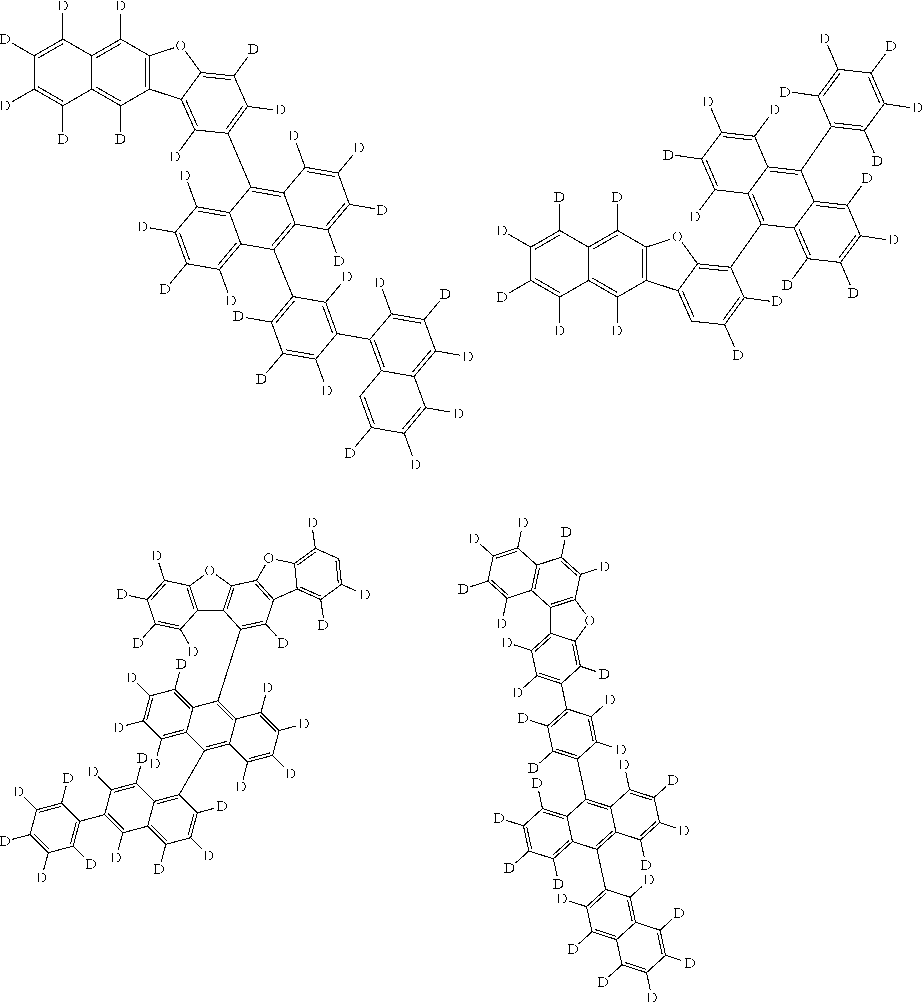

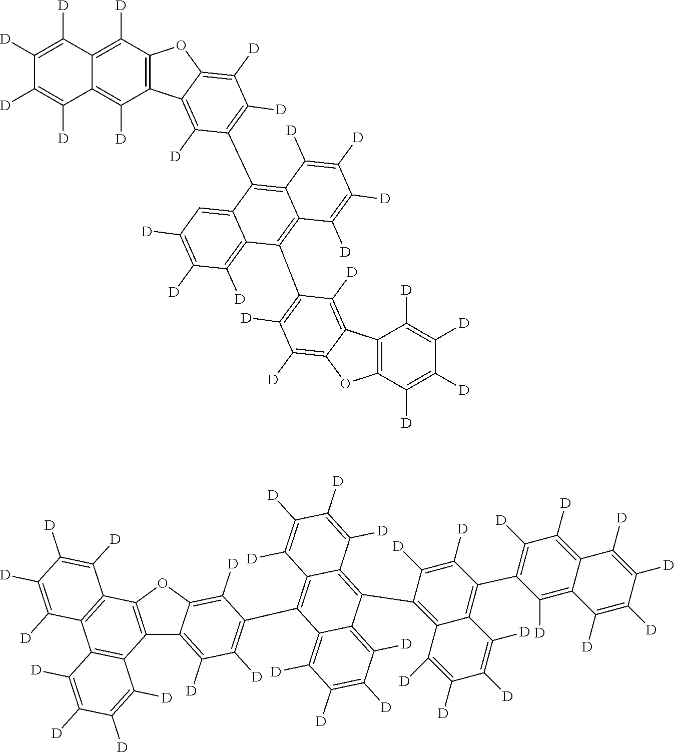 [SMILES: [2H]c1cc2c(-c3c([2H])c([2H])c4oc5c([2H])c6c([2H])c([2H])c([2H])c([2H])c6c([2H])c5c4c3[2H])c3c([2H])c([2H])c([2H])c([2H])c3c(-c3c([2H])c([2H])c4oc5c([2H])c([2H])c([2H])c([2H])c5c4c3[2H])c2c([2H])c1[2H] ; [2H]c1c([2H])c([2H])c2c([2H])c(-c3c([2H])c([2H])c(-c4c5c([2H])c([2H])c([2H])c([2H])c5c(-c5c([2H])c([2H])c6c(oc7c8c([2H])c([2H])c([2H])c([2H])c8c8c([2H])c([2H])c([2H])c([2H])c8c76)c5[2H])c5c([2H])c([2H])c([2H])c([2H])c45)c4c([2H])c([2H])c([2H])c([2H])c34)c([2H])c([2H])c2c1[2H]]

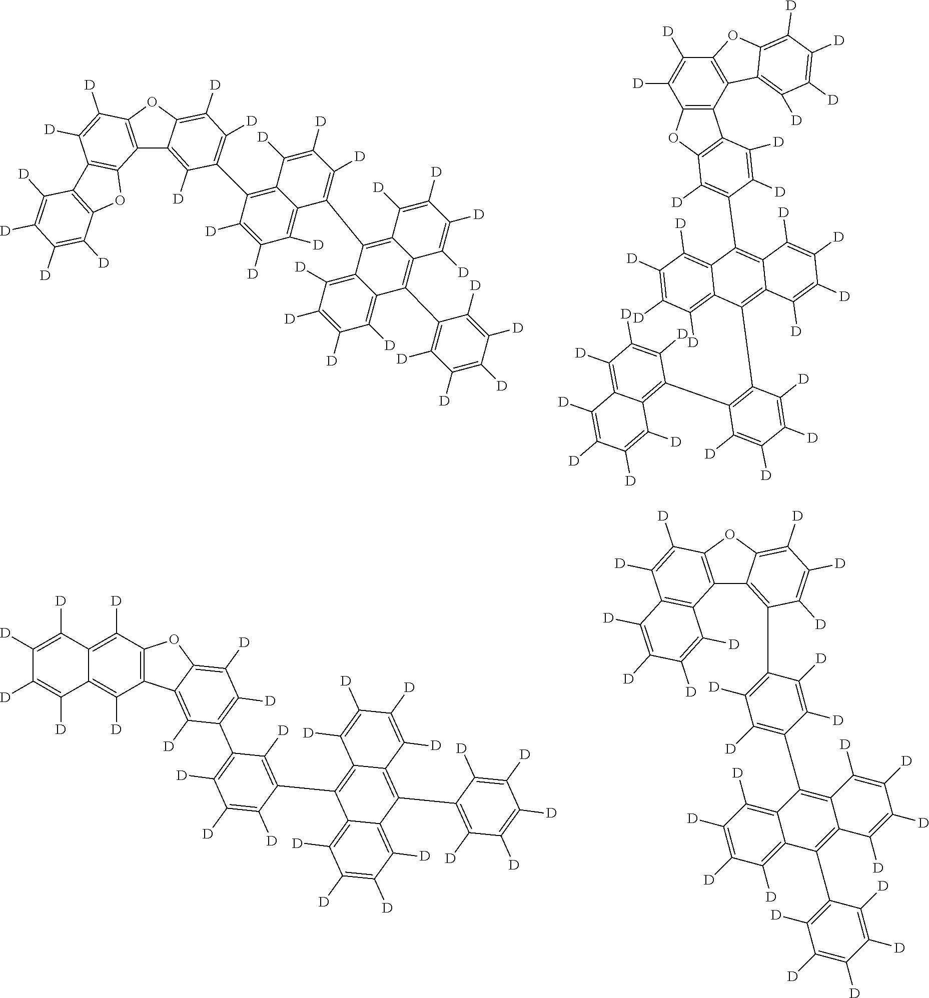

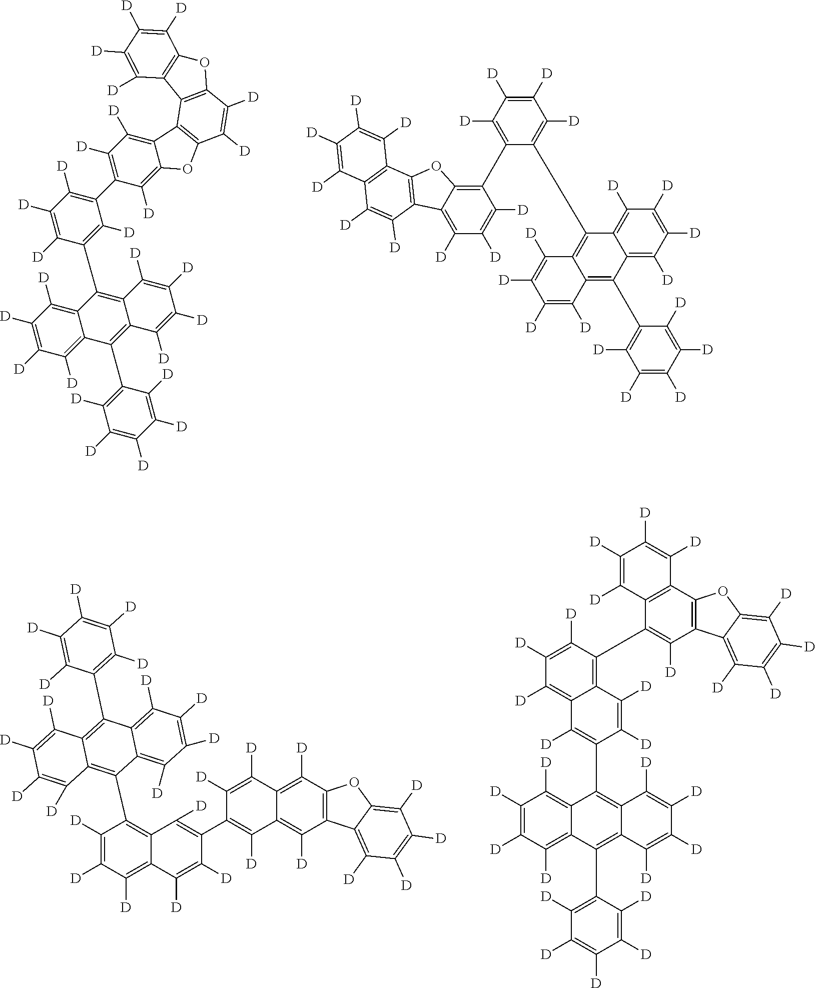

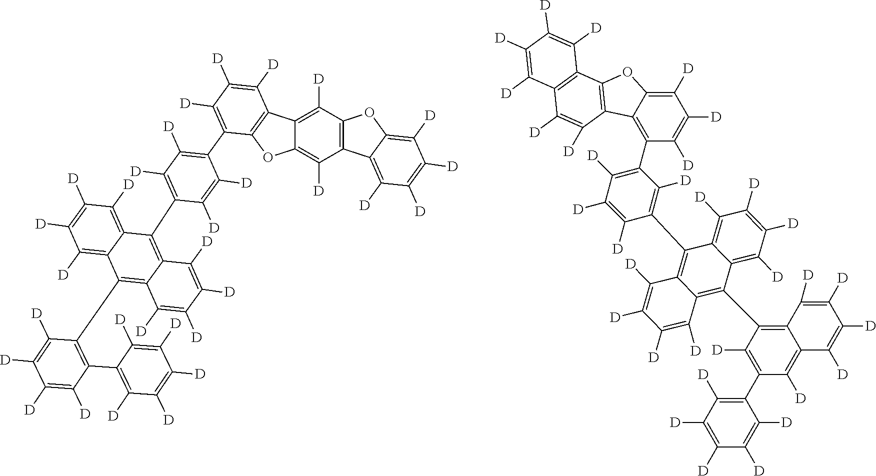

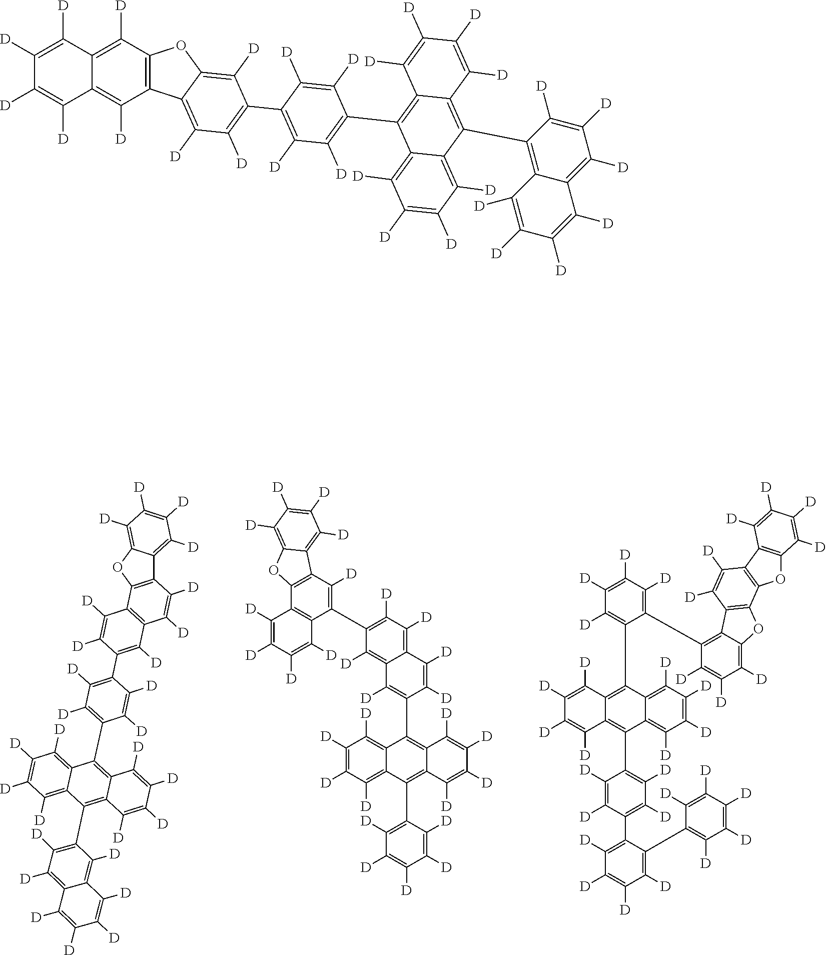

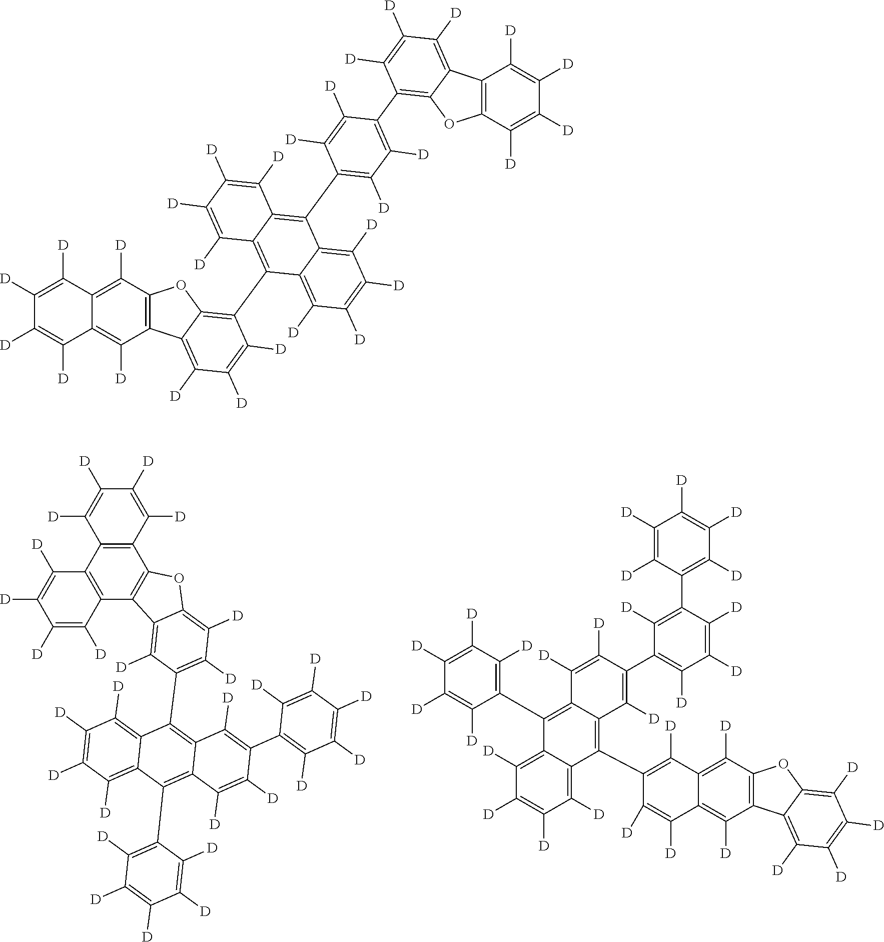

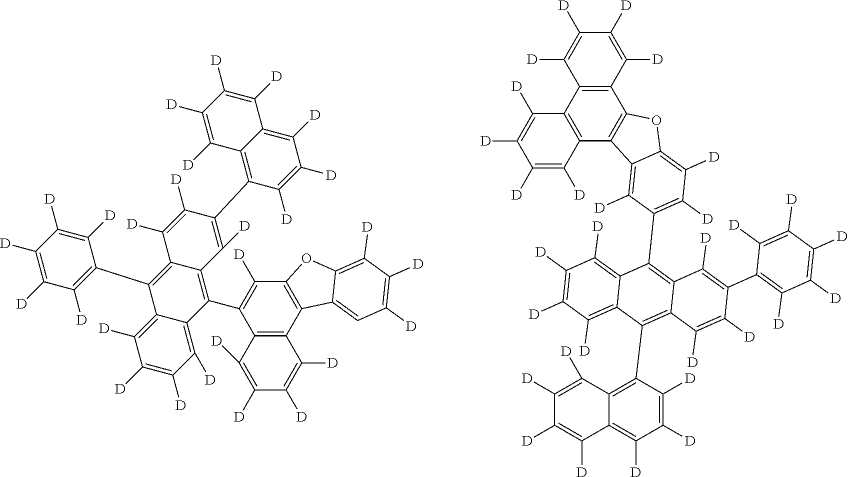 [SMILES: [2H]c1cc2c(oc3c([2H])c(-c4c5c([2H])c([2H])c([2H])c([2H])c5c(-c5c([2H])c([2H])c([2H])c([2H])c5[2H])c5c([2H])c([2H])c(-c6c([2H])c([2H])c([2H])c7c([2H])c([2H])c([2H])c([2H])c67)c([2H])c45)c4c([2H])c([2H])c([2H])c([2H])c4c32)c([2H])c1[2H] ; [2H]c1c([2H])c([2H])c(-c2c([2H])c([2H])c3c(-c4c([2H])c([2H])c([2H])c5c([2H])c([2H])c([2H])c([2H])c45)c4c([2H])c([2H])c([2H])c([2H])c4c(-c4c([2H])c([2H])c5oc6c7c([2H])c([2H])c([2H])c([2H])c7c7c([2H])c([2H])c([2H])c([2H])c7c6c5c4[2H])c3c2[2H])c([2H])c1[2H]]

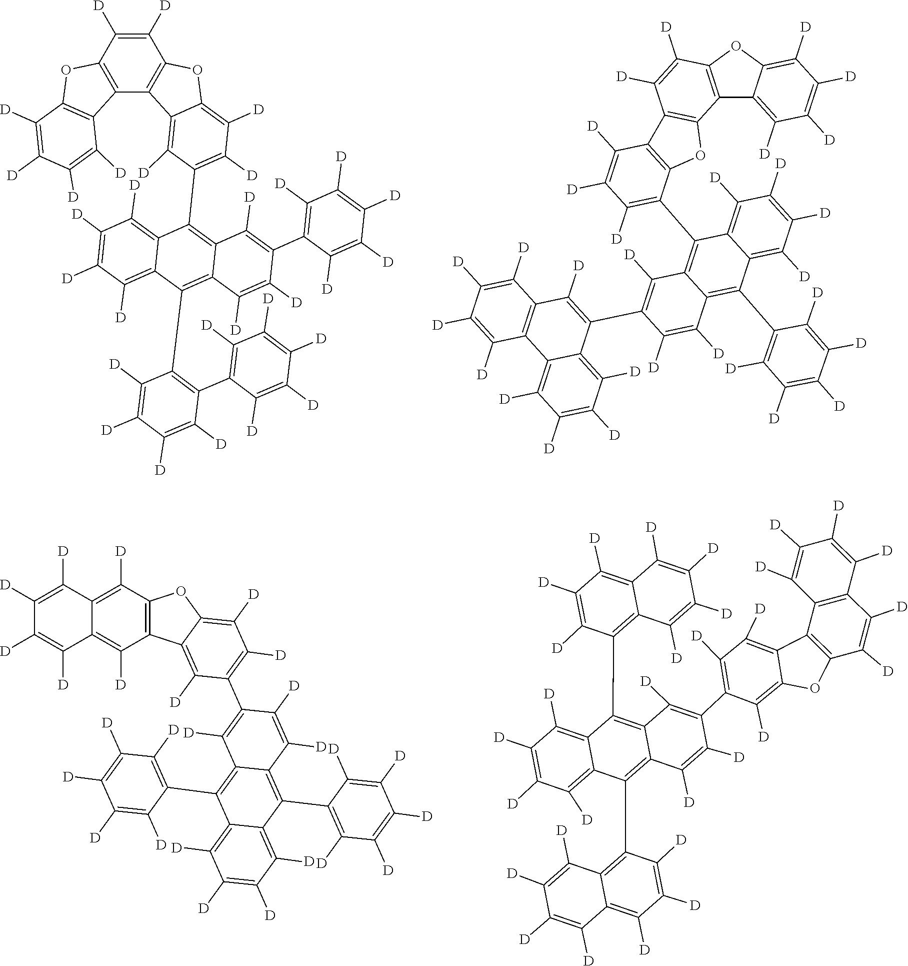

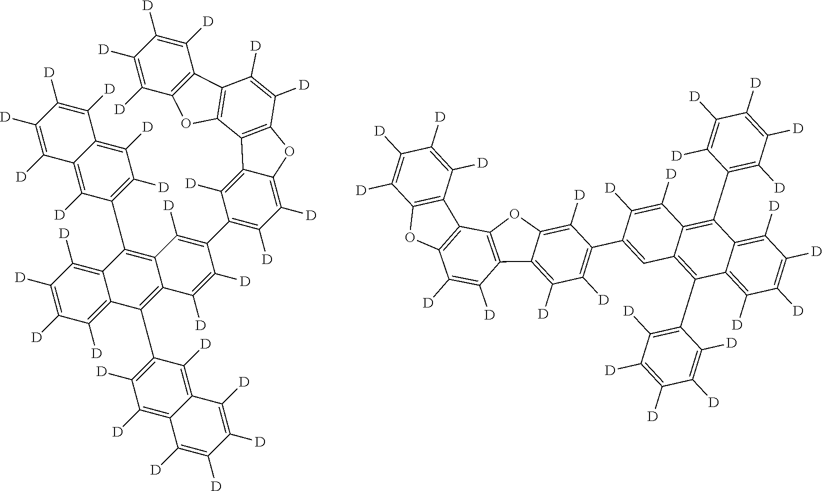 [SMILES: [2H]c1c([2H])c([2H])c2c(oc3c2c([2H])c([2H])c2oc4c([2H])c([2H])c(-c5c([2H])c([2H])c6c(-c7c([2H])c([2H])c8c([2H])c([2H])c([2H])c([2H])c8c7[2H])c7c([2H])c([2H])c([2H])c([2H])c7c(-c7c([2H])c([2H])c8c([2H])c([2H])c([2H])c([2H])c8c7[2H])c6c5[2H])c([2H])c4c23)c1[2H] ; [2H]c1c([2H])c([2H])c(-c2c3cc(-c4c([2H])c([2H])c5c(oc6c5c([2H])c([2H])c5oc7c([2H])c([2H])c([2H])c([2H])c7c56)c4[2H])c([2H])c([2H])c3c(-c3c([2H])c([2H])c([2H])c([2H])c3[2H])c3c([2H])c([2H])c([2H])c([2H])c23)c([2H])c1[2H]]

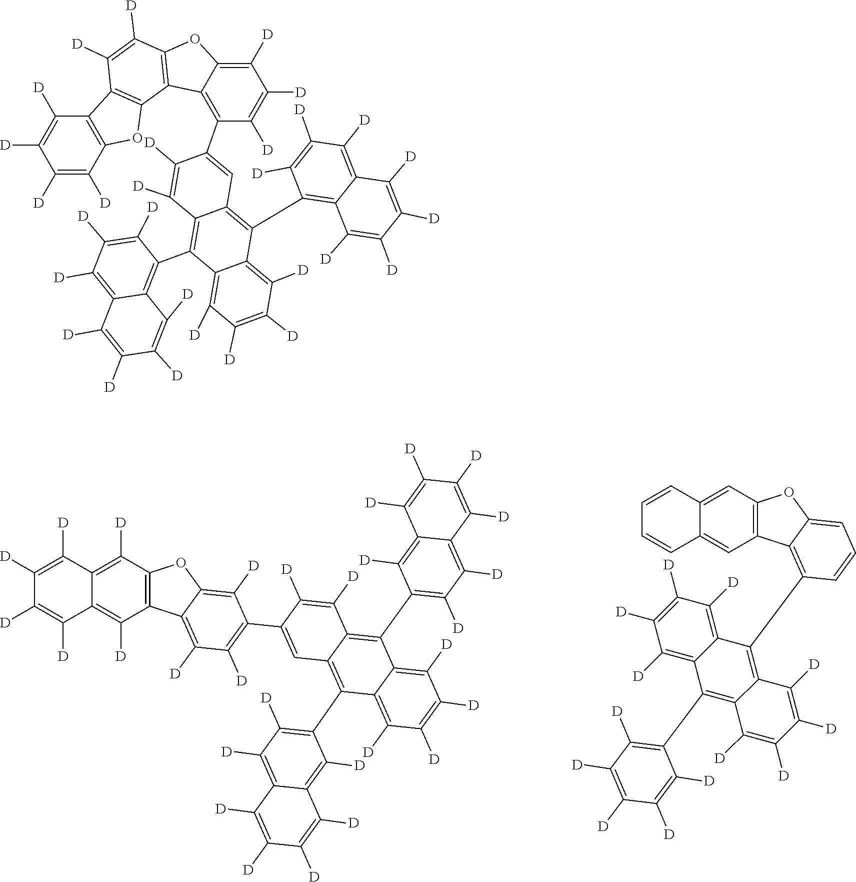

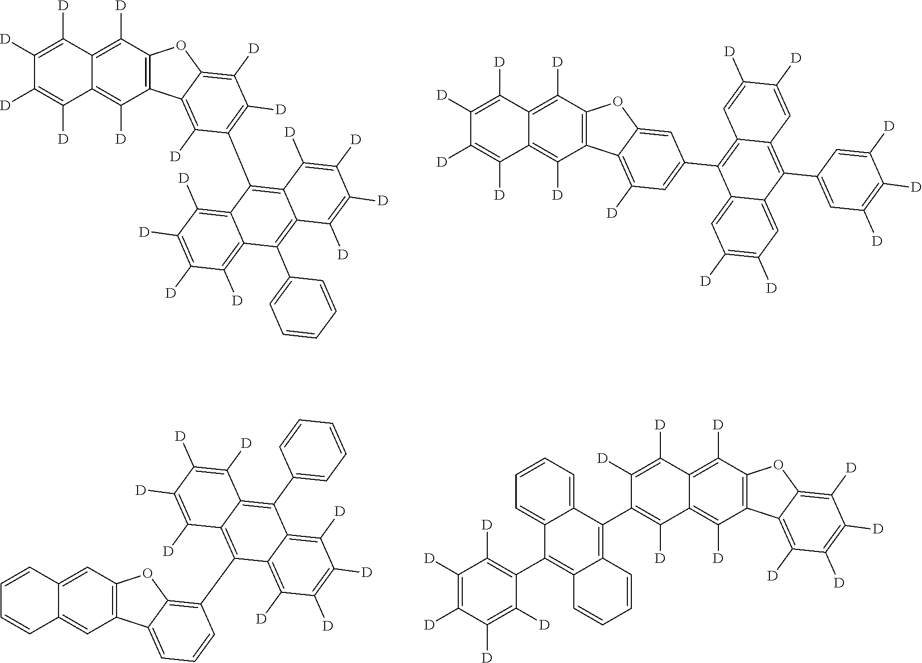

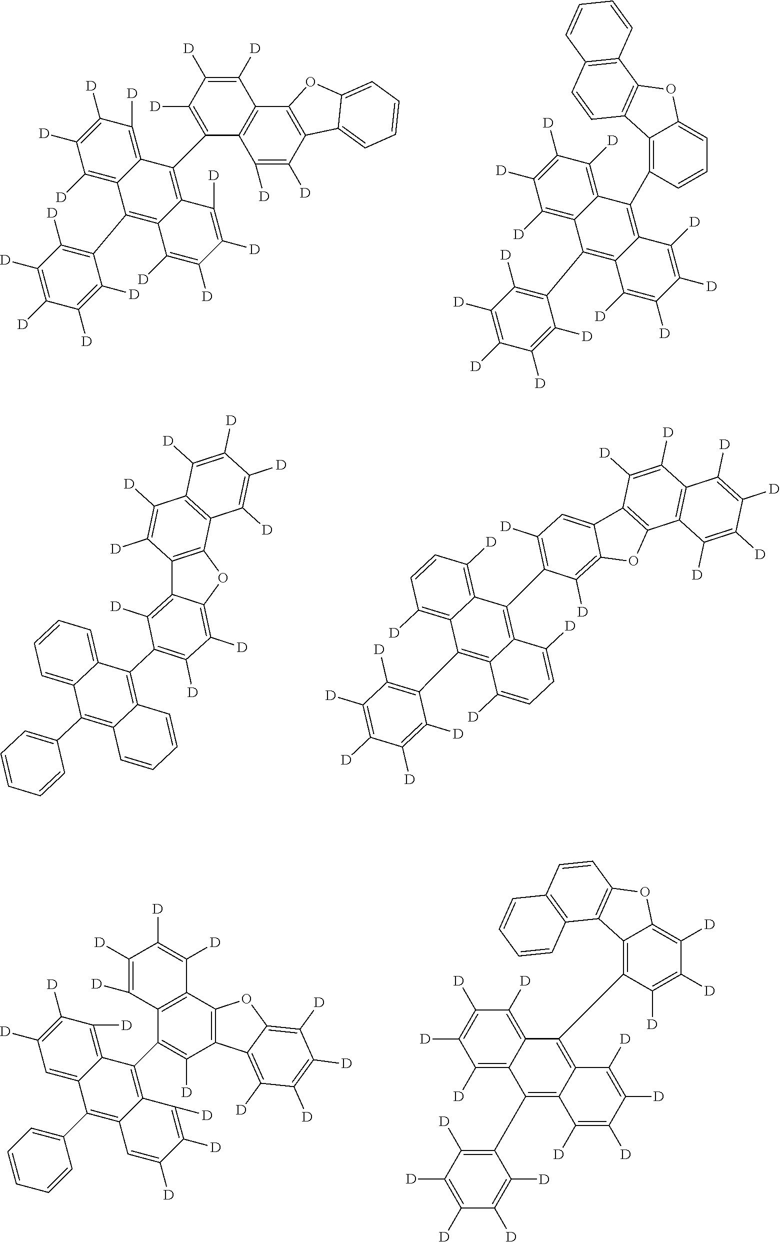

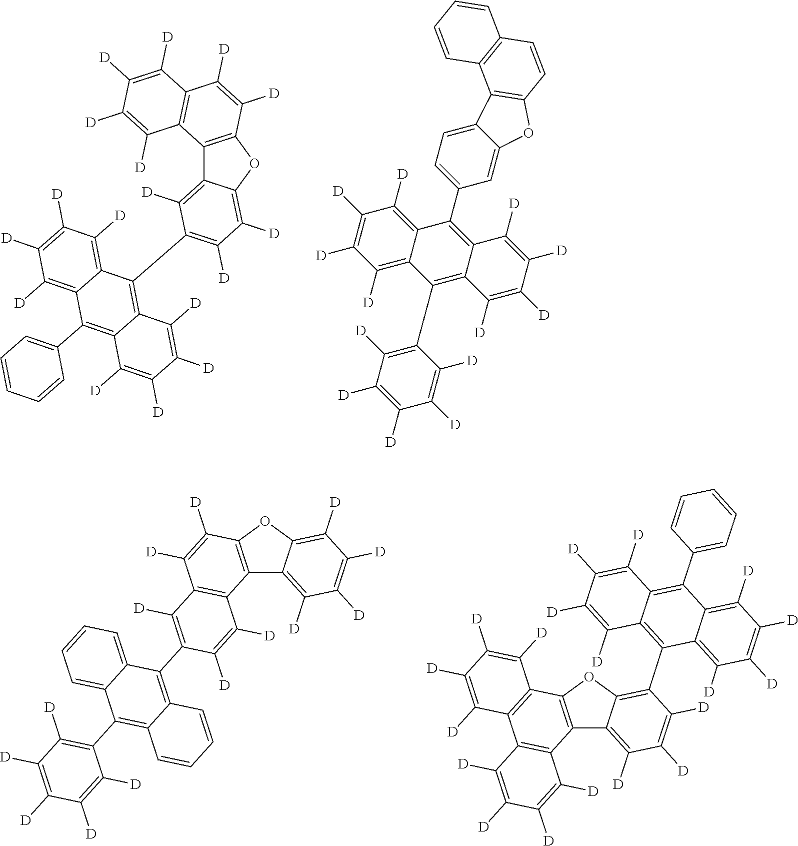

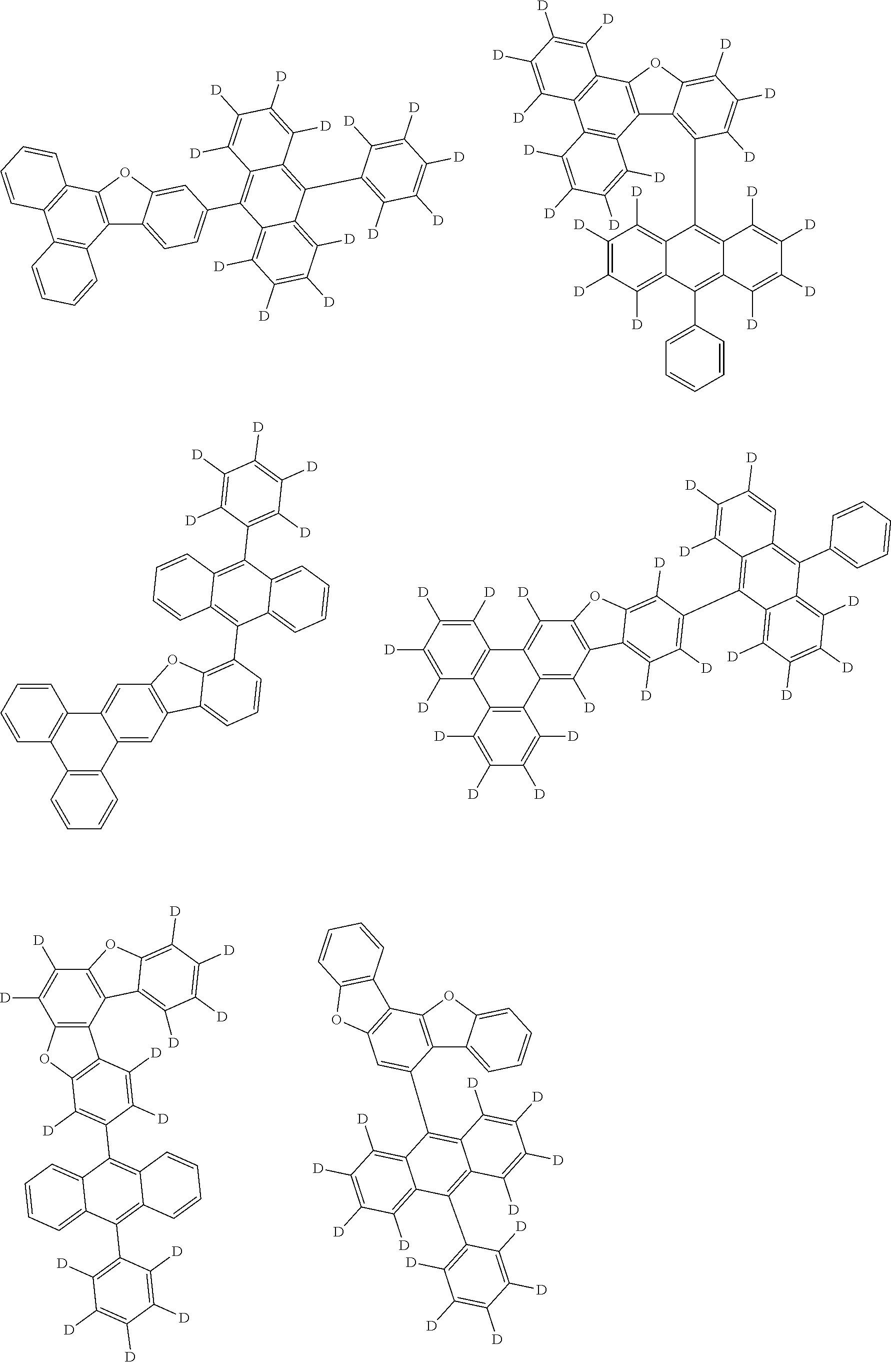

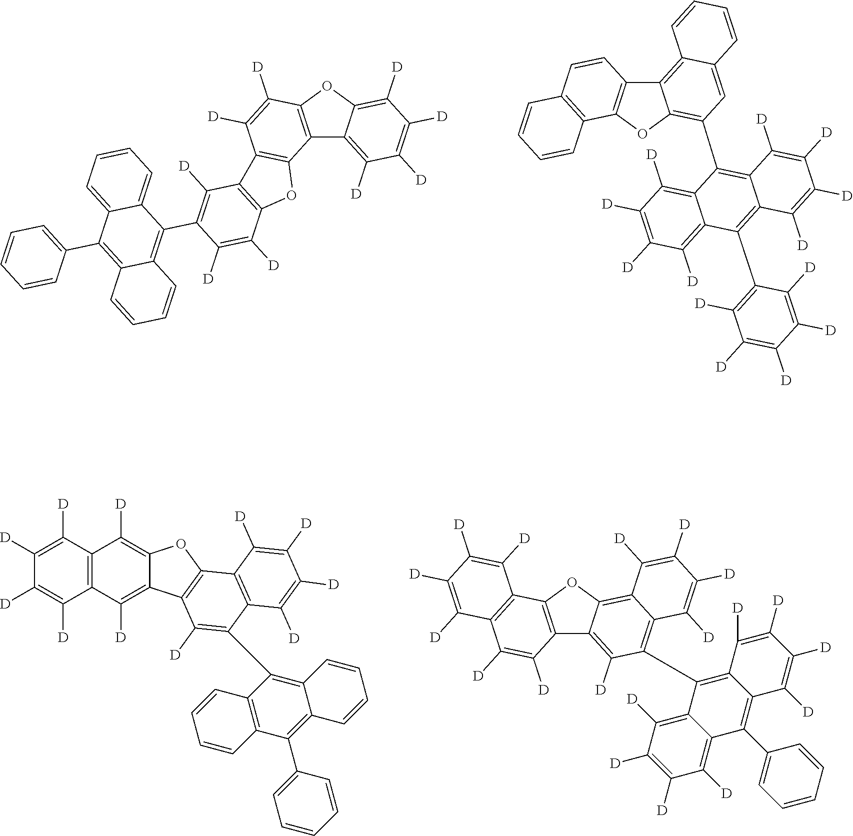

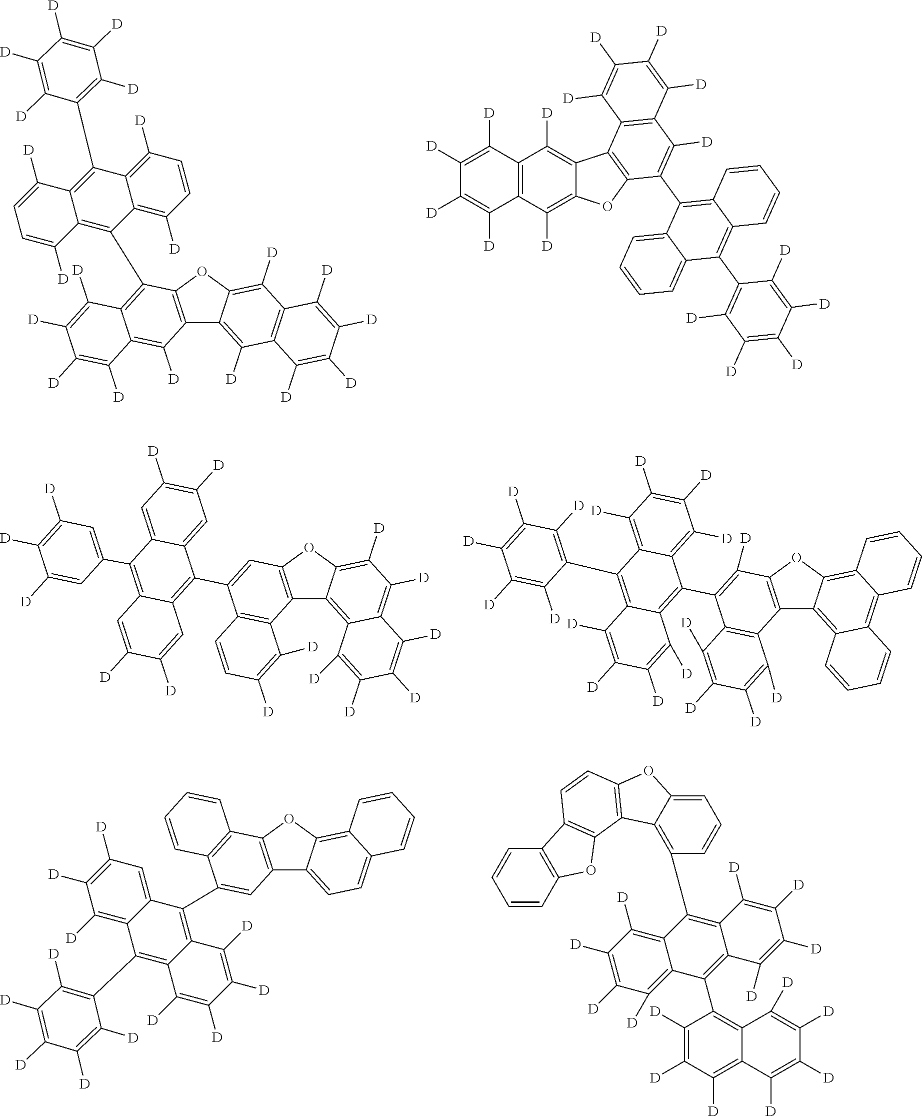

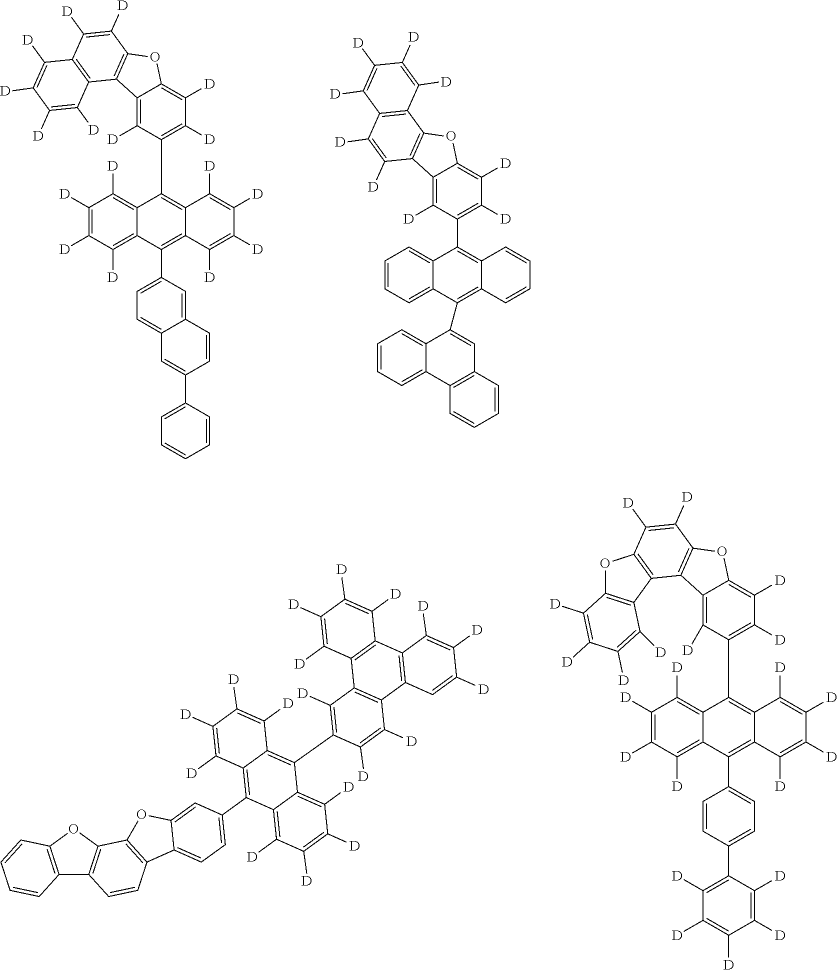

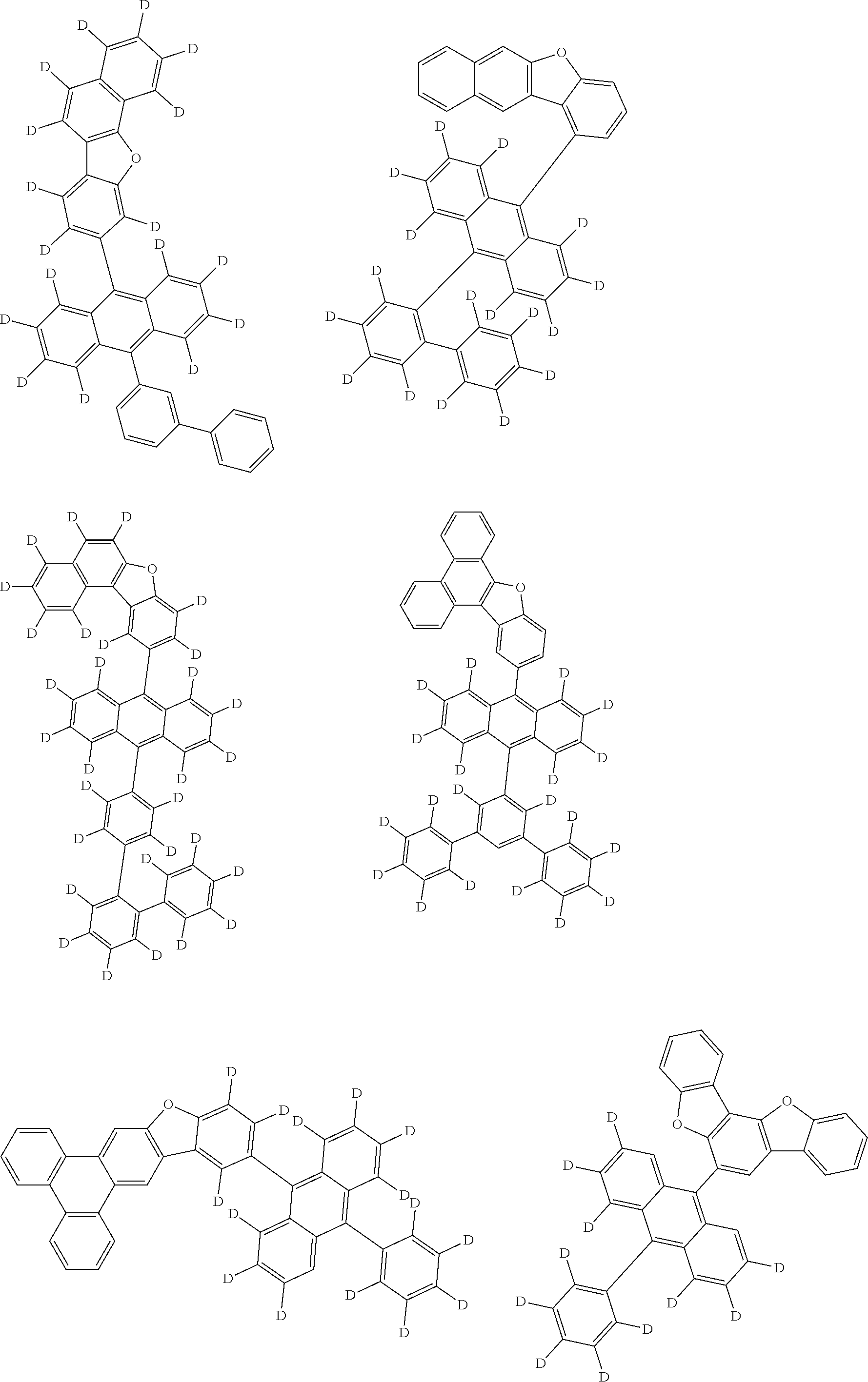

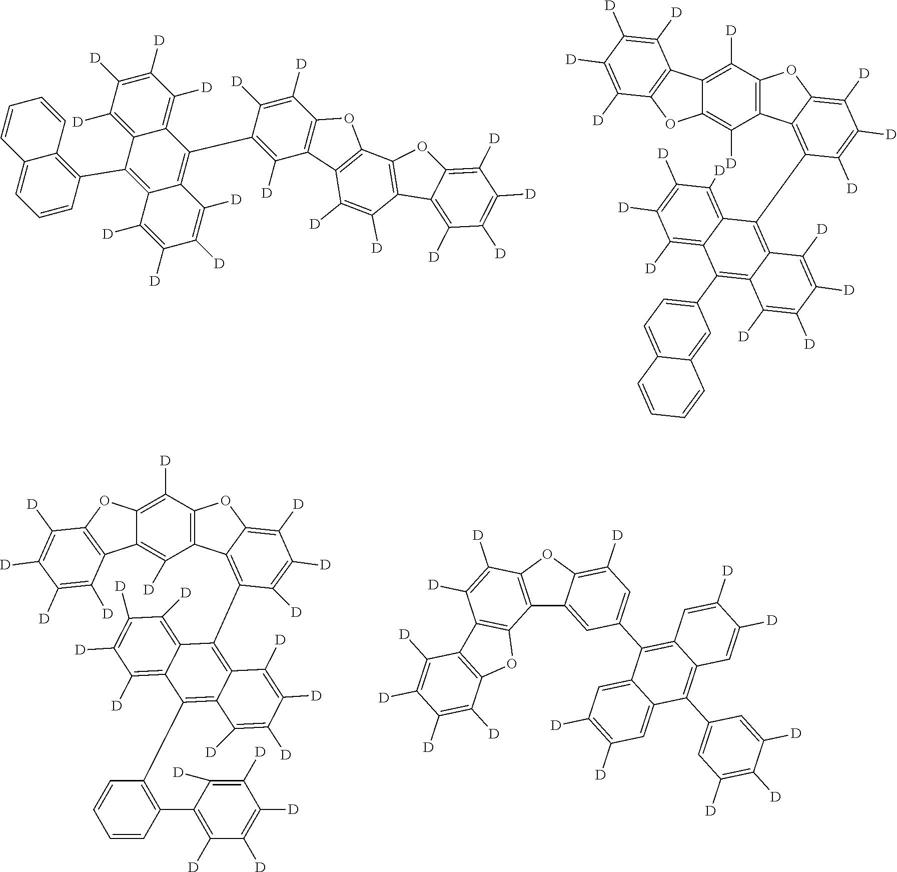

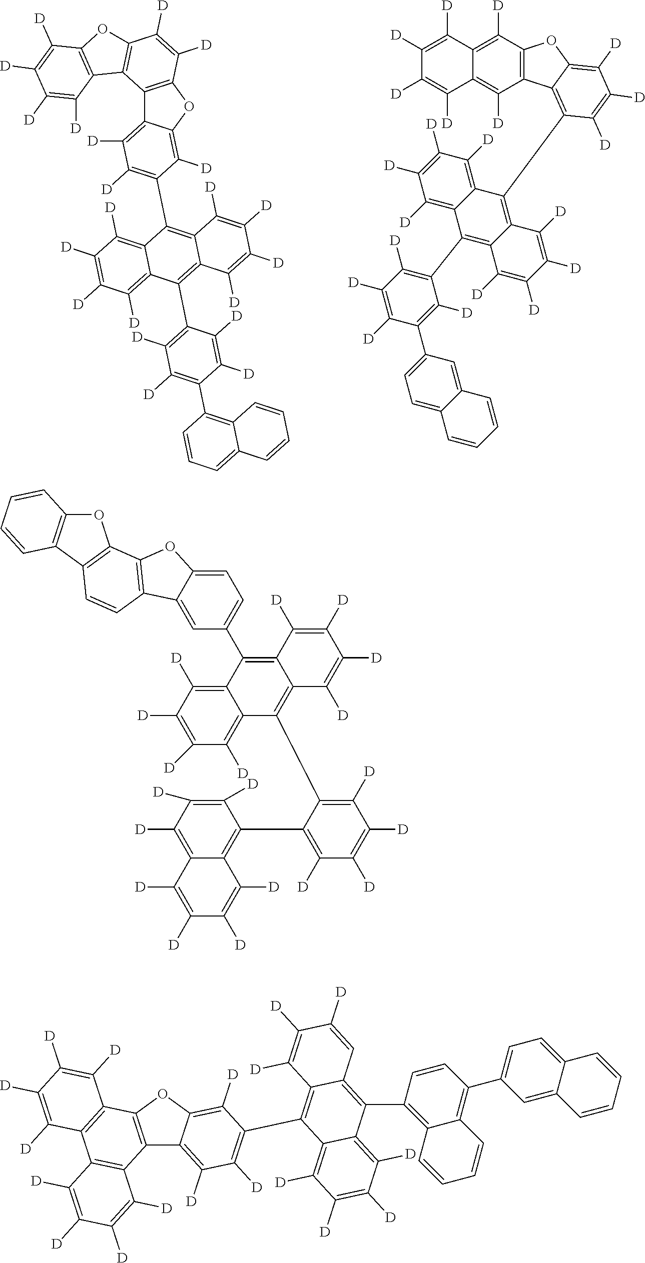

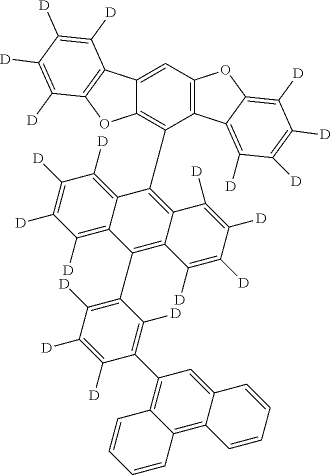 [SMILES: [2H]c1c([2H])c(-c2cc3ccccc3c3ccccc23)c([2H])c(-c2c3c([2H])c([2H])c([2H])c([2H])c3c(-c3c4oc5c([2H])c([2H])c([2H])c([2H])c5c4cc4oc5c([2H])c([2H])c([2H])c([2H])c5c34)c3c([2H])c([2H])c([2H])c([2H])c23)c1[2H]]

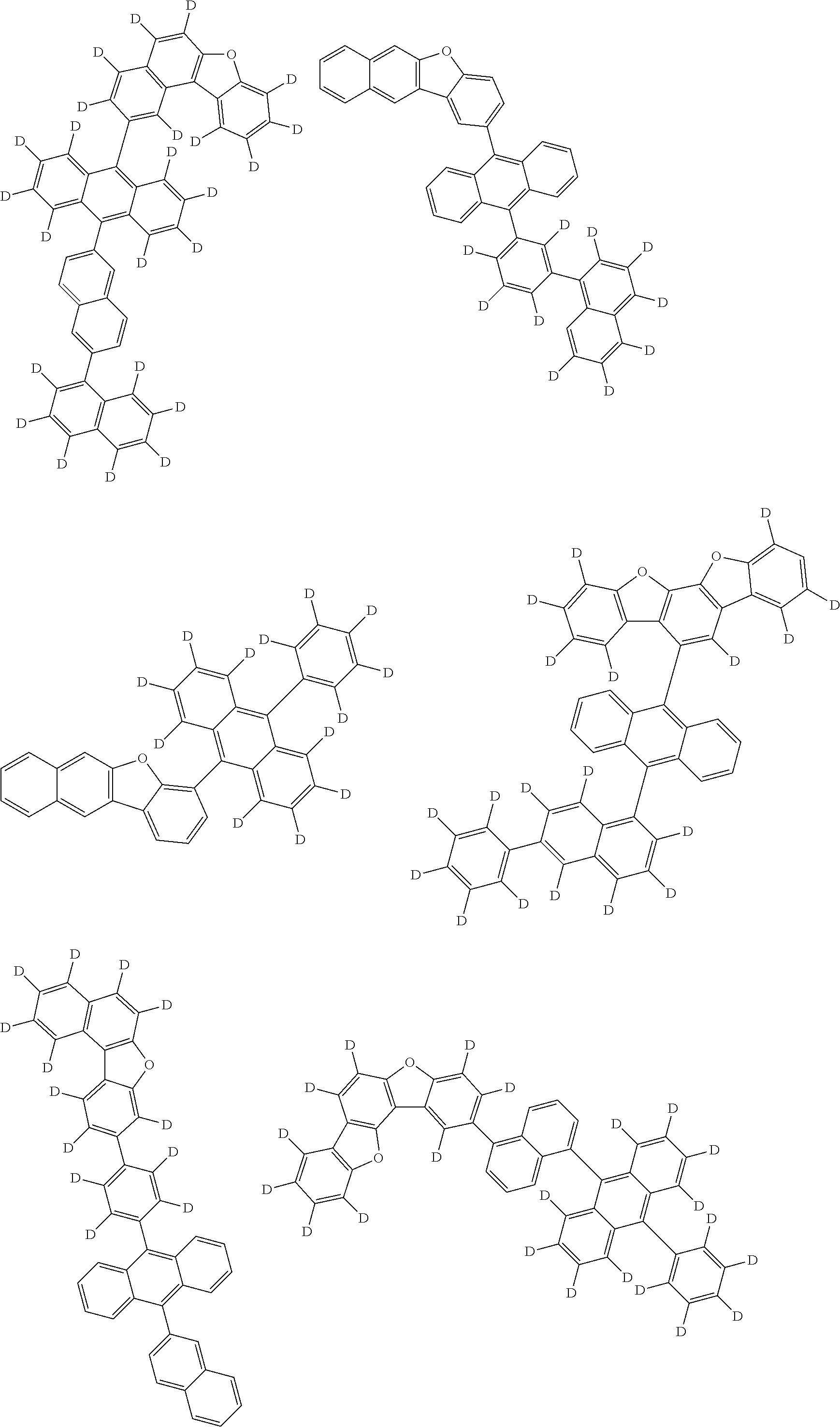

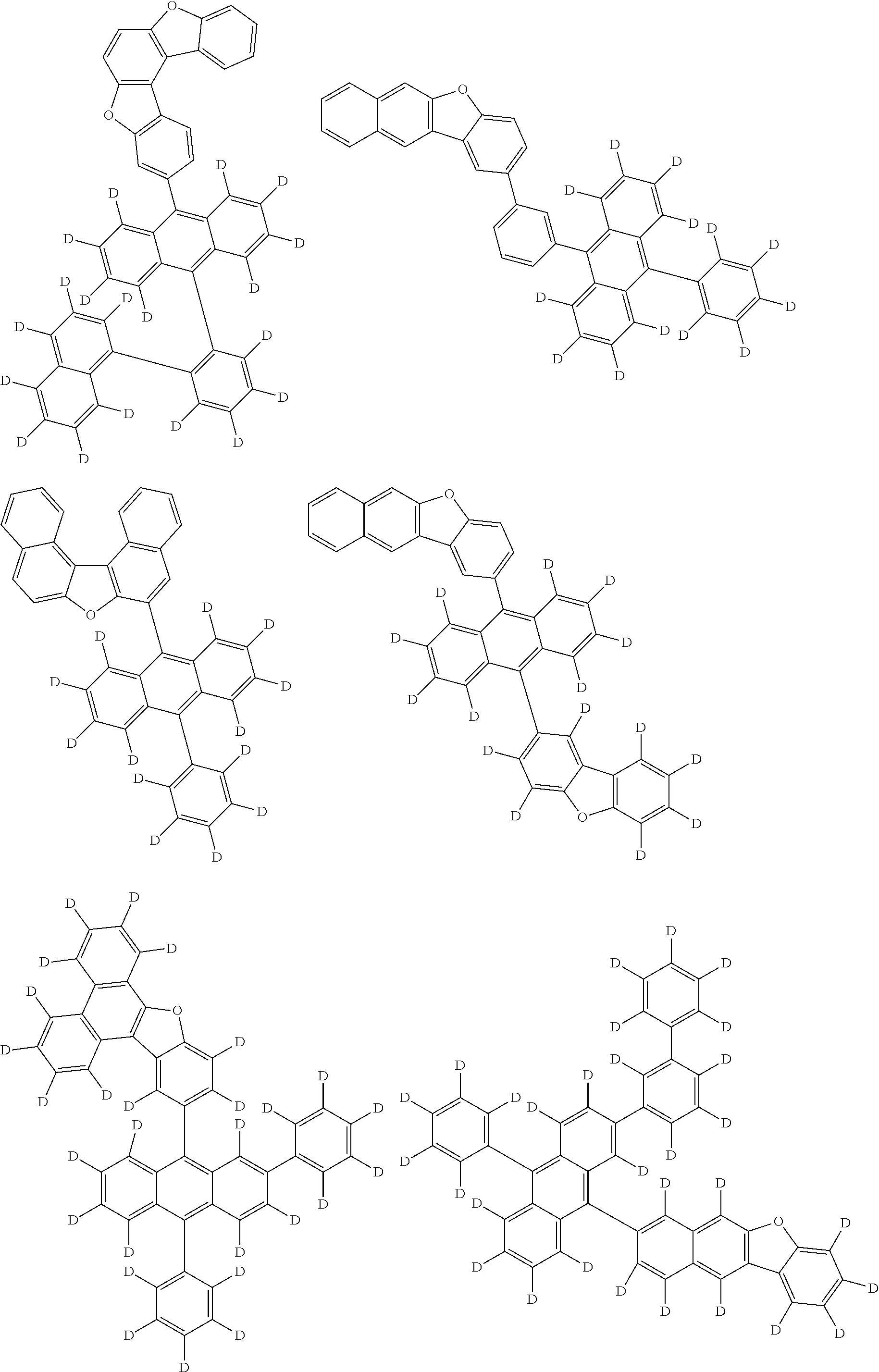

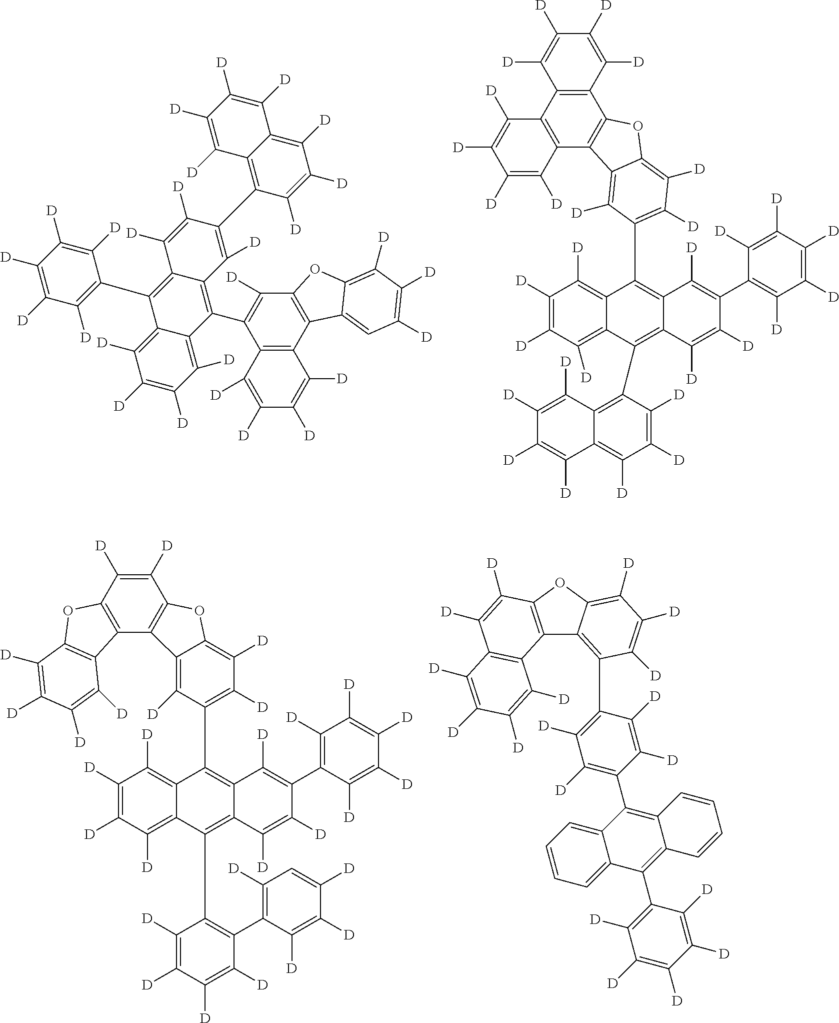

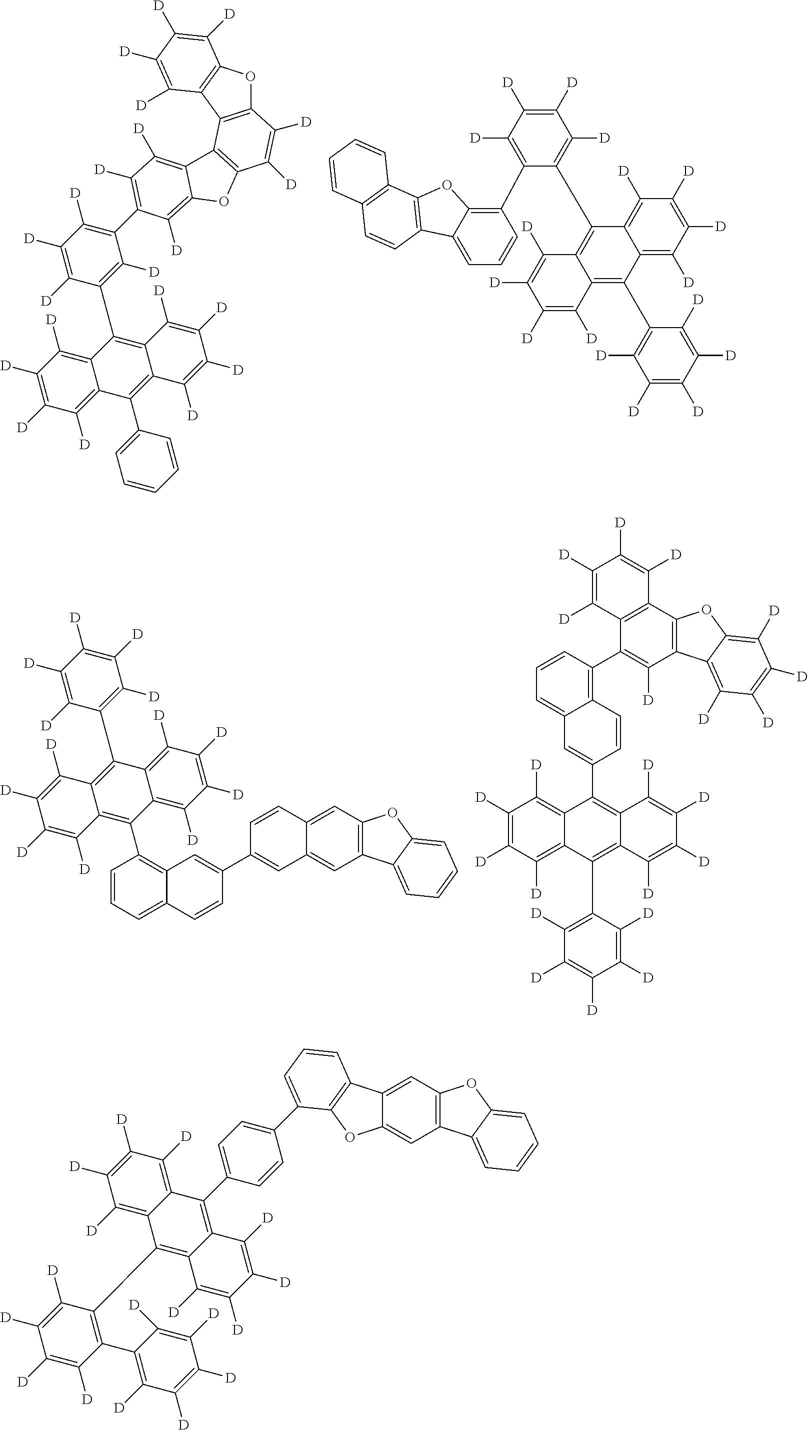

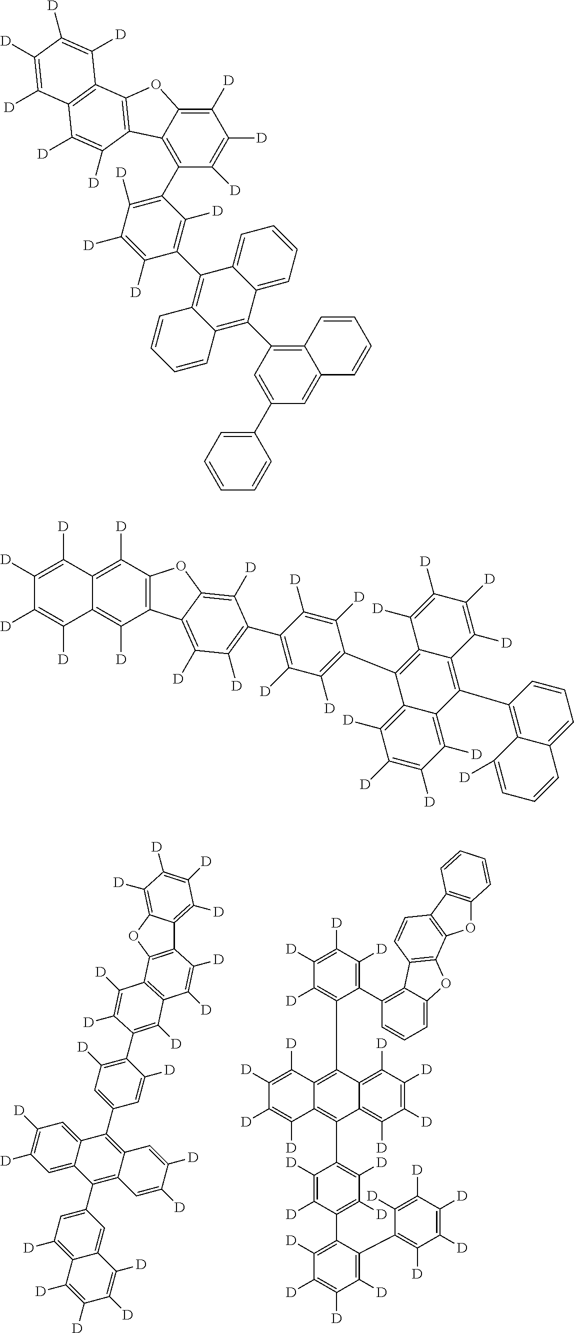

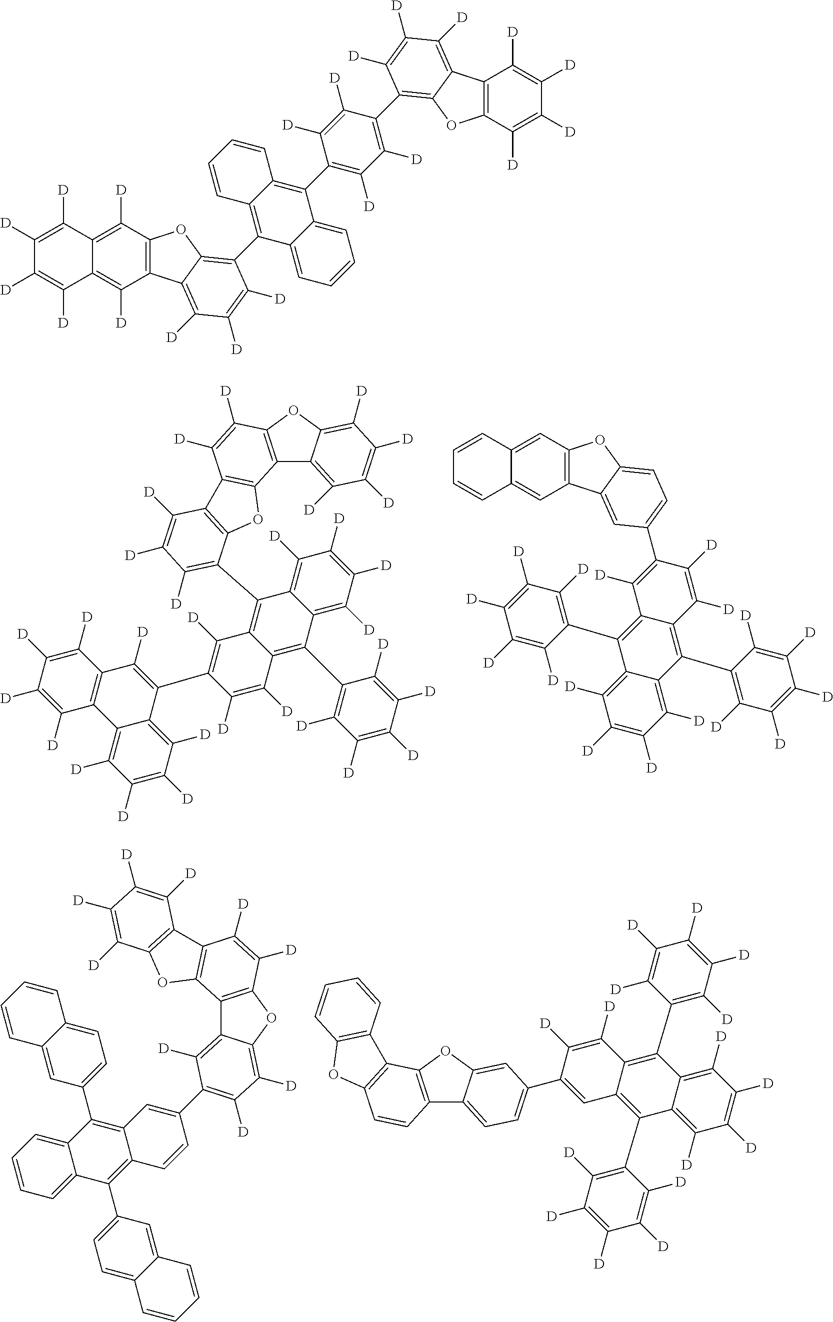

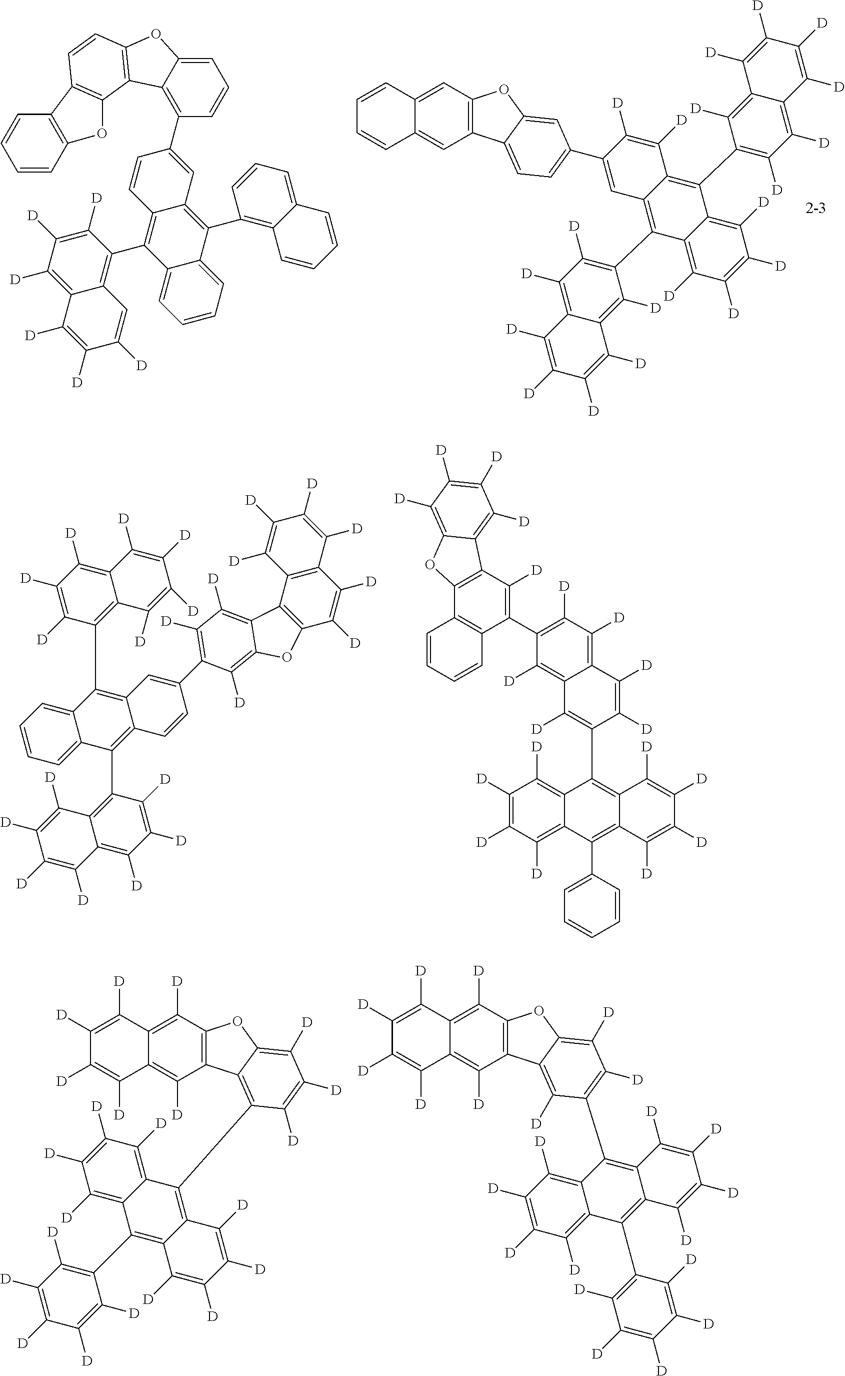

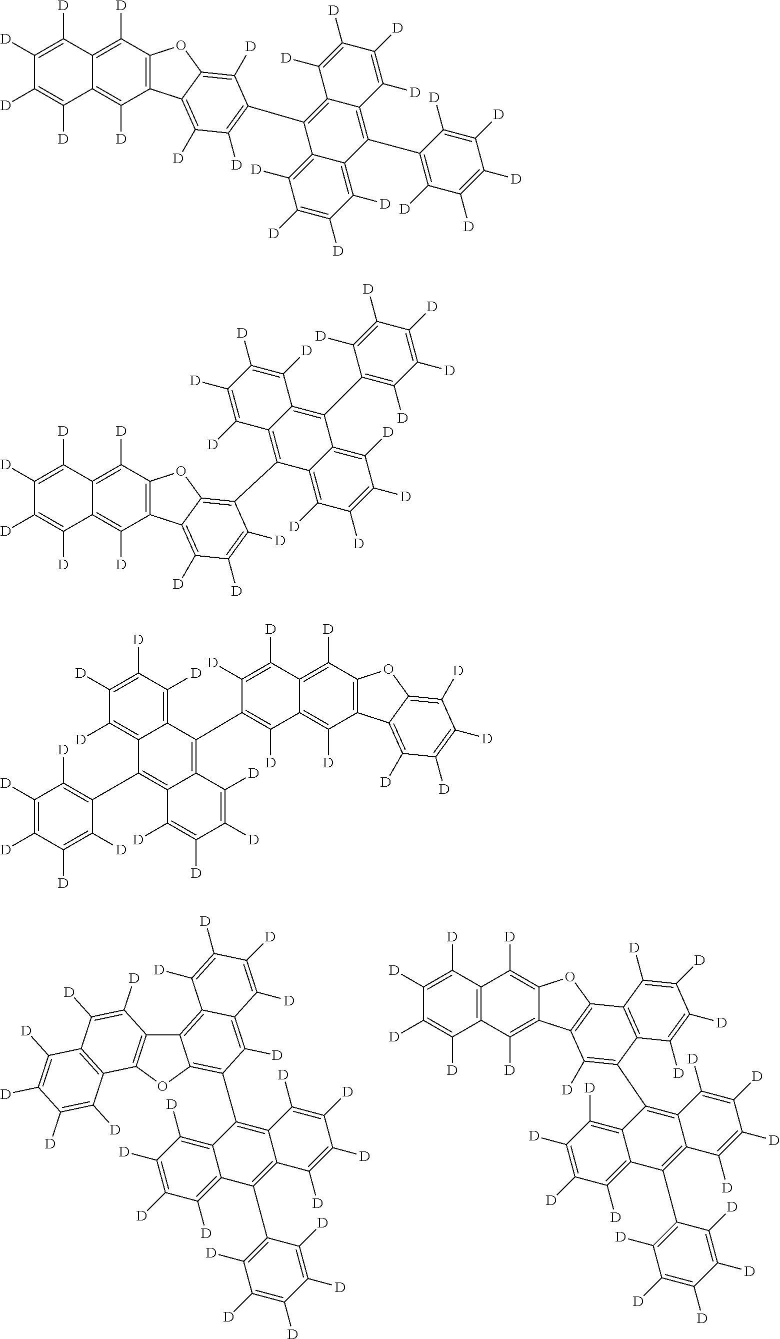

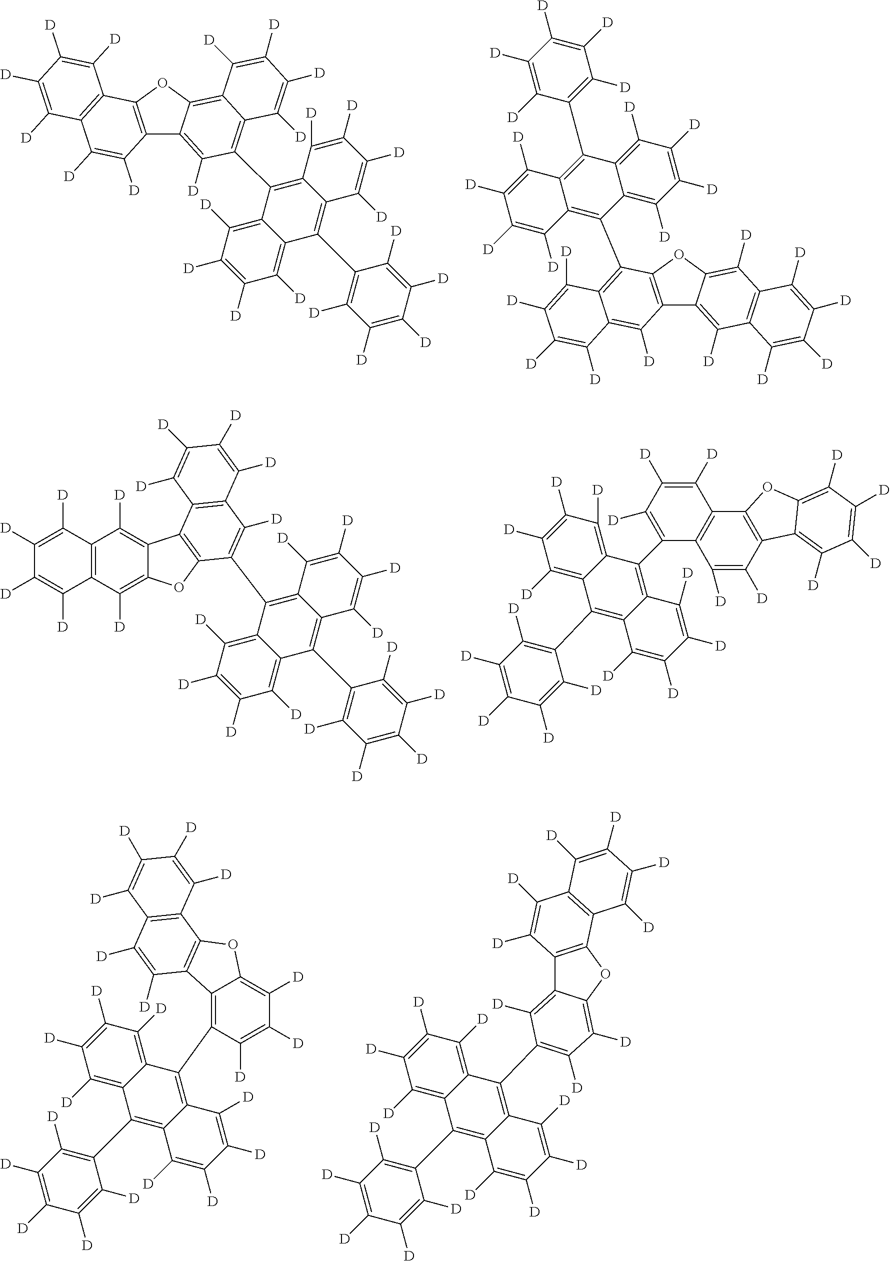

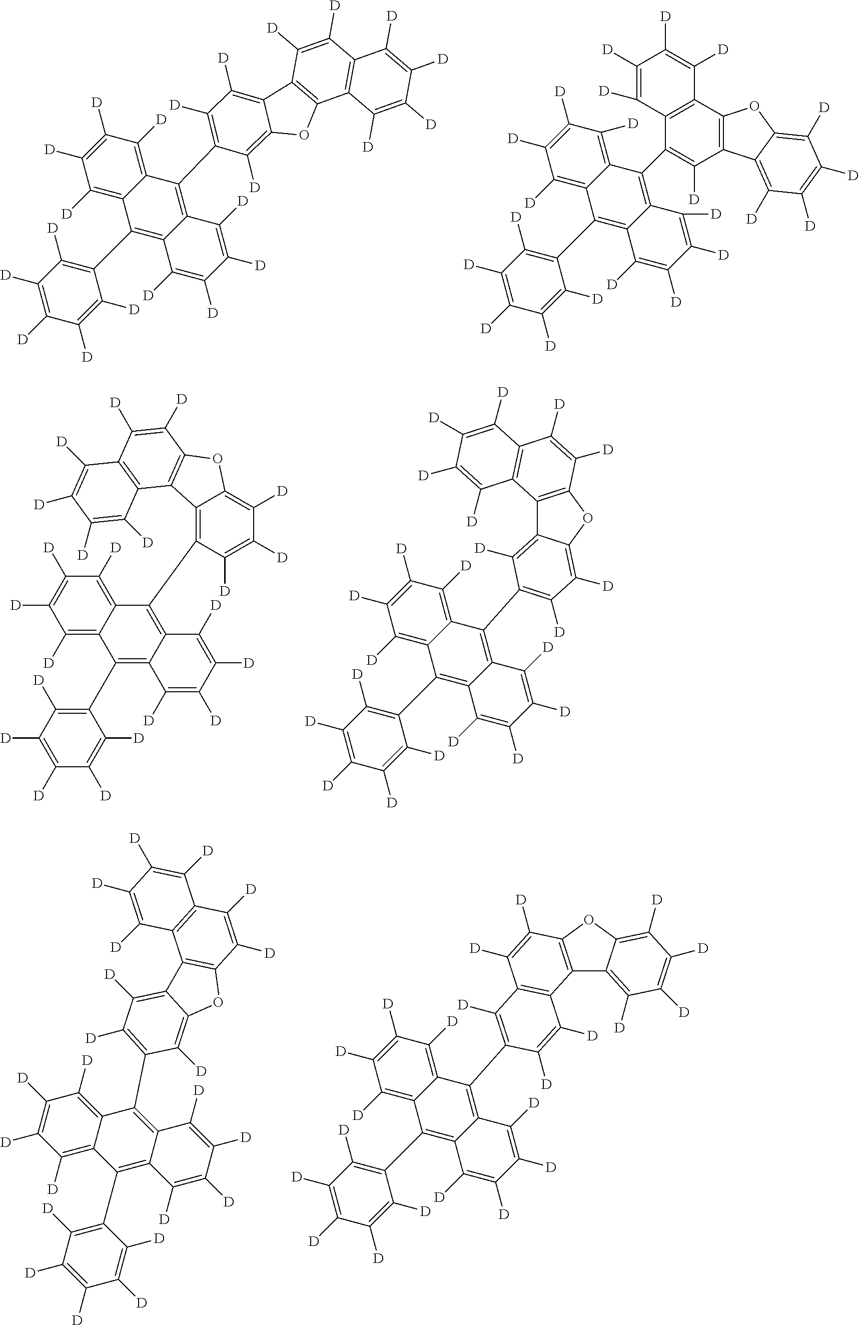

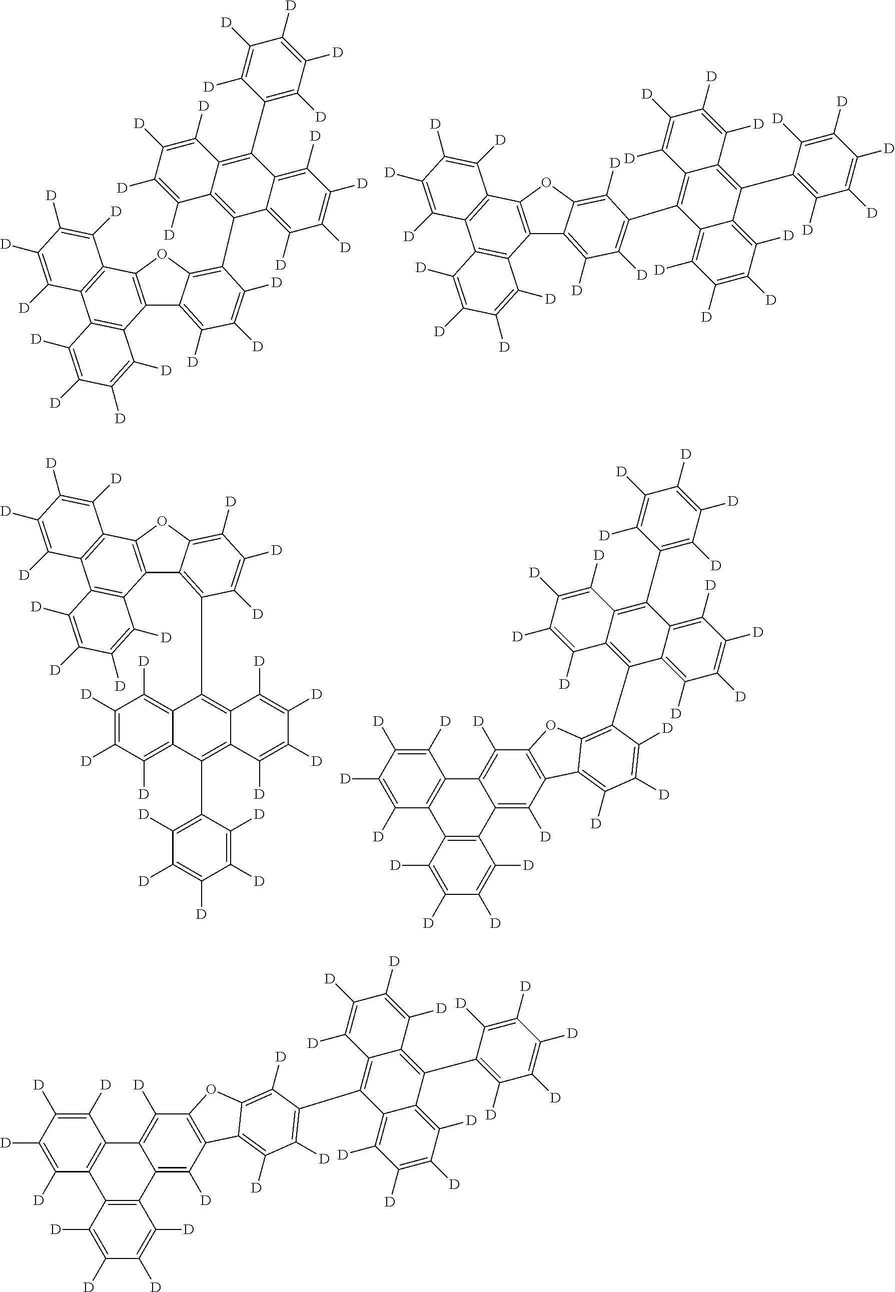

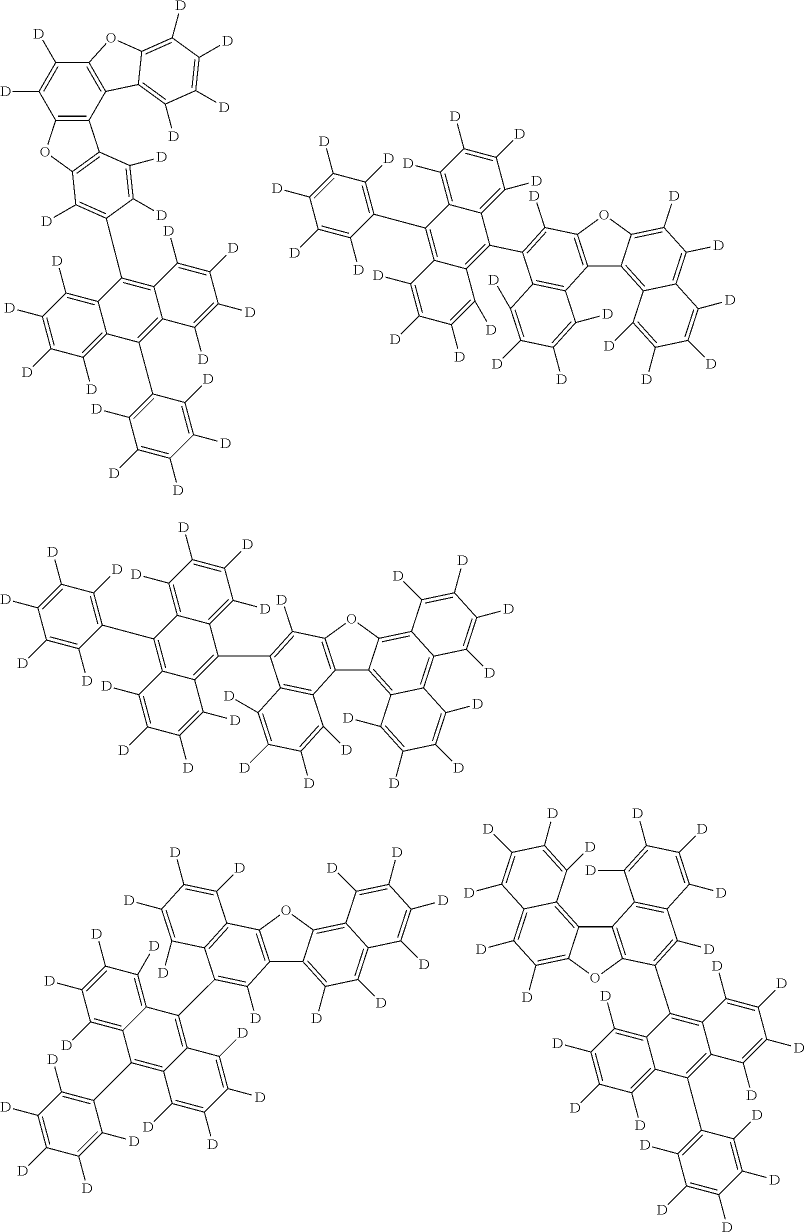

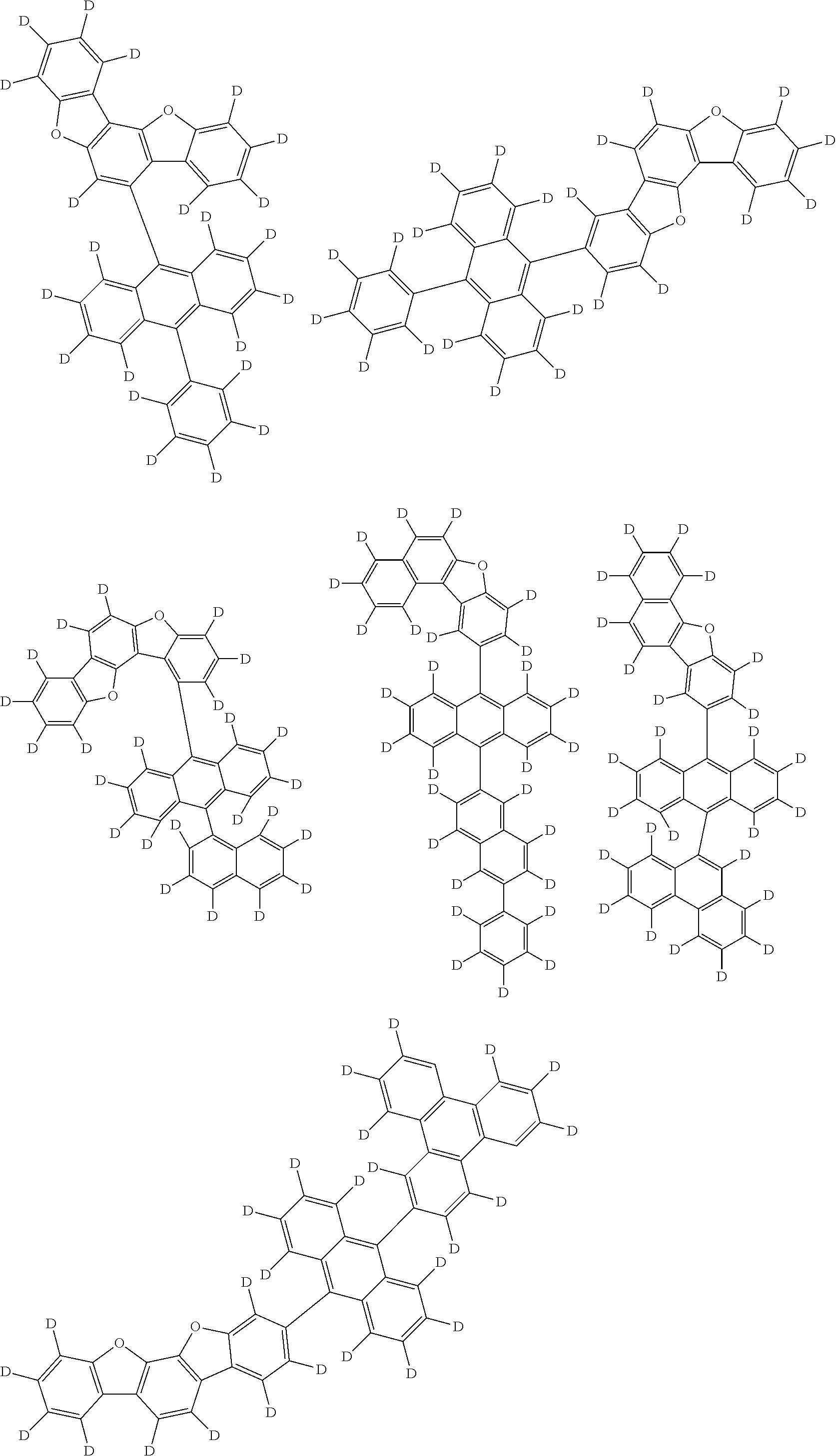

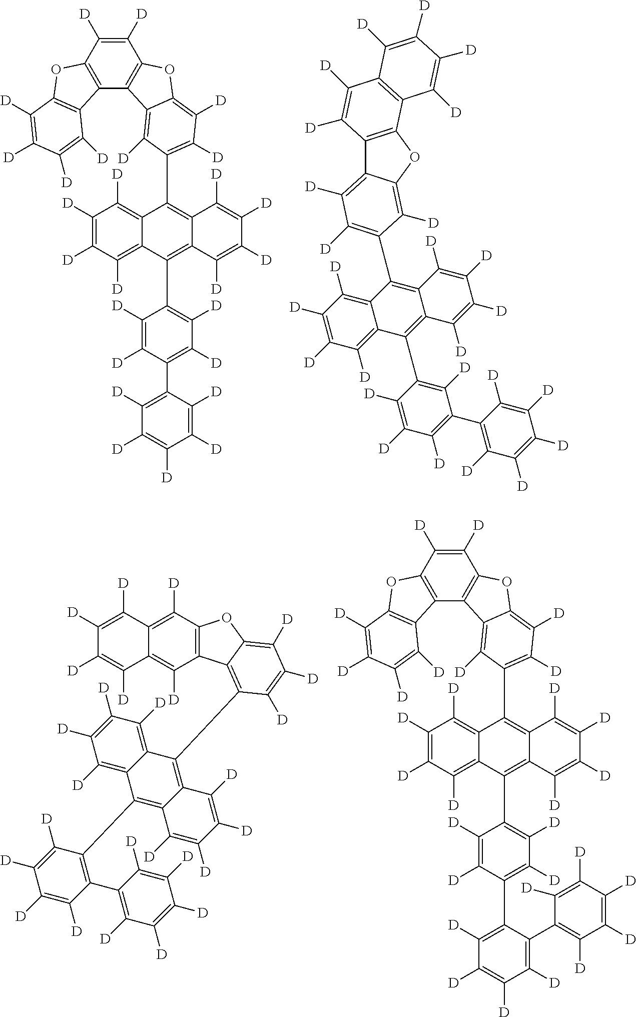

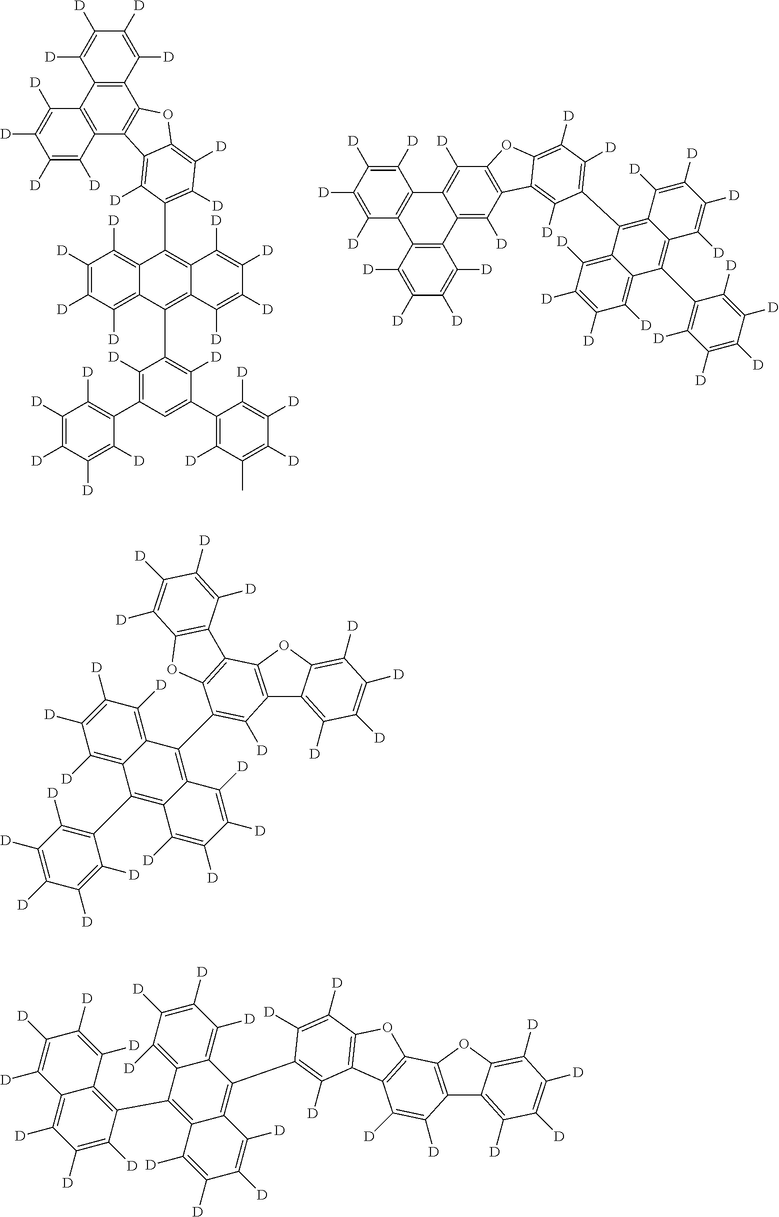

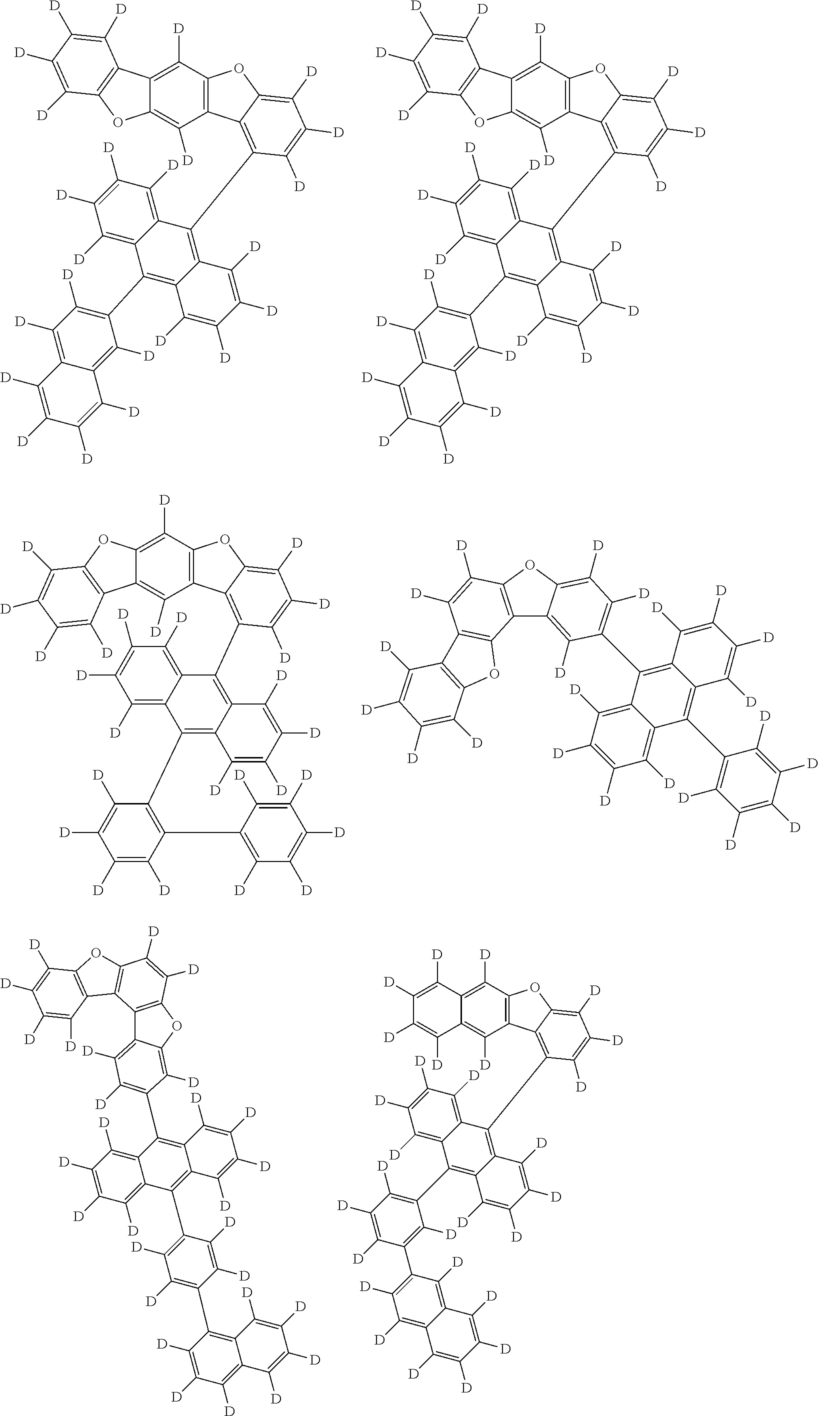

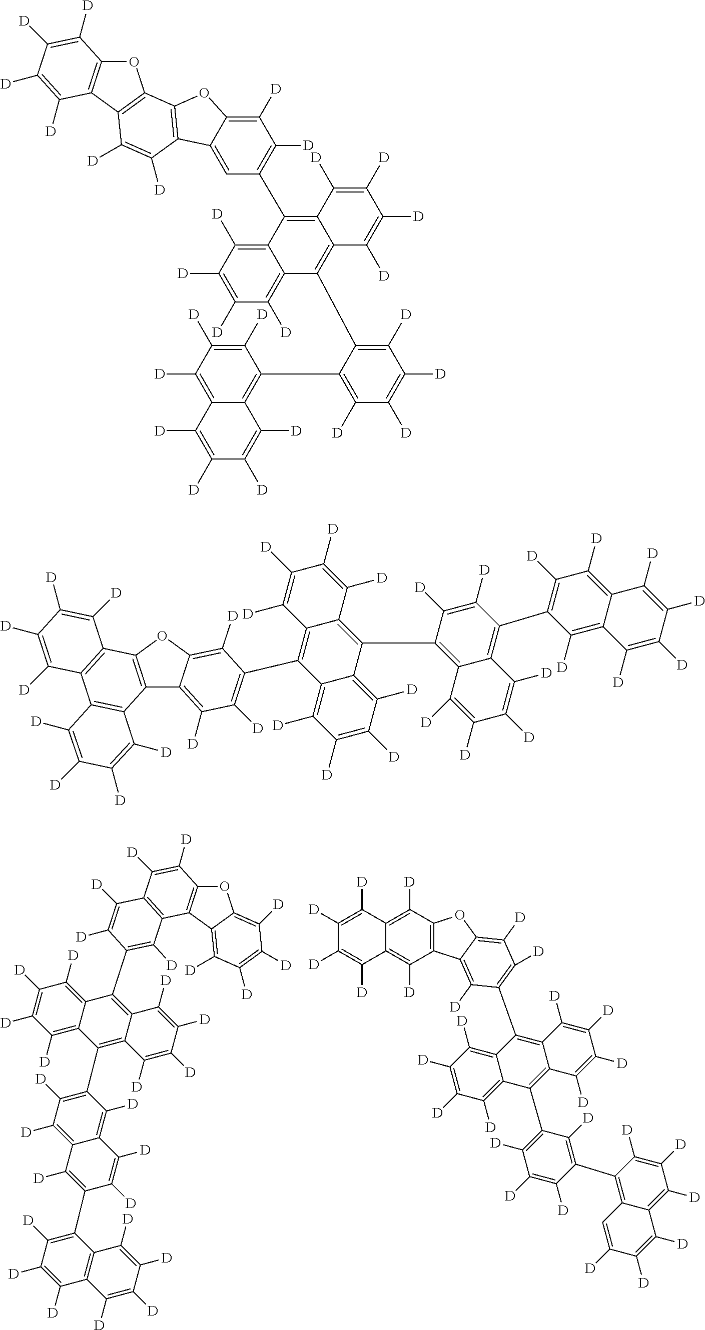

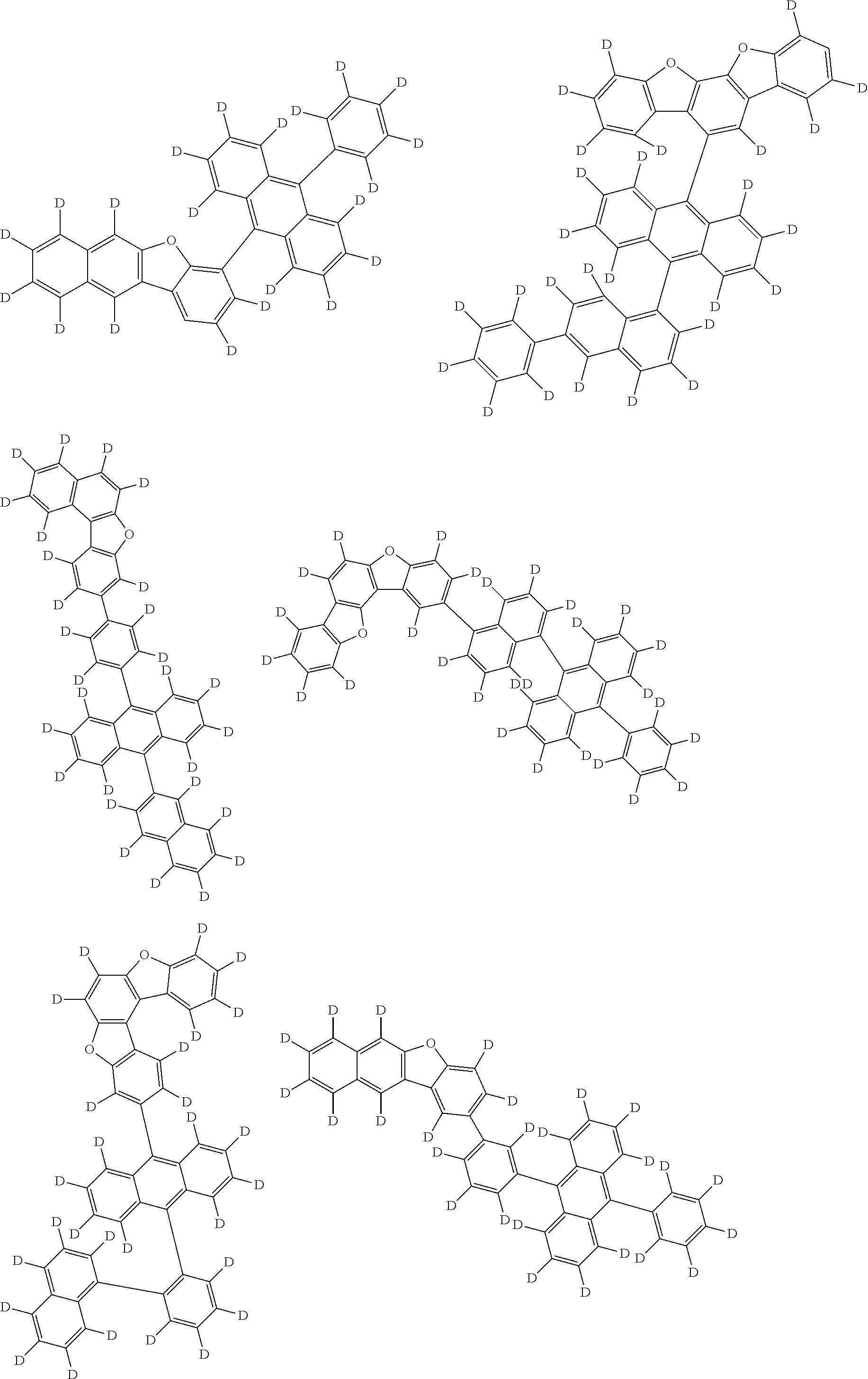

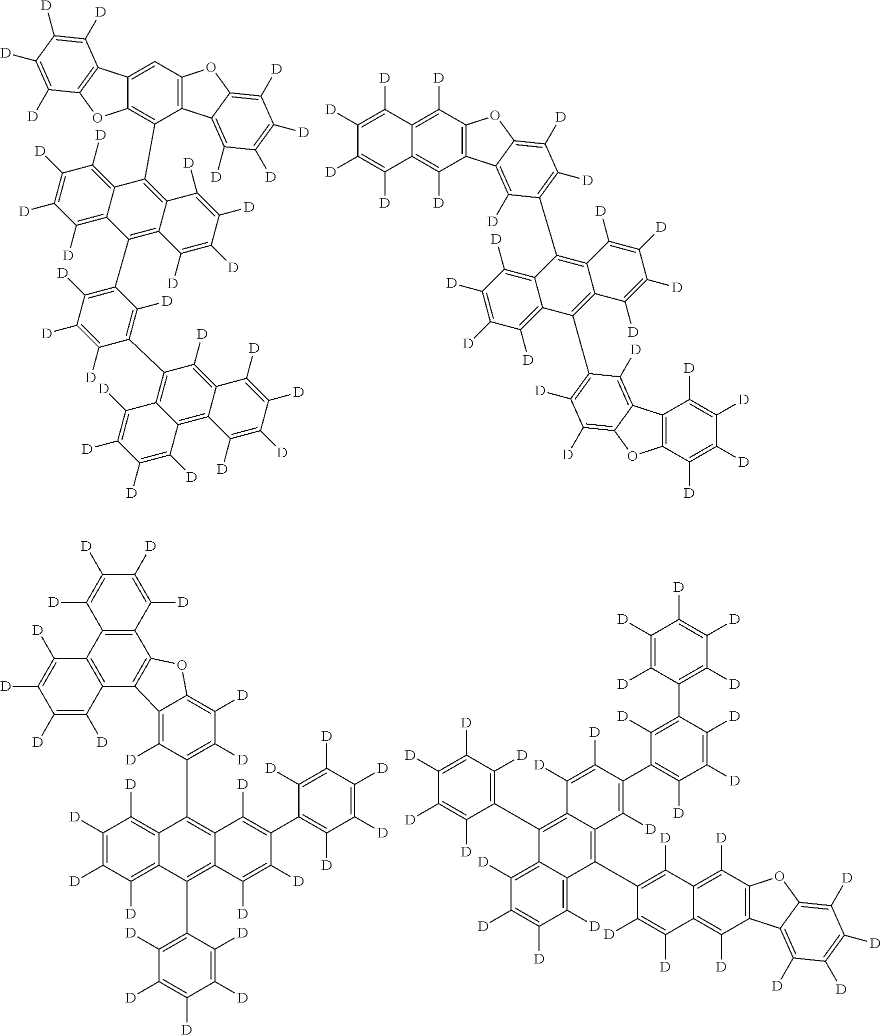

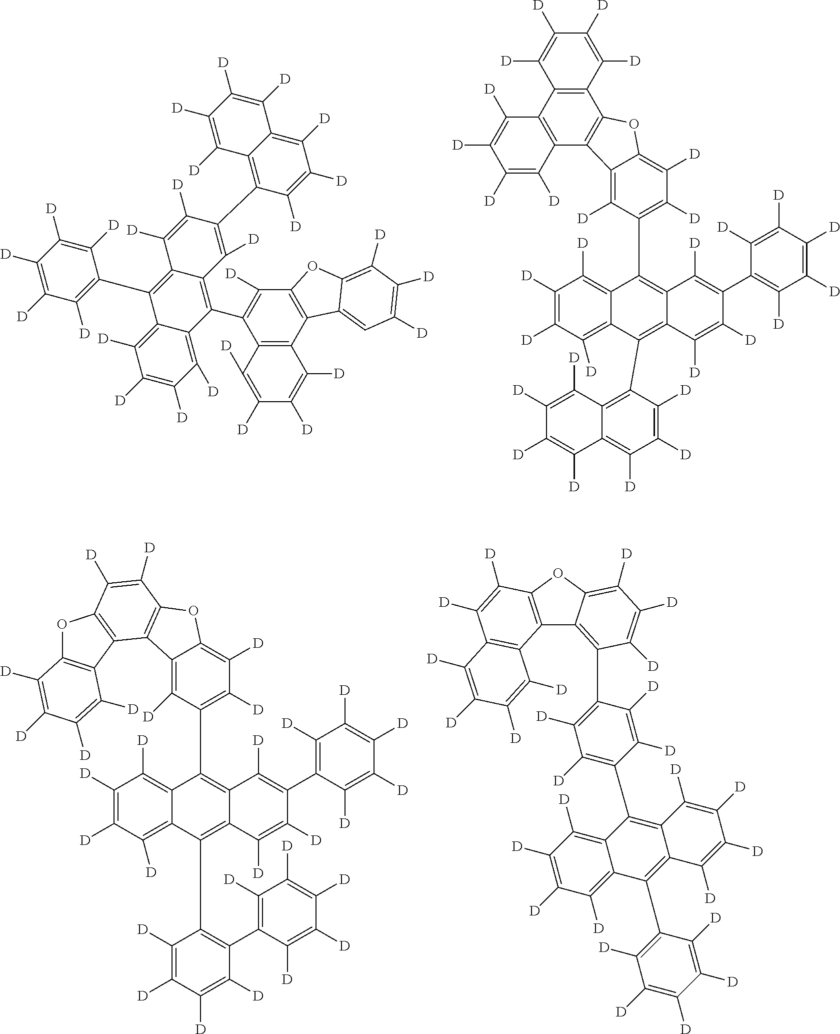

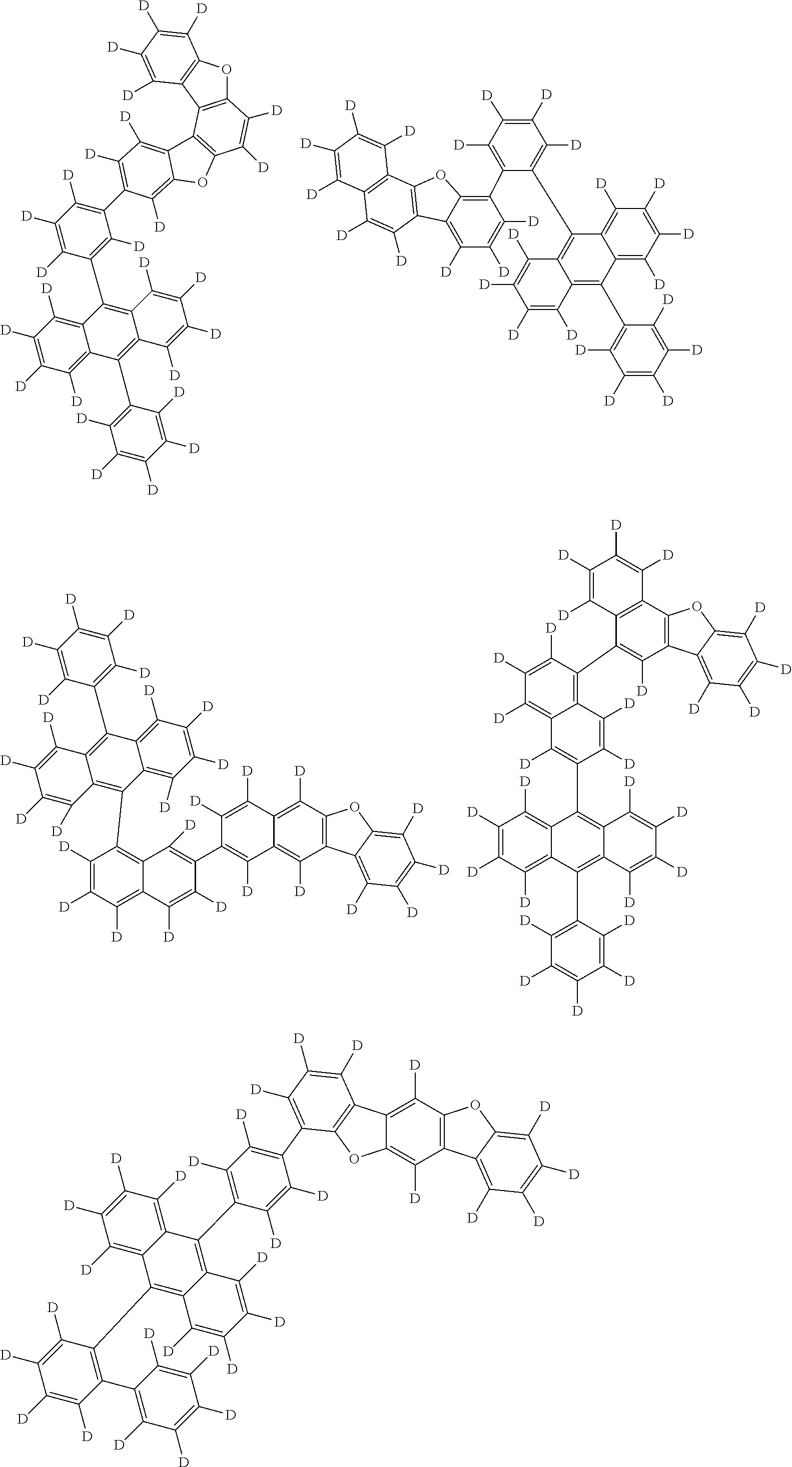

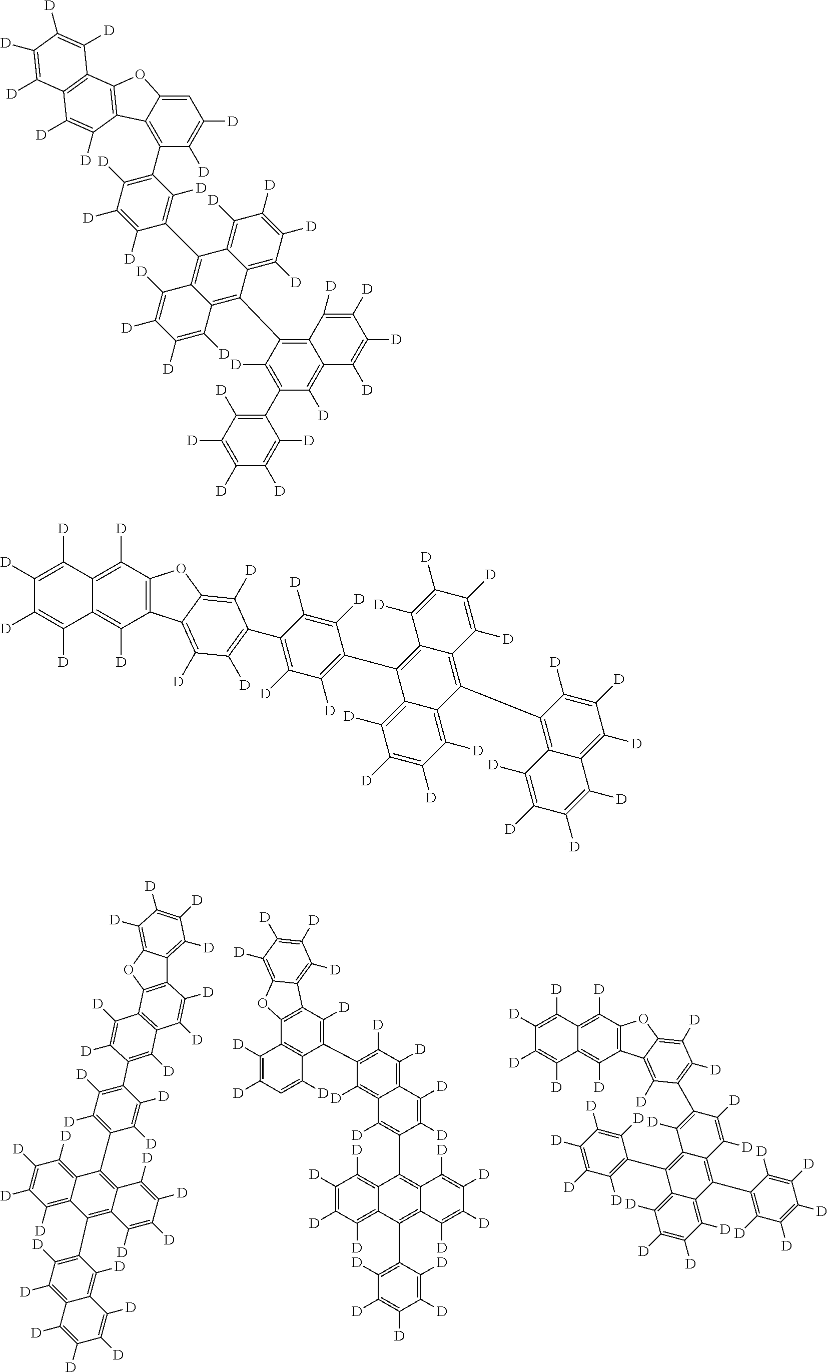

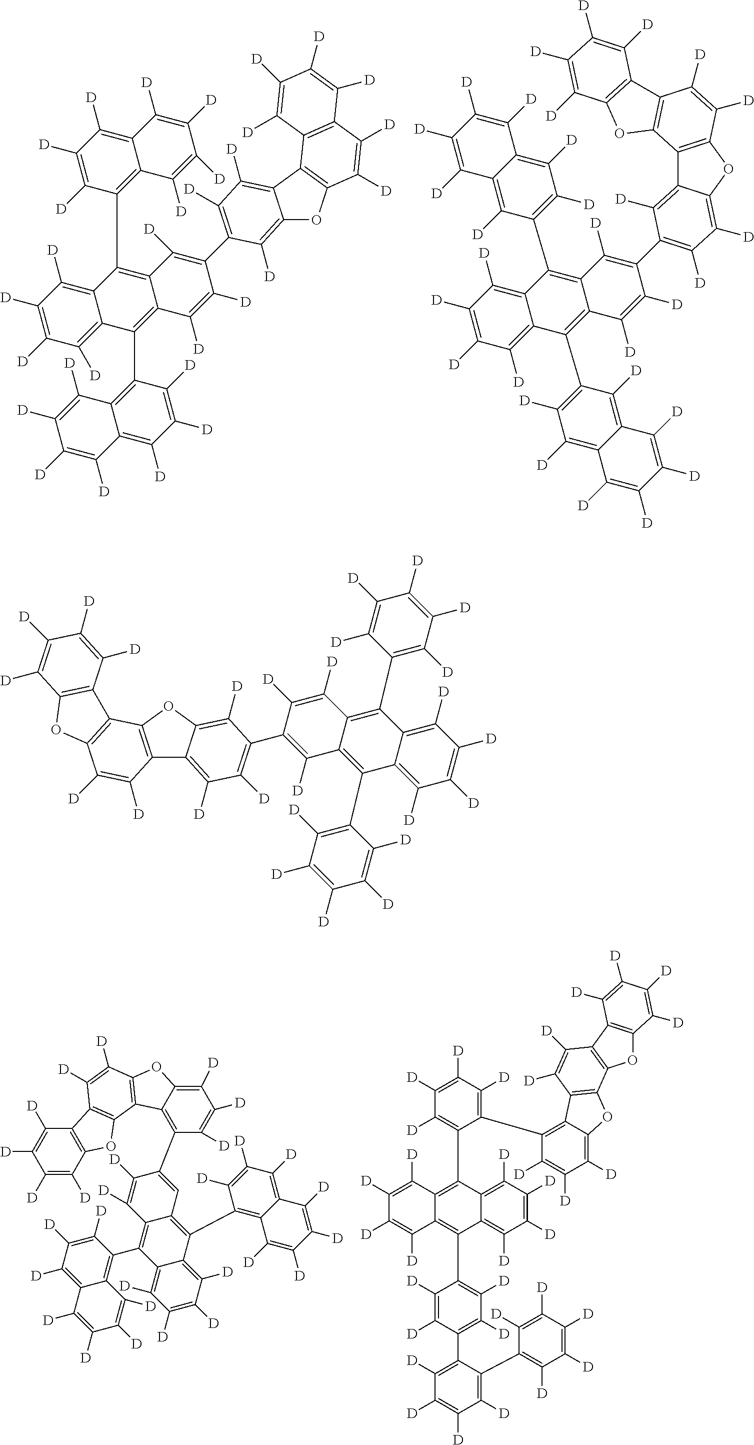

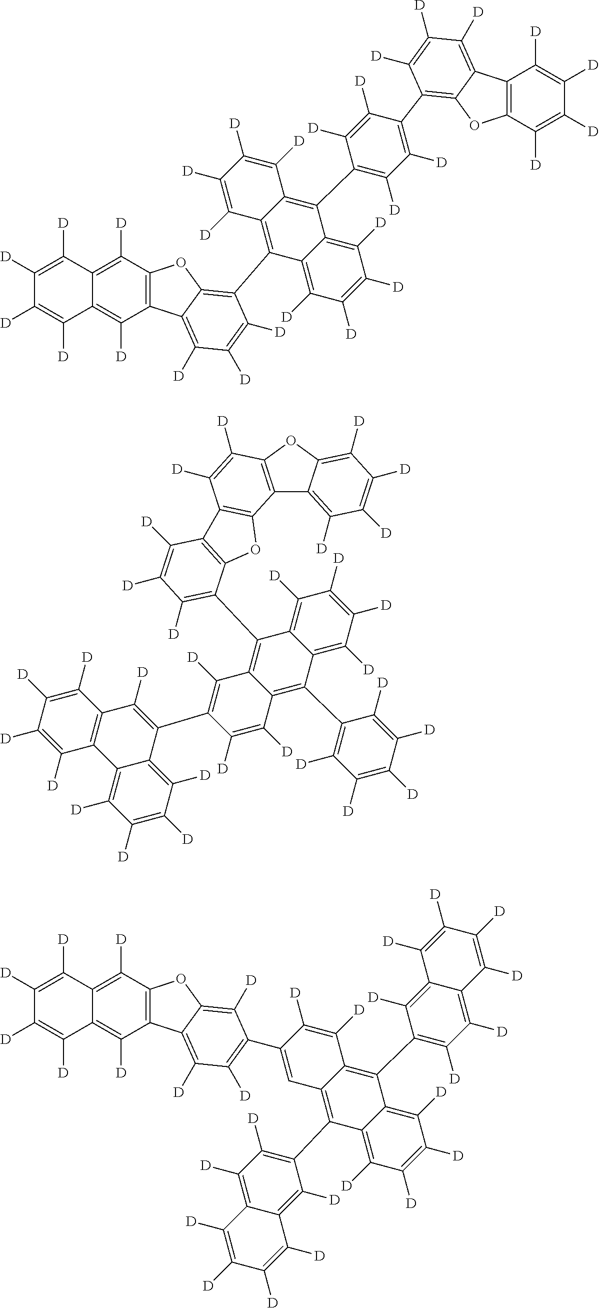

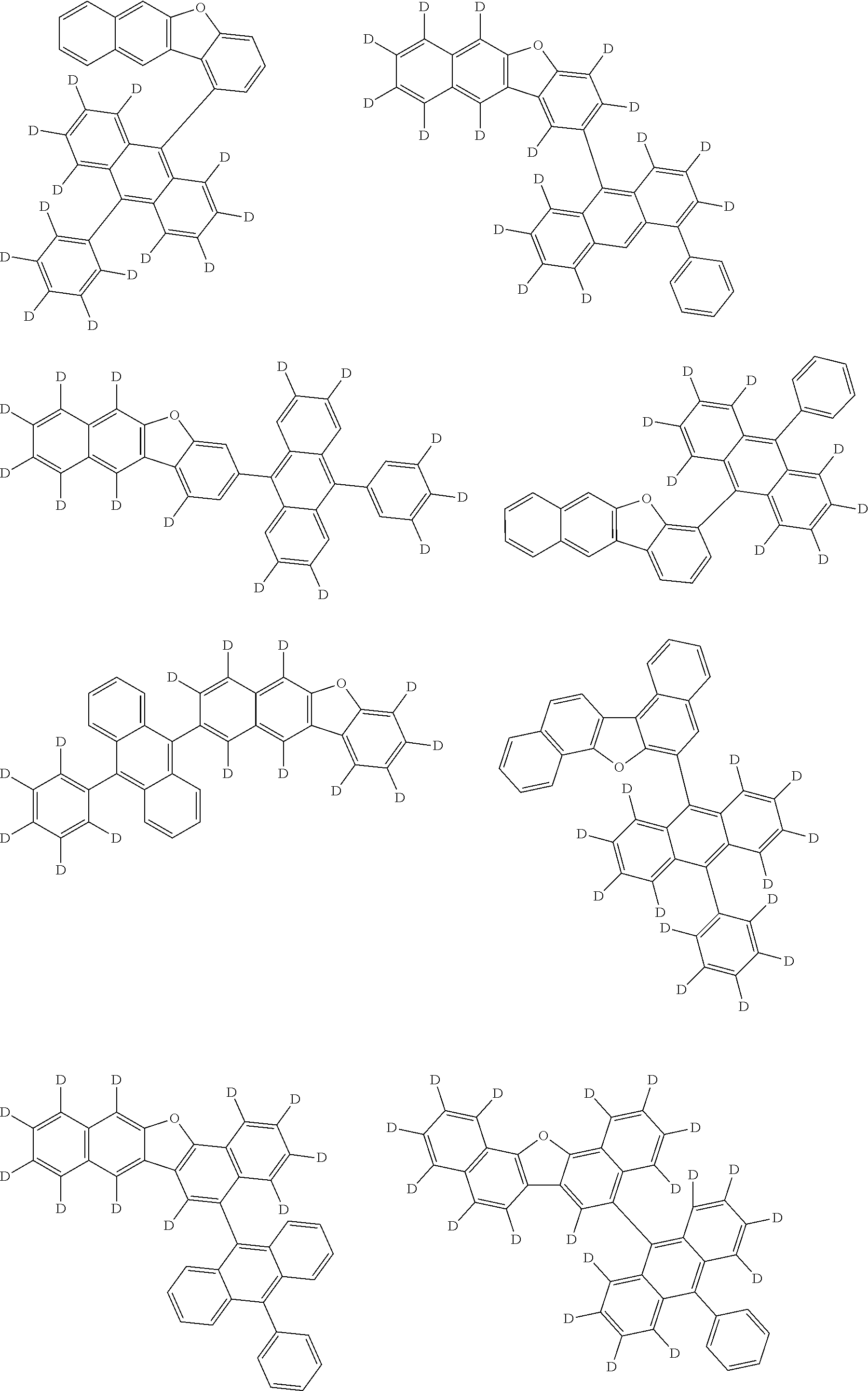

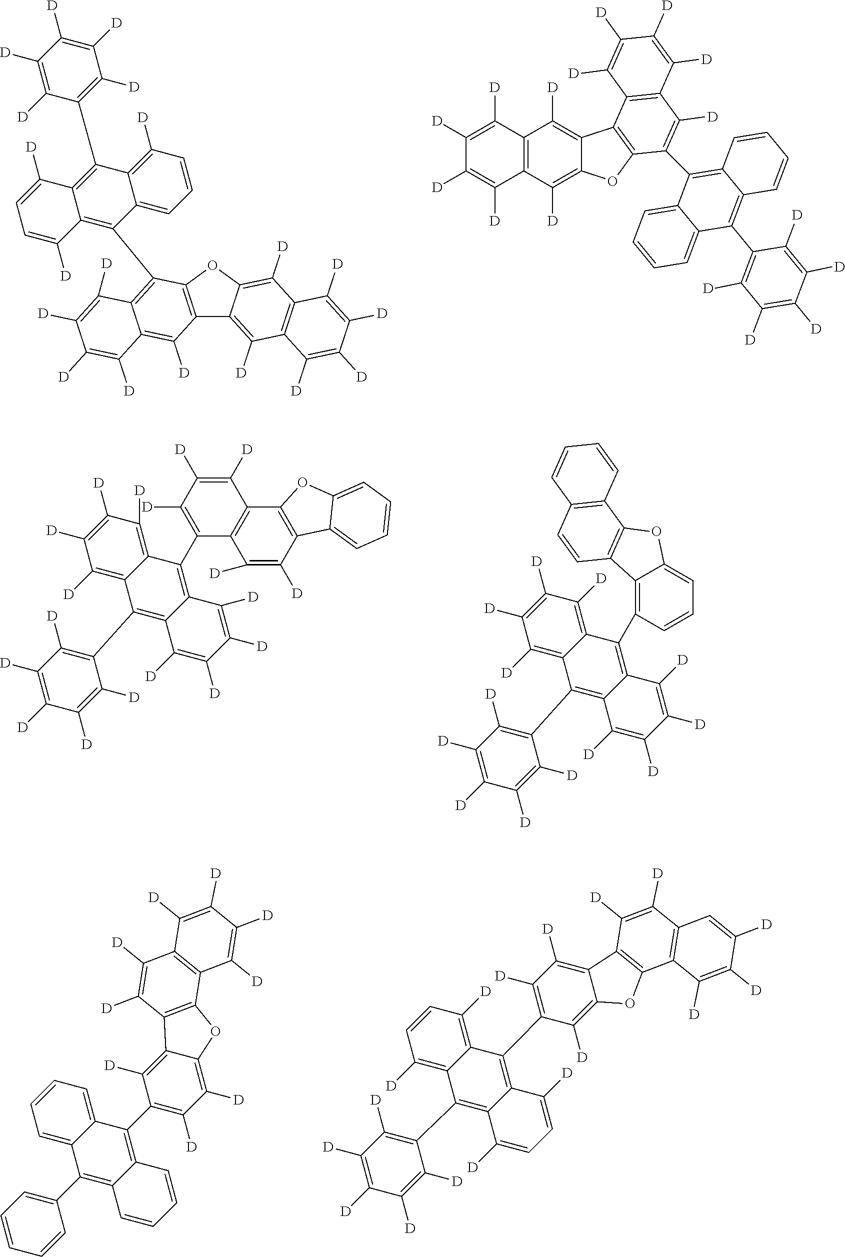

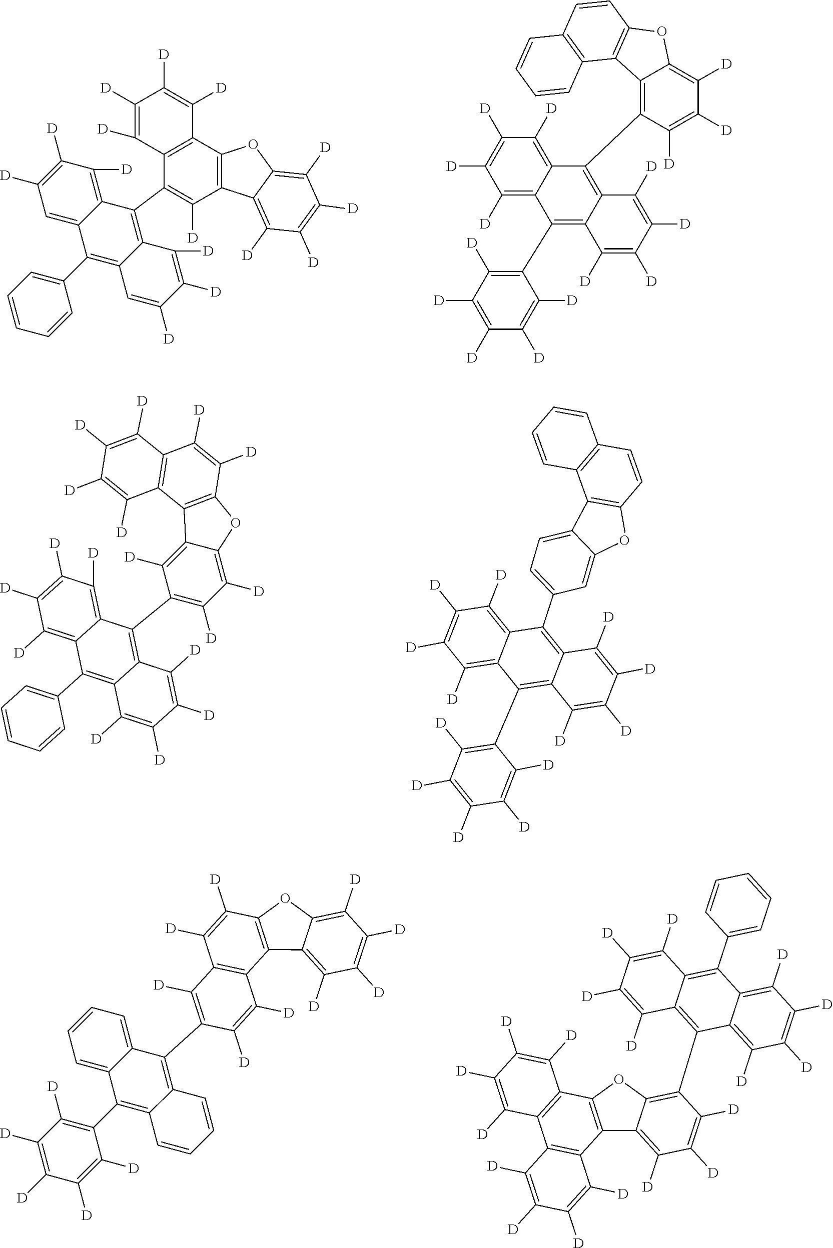

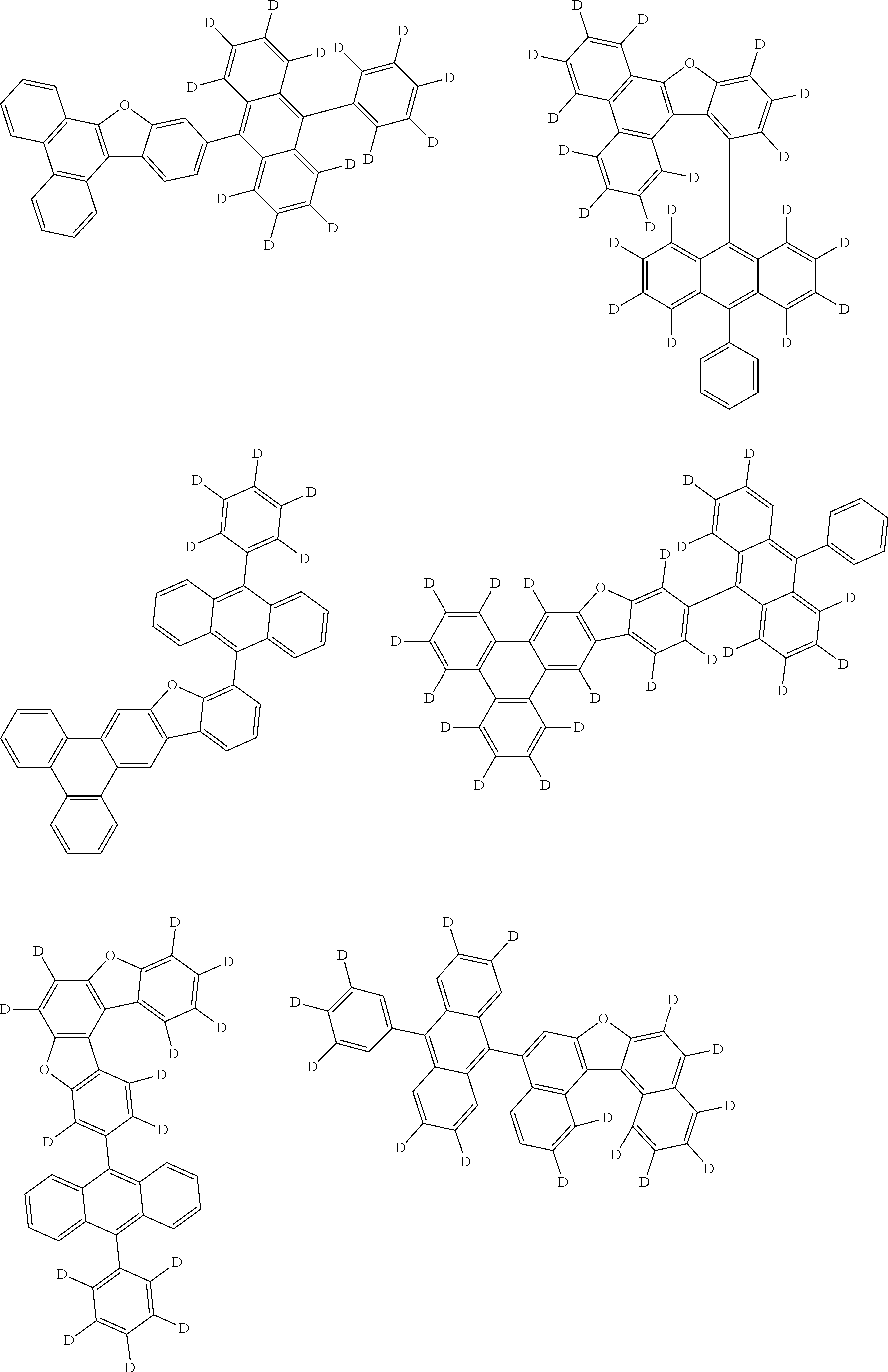

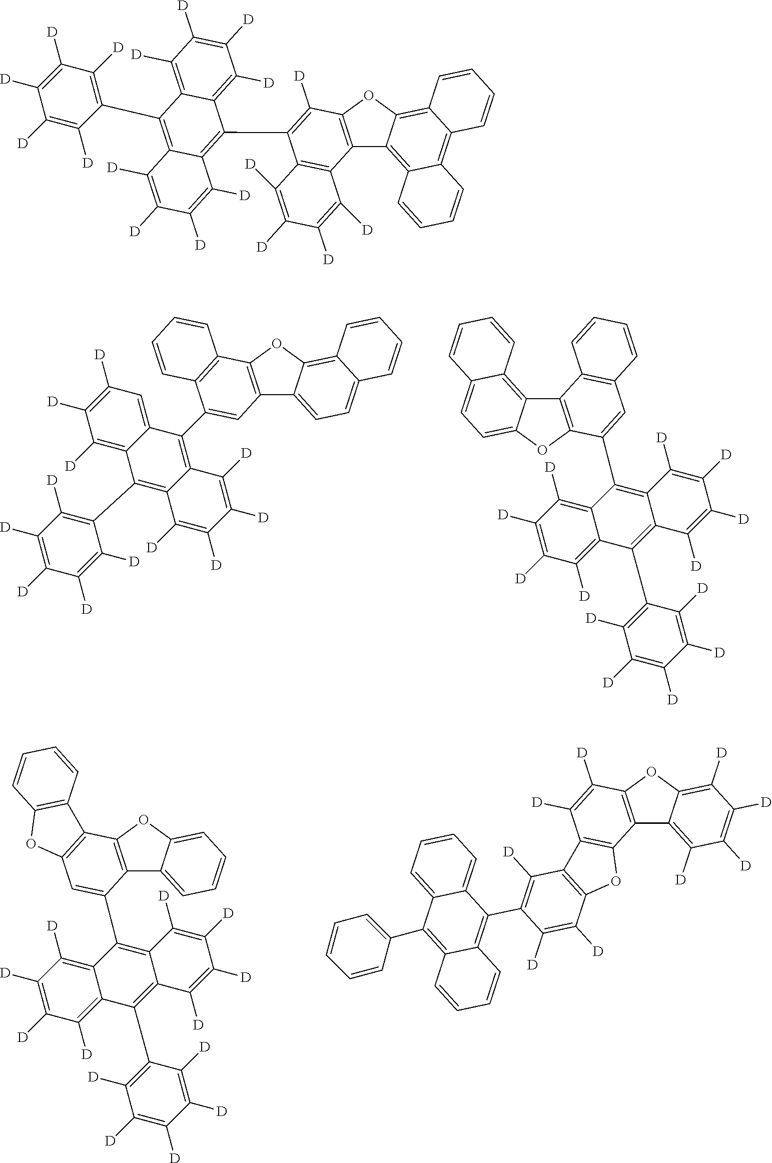

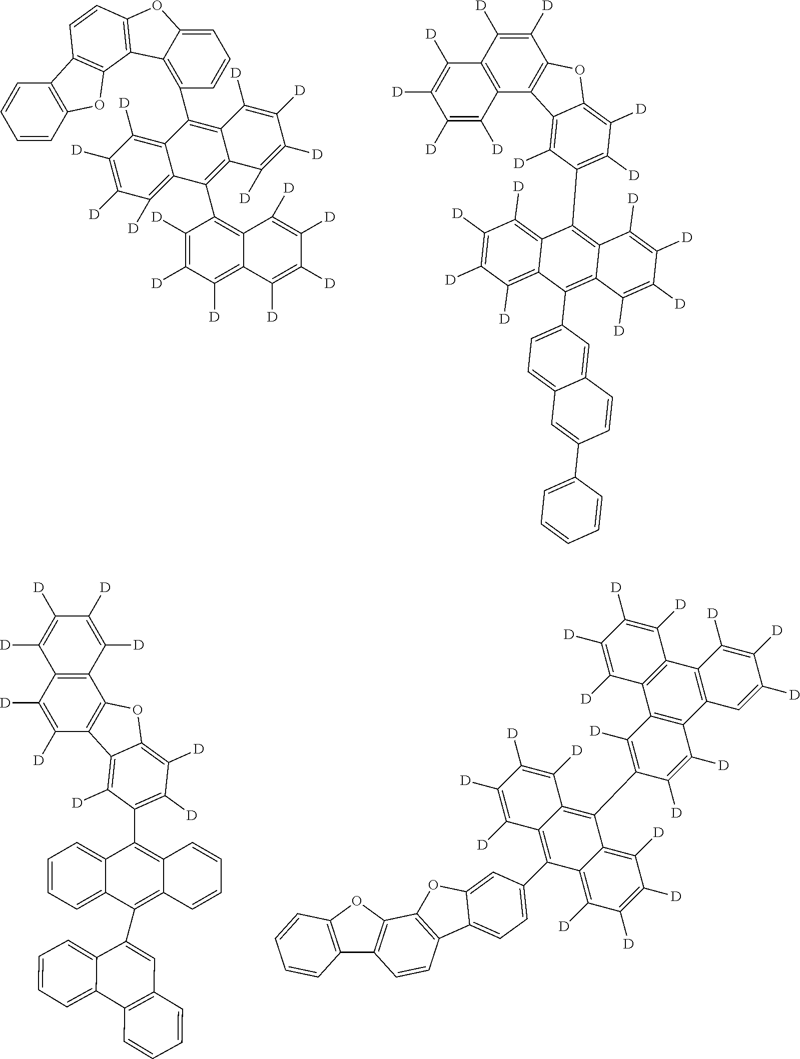

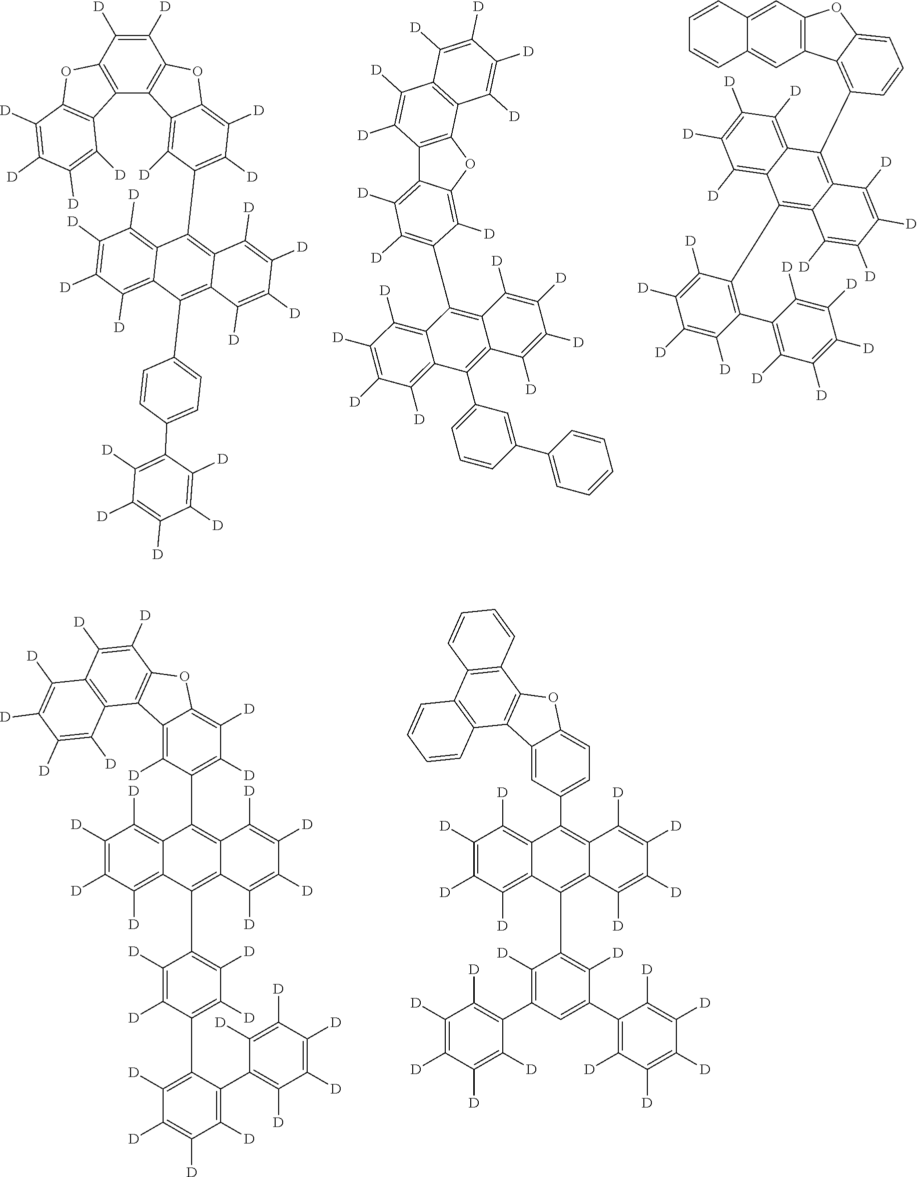

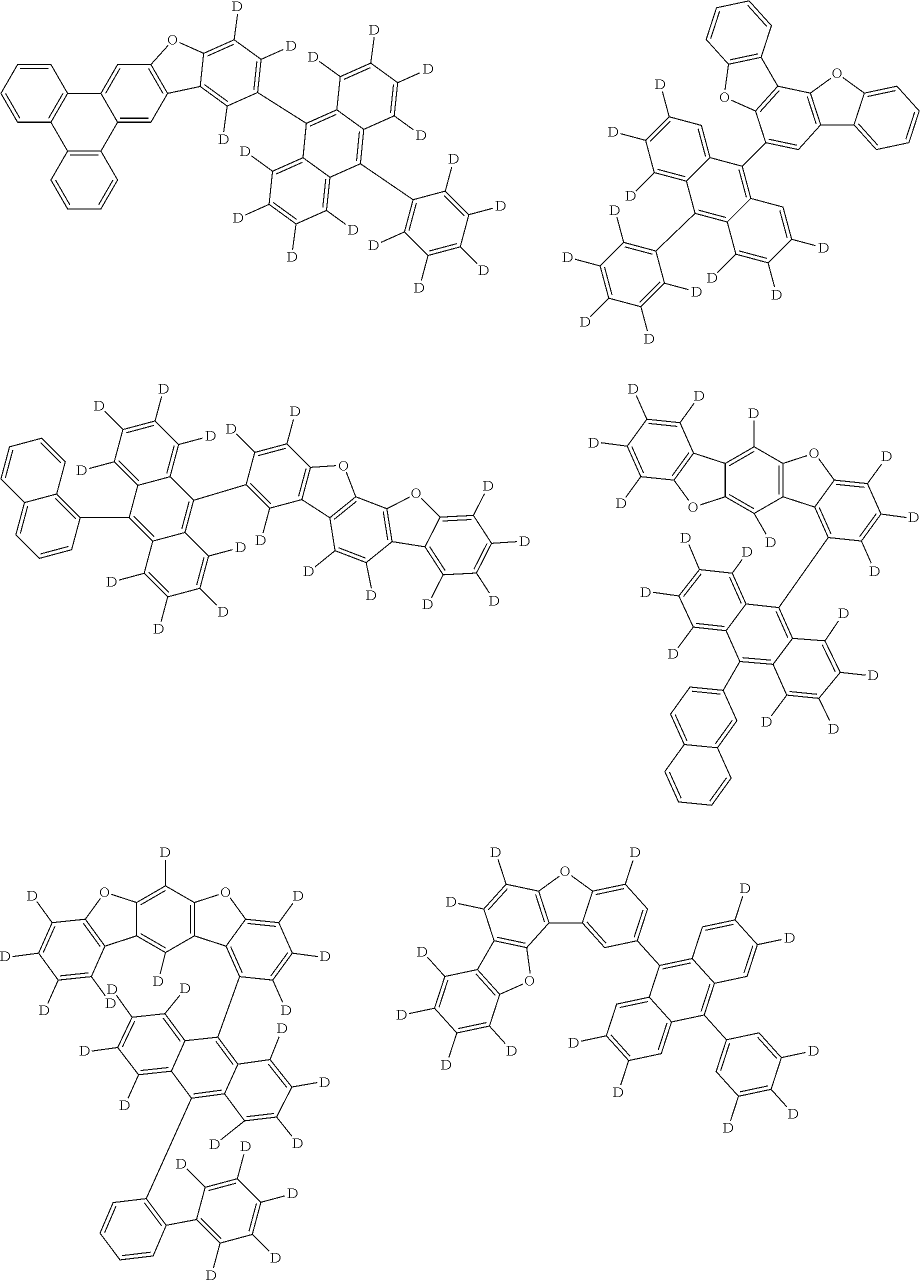

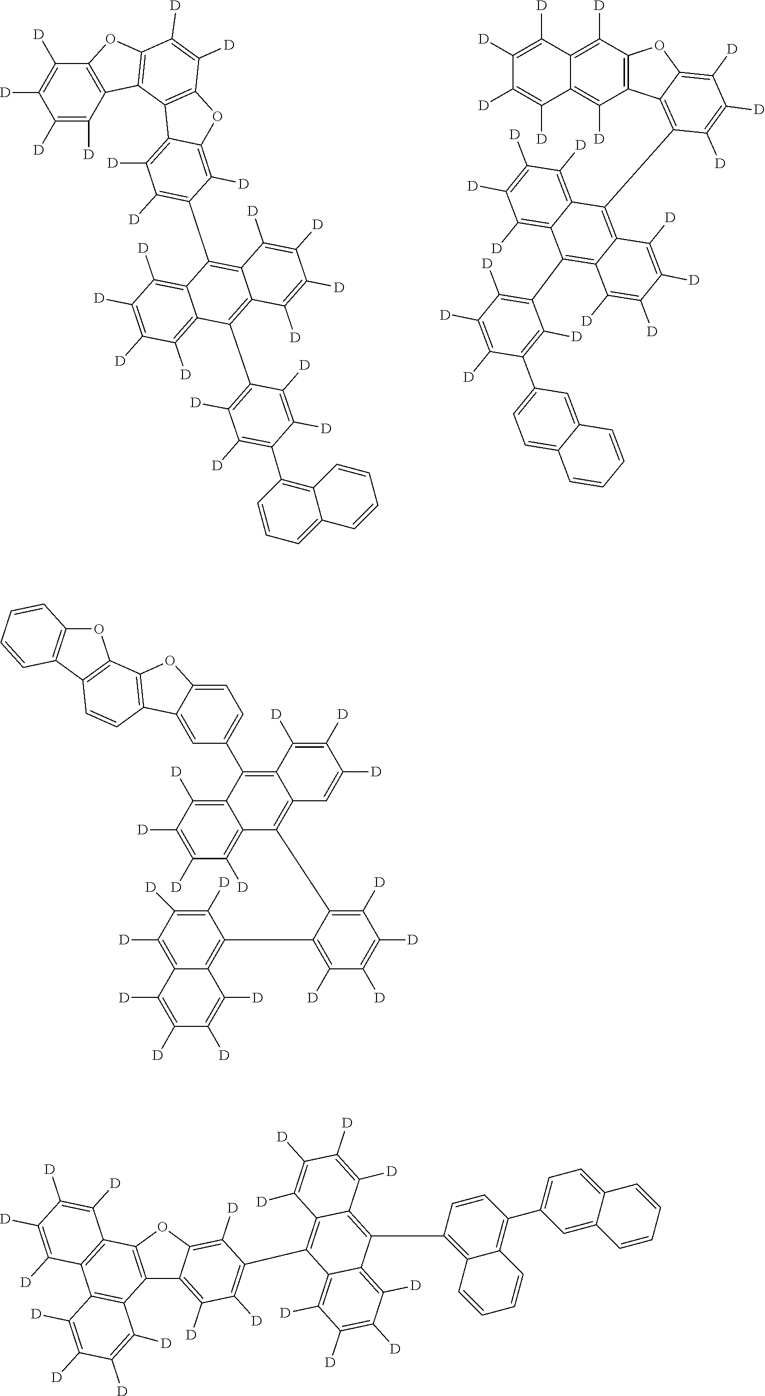

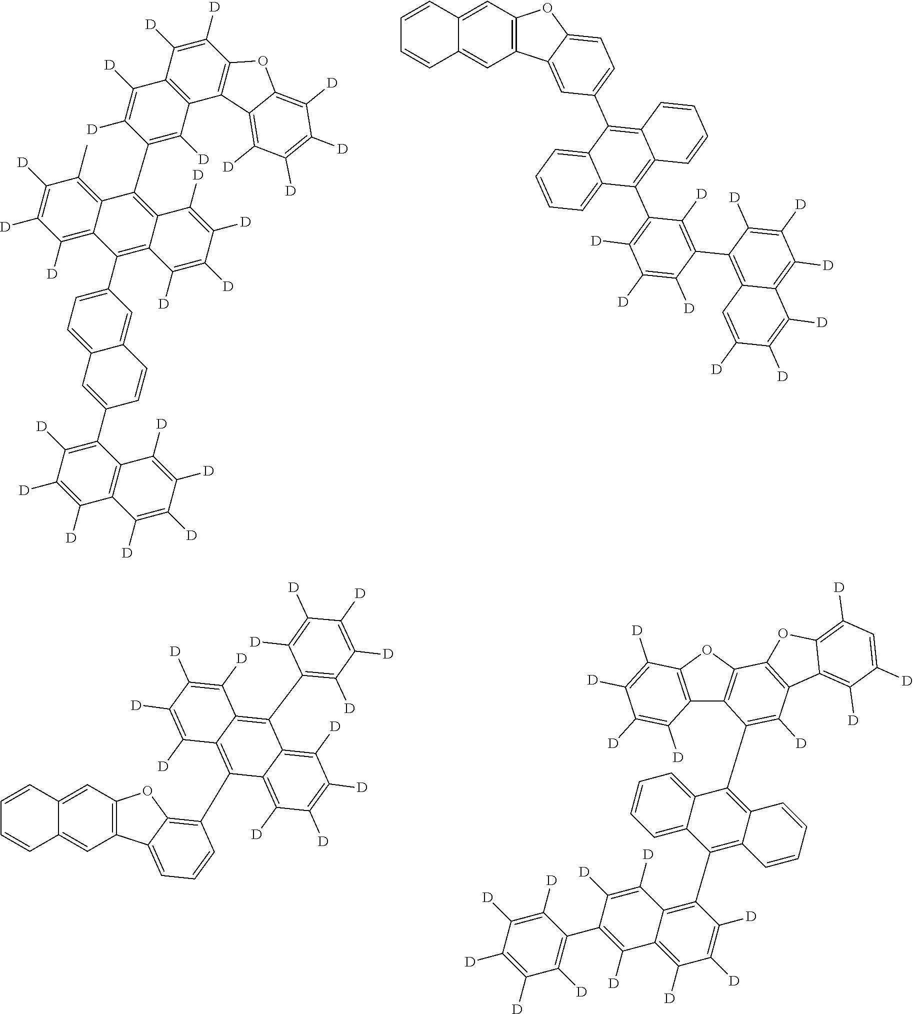

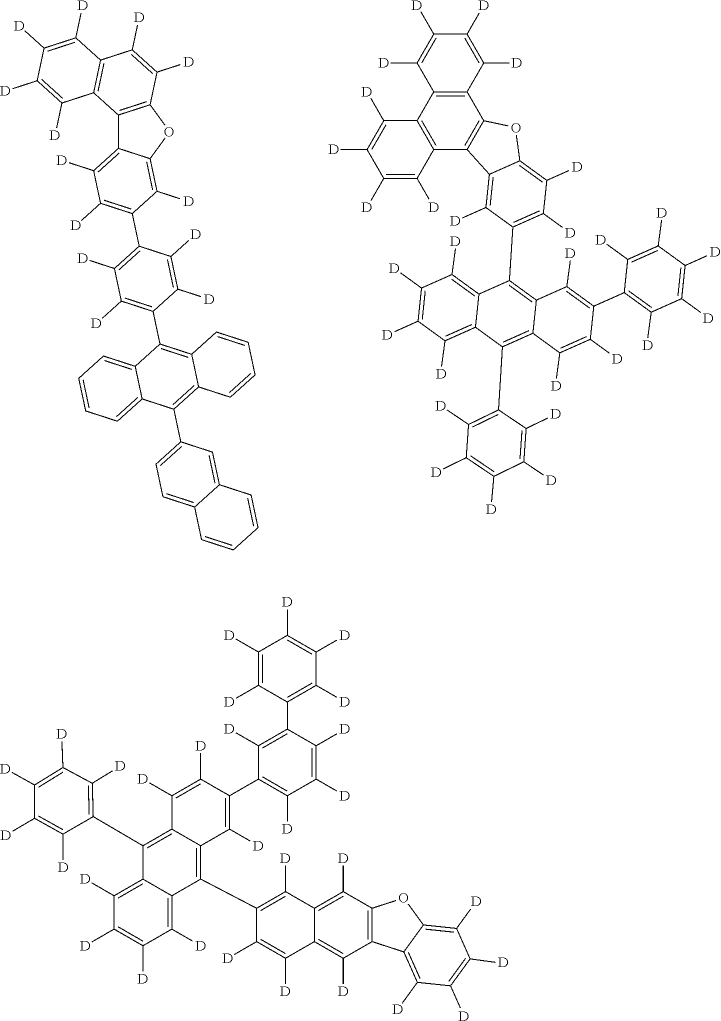

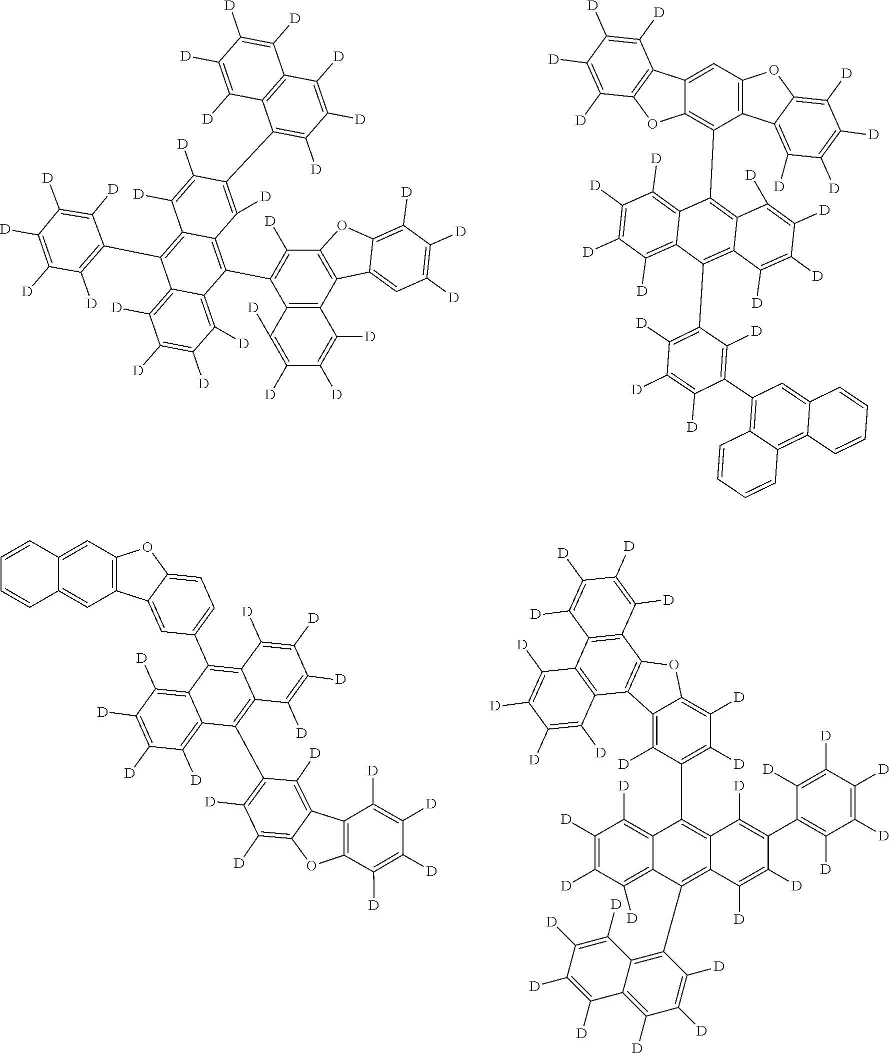

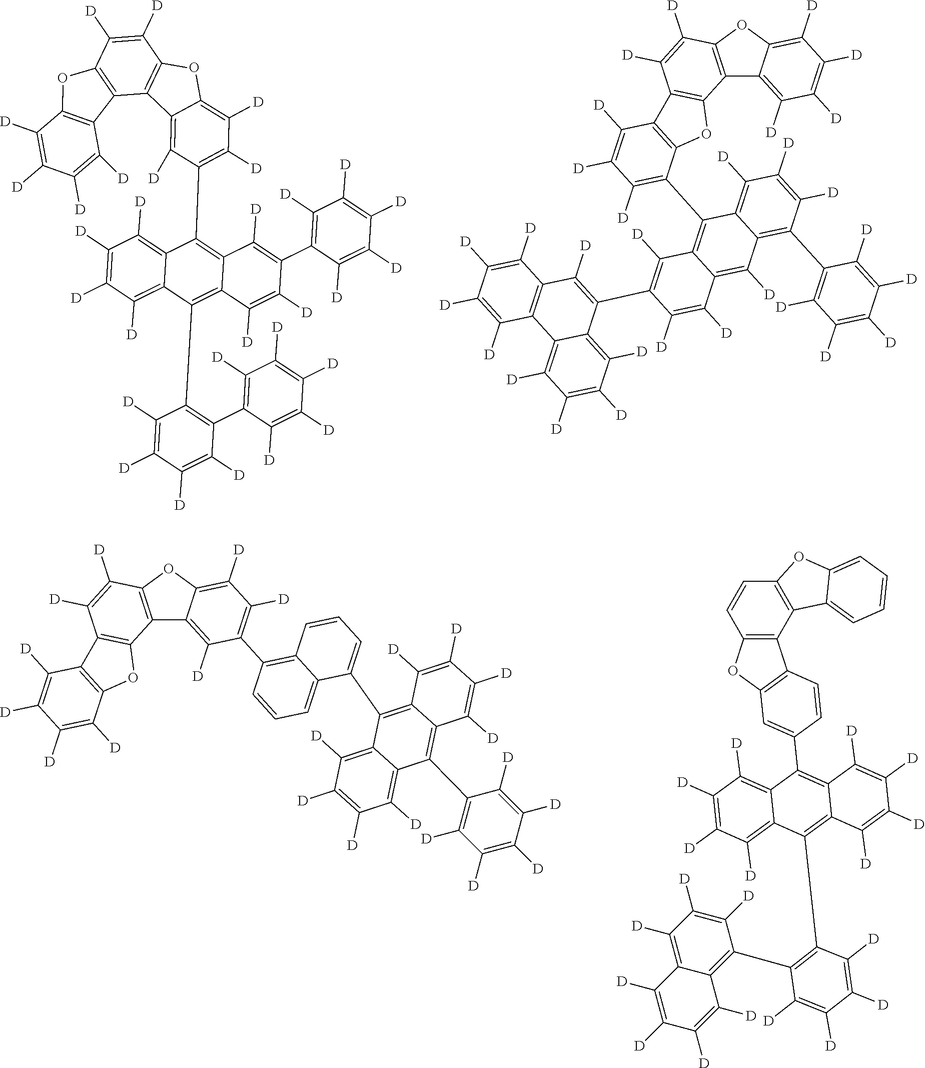

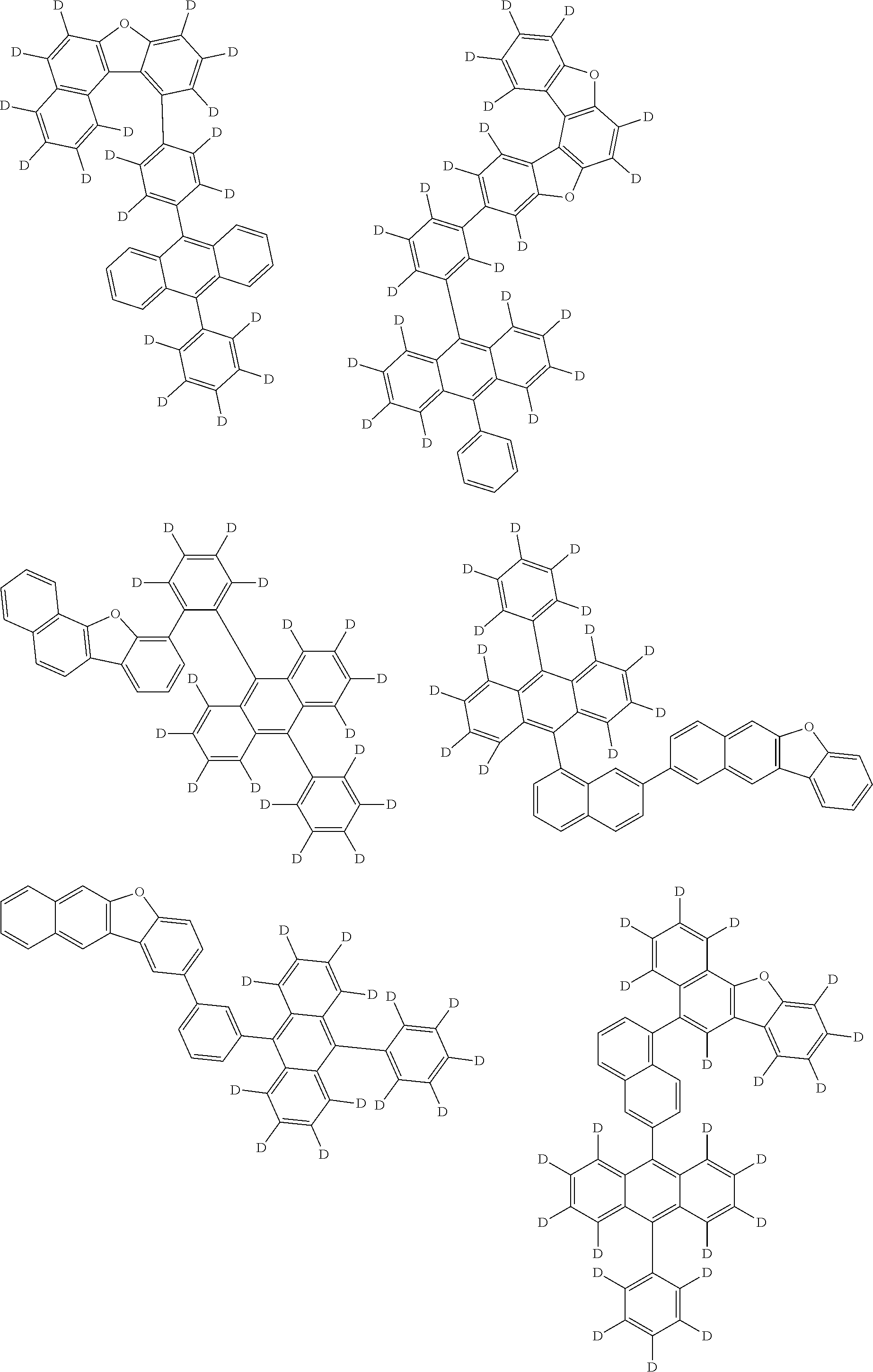

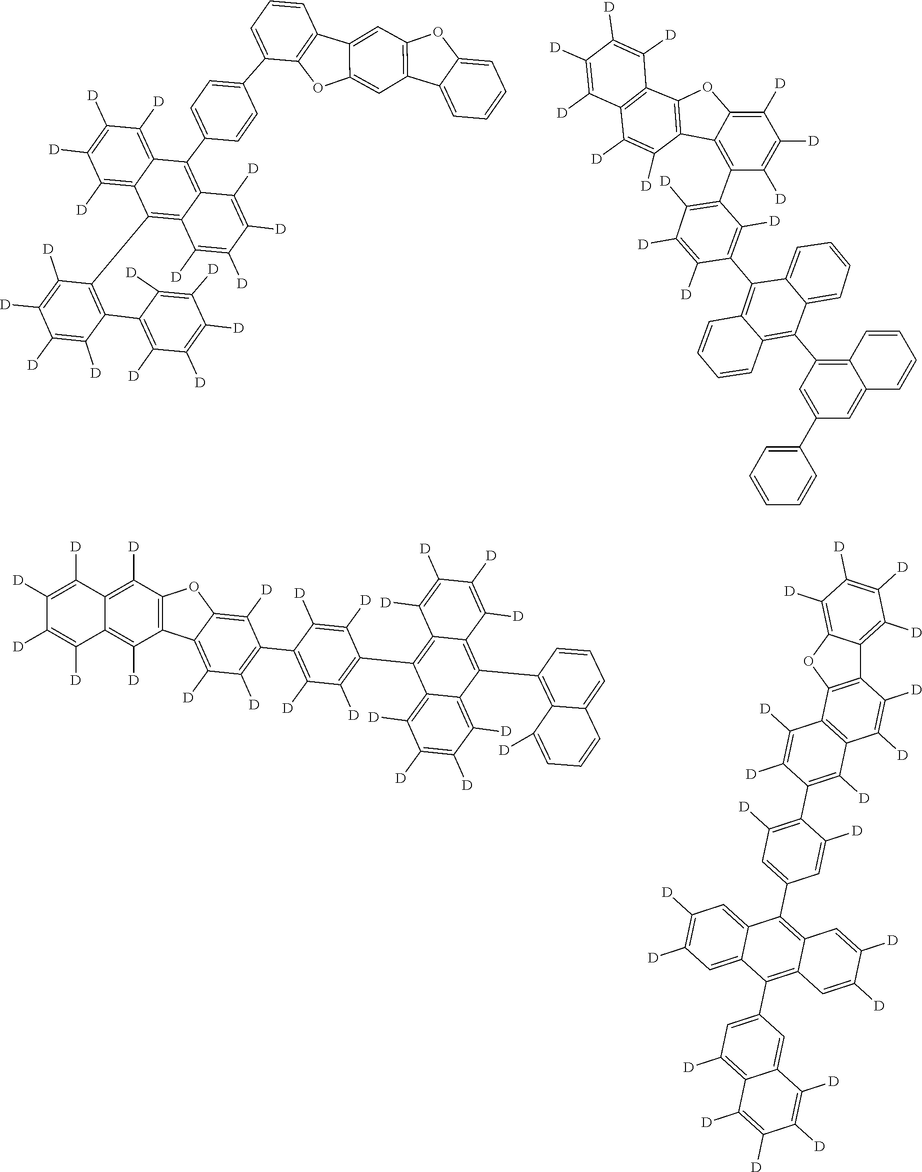

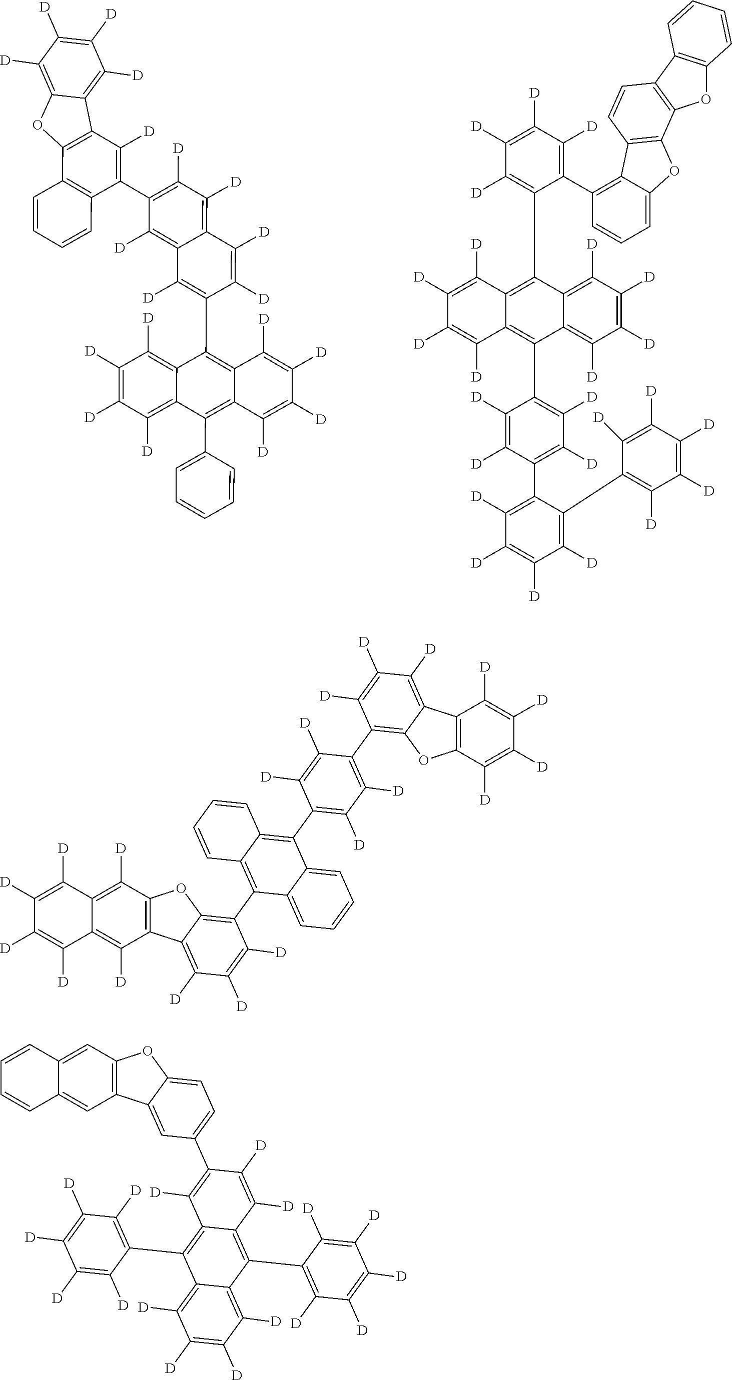

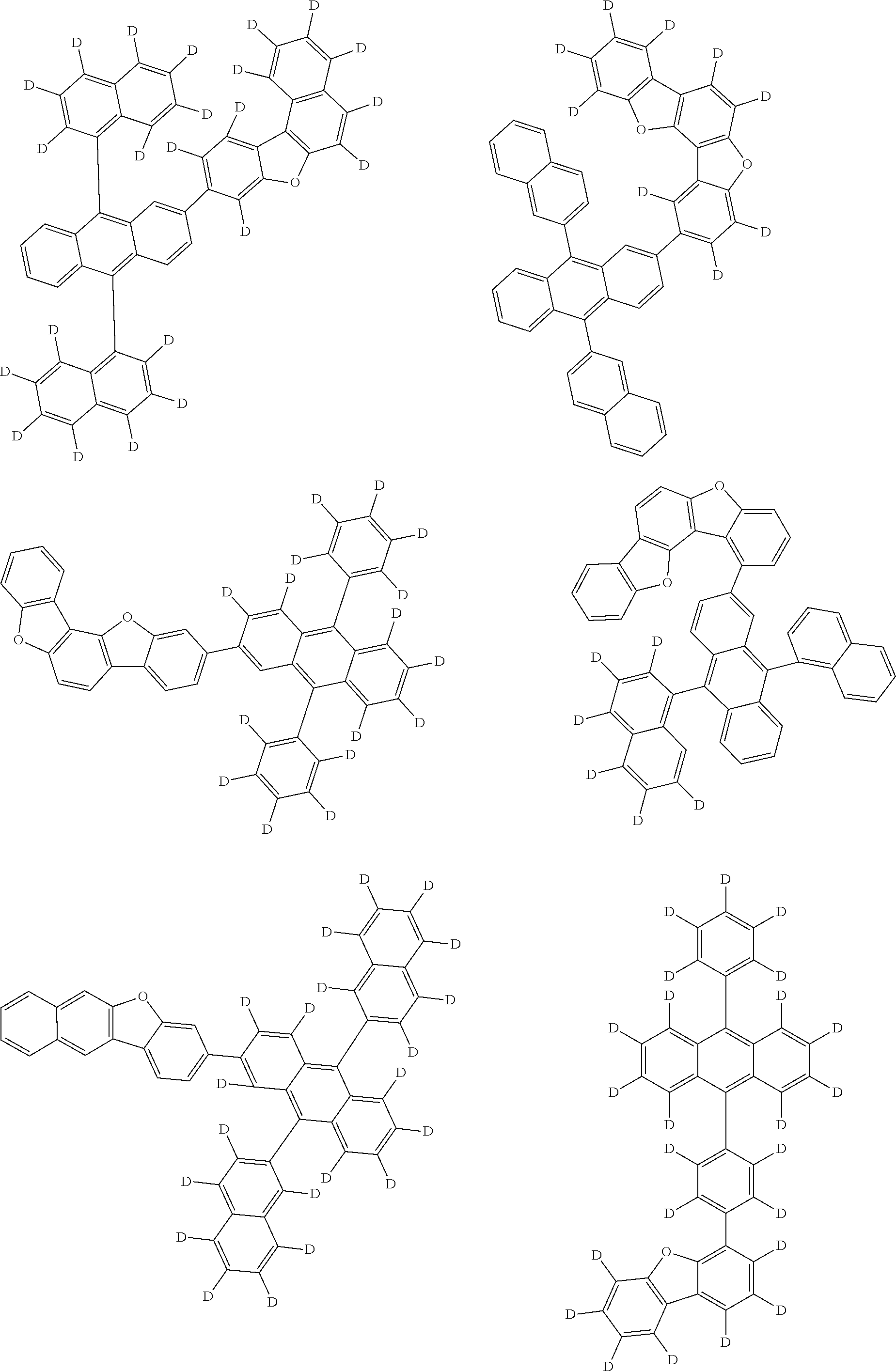

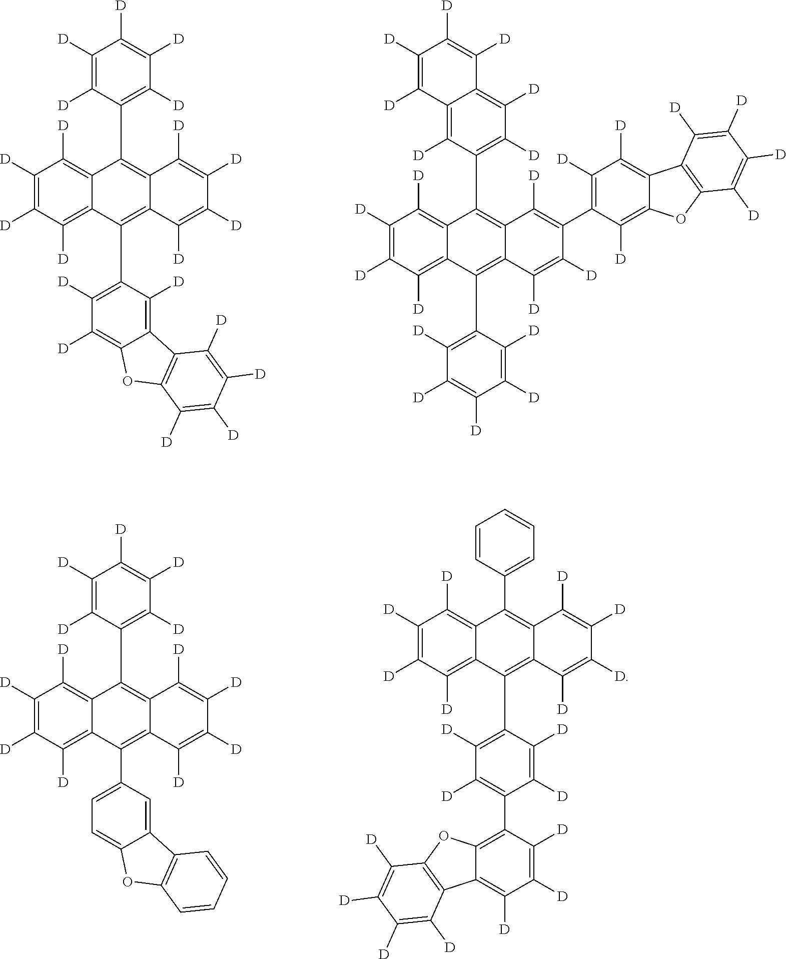

According to one embodiment of the present specification, one of the compound of Chemical Formula 1 and the compound of Chemical Formula 2 has a deuterium substitution rate of 10% to 100%, and when the deuterium substitution rate is less than 10%, synthesis is difficult, and an effect of improving a lifetime is insignificant when used in a device.

In one embodiment of the present specification, one of the compound of Chemical Formula 1 and the compound of Chemical Formula 2 has a deuterium substitution rate of 40% to 100%. When using the compound having a deuterium substitution rate of 40% to 100%, an effect of improving a lifetime is very superior when used in a device.

According to one embodiment of the present specification, two of the compound of Chemical Formula 1 and the compound of Chemical Formula 2 have a deuterium substitution rate of 10% to 100%. When two of the hosts have a deuterium substitution rate of 10% to 100%, superior efficiency and lifetime are obtained in a device.

According to one embodiment of the present specification, the compound of Chemical Formula 1 and the compound of Chemical Formula 2 have a mass ratio (mass of Chemical Formula 1:mass of Chemical Formula 2) of 1:9 to 9:1.

In one embodiment of the present specification, the compound of Chemical Formula 1 and the compound of Chemical Formula 2 satisfy the following Equation 1. When satisfying the following Equation 1, the two of compounds have a very different dipole moment value, and when using the two of compounds in a light emitting layer in a device, one of the compounds effectively improves hole injection and the other of the compounds controls an exciton generation region by controlling electrons into the light emitting layer, and as a result, device performance can be improved.

$$\vert D {M}_{host 1} - D {M}_{host 2} \vert > 0. 2 \qquad < Equation 1 >$$

DMₕₒₛₜ₁ is a dipole moment value of the compound of Chemical Formula 1, and

DMₕₒₛₜ₂ is a dipole moment value of the compound of Chemical Formula 2.

According to one embodiment of the present specification, the compound of Chemical Formula 1 has a dipole moment value of greater than or equal to 0 and less than 1 D, or greater than or equal to 0 and less than 0.5 D.

According to one embodiment of the present specification, the compound of Chemical Formula 2 has a dipole moment value of 0.5 D to 2 D, or greater than or equal to 0.7 D and less than 2 D.

In the present specification, a dipole moment is a physical quantity representing a degree of polarity and can be calculated by the following Mathematical Equation 1, and the unit is debye (D).

$$p ( r ) = {\int }_{V} ρ ( {r}_{0} ) ( {r}_{0} - r ) {d}^{3} {r}_{0} \qquad < Mathematical Equation 1 >$$

ρ(r₀): molecular density
V: volume
r: the point of observation
d³r₀: an elementary volume

The value of a dipole moment can be obtained by calculating molecular density in Mathematical Equation 1. For example, molecular density can be obtained by obtaining charge and dipole for each atom using a method referred to as Hirshfeld Charge Analysis and then conducting calculation according to the following equation, and a dipole moment can be obtained by putting the calculation result into Mathematical Equation 1.
Weight Function

$${W}_{α} ( r ) = {ρ}_{α} {( r - {R}_{α} ) [ {\sum }_{ρ} {ρ}_{β} ( r - {R}_{ρ} ) ]}^{- 1}$$

$${ρ}_{α} ( r - {R}_{α} ) : spherically averaged ground - state amomic density$$

$${\sum }_{ρ} {ρ}_{β} ( r - {R}_{ρ} ) : promolecule density$$

Deformation Density

$${ρ}_{d} ( r ) = ρ ( r ) - {\sum }_{α} {ρ}_{α} ( r - {R}_{α} )$$

ρ(t): molecular density
ρₐ(r−Rₐ): density of the free atom a located at coordinates R_{α}
Atomic Charge

$$q ( α ) = - \int {ρ}_{d} ( r ) {W}_{α} ( r ) {d}^{3} r$$

W_{α}(r): weight function

According to one embodiment of the present specification, the compound of Chemical Formula 1 and the compound of Chemical Formula 2 satisfy the following Equation 2. When forming an organic material layer through one deposition source by pre-mixing the compound of Chemical Formula 1 and the compound of Chemical Formula 2, a mixture having excellent uniformity can be obtained by satisfying the following Equation 2, and a uniform film can be obtained in a step of manufacturing a device as well.

$$\vert {T}_{sub 1} - {T}_{sub 2} \vert \leq 20 ° C \qquad < Equation 2 >$$

T_{sub1} is an evaporation temperature of the compound of Chemical Formula 1, and
T_{sub2} is an evaporation temperature of the compound of Chemical Formula 2.

According to one embodiment of the present specification, the “|T_{sub1}−T_{sub2}|” value can be 15° C. or lower.

In the present specification, the composition includes the compound of Chemical Formula 1 and the compound of Chemical Formula 2, and the mixing form, the mixing ratio and the like of the compound of Chemical Formula 1 and the compound of Chemical Formula 2 are not limited.

In one embodiment of the present specification, the composition can mean a composition in which the compound of Chemical Formula 1 and the compound of Chemical Formula 2 are physically mixed, or can mean a sublimation mixture composition in which physically mixed materials are placed in a boat of a sublimator and sublimed at high temperature and high pressure.

One embodiment of the present specification provides a deposition source prepared using the composition. The deposition source includes the composition in which the compound of Chemical Formula 1 and the compound of Chemical Formula 2 are physically mixed, or includes the sublimation mixture composition in which physically mixed materials are placed in a boat of a sublimator and sublimed at high temperature and high pressure. The compounds are uniformly mixed in the sublimation mixture composition prepared through a sublimator as above, and therefore, device lifetime or efficiency is enhanced when used in a device.

One embodiment of the present specification provides an organic electroluminescent device including a cathode; an anode; and a light emitting layer provided between the cathode and the anode, wherein the light emitting layer includes the composition.

In order to form a light emitting layer including the composition, co-deposition of depositing the compound of Chemical Formula 1 and the compound of Chemical Formula 2 each through a different deposition source can be used, or a method of pre-mixing the compound of Chemical Formula 1 and the compound of Chemical Formula 2 and depositing through one deposition source can be used.

According to one embodiment of the present specification, as a material of the light emitting layer, the compound of Chemical Formula 1 and the compound of Chemical Formula 2 can be included as a blue fluorescent host, and an additional dopant material can be included. When using co-deposition to prepare a blue fluorescent light emitting layer having such a mixed host material, three deposition sources are generally required, which makes the process very complicated and expensive. Accordingly, by forming an organic material layer through pre-mixing two or more types of the materials among three or more types of the compounds and evaporating from one deposition source, complexity of the manufacturing process can be reduced, and stable deposition resulting from simultaneous evaporation can be accomplished.

The two types of hosts (compounds of Chemical Formula 1 and Chemical Formula 2) exhibit stable miscibility, and can be simultaneously deposited from one deposition source since changes in the composition are within a certain range after mixing. Uniform simultaneous evaporation of the two types of hosts is important for performance continuity of a manufactured organic electroluminescent device.

According to one embodiment of the present specification, the light emitting layer includes the compound of Chemical Formula 1 and the compound of Chemical Formula 2 as a host, and further includes a dopant material. Herein, the dopant material can be included in approximately 0.01 mass % to 20 mass %, or 0.01 mass % to 10 mass % with respect to a total mass sum of the compound of Chemical Formula 1 and the compound of Chemical Formula 2 in the light emitting layer.

According to one embodiment of the present specification, the organic electroluminescent device is a multi-stack type, and one or two stacks thereof include the composition.

According to one embodiment of the present specification, an emission spectrum of the light emitting layer including the composition has Amax in 400 nm to 470 nm.

According to one embodiment of the present specification, the light emitting layer further includes a fluorescent dopant.

According to one embodiment of the present specification, the light emitting layer further includes a pyrene-based compound as a dopant.

According to another embodiment, the light emitting layer further includes a pyrene-based compound unsubstituted or substituted with deuterium as a dopant.

According to one embodiment of the present specification, the light emitting layer further includes a non-pyrene-based compound as a dopant.

According to another embodiment, the light emitting layer further includes a non-pyrene-based compound unsubstituted or substituted with deuterium as a dopant.

According to one embodiment of the present specification, the non-pyrene-based compound includes a boron-based compound.

According to another embodiment, the non-pyrene-based compound includes a boron-based compound unsubstituted or substituted with deuterium.

In another embodiment, the compound of Chemical Formula 1 and the compound of Chemical Formula 2 each have an evaporation temperature of lower than 400° C.

In another embodiment, the compound of Chemical Formula 1 has an evaporation temperature of higher than or equal to 200° C. and lower than 400° C., or higher than or equal to 230° C. and lower than or equal to 370° C.

According to another embodiment, the compound of Chemical Formula 2 has an evaporation temperature of higher than or equal to 200° C. and lower than 400° C., or higher than or equal to 230° C. and lower than or equal to 370° C.

When the compound of Chemical Formula 1 and the compound of Chemical Formula 2 are pre-mixed before deposition according to one embodiment of the present disclosure, they are simultaneously evaporated by one deposition source and need to be stable during the evaporation process. In other words, the film composition needs to be kept constant during the manufacturing process, and for this, changes in the composition of the mixed material need to be within a certain range. Having large changes in the composition can adversely affect performance of a manufactured device. Accordingly, the materials to be mixed need have a small difference in the evaporation temperature values. The evaporation temperature is measured at a deposition rate of 2 Å/s at, in a high vacuum deposition apparatus having a chamber base pressure of 1×10⁻⁴ torr to 1×10⁻⁹ torr, a place where the evaporation source of the material is evaporated, for example, on a surface locating at a determined distance from the evaporation crucible in the VTE apparatus. Various measured values such as temperature, pressure and deposition rate disclosed in the present specification are expected to have nominal variations due to expected errors in the measurements producing such quantitative values as understood by those skilled in the art.

The “determined distance” means a distance between the evaporation source and the deposited surface in the deposition apparatus, and is determined depending on the chamber size.

According to one embodiment of the present specification, the compound of Chemical Formula 1 or the compound of Chemical Formula 2 has a concentration of C1 in the composition, and has a concentration of C2 in a film formed by evaporating the composition at a deposition rate of 1 Å/s to 10 Å/s on a surface locating at a determined distance from a place where the composition is evaporated in a high vacuum deposition apparatus having a chamber base pressure of 1×10⁻⁴ torr to 1×10⁻⁹ torr, and satisfies the following Equation 3.

$$\vert ( C 1 - C 2 ) / C 1 \vert < 10 \% \qquad < Equation 3 >$$

According to one embodiment of the present specification, the compound of Chemical Formula 1 and the compound of Chemical Formula 2 both satisfy Equation 3.

In one embodiment of the present specification, the concentrations C1 and C2 are relative concentrations of the compound of Chemical Formula 1 or the compound of Chemical Formula 2. Accordingly, a conventional requirement for the two compounds forming the composition described above means that the relative concentration (C2) of the compound of Chemical Formula 1 in the as-deposited film needs to be as close as possible to the original relative concentration (C1) of the compound of Chemical Formula 1 in the evaporation source composition. Those skilled in the art will understand that the concentration of each component is expressed as a relative percentage. The concentration of each component in the composition can be measured using proper analysis methods such as high pressure liquid chromatography (HPLC) and nuclear magnetic resonance (NMR) spectroscopy. The inventors of the present disclosure use HPLC, and calculate the percentage by dividing the integrated area under the HPLC trace of each component by the total integrated area. HPLC can use different detectors such as UV-vis, a photo diode array detector, a refractive index detector, a fluorescence detector and a light scattering detector. Each component in the composition can react differently due to different material properties. Accordingly, the measured concentration can differ from the actual concentration in the composition, however, the relative ratio value of (C1−C2)/C1 is independent from the above-mentioned variables as long as the experimental conditions are calculated constant, for example, provided that all the concentrations need to be maintained under exactly the same HPLC parameters for each component. It is sometimes preferred to choose a measurement condition so that the calculated concentration is close to the actual concentration. However, this is not essential. Choosing a detection condition that accurately detects each component is important. For example, a fluorescence detector is not to be used when one of the components is not fluorescent.

In one embodiment of the present specification, an organic material layer obtained by depositing the composition through one deposition source can be a light emitting layer.

One embodiment of the present specification provides a method for manufacturing an organic electroluminescent device, the method including preparing the composition; preparing a substrate; forming a first electrode on the substrate; forming one or more organic material layers on the first electrode; and forming a second electrode on the organic material layer, wherein the forming of one or more organic material layers includes forming one or more organic material layers using the composition.

The organic material layer of the organic electroluminescent device of the present specification can be formed in a single layer structure, but can be formed in a multilayer structure in which two or more organic material layers are laminated. For example, as a representative example of the organic electroluminescent device of the present specification, the organic electroluminescent device can include only one light emitting layer as the organic material layer, but can have a structure including, in addition to the light emitting layer, a hole injection layer, a hole transfer layer, a layer carrying out hole injection and hole transfer at the same time, an electron control layer, a hole control layer, an additional light emitting layer, an electron transfer layer, an electron injection layer, a layer carrying out electron injection and electron transfer at the same time, and the like.

In one embodiment of the present specification, the organic electroluminescent device can be an organic electroluminescent device having a structure in which an anode, one or more organic material layers and a cathode are consecutively laminated on a substrate (normal type).

In one embodiment of the present specification, the organic electroluminescent device can be an organic electroluminescent device having a structure in a reverse direction in which a cathode, one or more organic material layers and an anode are consecutively laminated on a substrate (inverted type).

In the present specification, a description of a certain member being placed “on” another member includes not only a case of the one member being in contact with the another member but a case of still another member being present between the two member.

In the present specification, the “layer” has a meaning compatible with a ‘film’ mainly used in the art, and means coating covering a target area. The size of the “layer” is not limited, and each “layer” can have the same or a different size. According to one embodiment, the size of the “layer” can be the same as the whole device, can correspond to the size of a specific functional area, or can be as small as a single sub-pixel.

In the present specification, a meaning of a specific A material being included in a B layer includes both i) one or more types of A materials being included in one B layer, and ii) a B layer being formed in one or more layers, and an A material being included in one or more of the B layers that is a multilayer.

In the present specification, a meaning of a specific A material being included in a C layer or a D layer includes both i) being included in one or more layers of one or more C layers, ii) being included in one or more layers of one or more D layers, or iii) being included in each of one or more C layers and one or more D layers.

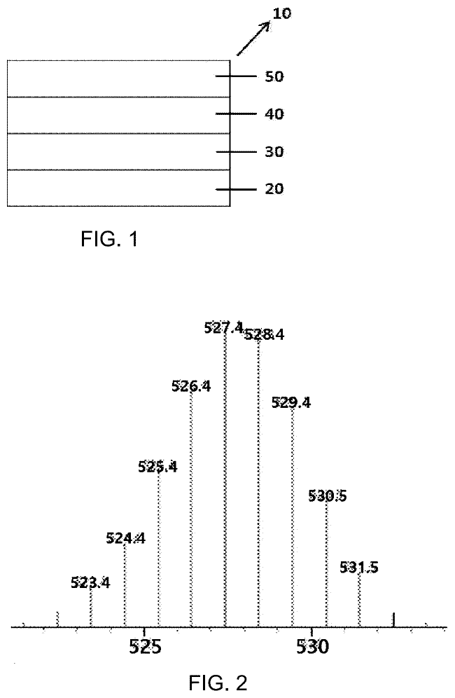

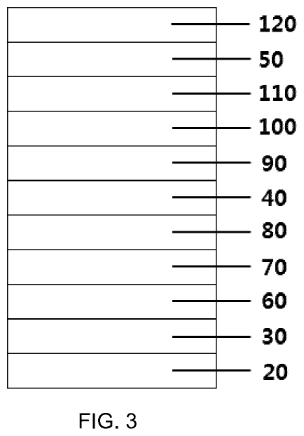

For example, structures of the organic electroluminescent device according to one embodiment of the present specification are illustrated in FIG. 1 and FIG. 3. FIG. 1 and FIG. 3 only illustrate the organic electroluminescent device, and the organic electroluminescent device is not limited thereto.

FIG. 1 illustrates a structure of the organic electroluminescent device (10) in which a substrate (20), an anode (30), a light emitting layer (40) and a cathode (50) are consecutively laminated.

FIG. 3 illustrates a structure of the organic electroluminescent device in which a substrate (20), an anode (30), a hole injection layer (60), a hole transfer layer (70), a hole control layer (80), a light emitting layer (40), an electron control layer (90), an electron transfer layer (100), an electron injection layer (110), a cathode (50) and a capping layer (120) are consecutively laminated.

The organic electroluminescent device of the present specification can be manufactured using materials and methods known in the art, except that one or more of the light emitting layers include the composition described above.

When the organic electroluminescent device includes a plurality of organic material layers, the organic material layers can be formed with the same materials or different materials.

For example, the organic electroluminescent device according to the present specification can be manufactured by forming an anode on a substrate by depositing a metal, a metal oxide having conductivity, or an alloy thereof using a physical vapor deposition (PVD) method such as sputtering or e-beam evaporation, forming an organic material layer including one or more of a hole injection layer, a hole transfer layer, a layer carrying out hole injection and hole transfer at the same time, an electron control layer, a hole control layer, a light emitting layer, an electron transfer layer, an electron injection layer, a layer carrying out electron injection and electron transfer at the same time thereon, and then depositing a material usable as a cathode thereon. In addition to such a method, the organic electroluminescent device can also be manufactured by consecutively depositing a cathode material, an organic material layer and an anode material on a substrate.

The one or more organic material layers can be formed using methods known in the art such as a deposition process and a solvent process. When the organic material layer includes two or more materials in the deposition process, co-deposition of depositing the two or more materials each through a different deposition source can be used, or a method of depositing through one deposition source after pre-mixing the two or more materials can be used. Examples of the solvent process can include a method of spin coating, dip coating, doctor blading, screen printing, inkjet printing, a thermal transfer method or the like.

The anode is an electrode injecting holes, and as the anode material, materials having large work function are normally preferred so that hole injection to an organic material layer is smooth. Specific examples of the anode material usable in the present disclosure include metals such as vanadium, chromium, copper, zinc and gold, or alloys thereof; metal oxides such as zinc oxide, indium oxide, indium tin oxide (ITO) and indium zinc oxide (IZO); combinations of metals and oxides such as ZnO:Al or SnO₂:Sb; conductive polymers such as poly(3-methylthiophene), poly[3,4-(ethylene-1,2-dioxy)thiophene] (PEDOT), polypyrrole and polyaniline, but are not limited thereto.

The cathode is an electrode injecting electrons, and as the cathode material, materials having small work function are normally preferred so that electron injection to an organic material layer is smooth. Specific examples of the cathode material include metals such as magnesium, calcium, sodium, potassium, titanium, indium, yttrium, lithium, gadolinium, aluminum, silver, tin and lead, or alloys thereof; multilayer structure materials such as LiF/Al or LiO/Al, and the like, but are not limited thereto.

The hole injection layer is a layer performing a role of smoothly injecting holes from an anode to a light emitting layer, and the hole injection material is a material capable of favorably receiving holes from an anode at a low voltage. The highest occupied molecular orbital (HOMO) of the hole injection material is preferably in between the work function of an anode material and the HOMO of surrounding organic material layers. Specific examples of the hole injection material include metal porphyrins, oligothiophene, arylamine-based organic materials, hexanitrile hexaazatriphenylene-based organic materials, quinacridone-based organic materials, perylene-based organic materials, anthraquinone, and polyaniline- and polythiophene-based conductive polymers, and the like, but are not limited thereto.

According to one embodiment of the present specification, the hole injection layer includes a compound of the following Chemical Formula HI-1, but is not limited thereto:

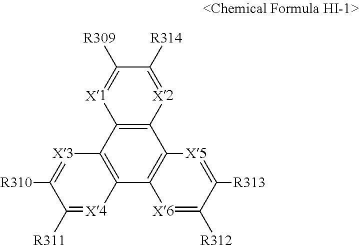

wherein in Chemical Formula HI-1:
at least one of X′1 to X′6 is N, and the rest are CH; and
R309 to R314 are the same as or different from each other, and each independently is hydrogen, deuterium, a cyano group, a substituted or unsubstituted alkyl group, a substituted or unsubstituted amine group, a substituted or unsubstituted aryl group, or a substituted or unsubstituted heteroaryl group, or bond to adjacent groups to form a substituted or unsubstituted ring.

According to one embodiment of the present specification, X′ 1 to X′ 6 are N.

According to one embodiment of the present specification, R309 to R314 are a cyano group.

According to one embodiment of the present specification, Chemical Formula HI-1 is the following compound:

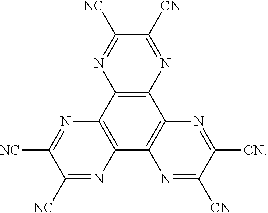 [SMILES: N#Cc1nc2c3nc(C#N)c(C#N)nc3c3nc(C#N)c(C#N)nc3c2nc1C#N]

The hole transfer layer can perform a role of smoothly transferring holes. As the hole transfer material, materials capable of receiving holes from an anode or a hole injection layer, moving the holes to a light emitting layer, and having high mobility for the holes are suited. Specific examples thereof include arylamine-based organic materials, conductive polymers, block copolymers having conjugated parts and non-conjugated parts together, and the like, but are not limited thereto.

In one embodiment of the present specification, the hole transfer layer includes a compound of the following Chemical Formula HT-1:

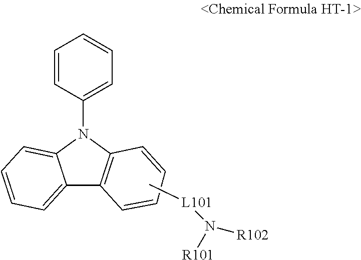

wherein in Chemical Formula HT-1:
L101 is a direct bond or a substituted or unsubstituted arylene group; and
R101 and R102 are the same as or different from each other, and each independently is hydrogen, deuterium, a substituted or unsubstituted alkyl group; a substituted or unsubstituted amine group; a substituted or unsubstituted aryl group, or a substituted or unsubstituted heterocyclic group.

In one embodiment of the present specification, L101 is a substituted or unsubstituted phenylene group or a substituted or unsubstituted naphthylene group.

In one embodiment of the present specification, L101 is a substituted or unsubstituted phenylene group.

In one embodiment of the present specification, L101 is a phenylene group.

In one embodiment of the present specification, R101 and R102 are the same as or different from each other, and each independently is a substituted or unsubstituted aryl group.

In one embodiment of the present specification, R101 and R102 are the same as or different from each other, and each independently is a substituted or unsubstituted monocyclic aryl group or a substituted or unsubstituted polycyclic aryl group.

In one embodiment of the present specification, R101 and R102 are the same as or different from each other, and each independently is a substituted or unsubstituted phenyl group, a substituted or unsubstituted biphenyl group, a substituted or unsubstituted terphenyl group, a substituted or unsubstituted naphthyl group, a substituted or unsubstituted anthracenyl group, a substituted or unsubstituted phenanthrene group, a substituted or unsubstituted triphenylene group, a substituted or unsubstituted pyrene group, or a substituted or unsubstituted fluorenyl group.

In one embodiment of the present specification, R101 and R102 are the same as or different from each other, and each independently is a substituted or unsubstituted biphenyl group or a substituted or unsubstituted fluorenyl group.

In one embodiment of the present specification, R101 and R102 are the same as or different from each other, and each independently is a biphenyl group or a fluorenyl group substituted with an alkyl group.

In one embodiment of the present specification, Chemical Formula HT-1 is the following compound:

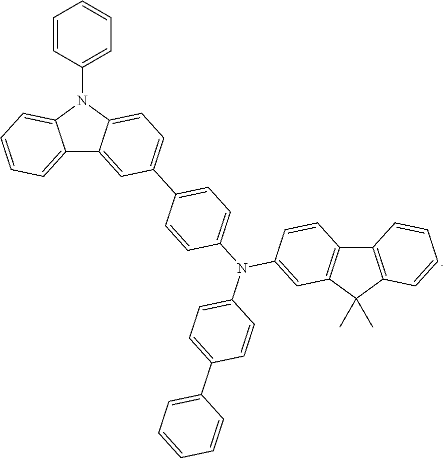 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21]

A hole control layer can be provided between the hole transfer layer and the light emitting layer. Materials known in the art can be used as the hole control layer.

According to one embodiment of the present specification, the hole control layer includes a compound of the following Chemical Formula EB-1, but is not limited thereto:

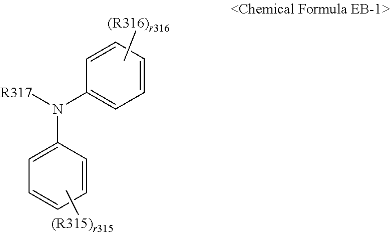

wherein in Chemical Formula EB-1:
R315 to R317 are the same as or different from each other, and each independently is any one selected from the group consisting of hydrogen, deuterium, a substituted or unsubstituted alkyl group; a substituted or unsubstituted aryl group, a substituted or unsubstituted heteroaryl group, and combinations thereof, or bond to adjacent groups to form a substituted or unsubstituted ring;
r315 is an integer of 1 to 5, and when r315 is 2 or greater, the two or more R315s are the same as or different from each other; and
r316 is an integer of 1 to 5, and when r316 is 2 or greater, the two or more R316s are the same as or different from each other.

According to one embodiment of the present specification, R317 is any one selected from the group consisting of a substituted or unsubstituted aryl group, a substituted or unsubstituted heteroaryl group, and combinations thereof.

According to one embodiment of the present specification, R317 is any one selected from the group consisting of a phenyl group, a biphenyl group, and combinations thereof.

According to one embodiment of the present specification, R315 and R316 are the same as or different from each other, and each independently is a substituted or unsubstituted aryl group.

According to one embodiment of the present specification, R315 and R316 are each independently is a substituted or unsubstituted polycyclic aryl group.

According to one embodiment of the present specification, R315 and R316 are each independently is a substituted or unsubstituted phenanthrenyl group.

According to one embodiment of the present specification, R315 and R316 are a phenanthrenyl group.

According to one embodiment of the present specification, Chemical Formula EB-1 is the following compound:

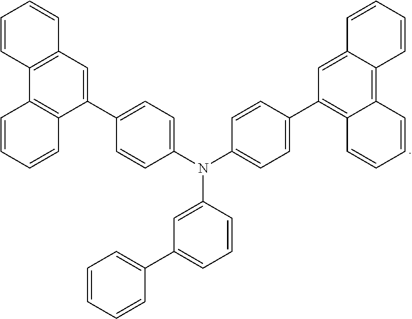 [SMILES: c1ccc(-c2cccc(N(c3ccc(-c4cc5ccccc5c5ccccc45)cc3)c3ccc(-c4cc5ccccc5c5ccccc45)cc3)c2)cc1]

An electron control layer can be provided between the electron transfer layer and the light emitting layer. The electron control layer is a layer blocking holes from reaching a cathode, and can be generally formed under the same condition as the hole injection layer. For example, materials used in the electron control layer can include oxadiazole derivatives, triazole derivatives, triazine derivatives, phenanthroline derivatives, BCP, aluminum complexes and the like, but are not limited thereto. Specifically, triazine derivatives can be used, however, the electron control layer is not limited thereto.

In one embodiment of the present specification, the electron control layer includes a compound of the following Chemical Formula HB-1:

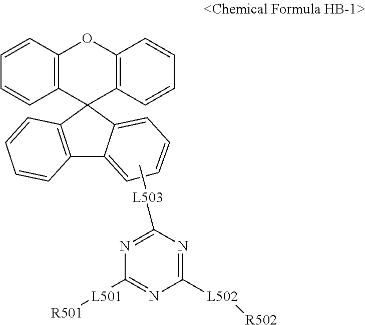

wherein in Chemical Formula HB-1:
L501 to L503 are the same as or different from each other, and each independently is a direct bond or a substituted or unsubstituted arylene group;
R501 and R502 are the same as or different from each other, and each independently is hydrogen, deuterium, a substituted or unsubstituted alkyl group, a substituted or unsubstituted amine group, a substituted or unsubstituted aryl group, or a substituted or unsubstituted heterocyclic group.

In one embodiment of the present specification, L501 to L503 are the same as or different from each other, and each independently is a direct bond, a substituted or unsubstituted phenylene group, or a substituted or unsubstituted naphthylene group.

In one embodiment of the present specification, L501 to L503 are the same as or different from each other, and each independently is a direct bond or a substituted or unsubstituted phenylene group.

In one embodiment of the present specification, L501 to L503 are the same as or different from each other, and each independently is a direct bond or a phenylene group.

In one embodiment of the present specification, R501 and R502 are the same as or different from each other, and each independently is a substituted or unsubstituted aryl group.

In one embodiment of the present specification, R501 and R502 are the same as or different from each other, and each independently is a substituted or unsubstituted monocyclic aryl group or a substituted or unsubstituted polycyclic aryl group.

In one embodiment of the present specification, R501 and R502 are the same as or different from each other, and each independently is a substituted or unsubstituted phenyl group, a substituted or unsubstituted biphenyl group, a substituted or unsubstituted terphenyl group, a substituted or unsubstituted naphthyl group, a substituted or unsubstituted anthracenyl group, a substituted or unsubstituted phenanthrene group, a substituted or unsubstituted triphenylene group, a substituted or unsubstituted pyrene group, or a substituted or unsubstituted fluorenyl group.

In one embodiment of the present specification, R501 and R502 are the same as or different from each other, and each independently is a substituted or unsubstituted phenyl group or a substituted or unsubstituted naphthyl group.

In one embodiment of the present specification, R501 and R502 are the same as or different from each other, and each independently is a phenyl group or a naphthyl group.

In one embodiment of the present specification, Chemical Formula HB-1 is the following compound:

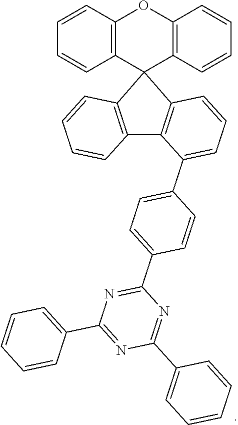 [SMILES: c1ccc(-c2nc(-c3ccccc3)nc(-c3ccc(-c4cccc5c4-c4ccccc4C54c5ccccc5Oc5ccccc54)cc3)n2)cc1]

The light emitting layer can emit red, green or blue light, and can be formed with a phosphorescence material or a fluorescence material. The light emitting material is a material capable of emitting light in a visible region by receiving holes and electrons from a hole transfer layer and an electron transfer layer, respectively, and binding the holes and the electrons, and is preferably a material having favorable quantum efficiency for fluorescence or phosphorescence.

In addition to the two types of hosts of the composition described above, a host material of the light emitting layer includes fused aromatic ring derivatives, heteroring-containing compounds or the like. Specifically, the fused aromatic ring derivative includes anthracene derivatives, pyrene derivatives, naphthalene derivatives, pentacene derivatives, phenanthrene compounds, fluoranthene compounds and the like, and the heteroring-containing compound includes carbazole derivatives, dibenzofuran derivatives, ladder-type furan compounds, pyrimidine derivatives and the like, however, the host material is not limited thereto.

When the light emitting layer emits red light, phosphorescence materials such as bis(1-phenylisoquinoline) acetylacetonate iridium (PIQIr(acac)), bis(1-phenylquinoline) acetylacetonate iridium (PQIr(acac)), tris(1-phenylquinoline) iridium (PQIr) or octaethylporphyrin platinum (PtOEP), or fluorescence materials such as tris(8-hydroxyquinolino)aluminum (Alq₃) can be used as the light emitting dopant, however, the light emitting dopant is not limited thereto. When the light emitting layer emits green light, phosphorescence materials such as fac tris(2-phenylpyridine) iridium (Ir(ppy)₃), or fluorescence materials such as tris(8-hydroxyquinolino)aluminum (Alq₃), anthracene-based compounds, pyrene-based compounds or boron-based compounds can be used as the light emitting dopant, however, the light emitting dopant is not limited thereto. When the light emitting layer emits blue light, phosphorescence materials such as (4,6-F₂ppy)₂Irpic, or fluorescence materials such as spiro-DPVBi, spiro-6P, distyrylbenzene (DSB), distyrylarylene (DSA), PFO-based polymers, PPV-based polymers, anthracene-based compounds, pyrene-based compounds or boron-based compounds can be used as the light emitting dopant, however, the light emitting dopant is not limited thereto.

According to one embodiment of the present specification, the dopant includes a compound of the following Chemical Formula D-1, but is not limited thereto:

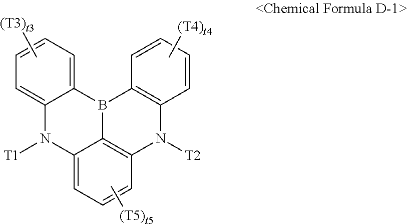

wherein in Chemical Formula D-1:
T1 to T5 are the same as or different from each other, and each independently is hydrogen, a substituted or unsubstituted alkyl group, a substituted or unsubstituted amine group, or a substituted or unsubstituted aryl group;
t3 and t4 are each an integer of 1 to 4;
t5 is an integer of 1 to 3;
when t3 is 2 or greater, the two or more T3s are the same as or different from each other;
when t4 is 2 or greater, the two or more T4s are the same as or different from each other; and
when t5 is 2 or greater, the two or more T5s are the same as or different from each other.

According to one embodiment of the present specification, T1 to T5 are the same as or different from each other, and each independently is hydrogen, a substituted or unsubstituted linear or branched alkyl group having 1 to 30 carbon atoms, a substituted or unsubstituted monocyclic or polycyclic arylamine group having 6 to 30 carbon atoms, or a substituted or unsubstituted monocyclic or polycyclic aryl group having 6 to 30 carbon atoms.

According to one embodiment of the present specification, T1 to T5 are the same as or different from each other, and each independently is hydrogen, a linear or branched alkyl group having 1 to 30 carbon atoms, a monocyclic or polycyclic arylamine group having 6 to 30 carbon atoms, or a monocyclic or polycyclic aryl group having 6 to 30 carbon atoms that is unsubstituted or substituted with a linear or branched alkyl group having 1 to 30 carbon atoms.

According to one embodiment of the present specification, T1 to T5 are the same as or different from each other, and each independently is hydrogen, a methyl group, a tert-butyl group, or a phenyl group that is unsubstituted or substituted with a tert-butyl group.

According to one embodiment of the present specification, Chemical Formula D-1 is the following compound:

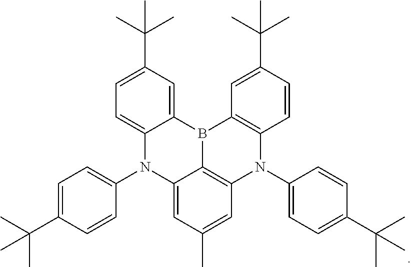 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1]

In one embodiment of the present specification, the dopant includes a compound of the following Chemical Formula D-2:

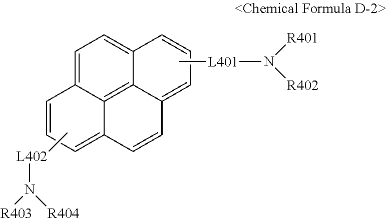

wherein in Chemical Formula D-2:
L401 and L402 are the same as or different from each other, and each independently is a direct bond or a substituted or unsubstituted arylene group; and
R401 to R404 are the same as or different from each other, and each independently is hydrogen, deuterium, a substituted or unsubstituted alkyl group, a substituted or unsubstituted amine group, a substituted or unsubstituted aryl group, or a substituted or unsubstituted heterocyclic group.

In one embodiment of the present specification, L401 and L402 are each a direct bond.

In one embodiment of the present specification, R401 to R404 are the same as or different from each other, and each independently is a substituted or unsubstituted aryl group or a substituted or unsubstituted heterocyclic group.

In one embodiment of the present specification, R401 to R404 are the same as or different from each other, and each independently is a substituted or unsubstituted monocyclic aryl group, a substituted or unsubstituted polycyclic aryl group, or a substituted or unsubstituted heterocyclic group.

In one embodiment of the present specification, R401 to R404 are the same as or different from each other, and each independently is a substituted or unsubstituted phenyl group, a substituted or unsubstituted biphenyl group, a substituted or unsubstituted terphenyl group, a substituted or unsubstituted naphthyl group, a substituted or unsubstituted anthracenyl group, a substituted or unsubstituted phenanthrene group, a substituted or unsubstituted triphenylene group, a substituted or unsubstituted pyrene group, a substituted or unsubstituted fluorenyl group, a substituted or unsubstituted dibenzofuran group, or a substituted or unsubstituted dibenzothiophene group.

In one embodiment of the present specification, R401 to R404 are the same as or different from each other, and each independently is a substituted or unsubstituted phenyl group or a substituted or unsubstituted dibenzofuran group.

In one embodiment of the present specification, R401 to R404 are the same as or different from each other, and each independently is a phenyl group that is unsubstituted or substituted with an alkyl group; or a dibenzofuran group that is unsubstituted or substituted with an alkyl group.

In one embodiment of the present specification, Chemical Formula D-2 is the following compound:

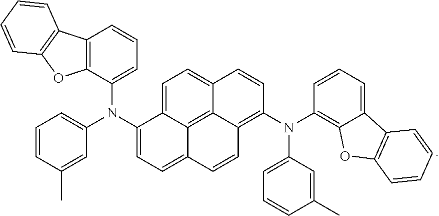 [SMILES: Cc1cccc(N(c2ccc3ccc4c(N(c5cccc(C)c5)c5cccc6c5oc5ccccc56)ccc5ccc2c3c54)c2cccc3c2oc2ccccc23)c1]

The electron transfer layer can perform a role of smoothly transferring electrons. As the electron transfer material, materials capable of favorably receiving electrons from a cathode, moving the electrons to a light emitting layer, and having high mobility for the electrons are suited. Specific examples thereof include Al complexes of 8-hydroxyquinoline; complexes including Alq₃; organic radical compounds; hydroxyflavon-metal complexes, and the like, but are not limited thereto.

The electron injection layer can perform a role of smoothly injecting electrons. As the electron injection material, compounds having an electron transferring ability, having an electron injection effect from a cathode, having an excellent electron injection effect for a light emitting layer or light emitting material, preventing excitons generated in the light emitting layer from migrating to a hole injection layer, and in addition thereto, having an excellent thin film forming ability are preferred. Specific examples thereof can include fluorenone, anthraquinodimethane, diphenoquinone, thiopyran dioxide, oxazole, oxadiazole, triazole, imidazole, perylene tetracarboxylic acid, fluorenylidene methane, anthrone or the like, and derivatives thereof, metal complex compounds, nitrogen-containing 5-membered ring derivatives, and the like, but are not limited thereto.

The metal complex compound includes 8-hydroxyquinolinato lithium, bis(8-hydroxyquinolinato) zinc, bis(8-hydroxyquinolinato) copper, bis(8-hydroxyquinolinato) manganese, tris(8-hydroxyquinolinato)aluminum, tris(2-methyl-8-hydroxyquinolinato)aluminum, tris(8-hydroxyquinolinato) gallium, bis(10-hydroxybenzo[h]quinolinato) beryllium, bis(10-hydroxybenzo[h]quinolinato) zinc, bis(2-methyl-8-quinolinato)-chlorogallium, bis(2-methyl-8-quinolinato) (o-cresolato)-gallium, bis(2-methyl-8-quinolinato) (1-naphtholato)aluminum, bis(2-methyl-8-quinolinato) (2-naphtholato) gallium and the like, but is not limited thereto.

The organic electroluminescent device according to the present disclosure can be a top-emission type, a bottom-emission type or a dual-emission type depending on the materials used.

### EXAMPLES

Hereinafter, the present specification will be described in more detail through examples. However, the following examples are for illustrative purposes only, and not for limiting the present specification.

### Preparation Example

### Preparation Example 1. Synthesis of Chemical Formula 1

A reaction material (1 eq.) and trifluoromethanesulfonic acid (cat.) were introduced to C₆D₆ (mass ratio 10 to 50 times with respect to reaction material), and the mixture was stirred for 10 minutes to 100 minutes at 70° C. After the reaction was finished, D₂O (excess) was introduced thereto, the result was stirred for 30 minutes, and trimethylamine (excess) was added dropwise thereto. The reaction solution was transferred to a separatory funnel, and extracted with water and chloroform. The extract was dried with MgSO₄, heated with toluene, and recrystallized to obtain products of the following Table 1.

TABLE 1

| | | | | Theo- | | Experi- | | | | |
|---|---|---|---|---|---|---|---|---|---|---|
| | | | | retical | Reac- | mental | H | D | D | Synthe- |
| | | | m/z of | max m/z | tion | max m/z | total | Sub- | Sub- | sized |
| Deuterated | Reaction | | Reaction | of | time | of | Num- | stitution | stitution | Yield |
| Compound | Material | Product | Material | Product | (min) | Product | ber | Number | Rate (%) | (%) |
| Compound 1-A | 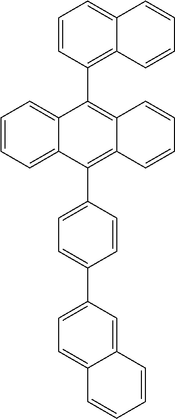 [SMILES: c1ccc2cc(-c3ccc(-c4c5ccccc5c(-c5cccc6ccccc56)c5ccccc45)cc3)ccc2c1] Compound A | 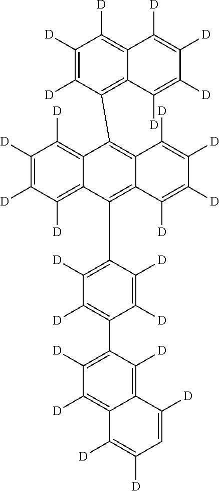 [SMILES: [2H]c1cc([2H])c2c([2H])c(-c3c([2H])c([2H])c(-c4c5c([2H])c([2H])c([2H])c([2H])c5c(-c5c([2H])c([2H])c([2H])c6c([2H])c([2H])c([2H])c([2H])c56)c5c([2H])c([2H])c([2H])c([2H])c45)c([2H])c3[2H])c([2H])c([2H])c2c1[2H]] | 506 | 531 | 50 | 530 | 25 | 24 | 96% | 70% |
| Compound 1-B | 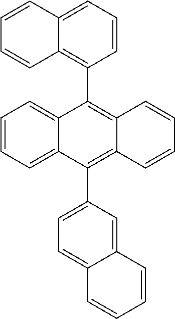 [SMILES: c1ccc2cc(-c3c4ccccc4c(-c4cccc5ccccc45)c4ccccc34)ccc2c1] Compound B | 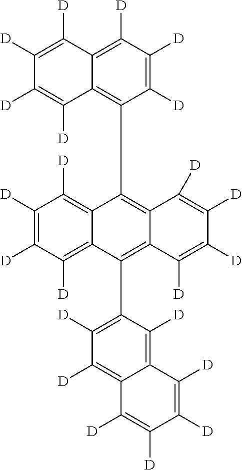 [SMILES: [2H]c1c([2H])c([2H])c2c([2H])c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c2c1[2H]] | 430 | 452 | 50 | 452 | 22 | 22 | 100% | 73% |
| Compound 1-C | 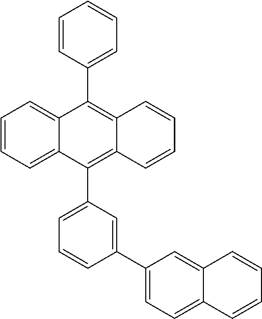 [SMILES: c1ccc(-c2c3ccccc3c(-c3cccc(-c4ccc5ccccc5c4)c3)c3ccccc23)cc1] Compound C | 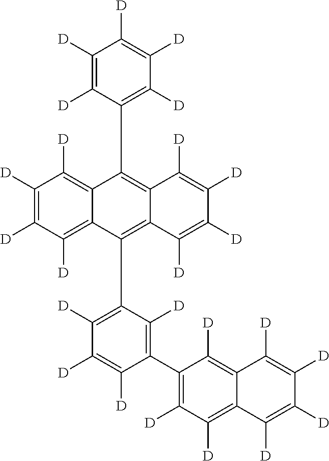 [SMILES: [2H]c1c([2H])c([2H])c(-c2c3c([2H])c([2H])c([2H])c([2H])c3c(-c3c([2H])c([2H])c([2H])c(-c4c([2H])c([2H])c5c([2H])c([2H])c([2H])c([2H])c5c4[2H])c3[2H])c3c([2H])c([2H])c([2H])c([2H])c23)c([2H])c1[2H]] | 456 | 480 | 45 | 473 | 24 | 17 | 71% | 74% |
| Compound 1-D | 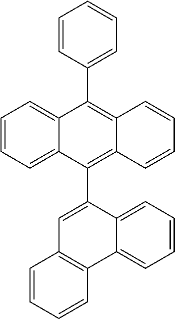 [SMILES: c1ccc(-c2c3ccccc3c(-c3cc4ccccc4c4ccccc34)c3ccccc23)cc1] Compound D | 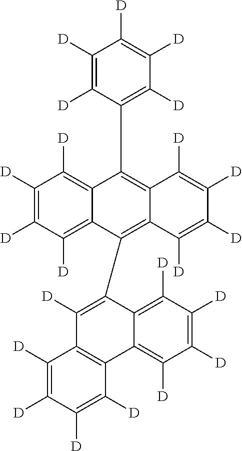 [SMILES: [2H]c1c([2H])c([2H])c(-c2c3c([2H])c([2H])c([2H])c([2H])c3c(-c3c([2H])c4c([2H])c([2H])c([2H])c([2H])c4c4c([2H])c([2H])c([2H])c([2H])c34)c3c([2H])c([2H])c([2H])c([2H])c23)c([2H])c1[2H]] | 430 | 452 | 30 | 443 | 22 | 13 | 59% | 69% |
| Compound 1-E | 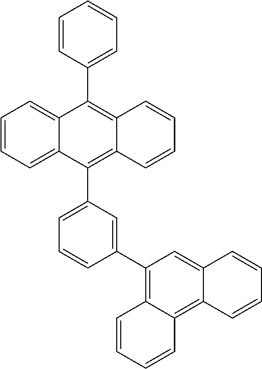 [SMILES: c1ccc(-c2c3ccccc3c(-c3cccc(-c4cc5ccccc5c5ccccc45)c3)c3ccccc23)cc1] Compound E | 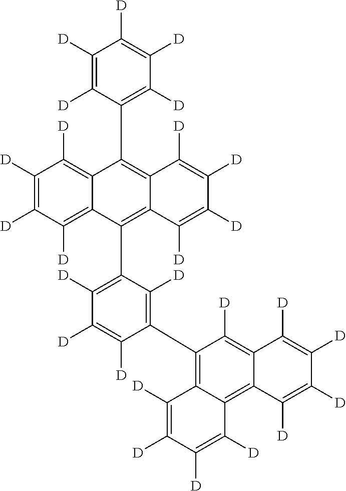 [SMILES: [2H]c1c([2H])c([2H])c(-c2c3c([2H])c([2H])c([2H])c([2H])c3c(-c3c([2H])c([2H])c([2H])c(-c4c([2H])c5c([2H])c([2H])c([2H])c([2H])c5c5c([2H])c([2H])c([2H])c([2H])c45)c3[2H])c3c([2H])c([2H])c([2H])c([2H])c23)c([2H])c1[2H]] | 506 | 532 | 40 | 522 | 26 | 16 | 62% | 65% |
| Compound 1-F | 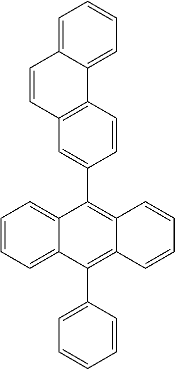 [SMILES: c1ccc(-c2c3ccccc3c(-c3ccc4c(ccc5ccccc54)c3)c3ccccc23)cc1] Compound F | 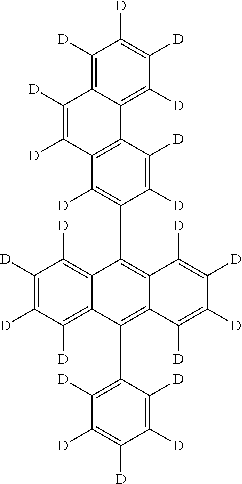 [SMILES: [2H]c1c([2H])c([2H])c(-c2c3c([2H])c([2H])c([2H])c([2H])c3c(-c3c([2H])c([2H])c4c(c3[2H])c([2H])c([2H])c3c([2H])c([2H])c([2H])c([2H])c34)c3c([2H])c([2H])c([2H])c([2H])c23)c([2H])c1[2H]] | 430 | 452 | 40 | 448 | 22 | 18 | 82% | 70% |
| Compound 1-G | 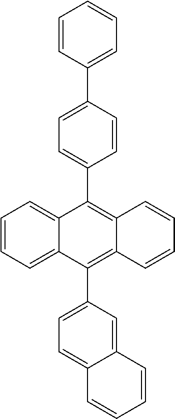 [SMILES: c1ccc(-c2ccc(-c3c4ccccc4c(-c4ccc5ccccc5c4)c4ccccc34)cc2)cc1] Compound G | 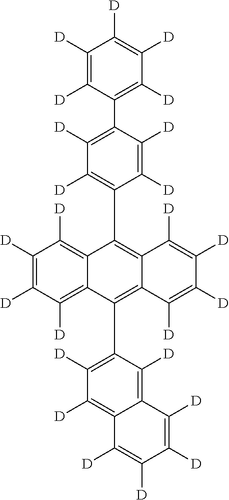 [SMILES: [2H]c1c([2H])c([2H])c(-c2c([2H])c([2H])c(-c3c4c([2H])c([2H])c([2H])c([2H])c4c(-c4c([2H])c([2H])c5c([2H])c([2H])c([2H])c([2H])c5c4[2H])c4c([2H])c([2H])c([2H])c([2H])c34)c([2H])c2[2H])c([2H])c1[2H]] | 456 | 480 | 50 | 478 | 24 | 22 | 92% | 73% |
| Compound 1-H | 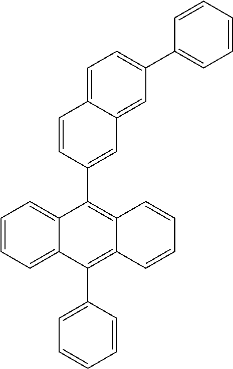 [SMILES: c1ccc(-c2ccc3ccc(-c4c5ccccc5c(-c5ccccc5)c5ccccc45)cc3c2)cc1] Compound H | 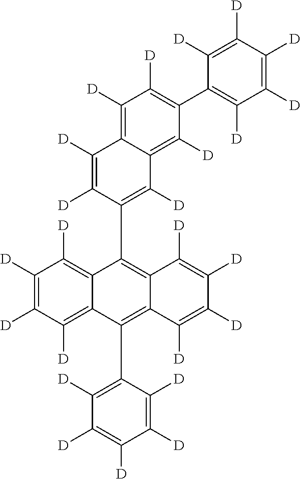 [SMILES: [2H]c1c([2H])c([2H])c(-c2c([2H])c([2H])c3c([2H])c([2H])c(-c4c5c([2H])c([2H])c([2H])c([2H])c5c(-c5c([2H])c([2H])c([2H])c([2H])c5[2H])c5c([2H])c([2H])c([2H])c([2H])c45)c([2H])c3c2[2H])c([2H])c1[2H]] | 456 | 480 | 25 | 468 | 24 | 12 | 50% | 71% |
| Compound 1-I | 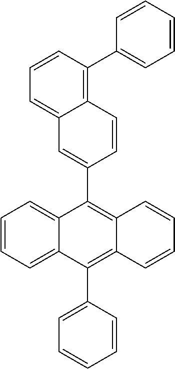 [SMILES: c1ccc(-c2cccc3cc(-c4c5ccccc5c(-c5ccccc5)c5ccccc45)ccc23)cc1] Compound I | 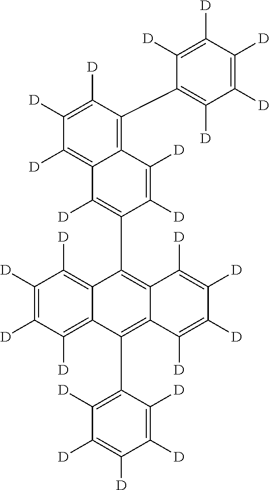 [SMILES: [2H]c1c([2H])c([2H])c(-c2c([2H])c([2H])c([2H])c3c([2H])c(-c4c5c([2H])c([2H])c([2H])c([2H])c5c(-c5c([2H])c([2H])c([2H])c([2H])c5[2H])c5c([2H])c([2H])c([2H])c([2H])c45)c([2H])c([2H])c23)c([2H])c1[2H]] | 456 | 480 | 40 | 477 | 24 | 21 | 88% | 68% |
| Compound 1-J | 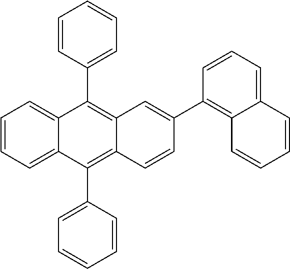 [SMILES: c1ccc(-c2c3ccccc3c(-c3ccccc3)c3cc(-c4cccc5ccccc45)ccc23)cc1] Compound J | 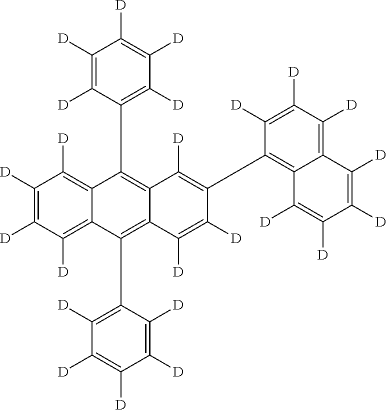 [SMILES: [2H]c1c([2H])c([2H])c(-c2c3c([2H])c([2H])c([2H])c([2H])c3c(-c3c([2H])c([2H])c([2H])c([2H])c3[2H])c3c([2H])c(-c4c([2H])c([2H])c([2H])c5c([2H])c([2H])c([2H])c([2H])c45)c([2H])c([2H])c23)c([2H])c1[2H]] | 456 | 480 | 50 | 477 | 24 | 21 | 88% | 65% |
| Compound 1-K | 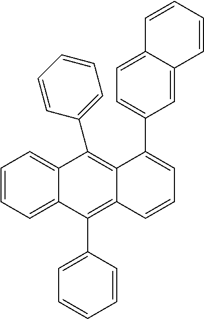 [SMILES: c1ccc(-c2c3ccccc3c(-c3ccccc3)c3c(-c4ccc5ccccc5c4)cccc23)cc1] Compound K | 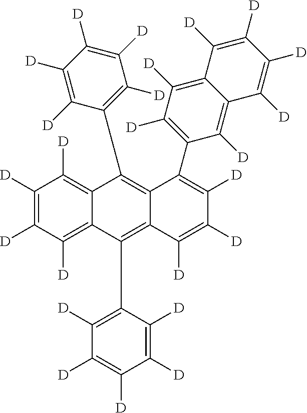 [SMILES: [2H]c1c([2H])c([2H])c(Cc2c3c([2H])c([2H])c([2H])c([2H])c3c(-c3c([2H])c([2H])c([2H])c([2H])c3[2H])c3c([2H])c([2H])c([2H])c(-c4c([2H])c([2H])c5c([2H])c([2H])c([2H])c([2H])c5c4[2H])c23)c([2H])c1[2H]] | 456 | 480 | 50 | 476 | 24 | 20 | 83% | 70% |
| Compound 1-L | 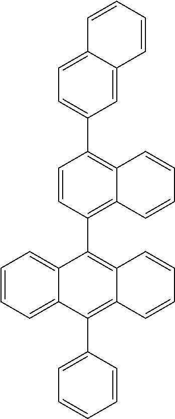 [SMILES: c1ccc(-c2c3ccccc3c(-c3ccc(-c4ccc5ccccc5c4)c4ccccc34)c3ccccc23)cc1] Compound L | 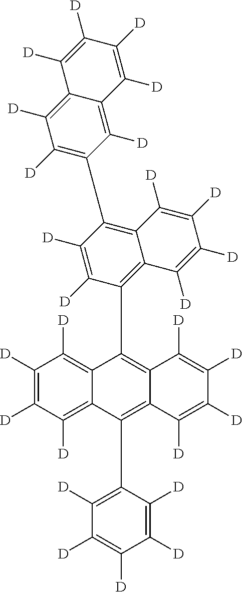 [SMILES: [2H]c1c([2H])c([2H])c(-c2c3c([2H])c([2H])c([2H])c([2H])c3c(-c3c([2H])c([2H])c(-c4c([2H])c([2H])c5c([2H])c([2H])c([2H])c([2H])c5c4[2H])c4c([2H])c([2H])c([2H])c([2H])c34)c3c([2H])c([2H])c([2H])c([2H])c23)c([2H])c1[2H]] | 506 | 532 | 50 | 529 | 26 | 23 | 88% | 66% |
| Compound 1-M | 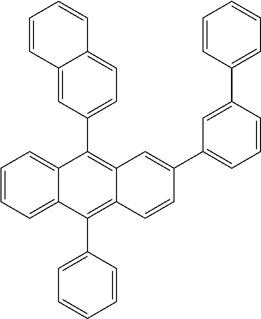 [SMILES: c1ccc(-c2cccc(-c3ccc4c(-c5ccccc5)c5ccccc5c(-c5ccc6ccccc6c5)c4c3)c2)cc1] Compound M | 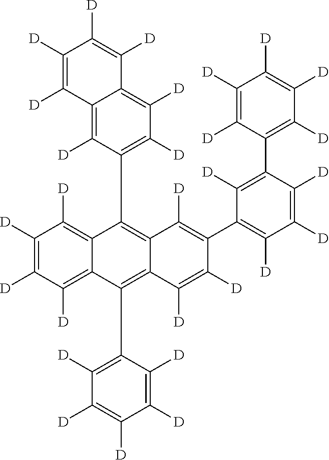 [SMILES: [2H]c1c([2H])c([2H])c(-c2c([2H])c([2H])c([2H])c(-c3c([2H])c([2H])c4c(-c5c([2H])c([2H])c([2H])c([2H])c5[2H])c5c([2H])c([2H])c([2H])c([2H])c5c(-c5c([2H])c([2H])c6c([2H])c([2H])c([2H])c([2H])c6c5[2H])c4c3[2H])c2[2H])c([2H])c1[2H]] | 532 | 560 | 30 | 551 | 28 | 19 | 68% | 72% |
| Compound 1-O | 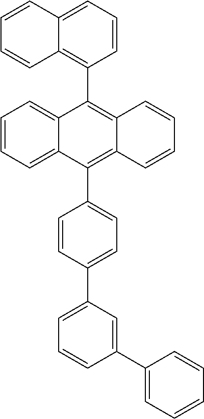 [SMILES: c1ccc(-c2cccc(-c3ccc(-c4c5ccccc5c(-c5cccc6ccccc56)c5ccccc45)cc3)c2)cc1] Compound O | 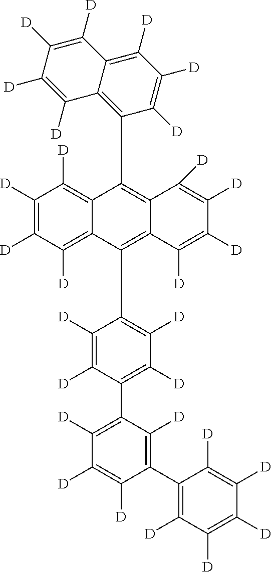 [SMILES: [2H]c1c([2H])c([2H])c(-c2c([2H])c([2H])c([2H])c(-c3c([2H])c([2H])c(-c4c5c([2H])c([2H])c([2H])c([2H])c5c(-c5c([2H])c([2H])c([2H])c6c([2H])c([2H])c([2H])c([2H])c56)c5c([2H])c([2H])c([2H])c([2H])c45)c([2H])c3[2H])c2[2H])c([2H])c1[2H]] | 532 | 560 | 40 | 556 | 28 | 24 | 86% | 71% |
| Compound 1-P | 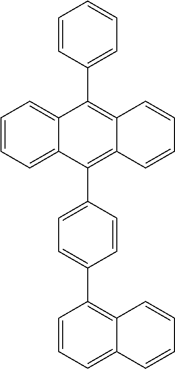 [SMILES: c1ccc(-c2c3ccccc3c(-c3ccc(-c4cccc5ccccc45)cc3)c3ccccc23)cc1] Compound P | 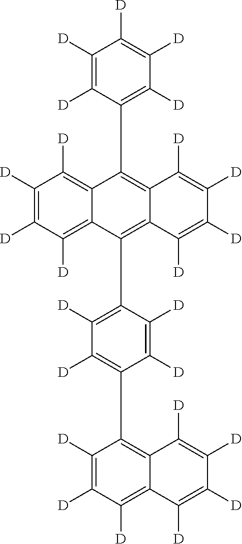 [SMILES: [2H]c1c([2H])c([2H])c(-c2c3c([2H])c([2H])c([2H])c([2H])c3c(-c3c([2H])c([2H])c(-c4c([2H])c([2H])c([2H])c5c([2H])c([2H])c([2H])c([2H])c45)c([2H])c3[2H])c3c([2H])c([2H])c([2H])c([2H])c23)c([2H])c1[2H]] | 456 | 480 | 60 | 480 | 24 | 24 | 100% | 73% |
| Compound 1-Q | 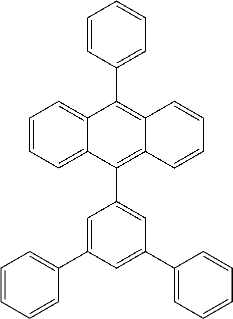 [SMILES: c1ccc(-c2cc(-c3ccccc3)cc(-c3c4ccccc4c(-c4ccccc4)c4ccccc34)c2)cc1] Compound Q | 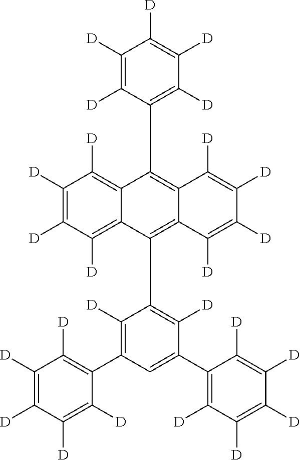 [SMILES: [2H]c1c([2H])c([2H])c(-c2cc(-c3c([2H])c([2H])c([2H])c([2H])c3[2H])c([2H])c(-c3c4c([2H])c([2H])c([2H])c([2H])c4c(-c4c([2H])c([2H])c([2H])c([2H])c4[2H])c4c([2H])c([2H])c([2H])c([2H])c34)c2[2H])c([2H])c1[2H]] | 482 | 507 | 35 | 500 | 25 | 18 | 72% | 65% |
| Compound 1-R | 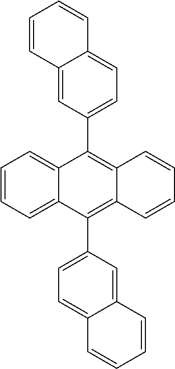 [SMILES: c1ccc2cc(-c3c4ccccc4c(-c4ccc5ccccc5c4)c4ccccc34)ccc2c1] Compound R | 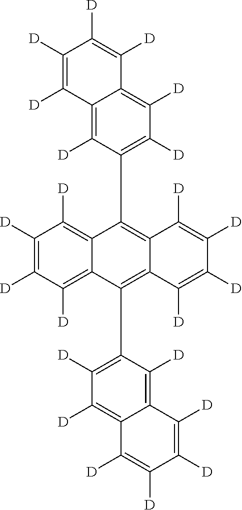 [SMILES: [2H]c1c([2H])c([2H])c2c([2H])c(-c3c4c([2H])c([2H])c([2H])c([2H])c4c(-c4c([2H])c([2H])c5c([2H])c([2H])c([2H])c([2H])c5c4[2H])c4c([2H])c([2H])c([2H])c([2H])c34)c([2H])c([2H])c2c1[2H]] | 430 | 452 | 50 | 447 | 22 | 17 | 77% | 66% |
| Compound 1-S | 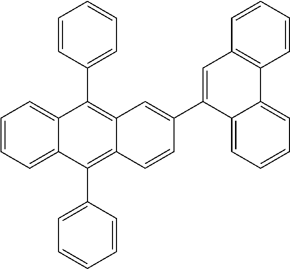 [SMILES: c1ccc(-c2c3ccccc3c(-c3ccccc3)c3cc(-c4cc5ccccc5c5ccccc45)ccc23)cc1] Compound S | 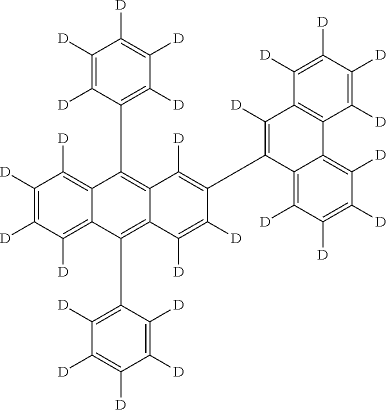 [SMILES: [2H]c1c([2H])c([2H])c(-c2c3c([2H])c([2H])c([2H])c([2H])c3c(-c3c([2H])c([2H])c([2H])c([2H])c3[2H])c3c([2H])c(-c4c([2H])c5c([2H])c([2H])c([2H])c([2H])c5c5c([2H])c([2H])c([2H])c([2H])c45)c([2H])c([2H])c23)c([2H])c1[2H]] | 506 | 532 | 60 | 530 | 26 | 24 | 92% | 71% |
| Compound 1-T | 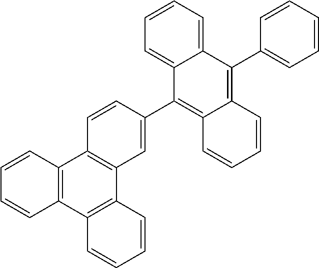 [SMILES: c1ccc(-c2c3ccccc3c(-c3ccc4c5ccccc5c5ccccc5c4c3)c3ccccc23)cc1] Compound T | 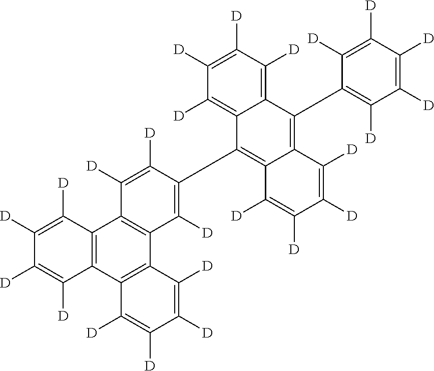 [SMILES: [2H]c1c([2H])c([2H])c(-c2c3c([2H])c([2H])c([2H])c([2H])c3c(-c3c([2H])c([2H])c4c5c([2H])c([2H])c([2H])c([2H])c5c5c([2H])c([2H])c([2H])c([2H])c5c4c3[2H])c3c([2H])c([2H])c([2H])c([2H])c23)c([2H])c1[2H]] | 480 | 503 | 45 | 495 | 23 | 18 | 78% | 70% |
| Compound 1-U | 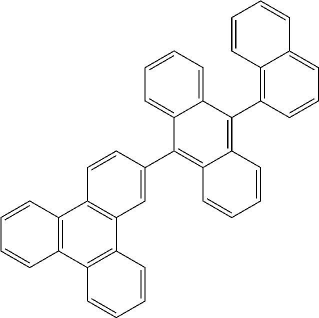 [SMILES: c1ccc2c(-c3c4ccccc4c(-c4ccc5c6ccccc6c6ccccc6c5c4)c4ccccc34)cccc2c1] Compound U | 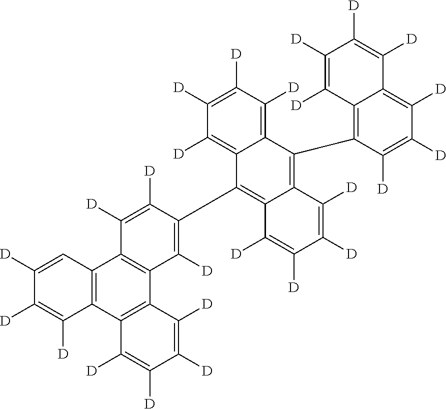 [SMILES: [2H]c1cc2c(c([2H])c1[2H])c1c([2H])c([2H])c([2H])c([2H])c1c1c([2H])c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c21] | 530 | 555 | 45 | 549 | 25 | 19 | 76% | 68% |
| Compound 1-V | 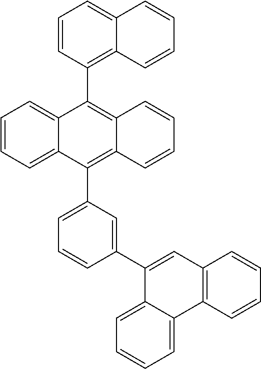 [SMILES: c1cc(-c2c3ccccc3c(-c3cccc4ccccc34)c3ccccc23)cc(-c2cc3ccccc3c3ccccc23)c1] Compound V | 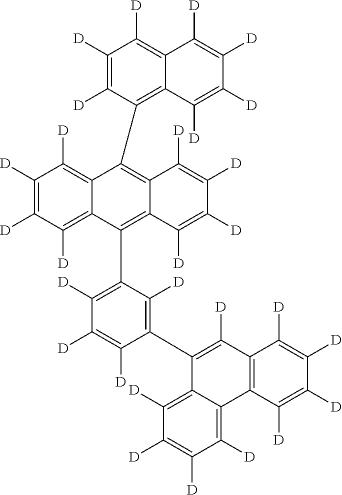 [SMILES: [2H]c1c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c([2H])c(-c2c([2H])c3c([2H])c([2H])c([2H])c([2H])c3c3c([2H])c([2H])c([2H])c([2H])c23)c1[2H]] | 556 | 584 | 50 | 580 | 28 | 24 | 86% | 64% |
| Compound 1-W | 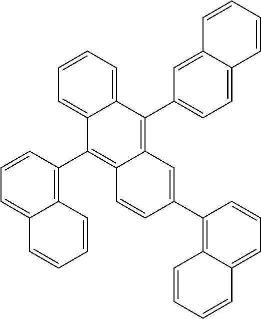 [SMILES: c1ccc2cc(-c3c4ccccc4c(-c4cccc5ccccc45)c4ccc(-c5cccc6ccccc56)cc34)ccc2c1] Compound W | 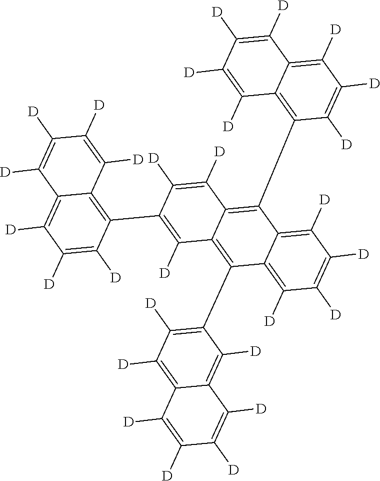 [SMILES: [2H]c1c([2H])c([2H])c2c([2H])c(-c3c4c([2H])c([2H])c([2H])c([2H])c4c(-c4c([2H])c([2H])c([2H])c5c([2H])c([2H])c([2H])c([2H])c45)c4c([2H])c([2H])c(-c5c([2H])c([2H])c([2H])c6c([2H])c([2H])c([2H])c([2H])c56)c([2H])c34)c([2H])c([2H])c2c1[2H]] | 556 | 584 | 60 | 582 | 28 | 26 | 93% | 70% |

Each product had a different degree of deuterium substitution depending on the reaction time, and the substitution rate was determined by the maximum m/z (M+) value. Compound A to Compound W, which are the reaction materials, were synthesized with reference to prior documents such as JP 4070676 B2, KR 10-1477844 B1, U.S. Pat. No. 6,465,115 B2, JP 3148176 B2, JP 4025136 B2, JP 4188082 B2, JP 5015459 B2, KR 10-1979037 B1, KR 10-1550351 B1, KR 10-1503766 B1, KR 10-0826364 B1, KR 10-0749631 B1 and KR 10-1115255 B1. In addition, Compounds 1-A to 1-W, which are the deuterium-substituted products, were synthesized with reference to the prior document KR 10-1538534 B1.

In Table 1, deuterium (-D) bonding to the synthesized products means capable of bonding to the indicated position, and it does not necessarily mean that deuterium is bound to bond to the indicated position.

### Preparation Example 2. Synthesis of Chemical Formula 2

A reaction material (1 eq.) and trifluoromethanesulfonic acid (cat.) were introduced to C₆D₆ (mass ratio 10 to 50 times with respect to reaction material), and the mixture was stirred for 10 minutes to 100 minutes at 70° C. After the reaction was finished, D₂O (excess) was introduced thereto, the result was stirred for 30 minutes, and trimethylamine (excess) was added dropwise thereto. The reaction solution was transferred to a separatory funnel, and extracted with water and chloroform. The extract was dried with MgSO₄, heated with toluene, and recrystallized to obtain products of the following Table 2 and Table 3.

TABLE 2

| | | | m/z of | Theo- | | Experi- | | | D | |
|---|---|---|---|---|---|---|---|---|---|---|
| | | | Re- | retical | Reac- | mental | H | D | Sub- | Synthe- |
| | | | action | max m/z | tion | max m/z | total | Sub- | stitution | sized |
| Deuterated | Reaction | | Ma- | of | time | of | Num- | stitution | Rate | Yield |
| Compound | Material | Product | terial | Product | (min) | Product | ber | Number | (%) | (%) |
| Compound 2-1 | 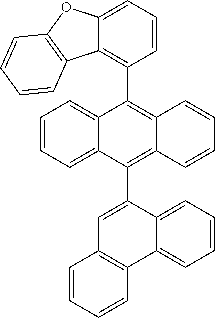 [SMILES: c1ccc2c(c1)cc(-c1c3ccccc3c(-c3cccc4oc5ccccc5c34)c3ccccc13)c1ccccc12] Compound 1 | 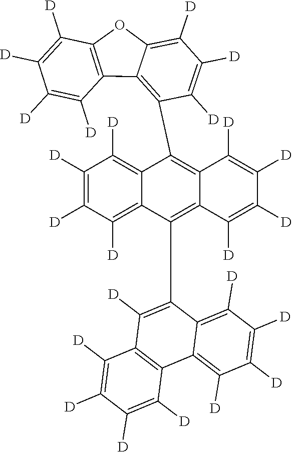 [SMILES: [2H]c1c([2H])c([2H])c2c(oc3c([2H])c([2H])c([2H])c(-c4c5c([2H])c([2H])c([2H])c([2H])c5c(-c5c([2H])c6c([2H])c([2H])c([2H])c([2H])c6c6c([2H])c([2H])c([2H])c([2H])c56)c5c([2H])c([2H])c([2H])c([2H])c45)c32)c1[2H]] | 520 | 544 | 30 | 538 | 24 | 18 | 75% | 70% |
| Compound 2-2 | 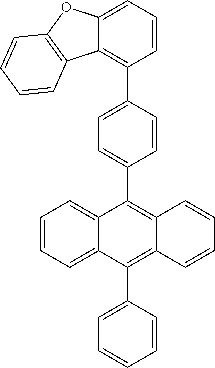 [SMILES: c1ccc(-c2c3ccccc3c(-c3ccc(-c4cccc5oc6ccccc6c45)cc3)c3ccccc23)cc1] Compound 2 | 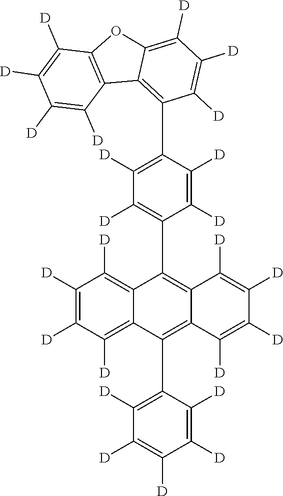 [SMILES: [2H]c1c([2H])c([2H])c(-c2c3c([2H])c([2H])c([2H])c([2H])c3c(-c3c([2H])c([2H])c(-c4c([2H])c([2H])c([2H])c5oc6c([2H])c([2H])c([2H])c([2H])c6c45)c([2H])c3[2H])c3c([2H])c([2H])c([2H])c([2H])c23)c([2H])c1[2H]] | 496 | 520 | 30 | 513 | 24 | 17 | 71% | 73% |
| Compound 2-3 | 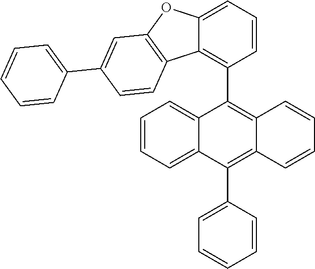 [SMILES: c1ccc(-c2ccc3c(c2)oc2cccc(-c4c5ccccc5c(-c5ccccc5)c5ccccc45)c23)cc1] Compound 3 | 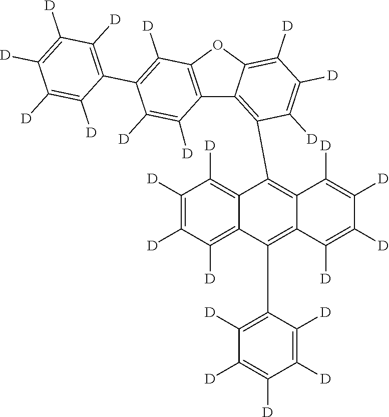 [SMILES: [2H]c1c([2H])c([2H])c(-c2c([2H])c([2H])c3c(oc4c([2H])c([2H])c([2H])c(-c5c6c([2H])c([2H])c([2H])c([2H])c6c(-c6c([2H])c([2H])c([2H])c([2H])c6[2H])c6c([2H])c([2H])c([2H])c([2H])c56)c43)c2[2H])c([2H])c1[2H]] | 496 | 520 | 50 | 520 | 24 | 24 | 100% | 74% |
| Compound 2-4 | 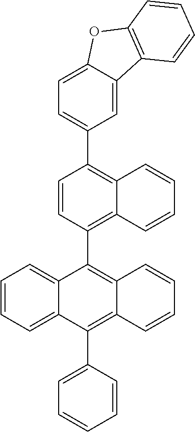 [SMILES: c1ccc(-c2c3ccccc3c(-c3ccc(-c4ccc5oc6ccccc6c5c4)c4ccccc34)c3ccccc23)cc1] Compound 4 | 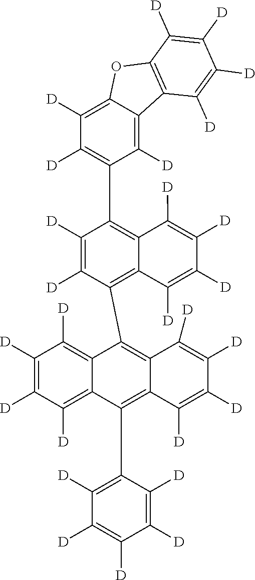 [SMILES: [2H]c1c([2H])c([2H])c(-c2c3c([2H])c([2H])c([2H])c([2H])c3c(-c3c([2H])c([2H])c(-c4c([2H])c([2H])c5oc6c([2H])c([2H])c([2H])c([2H])c6c5c4[2H])c4c([2H])c([2H])c([2H])c([2H])c34)c3c([2H])c([2H])c([2H])c([2H])c23)c([2H])c1[2H]] | 546 | 572 | 15 | 560 | 26 | 14 | 54% | 69% |
| Compound 2-5 | 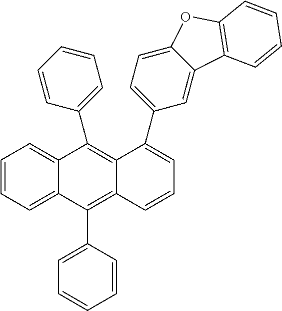 [SMILES: c1ccc(-c2c3ccccc3c(-c3ccccc3)c3c(-c4ccc5oc6ccccc6c5c4)cccc23)cc1] Compound 5 | 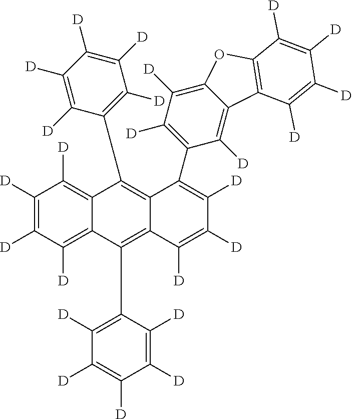 [SMILES: [2H]c1c([2H])c([2H])c(Cc2c3c([2H])c([2H])c([2H])c([2H])c3c(-c3c([2H])c([2H])c([2H])c([2H])c3[2H])c3c([2H])c([2H])c([2H])c(-c4c([2H])c([2H])c5oc6c([2H])c([2H])c([2H])c([2H])c6c5c4[2H])c23)c([2H])c1[2H]] | 496 | 519 | 25 | 510 | 23 | 14 | 61% | 70% |
| Compound 2-6 | 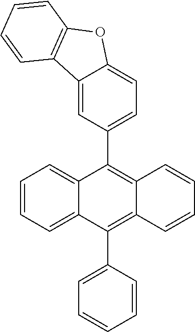 [SMILES: c1ccc(-c2c3ccccc3c(-c3ccc4oc5ccccc5c4c3)c3ccccc23)cc1] Compound 6 | 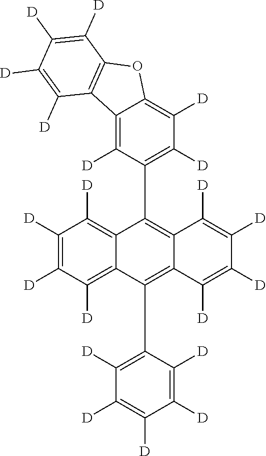 [SMILES: [2H]c1c([2H])c([2H])c(-c2c3c([2H])c([2H])c([2H])c([2H])c3c(-c3c([2H])c([2H])c4oc5c([2H])c([2H])c([2H])c([2H])c5c4c3[2H])c3c([2H])c([2H])c([2H])c([2H])c23)c([2H])c1[2H]] | 420 | 44 | 35 | 438 | 20 | 18 | 90% | 73% |
| Compound 2-7 | 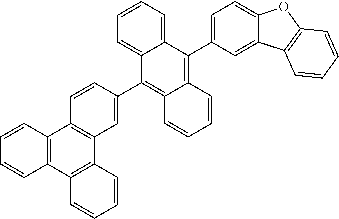 [SMILES: c1ccc2c(c1)oc1ccc(-c3c4ccccc4c(-c4ccc5c6ccccc6c6ccccc6c5c4)c4ccccc34)cc12] Compound 7 | 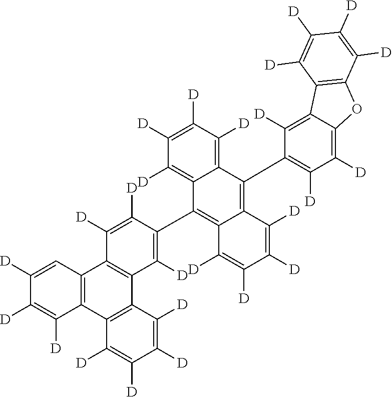 [SMILES: [2H]c1cc2c(c([2H])c1[2H])c1c([2H])c([2H])c([2H])c([2H])c1c1c([2H])c(-c3c4c([2H])c([2H])c([2H])c([2H])c4c(-c4c([2H])c([2H])c5oc6c([2H])c([2H])c([2H])c([2H])c6c5c4[2H])c4c([2H])c([2H])c([2H])c([2H])c34)c([2H])c([2H])c21] | 570 | 595 | 40 | 591 | 25 | 21 | 84% | 71% |
| Compound 2-8 | 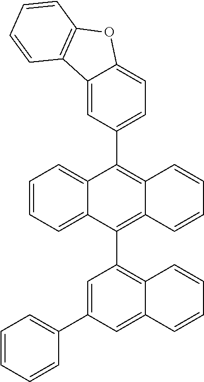 [SMILES: c1ccc(-c2cc(-c3c4ccccc4c(-c4ccc5oc6ccccc6c5c4)c4ccccc34)c3ccccc3c2)cc1] Compound 8 | 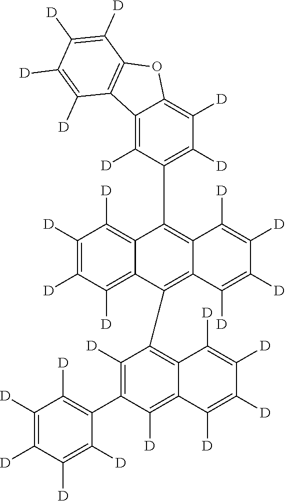 [SMILES: [2H]c1c([2H])c([2H])c(-c2c([2H])c(-c3c4c([2H])c([2H])c([2H])c([2H])c4c(-c4c([2H])c([2H])c5oc6c([2H])c([2H])c([2H])c([2H])c6c5c4[2H])c4c([2H])c([2H])c([2H])c([2H])c34)c3c([2H])c([2H])c([2H])c([2H])c3c2[2H])c([2H])c1[2H]] | 546 | 572 | 10 | 558 | 26 | 12 | 46% | 68% |
| Compound 2-9 | 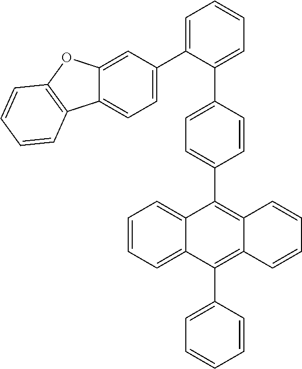 [SMILES: c1ccc(-c2c3ccccc3c(-c3ccc(-c4ccccc4-c4ccc5c(c4)oc4ccccc45)cc3)c3ccccc23)cc1] Compound 9 | 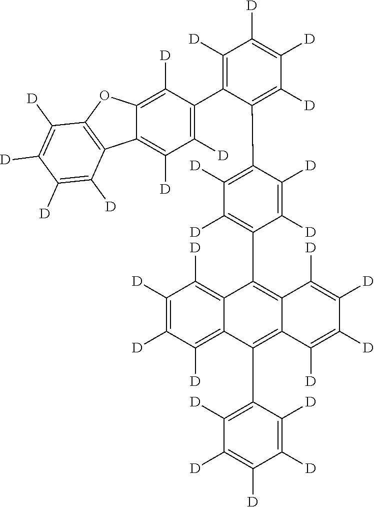 [SMILES: [2H]c1c([2H])c([2H])c(-c2c3c([2H])c([2H])c([2H])c([2H])c3c(-c3c([2H])c([2H])c(-c4c([2H])c([2H])c([2H])c([2H])c4-c4c([2H])c([2H])c5c(oc6c([2H])c([2H])c([2H])c([2H])c65)c4[2H])c([2H])c3[2H])c3c([2H])c([2H])c([2H])c([2H])c23)c([2H])c1[2H]] | 572 | 600 | 60 | 596 | 28 | 24 | 86% | 65% |
| Compound 2-10 | 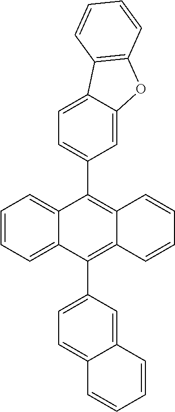 [SMILES: c1ccc2cc(-c3c4ccccc4c(-c4ccc5c(c4)oc4ccccc45)c4ccccc34)ccc2c1] Compound 10 | 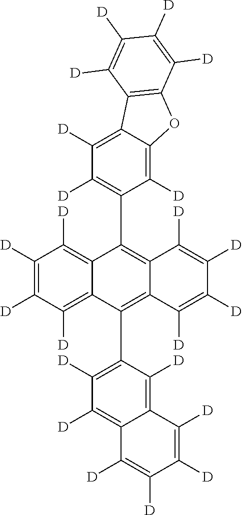 [SMILES: [2H]c1c([2H])c([2H])c2c(oc3c([2H])c(-c4c5c([2H])c([2H])c([2H])c([2H])c5c(-c5c([2H])c([2H])c6c([2H])c([2H])c([2H])c([2H])c6c5[2H])c5c([2H])c([2H])c([2H])c([2H])c45)c([2H])c([2H])c32)c1[2H]] | 470 | 492 | 50 | 492 | 22 | 22 | 100% | 66% |
| Compound 2-11 | 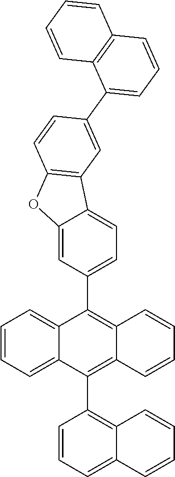 [SMILES: c1ccc2c(-c3ccc4oc5cc(-c6c7ccccc7c(-c7cccc8ccccc78)c7ccccc67)ccc5c4c3)cccc2c1] Compound 11 | 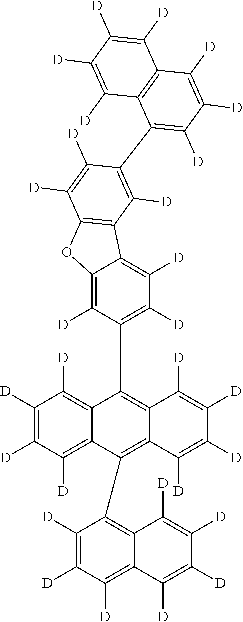 [SMILES: [2H]c1c(-c2c([2H])c([2H])c([2H])c3c([2H])c([2H])c([2H])c([2H])c23)c([2H])c2c(oc3c([2H])c(-c4c5c([2H])c([2H])c([2H])c([2H])c5c(-c5c([2H])c([2H])c([2H])c6c([2H])c([2H])c([2H])c([2H])c56)c5c([2H])c([2H])c([2H])c([2H])c45)c([2H])c([2H])c32)c1[2H]] | 596 | 624 | 55 | 620 | 28 | 24 | 86% | 72% |
| Compound 2-12 | 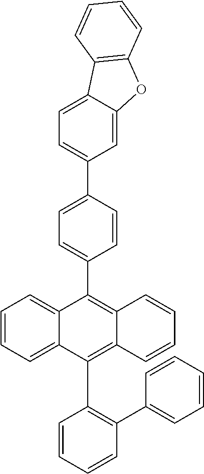 [SMILES: c1ccc(-c2ccccc2-c2c3ccccc3c(-c3ccc(-c4ccc5c(c4)oc4ccccc45)cc3)c3ccccc23)cc1] Compound 12 | 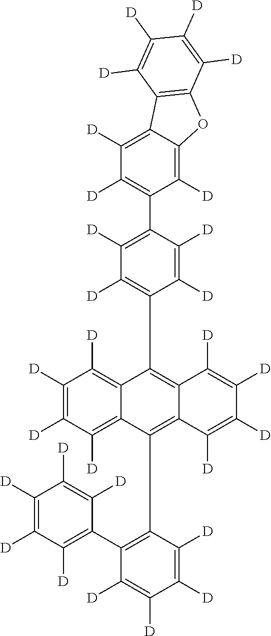 [SMILES: [2H]c1c([2H])c([2H])c(-c2c([2H])c([2H])c([2H])c([2H])c2-c2c3c([2H])c([2H])c([2H])c([2H])c3c(-c3c([2H])c([2H])c(-c4c([2H])c([2H])c5c(oc6c([2H])c([2H])c([2H])c([2H])c65)c4[2H])c([2H])c3[2H])c3c([2H])c([2H])c([2H])c([2H])c23)c([2H])c1[2H]] | 572 | 600 | 40 | 593 | 28 | 21 | 75% | 71% |
| Compound 2-13 | 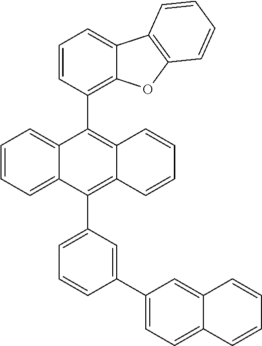 [SMILES: c1cc(-c2ccc3ccccc3c2)cc(-c2c3ccccc3c(-c3cccc4c3oc3ccccc34)c3ccccc23)c1] Compound 13 | 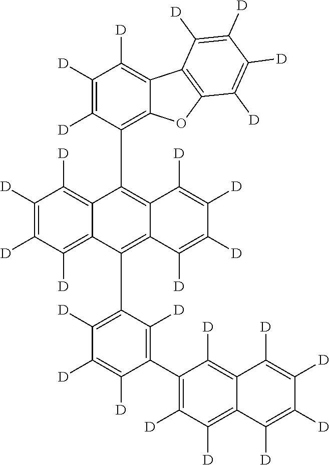 [SMILES: [2H]c1c([2H])c(-c2c([2H])c([2H])c3c([2H])c([2H])c([2H])c([2H])c3c2[2H])c([2H])c(-c2c3c([2H])c([2H])c([2H])c([2H])c3c(-c3c([2H])c([2H])c([2H])c4c3oc3c([2H])c([2H])c([2H])c([2H])c34)c3c([2H])c([2H])c([2H])c([2H])c23)c1[2H]] | 546 | 572 | 75 | 572 | 26 | 26 | 100% | 73% |
| Compound 2-14 | 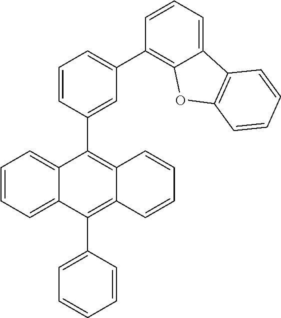 [SMILES: c1ccc(-c2c3ccccc3c(-c3cccc(-c4cccc5c4oc4ccccc45)c3)c3ccccc23)cc1] Compound 14 | 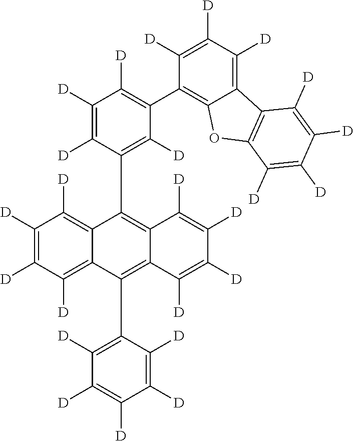 [SMILES: [2H]c1c([2H])c([2H])c(-c2c3c([2H])c([2H])c([2H])c([2H])c3c(-c3c([2H])c([2H])c([2H])c(-c4c([2H])c([2H])c([2H])c5c4oc4c([2H])c([2H])c([2H])c([2H])c45)c3[2H])c3c([2H])c([2H])c([2H])c([2H])c23)c([2H])c1[2H]] | 496 | 520 | 60 | 519 | 24 | 23 | 96% | 65% |
| Compound 2-15 | 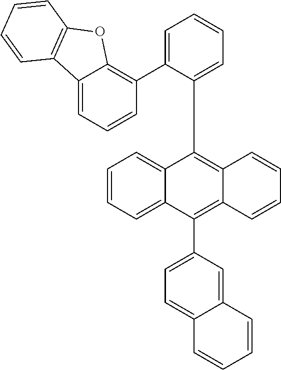 [SMILES: c1ccc(-c2cccc3c2oc2ccccc23)c(-c2c3ccccc3c(-c3ccc4ccccc4c3)c3ccccc23)c1] Compound 15 | 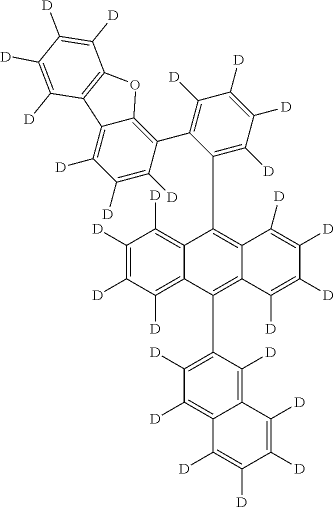 [SMILES: [2H]c1c([2H])c([2H])c(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c(-c2c([2H])c([2H])c([2H])c3c2oc2c([2H])c([2H])c([2H])c([2H])c23)c1[2H]] | 546 | 572 | 60 | 568 | 26 | 22 | 85% | 66% |
| Compound 2-16 | 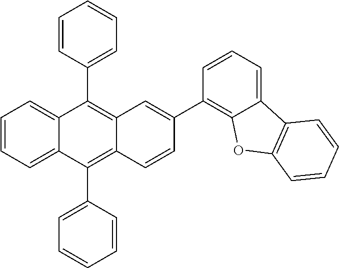 [SMILES: c1ccc(-c2c3ccccc3c(-c3ccccc3)c3cc(-c4cccc5c4oc4ccccc45)ccc23)cc1] Compound 16 | 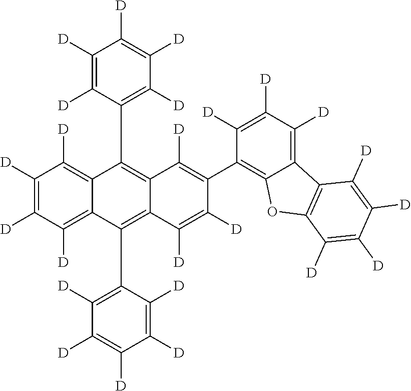 [SMILES: [2H]c1c([2H])c([2H])c(-c2c3c([2H])c([2H])c([2H])c([2H])c3c(-c3c([2H])c([2H])c([2H])c([2H])c3[2H])c3c([2H])c(-c4c([2H])c([2H])c([2H])c5c4oc4c([2H])c([2H])c([2H])c([2H])c45)c([2H])c([2H])c23)c([2H])c1[2H]] | 496 | 520 | 50 | 518 | 24 | 22 | 92% | 70% |
| Compound 2-17 | 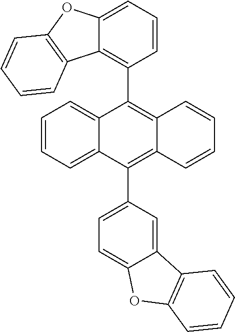 [SMILES: c1ccc2c(c1)oc1ccc(-c3c4ccccc4c(-c4cccc5oc6ccccc6c45)c4ccccc34)cc12] Compound 17 | 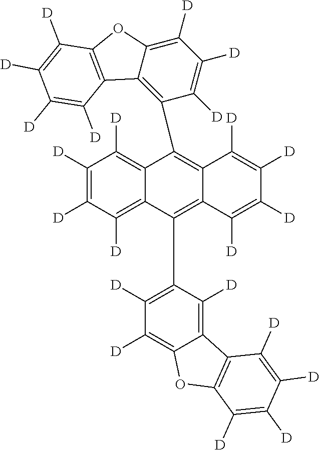 [SMILES: [2H]c1c([2H])c([2H])c2c(oc3c([2H])c([2H])c(-c4c5c([2H])c([2H])c([2H])c([2H])c5c(-c5c([2H])c([2H])c([2H])c6oc7c([2H])c([2H])c([2H])c([2H])c7c56)c5c([2H])c([2H])c([2H])c([2H])c45)c([2H])c32)c1[2H]] | 510 | 532 | 20 | 525 | 22 | 15 | 68% | 68% |
| Compound 2-18 | 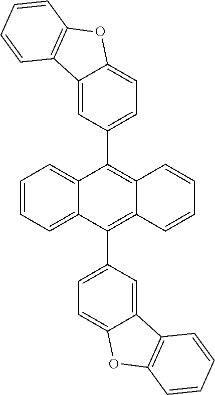 [SMILES: c1ccc2c(c1)oc1ccc(-c3c4ccccc4c(-c4ccc5oc6ccccc6c5c4)c4ccccc34)cc12] Compound 18 | 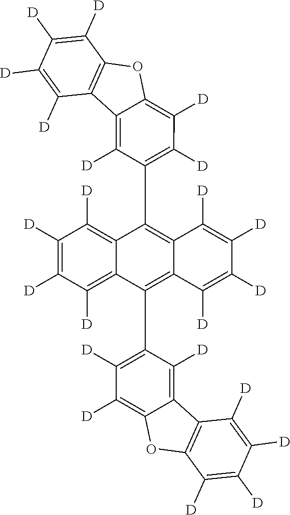 [SMILES: [2H]c1c([2H])c([2H])c2c(oc3c([2H])c([2H])c(-c4c5c([2H])c([2H])c([2H])c([2H])c5c(-c5c([2H])c([2H])c6oc7c([2H])c([2H])c([2H])c([2H])c7c6c5[2H])c5c([2H])c([2H])c([2H])c([2H])c45)c([2H])c32)c1[2H]] | 510 | 532 | 30 | 528 | 22 | 18 | 82% | 64% |
| Compound 2-19 | 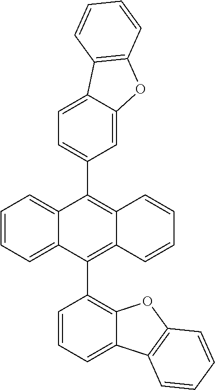 [SMILES: c1ccc2c(c1)oc1cc(-c3c4ccccc4c(-c4cccc5c4oc4ccccc45)c4ccccc34)ccc12] Compound 19 | 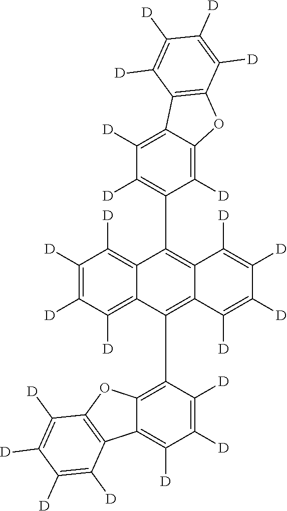 [SMILES: [2H]c1c([2H])c([2H])c2c(oc3c([2H])c(-c4c5c([2H])c([2H])c([2H])c([2H])c5c(-c5c([2H])c([2H])c([2H])c6c5oc5c([2H])c([2H])c([2H])c([2H])c56)c5c([2H])c([2H])c([2H])c([2H])c45)c([2H])c([2H])c32)c1[2H]] | 510 | 532 | 40 | 531 | 22 | 21 | 95% | 68% |
| Compound 2-20 | 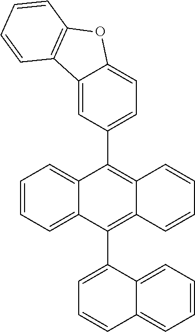 [SMILES: c1ccc2c(-c3c4ccccc4c(-c4ccc5oc6ccccc6c5c4)c4ccccc34)cccc2c1] Compound 20 | 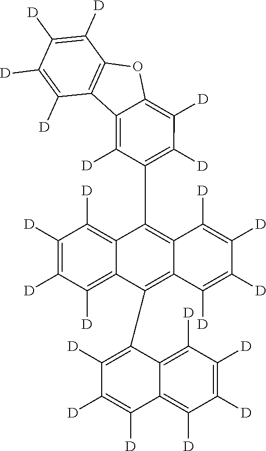 [SMILES: [2H]c1c([2H])c([2H])c2c(oc3c([2H])c([2H])c(-c4c5c([2H])c([2H])c([2H])c([2H])c5c(-c5c([2H])c([2H])c([2H])c6c([2H])c([2H])c([2H])c([2H])c56)c5c([2H])c([2H])c([2H])c([2H])c45)c([2H])c32)c1[2H]] | 470 | 492 | 60 | 492 | 22 | 22 | 100% | 70% |
| Compound 2-21 | 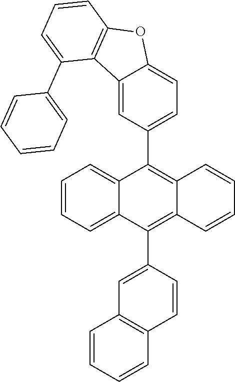 [SMILES: c1ccc(-c2cccc3oc4ccc(-c5c6ccccc6c(-c6ccc7ccccc7c6)c6ccccc56)cc4c23)cc1] Compound 21 | 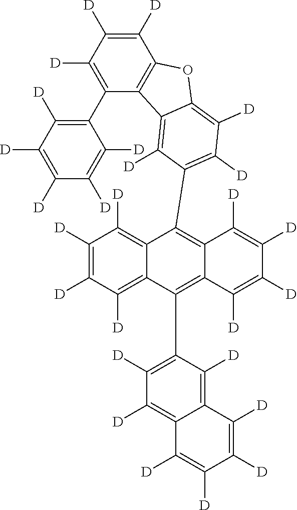 [SMILES: [2H]c1c([2H])c([2H])c(-c2c([2H])c([2H])c([2H])c3oc4c([2H])c([2H])c(-c5c6c([2H])c([2H])c([2H])c([2H])c6c(-c6c([2H])c([2H])c7c([2H])c([2H])c([2H])c([2H])c7c6[2H])c6c([2H])c([2H])c([2H])c([2H])c56)c([2H])c4c23)c([2H])c1[2H]] | 546 | 572 | 30 | 569 | 26 | 23 | 88% | 69% |
| Compound 2-22 | 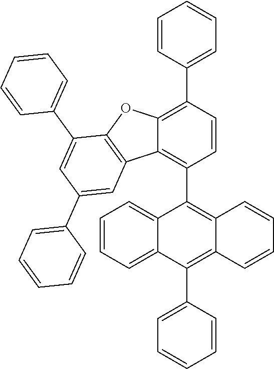 [SMILES: c1ccc(-c2cc(-c3ccccc3)c3oc4c(-c5ccccc5)ccc(-c5c6ccccc6c(-c6ccccc6)c6ccccc56)c4c3c2)cc1] Compound 22 | 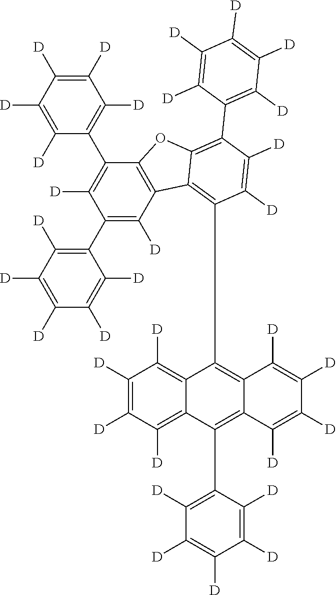 [SMILES: [2H]c1c([2H])c([2H])c(-c2c([2H])c(-c3c([2H])c([2H])c([2H])c([2H])c3[2H])c3oc4c(-c5c([2H])c([2H])c([2H])c([2H])c5[2H])c([2H])c([2H])c(-c5c6c([2H])c([2H])c([2H])c([2H])c6c(-c6c([2H])c([2H])c([2H])c([2H])c6[2H])c6c([2H])c([2H])c([2H])c([2H])c56)c4c3c2[2H])c([2H])c1[2H]] | 648 | 680 | 50 | 677 | 32 | 29 | 91% | 72% |
| Compound 2-23 | 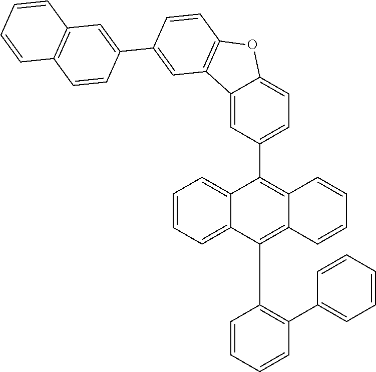 [SMILES: c1ccc(-c2ccccc2-c2c3ccccc3c(-c3ccc4oc5ccc(-c6ccc7ccccc7c6)cc5c4c3)c3ccccc23)cc1] Compound 23 | 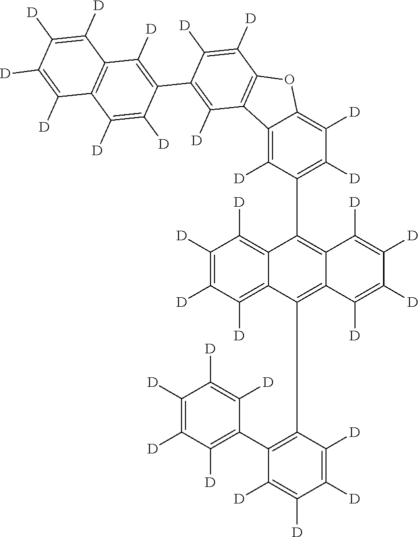 [SMILES: [2H]c1c([2H])c([2H])c(-c2c([2H])c([2H])c([2H])c([2H])c2-c2c3c([2H])c([2H])c([2H])c([2H])c3c(-c3c([2H])c([2H])c4oc5c([2H])c([2H])c(-c6c([2H])c([2H])c7c([2H])c([2H])c([2H])c([2H])c7c6[2H])c([2H])c5c4c3[2H])c3c([2H])c([2H])c([2H])c([2H])c23)c([2H])c1[2H]] | 622 | 652 | 50 | 648 | 30 | 26 | 87% | 73% |
| Compound 2-24 | 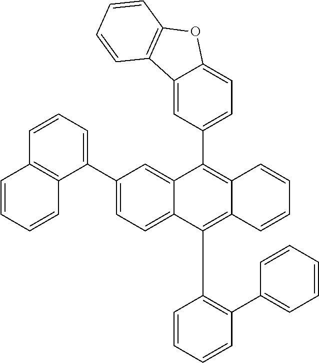 [SMILES: c1ccc(-c2ccccc2-c2c3ccccc3c(-c3ccc4oc5ccccc5c4c3)c3cc(-c4cccc5ccccc45)ccc23)cc1] Compound 24 | 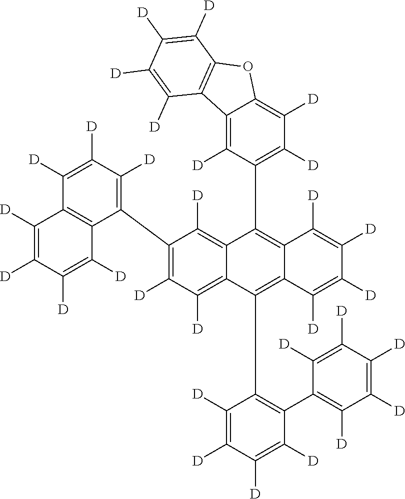 [SMILES: [2H]c1c([2H])c([2H])c(-c2c([2H])c([2H])c([2H])c([2H])c2-c2c3c([2H])c([2H])c([2H])c([2H])c3c(-c3c([2H])c([2H])c4oc5c([2H])c([2H])c([2H])c([2H])c5c4c3[2H])c3c([2H])c(-c4c([2H])c([2H])c([2H])c5c([2H])c([2H])c([2H])c([2H])c45)c([2H])c([2H])c23)c([2H])c1[2H]] | 622 | 652 | 60 | 648 | 30 | 26 | 87% | 80% |
| Compound 2-25 | 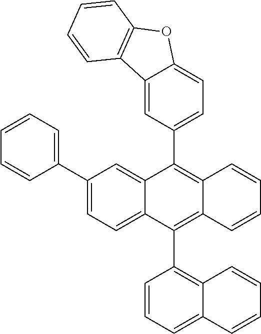 [SMILES: c1ccc(-c2ccc3c(-c4cccc5ccccc45)c4ccccc4c(-c4ccc5oc6ccccc6c5c4)c3c2)cc1] Compound 25 | 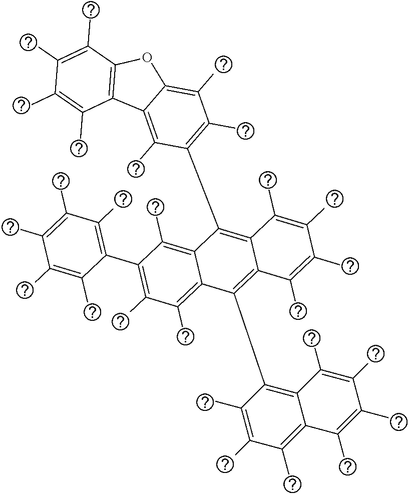 | 546 | 572 | 50 | 568 | 26 | 22 | 85% | 71% |
| Compound 2-26 | 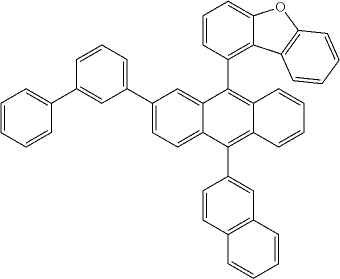 [SMILES: c1ccc(-c2cccc(-c3ccc4c(-c5ccc6ccccc6c5)c5ccccc5c(-c5cccc6oc7ccccc7c56)c4c3)c2)cc1] Compound 26 | 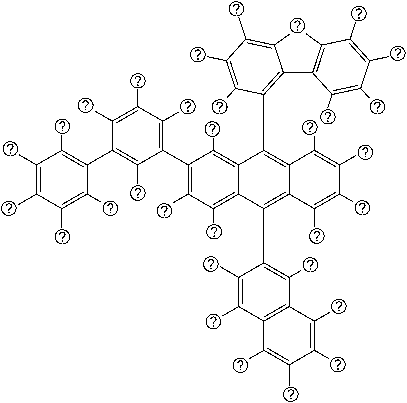 | 622 | 652 | 70 | 650 | 30 | 28 | 93% | 73% |
| Compound 2-27 | 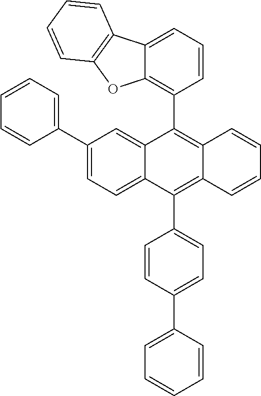 [SMILES: c1ccc(-c2ccc(-c3c4ccccc4c(-c4cccc5c4oc4ccccc45)c4cc(-c5ccccc5)ccc34)cc2)cc1] Compound 27 | 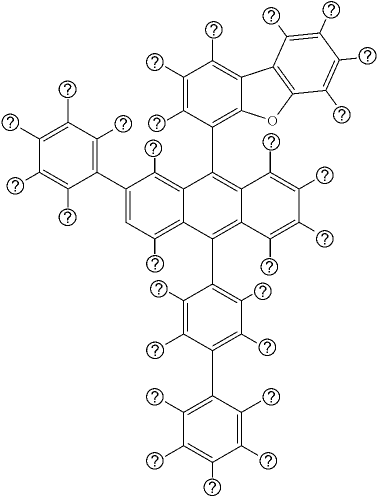 [symbol] | 572 | 599 | 60 | 598 | 27 | 26 | 96% | 72% |

[symbol]

indicates data missing or illegible when filed

[Each product had a different degree of deuterium substitution depending on the reaction time, and the substitution rate was determined by the maximum m/z (M+) value]

Compound 1 to Compound 27, which are the reaction materials, were synthesized with reference to prior documents of the applicant such as KR 10-1964435 B1, KR 10-1899728 B1, KR 10-1975945 B1, KR 10-2018-0098122 A, KR 10-2018-0102937 A and KR 10-2018-0103352 A. In addition, Compounds 2-1 to 2-27, which are the deuterium-substituted products, were synthesized with reference to the prior document KR 10-1538534 B1.

In Table 2, deuterium (-D) bonding to the synthesized products means capable of bonding to the indicated position, and it does not necessarily mean that deuterium is bound to bond to the indicated position.

TABLE 3

| | | | m/z of | Theo- | | Experi- | | | | |
|---|---|---|---|---|---|---|---|---|---|---|
| | | | Reac- | retical | Reac- | mental | H | D | D | Synthe- |
| | | | tion | max m/z | tion | max m/z | total | Sub- | Sub- | sized |
| Deuterated | | | Ma- | of | time | of | Num- | stitution | stitution | Yield |
| Compound | Reaction Material | Product | terial | Product | (min) | Product | ber | Number | Rate(%) | (%) |
| Compound 2-28 | 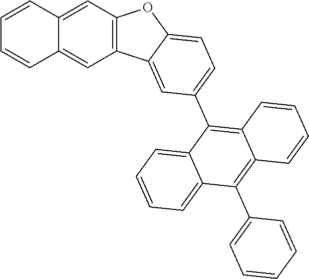 [SMILES: c1ccc(-c2c3ccccc3c(-c3ccc4oc5cc6ccccc6cc5c4c3)c3ccccc23)cc1] Compound 28 | 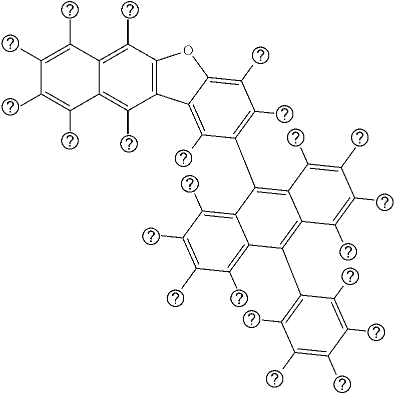 | 470 | 492 | 50 | 490 | 22 | 20 | 91% | 65% |
| Compound 2-29 | 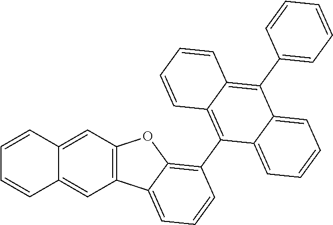 [SMILES: c1ccc(-c2c3ccccc3c(-c3cccc4c3oc3cc5ccccc5cc34)c3ccccc23)cc1] Compound 29 | 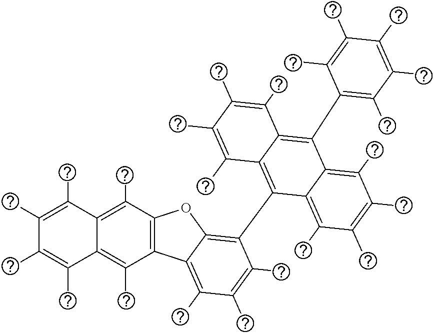 | 470 | 492 | 30 | 486 | 22 | 16 | 73% | 70% |
| Compound 2-30 | 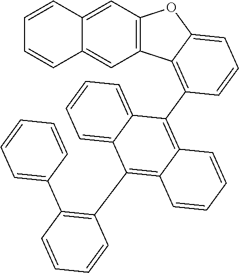 [SMILES: c1ccc(-c2ccccc2-c2c3ccccc3c(-c3cccc4oc5cc6ccccc6cc5c34)c3ccccc23)cc1] Compound 30 | 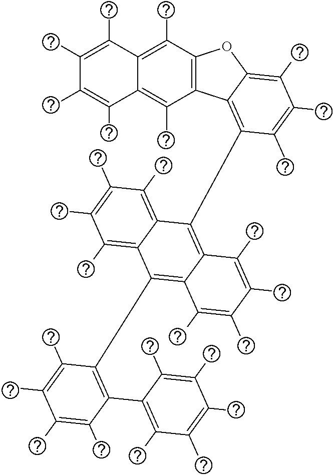 | 546 | 572 | 50 | 569 | 26 | 23 | 88% | 71% |
| Compound 2-31 | 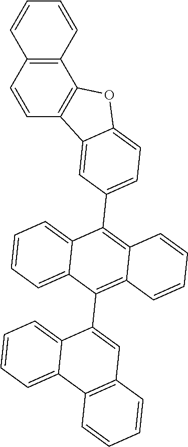 [SMILES: c1ccc2c(c1)cc(-c1c3ccccc3c(-c3ccc4oc5c6ccccc6ccc5c4c3)c3ccccc13)c1ccccc12] Compound 31 | 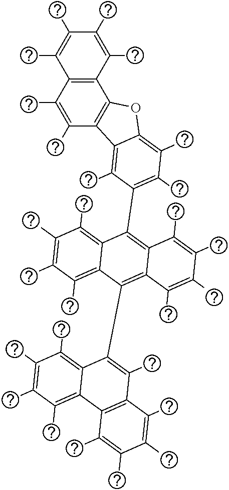 | 570 | 596 | 30 | 590 | 26 | 20 | 77% | 65% |
| Compound 2-32 | 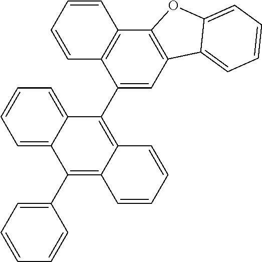 [SMILES: c1ccc(-c2c3ccccc3c(-c3cc4c5ccccc5oc4c4ccccc34)c3ccccc23)cc1] Compound 32 | 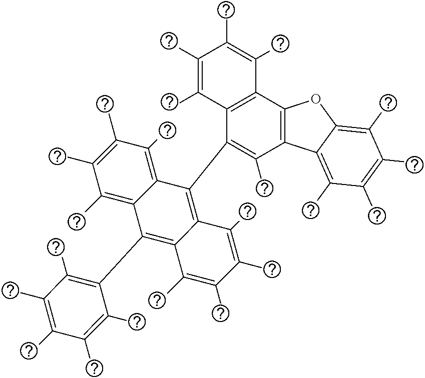 | 470 | 492 | 40 | 489 | 22 | 19 | 86% | 66% |
| Compound 2-33 | 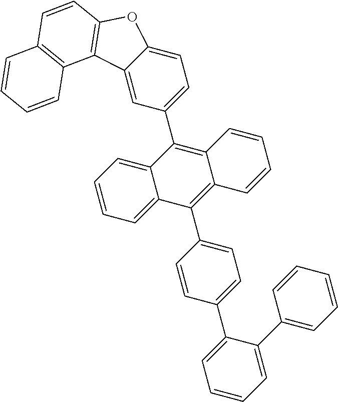 [SMILES: c1ccc(-c2ccccc2-c2ccc(-c3c4ccccc4c(-c4ccc5oc6ccc7ccccc7c6c5c4)c4ccccc34)cc2)cc1] Compound 33 | 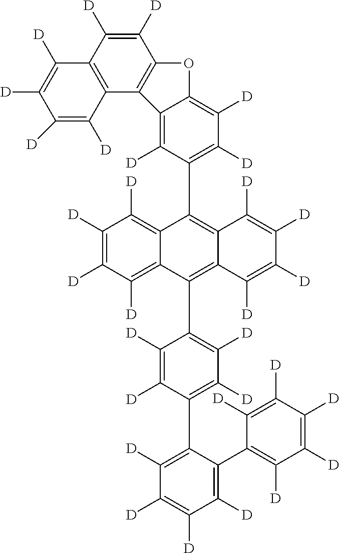 [SMILES: [2H]c1c([2H])c([2H])c(-c2c([2H])c([2H])c([2H])c([2H])c2-c2c([2H])c([2H])c(-c3c4c([2H])c([2H])c([2H])c([2H])c4c(-c4c([2H])c([2H])c5oc6c([2H])c([2H])c7c([2H])c([2H])c([2H])c([2H])c7c6c5c4[2H])c4c([2H])c([2H])c([2H])c([2H])c34)c([2H])c2[2H])c([2H])c1[2H]] | 622 | 652 | 50 | 649 | 30 | 27 | 90% | 71% |
| Compound 2-34 | 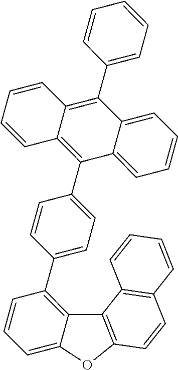 [SMILES: c1ccc(-c2c3ccccc3c(-c3ccc(-c4cccc5oc6ccc7ccccc7c6c45)cc3)c3ccccc23)cc1] Compound 34 | 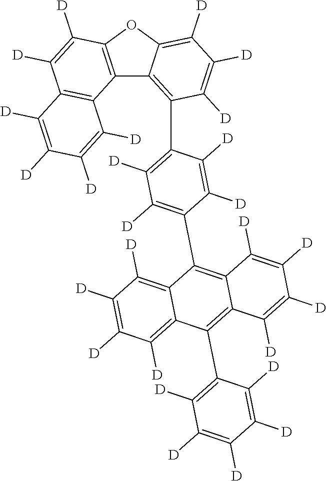 [SMILES: [2H]c1c([2H])c([2H])c(-c2c3c([2H])c([2H])c([2H])c([2H])c3c(-c3c([2H])c([2H])c(-c4c([2H])c([2H])c([2H])c5oc6c([2H])c([2H])c7c([2H])c([2H])c([2H])c([2H])c7c6c45)c([2H])c3[2H])c3c([2H])c([2H])c([2H])c([2H])c23)c([2H])c1[2H]] | 546 | 572 | 35 | 567 | 26 | 21 | 81% | 70% |
| Compound 2-35 | 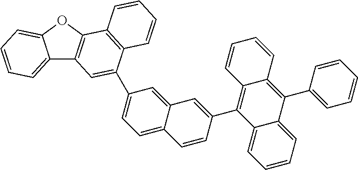 [SMILES: c1ccc(-c2c3ccccc3c(-c3ccc4ccc(-c5cc6c7ccccc7oc6c6ccccc56)cc4c3)c3ccccc23)cc1] Compound 35 | 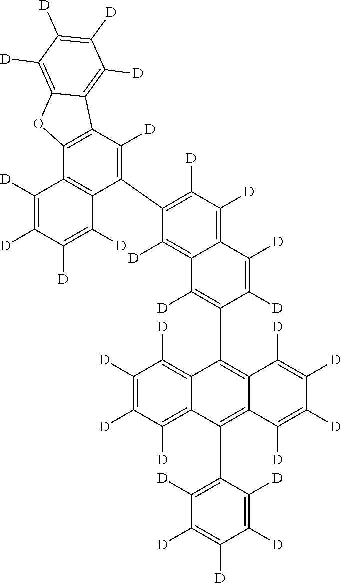 [SMILES: [2H]c1c([2H])c([2H])c(-c2c3c([2H])c([2H])c([2H])c([2H])c3c(-c3c([2H])c([2H])c4c([2H])c([2H])c(-c5c([2H])c6c(oc7c([2H])c([2H])c([2H])c([2H])c76)c6c([2H])c([2H])c([2H])c([2H])c56)c([2H])c4c3[2H])c3c([2H])c([2H])c([2H])c([2H])c23)c([2H])c1[2H]] | 596 | 624 | 40 | 619 | 28 | 23 | 82% | 75% |
| Compound 2-36 | 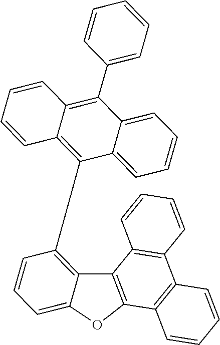 [SMILES: c1ccc(-c2c3ccccc3c(-c3cccc4oc5c6ccccc6c6ccccc6c5c34)c3ccccc23)cc1] Compound 36 | 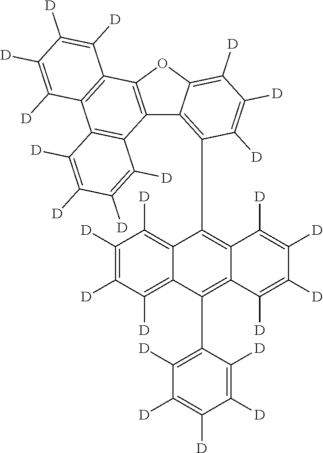 [SMILES: [2H]c1c([2H])c([2H])c(-c2c3c([2H])c([2H])c([2H])c([2H])c3c(-c3c([2H])c([2H])c([2H])c4oc5c6c([2H])c([2H])c([2H])c([2H])c6c6c([2H])c([2H])c([2H])c([2H])c6c5c34)c3c([2H])c([2H])c([2H])c([2H])c23)c([2H])c1[2H]] | 520 | 544 | 60 | 543 | 24 | 23 | 96% | 69% |
| Compound 2-37 | 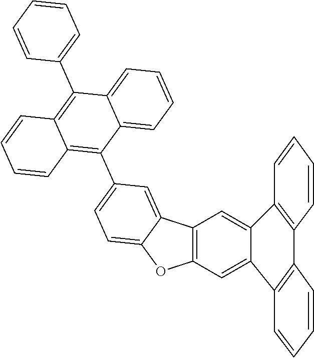 [SMILES: c1ccc(-c2c3ccccc3c(-c3ccc4oc5cc6c7ccccc7c7ccccc7c6cc5c4c3)c3ccccc23)cc1] Compound 37 | 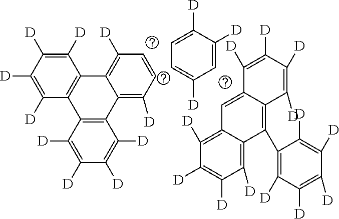 [symbol] | 570 | 596 | 60 | 594 | 26 | 24 | 92% | 68% |
| Compound 2-38 | 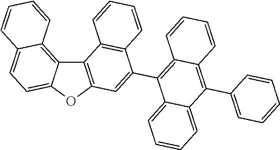 [SMILES: c1ccc(-c2c3ccccc3c(-c3cc4oc5ccc6ccccc6c5c4c4ccccc34)c3ccccc23)cc1] Compound 38 | 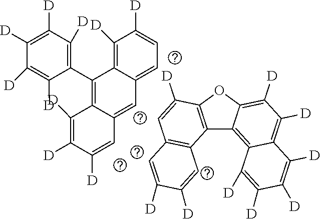 | 520 | 544 | 35 | 538 | 24 | 18 | 75% | 63% |
| Compound 2-39 | 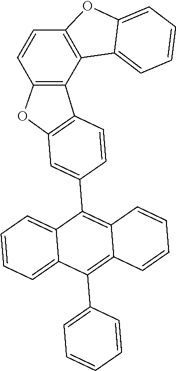 [SMILES: c1ccc(-c2c3ccccc3c(-c3ccc4c(c3)oc3ccc5oc6ccccc6c5c34)c3ccccc23)cc1] Compound 39 | 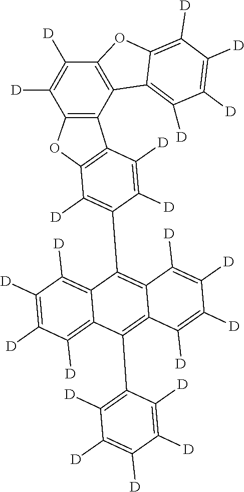 [SMILES: [2H]c1c([2H])c([2H])c(-c2c3c([2H])c([2H])c([2H])c([2H])c3c(-c3c([2H])c([2H])c4c(oc5c([2H])c([2H])c6oc7c([2H])c([2H])c([2H])c([2H])c7c6c54)c3[2H])c3c([2H])c([2H])c([2H])c([2H])c23)c([2H])c1[2H]] | 510 | 532 | 60 | 531 | 22 | 21 | 95% | 66% |
| Compound 2-40 | 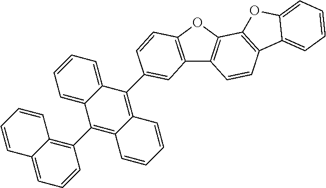 [SMILES: c1ccc2c(-c3c4ccccc4c(-c4ccc5oc6c(ccc7c8ccccc8oc76)c5c4)c4ccccc34)cccc2c1] Compound 40 | 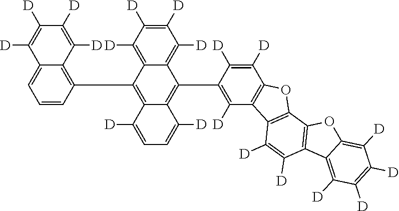 [SMILES: [2H]c1c([2H])c([2H])c2c(-c3c4c([2H])ccc([2H])c4c(-c4c([2H])c([2H])c5oc6c7oc8c([2H])c([2H])c([2H])c([2H])c8c7c([2H])c([2H])c6c5c4[2H])c4c([2H])c([2H])c([2H])c([2H])c34)cccc2c1[2H]] | 560 | 584 | 15 | 572 | 24 | 12 | 50% | 65% |
| Compound 2-41 | 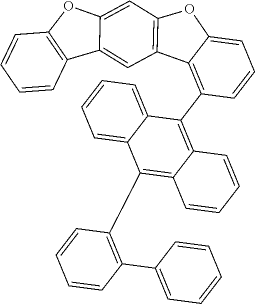 [SMILES: c1ccc(-c2ccccc2-c2c3ccccc3c(-c3cccc4oc5cc6oc7ccccc7c6cc5c34)c3ccccc23)cc1] Compound 41 | 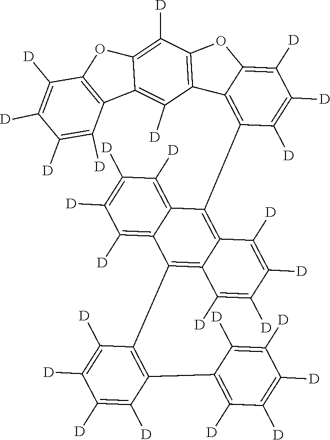 [SMILES: [2H]c1c([2H])c([2H])c(-c2c([2H])c([2H])c([2H])c([2H])c2-c2c3c([2H])c([2H])c([2H])c([2H])c3c(-c3c([2H])c([2H])c([2H])c4oc5c([2H])c6oc7c([2H])c([2H])c([2H])c([2H])c7c6c([2H])c5c34)c3c([2H])c([2H])c([2H])c([2H])c23)c([2H])c1[2H]] | 586 | 612 | 40 | 607 | 26 | 21 | 81% | 67% |
| Compound 2-42 | 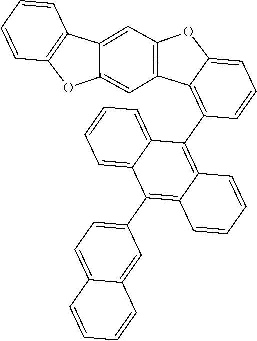 [SMILES: c1ccc2cc(-c3c4ccccc4c(-c4cccc5oc6cc7c(cc6c45)oc4ccccc47)c4ccccc34)ccc2c1] Compound 42 | 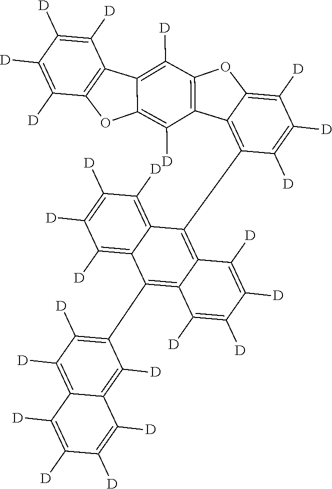 [SMILES: [2H]c1c([2H])c([2H])c2c(oc3c([2H])c4c(oc5c([2H])c([2H])c([2H])c(-c6c7c([2H])c([2H])c([2H])c([2H])c7c(-c7c([2H])c([2H])c8c([2H])c([2H])c([2H])c([2H])c8c7[2H])c7c([2H])c([2H])c([2H])c([2H])c67)c54)c([2H])c32)c1[2H]] | 560 | 584 | 75 | 584 | 24 | 24 | 100% | 70% |
| Compound 2-43 | 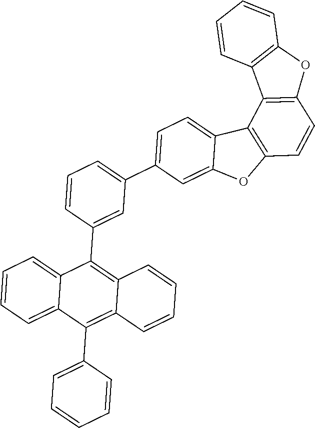 [SMILES: c1ccc(-c2c3ccccc3c(-c3cccc(-c4ccc5c(c4)oc4ccc6oc7ccccc7c6c45)c3)c3ccccc23)cc1] Compound 43 | 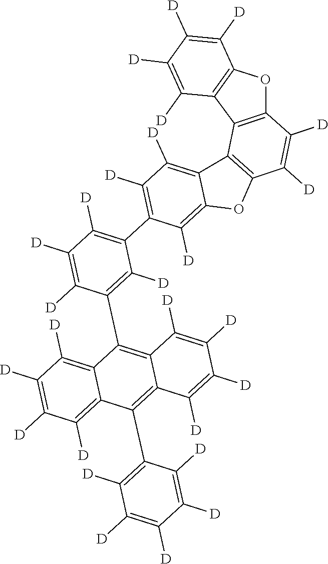 [SMILES: [2H]c1c([2H])c([2H])c(-c2c3c([2H])c([2H])c([2H])c([2H])c3c(-c3c([2H])c([2H])c([2H])c(-c4c([2H])c([2H])c5c(oc6c([2H])c([2H])c7oc8c([2H])c([2H])c([2H])c([2H])c8c7c65)c4[2H])c3[2H])c3c([2H])c([2H])c([2H])c([2H])c23)c([2H])c1[2H]] | 586 | 612 | 60 | 610 | 26 | 24 | 92% | 70% |
| Compound 2-44 | 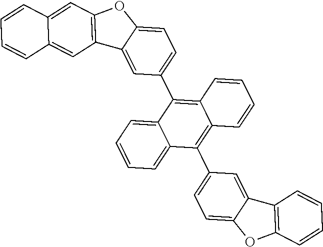 [SMILES: c1ccc2cc3c(cc2c1)oc1ccc(-c2c4ccccc4c(-c4ccc5oc6ccccc6c5c4)c4ccccc24)cc13] Compound 44 | 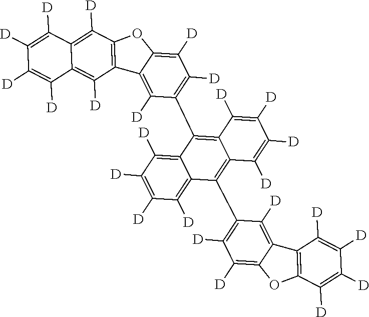 [SMILES: [2H]c1c([2H])c([2H])c2c(oc3c([2H])c([2H])c(-c4c5c([2H])c([2H])c([2H])c([2H])c5c(-c5c([2H])c([2H])c6oc7c([2H])c8c([2H])c([2H])c([2H])c([2H])c8c([2H])c7c6c5[2H])c5c([2H])c([2H])c([2H])c([2H])c45)c([2H])c32)c1[2H]] | 560 | 584 | 60 | 580 | 24 | 20 | 83% | 69% |
| Compound 2-45 | 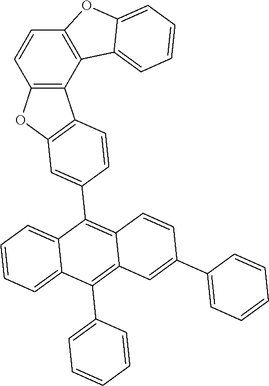 [SMILES: c1ccc(-c2ccc3c(-c4ccc5c(c4)oc4ccc6oc7ccccc7c6c45)c4ccccc4c(-c4ccccc4)c3c2)cc1] Compound 45 | 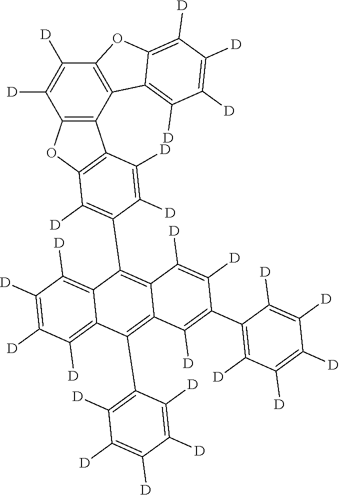 [SMILES: [2H]c1c([2H])c([2H])c(-c2c([2H])c([2H])c3c(-c4c([2H])c([2H])c5c(oc6c([2H])c([2H])c7oc8c([2H])c([2H])c([2H])c([2H])c8c7c65)c4[2H])c4c([2H])c([2H])c([2H])c([2H])c4c(-c4c([2H])c([2H])c([2H])c([2H])c4[2H])c3c2[2H])c([2H])c1[2H]] | 586 | 612 | 50 | 607 | 26 | 21 | 81% | 75% |
| Compound 2-46 | 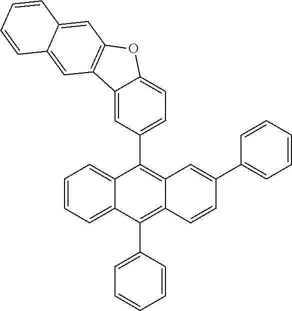 [SMILES: c1ccc(-c2ccc3c(-c4ccccc4)c4ccccc4c(-c4ccc5oc6cc7ccccc7cc6c5c4)c3c2)cc1] Compound 46 | 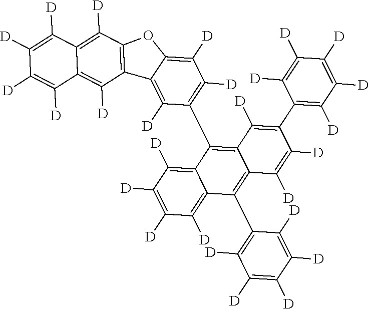 [SMILES: [2H]c1c([2H])c([2H])c(-c2c([2H])c([2H])c3c(-c4c([2H])c([2H])c([2H])c([2H])c4[2H])c4c([2H])c([2H])c([2H])c([2H])c4c(-c4c([2H])c([2H])c5oc6c([2H])c7c([2H])c([2H])c([2H])c([2H])c7c([2H])c6c5c4[2H])c3c2[2H])c([2H])c1[2H]] | 546 | 572 | 60 | 568 | 26 | 22 | 85% | 72% |
| Compound 2-47 | 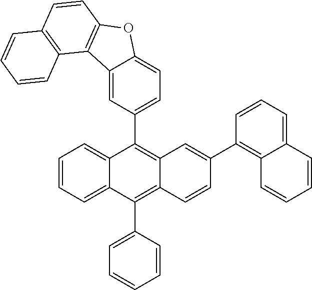 [SMILES: c1ccc(-c2c3ccccc3c(-c3ccc4oc5ccc6ccccc6c5c4c3)c3cc(-c4cccc5ccccc45)ccc23)cc1] Compound 47 | 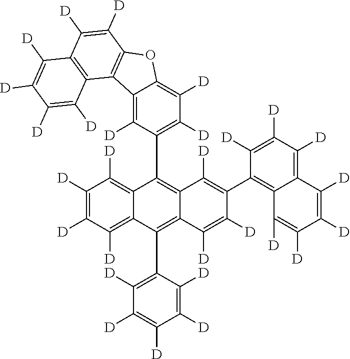 [SMILES: [2H]c1c([2H])c([2H])c(-c2c3c([2H])c([2H])c([2H])c([2H])c3c(-c3c([2H])c([2H])c4oc5c([2H])c([2H])c6c([2H])c([2H])c([2H])c([2H])c6c5c4c3[2H])c3c([2H])c(-c4c([2H])c([2H])c([2H])c5c([2H])c([2H])c([2H])c([2H])c45)c([2H])c([2H])c23)c([2H])c1[2H]] | 596 | 624 | 60 | 620 | 28 | 24 | 86% | 70% |

[symbol]

indicates data missing or illegible when filed

[Each product had a different degree of deuterium substitution depending on the reaction time, and the substitution rate was determined by the maximum m/z (M+) value]

Compound 28 to Compound 47, which are the reaction materials, were synthesized with reference to prior documents of the applicant such as KR 10-1994238 B1, KR 10-1670193 B1, KR 10-1754445 B1 and KR 10-1368164 B1. In addition, Compounds 2-28 to 2-47, which are the deuterium-substituted products, were synthesized with reference to the prior document KR 10-1538534 B1.

In Table 3, deuterium (-D) bonding to the synthesized products means capable of bonding to the indicated position, and it does not necessarily mean that deuterium is bound to bond to the indicated position.

A dipole moment (DM) and an evaporation temperature of each of the reaction materials described in the preparation examples are shown in the following [Table 4].

TABLE 4

| | | Evaporation |
|---|---|---|
| | DM | Temperature |
| | (D) | (° C.) |
| Compound A | 0.29 | 270 |
| Compound B | 0.17 | 250 |
| Compound C | 0.21 | 260 |
| Compound D | 0.18 | 240 |
| Compound E | 0.12 | 260 |
| Compound F | 0.15 | 240 |
| Compound G | 0.06 | 250 |
| Compound H | 0.20 | 250 |
| Compound I | 0.23 | 250 |
| Compound J | 0.16 | 250 |
| Compound K | 0.29 | 240 |
| Compound L | 0.21 | 260 |
| Compound M | 0.24 | 270 |
| Compound O | 0.18 | 270 |
| Compound P | 0.15 | 260 |
| Compound Q | 0.17 | 260 |
| Compound R | 0.02 | 270 |
| Compound S | 0.30 | 260 |
| Compound T | 0.08 | 260 |
| Compound U | 0.12 | 270 |
| Compound V | 0.17 | 290 |
| Compound W | 0.24 | 290 |
| Compound 1 | 1.01 | 260 |
| Compound 2 | 1.21 | 270 |
| Compound 3 | 1.23 | 270 |
| Compound 4 | 0.81 | 290 |
| Compound 5 | 1.24 | 260 |
| Compound 6 | 0.82 | 240 |
| Compound 7 | 0.89 | 260 |
| Compound 8 | 0.70 | 260 |
| Compound 9 | 1.20 | 280 |
| Compound 10 | 0.69 | 260 |
| Compound 11 | 0.73 | 290 |
| Compound 12 | 1.01 | 270 |
| Compound 13 | 0.64 | 260 |
| Compound 14 | 0.60 | 250 |
| Compound 15 | 0.63 | 270 |
| Compound 16 | 1.01 | 260 |
| Compound 17 | 0.74 | 260 |
| Compound 18 | 0.49 | 260 |
| Compound 19 | 0.64 | 260 |
| Compound 20 | 0.66 | 260 |
| Compound 21 | 0.95 | 270 |
| Compound 22 | 1.02 | 290 |
| Compound 23 | 0.94 | 290 |
| Compound 24 | 1.11 | 300 |
| Compound 25 | 1.05 | 270 |
| Compound 26 | 1.02 | 300 |
| Compound 27 | 1.07 | 270 |
| Compound 28 | 1.03 | 270 |
| Compound 29 | 1.02 | 260 |
| Compound 30 | 1.12 | 280 |
| Compound 31 | 0.94 | 290 |
| Compound 32 | 0.91 | 270 |
| Compound 33 | 1.01 | 290 |
| Compound 34 | 0.98 | 280 |
| Compound 35 | 1.15 | 300 |
| Compound 36 | 1.04 | 260 |
| Compound 37 | 1.10 | 270 |
| Compound 38 | 0.90 | 280 |
| Compound 39 | 1.15 | 280 |
| Compound 40 | 1.17 | 290 |
| Compound 41 | 1.25 | 280 |
| Compound 42 | 1.22 | 290 |
| Compound 43 | 1.28 | 290 |
| Compound 44 | 1.01 | 290 |
| Compound 45 | 1.21 | 290 |
| Compound 46 | 1.20 | 280 |
| Compound 47 | 1.22 | 290 |

Compounds A to W and Compounds 1-A to 1-W have a difference in the chemical structures of carbon-hydrogen skeleton and carbon-deuterium skeleton, but have the same basic chemical skeleton and have almost the same dipole moment value, and therefore, the dipole moment values and the evaporation temperature values of Compounds A to W can be considered to be the same as the values of Compounds 1-A to 1-W. In addition, Compounds 1 to 47 can be considered to have the same dipole moment values and the evaporation temperature values as Compounds 2-1 to 2-47. The compounds corresponding to the compounds of Chemical Formula 1 and the compounds corresponding to Chemical Formula 2 among the compounds synthesized in the preparation examples chemically and structurally have a difference in the dipole moment. Compounds A to W corresponding to Chemical Formula 1 have a skeleton based only on carbon and hydrogen by having an aryl-based substituent, and sectionalization of few and many electrons is limited in the chemical structure leading to the result that the maximum value of the dipole moment (DM) value is not greater than 0.3 debye. On the other hand, it is identified that Compounds 1 to 47 corresponding to Chemical Formula 2 have the anthracene skeleton substituted with aryl or heteroaryl-including furan including relatively electron-sufficient oxygen, and, by having a potential to deepen the sectionalization of electrons in the chemical structure having a carbon-hydrogen skeleton, have a relatively higher dipole moment (DM) compared to Compounds A to W corresponding to Chemical Formula 1. Accordingly, the combination of the two structures proposed in this document has a range that the DM difference between the two materials is greater than a minimum of 0.2.

### Experimental Example

### Experimental Example 1

### <Preparation of Mixture>

It is identified that the compounds synthesized in the preparation examples have an evaporation temperature of lower than 400° C., and having a higher evaporation temperature reveals many limitations to be used as a material of an organic electroluminescent device. In addition, in order to pre-mix the mixture of one type of the compounds corresponding to Chemical Formula 1 and one type of the compounds corresponding to Chemical Formula 2 before evaporation by one evaporation source, the following Equation 2 needs to be preferably satisfied. A mixture having superior uniformity can be obtained when satisfying the following Equation 2, and a uniform film can also be obtained in the step of manufacturing a device. Experiments of the following (1) and (2) were conducted in order to show such an effect.

$$\vert {T}_{sub 1} - {T}_{sub 2} \vert \leq 20 ° C \qquad < Equation 2 >$$

(T_{sub1} is an evaporation temperature of the compound of Chemical Formula 1, and T_{sub2} is an evaporation temperature of the compound of Chemical Formula 2.)

(1)

In order to identify miscibility of the compound of Chemical Formula 1 and the compound of Chemical Formula 2, a film formed by pre-mixing the materials and then evaporating the mixture was tested using a high pressure liquid chromatography (HPLC) analysis. Compound J prepared in the preparation example was used as the compound of Chemical Formula 1, and Compound 6 prepared in the preparation example was used as the compound of Chemical Formula 2.

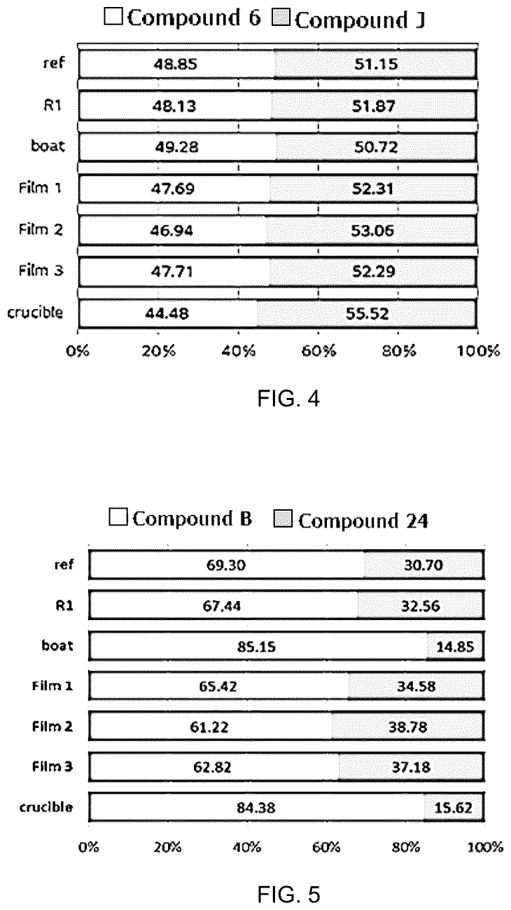

Specifically, 0.15 g of Compound J (or Compound 1-J) and 0.15 g of Compound 6 (or Compound 2-6) were mixed (mass ratio 1:1) and pulverized to obtain a composition, and the obtained composition was prepared as a sublimation mixture composition using a sublimator. After that, the prepared sublimation mixture composition was loaded on a crucible into a VTE vacuum chamber. The chamber was pumped down to a pressure of 10⁻⁷ torr. The pre-mixed components were deposited on a glass substrate at a rate of 2 Å/second. A film of 600 Å was deposited without interrupting the deposition process so as to avoid cooling of the raw materials and to keep the raw materials at a proper temperature, and the process was further repeated twice replacing the substrate. Three of such substrate samples were taken to analyze the deposited film by HPLC, and the results are each shown as film 1 to film 3 in FIG. 4. From the experimental results shown in FIG. 4, it was identified that the compositions of Compound J and Compound 6 did not change significantly. A change in the concentration (the following Equation 3) before and after deposition of 10% or less and preferably 5% or less throughout the whole process is considered to be excellent and useful for commercially available OLED applications, and the above-described change in the concentration is considered to be maintained when a difference in the evaporation temperatures between the mixed two compounds is a temperature difference of 20° C. or lower. (Difference in the evaporation temperatures between Compound J and Compound 6:10° C.)

The slight variation in the concentration range of the following Equation 3 did not reveal any trend device-wise, and the sample collection and the HPLC analysis were able to be explained by the following Equation 3.

$$\vert ( C 1 - C 2 ) / C 1 \vert < 10 \% \qquad < Equation 3 >$$

Based on Equation 3,
when the compound of Compound 6 has a concentration C1: 48.85% in the composition,
1) the concentration of Film 1 (C2) is 47.69%, and therefore, the change in the concentration is 2.3%,
2) the concentration of Film 2 (C2) is 46.94%, and therefore, the change in the concentration is 3.9%,
3) the concentration of Film 3 (C2) is 47.71%, and therefore, the change in the concentration is 2.3%.

It was observed that the change in the concentration was not significant in film 1 to film 3 prepared above, and the deviation between the films was small. Accordingly, it was identified that the conditions of the above and Equation 2 were preferable.

(2)

Results of a mixture example not satisfying Equation 2 are illustrated. Herein, Compound B and Compound 24 were used.

For mixing, 0.21 g of Compound B (or Compound 1-B) and 0.09 g of Compound 24 (or Compound 2-24) were mixed (mass ratio 7:3 mixing), and pulverized. The preparation condition was the same as in (1), and the results are shown in the following Picture [2].

Based on Equation 3,
when the compound of Compound 24 has a concentration C1: 69.30% in the composition,
1) the concentration of Film 1 (C2) is 65.42%, and therefore, the change in the concentration is 5.5%,
2) the concentration of Film 2 (C2) is 61.22%, and therefore, the change in the concentration is 11.6%,
3) the concentration of Film 3 (C2) is 62.82%, and therefore, the change in the concentration is 9.3%.

The change in the concentration was significant in film 1 to film 3 prepared above, and particularly, with the change of 10% or greater, a large deviation between the films was observed. Accordingly, a uniform film was not able to be obtained when pre-mixing the combination of the compound of Chemical Formula 1 and the compound of Chemical Formula 2 not satisfying Equation 2 and forming a film using one evaporation source.

### <Experimental Example 2> Manufacture of OLED

### Example 1

As an anode, a substrate having ITO/Ag/ITO deposited to 70 Å/1000 Å/70 Å was cut to a size of 50 mm×50 mm×0.5 mm, placed in distilled water containing dissolved dispersant, and ultrasonically cleaned. A product of Fischer Co. was used as the dispersant, and as the distilled water, distilled water filtered twice with a filter manufactured by Millipore Co. was used. After the ITO was cleaned for 30 minutes, ultrasonic cleaning was repeated twice using distilled water for 10 minutes. After the cleaning with distilled water was finished, the substrate was ultrasonically cleaned with solvents of isopropyl alcohol, acetone and methanol in this order, and then dried.

On the anode prepared as above, a hole injection layer was formed by thermal vacuum depositing the following compound HI-1 to a thickness of 50 Å, and a hole transfer layer was formed thereon by vacuum depositing the following compound HT1, a material transferring holes, to a thickness of 1150 Å. Subsequently, a hole control layer was formed using the following compound EB1 (150 Å), and then a light emitting layer was formed by vacuum depositing a mixture prepared using Compound A synthesized in Preparation Example 1 and Compound 2-1 synthesized in Preparation Example 2, and a the following compound BD1 (2 mass %) as dopant to a thickness of 360 Å. After that, an electron control layer was formed by depositing the following compound HB1 to a thickness of 50 Å, and an electron transfer layer having a thickness of 250 Å was formed by mixing the following compounds ET1 and Liq at a 5:5 mass ratio. Magnesium and lithium fluoride (LiF) having a thickness of 50 Å were consecutively formed to a film as an electron injection layer, then magnesium and silver (1:4) were formed to 200 Å as a cathode, and then the following compound CP1 was deposited to 600 Å to complete a device. In the process, the deposition rates of the organic materials were maintained at 1 Å/sec.

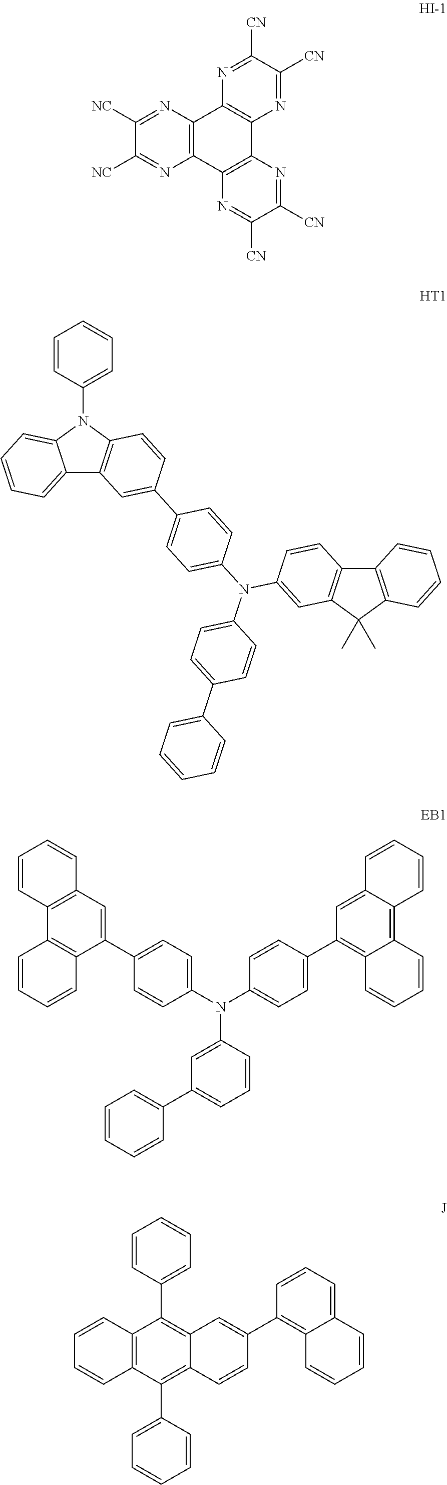

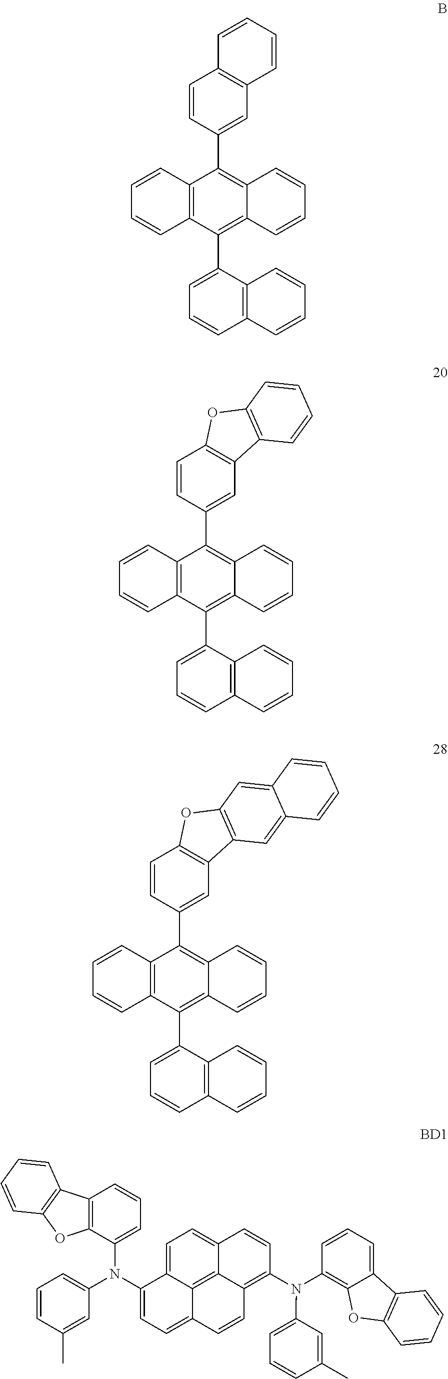

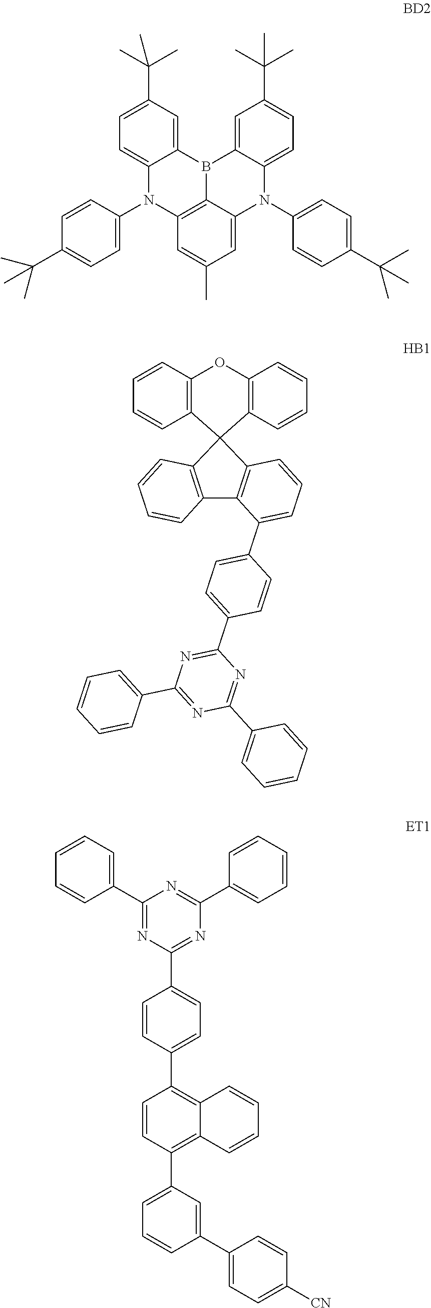 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1 ; c1ccc(-c2nc(-c3ccccc3)nc(-c3ccc(-c4cccc5c4-c4ccccc4C54c5ccccc5Oc5ccccc54)cc3)n2)cc1 ; N#Cc1ccc(-c2cccc(-c3ccc(-c4ccc(-c5nc(-c6ccccc6)nc(-c6ccccc6)n5)cc4)c4ccccc34)c2)cc1]

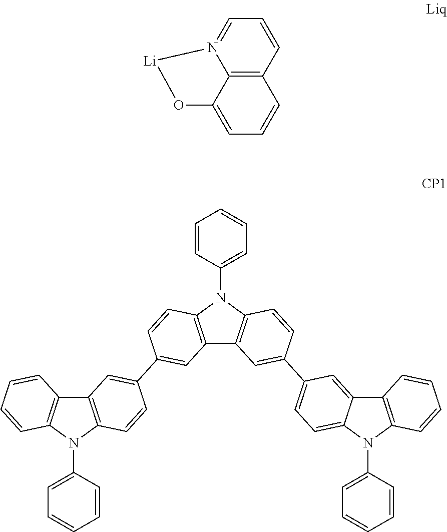

### Examples 2 to 43, Example 1-1 and Comparative Examples 1 to 6

Devices of Examples 2 to 43, Example 1-1 and Comparative Examples 1 to 6 were manufactured in the same manner as in Example 1, except that materials described in the following Table 6 were used as the light emitting layer material, and a different light emitting layer forming method was used. In Example 1, the light emitting layer was formed by pre-mixing Compound A and Compound 2-1 before forming the layer and through one deposition source as in Experimental Example 1, and in the comparative examples and the examples having the deposition method as co-deposition in the following Table 6, the light emitting layer was formed by depositing the first host, the second host and the dopant each through a different deposition source.

A difference in the dipole moment values and a difference in the evaporation temperatures between the two types of host materials used as the light emitting layer material in Comparative Examples 1 to 6 and Examples 1 to 43 are shown in the following Table 5.

TABLE 5

| | Combination of | Representative | Representative | | Difference in |
|---|---|---|---|---|---|
| | Light Emitting | Structure of | Structure of | | Evaporation |
| | Layer Compound | Chemical | Chemical | Difference | Temperature |
| | (Mass Ratio) | Formula 1 | Formula 2 | in DM (D) | (° C.) |
| Comparative | Compound J:Compound 20 | Compound J | Compound 20 | (0.50) | (10) |
| Example 1 | (1:1) | | | | |
| Comparative | Compound J:Compound 20 | Compound J | Compound 20 | (0.50) | (10) |
| Example 2 | (2:1) | | | | |
| Comparative | Compound B:Compound 28 | Compound B | Compound 28 | (0.86) | (20) |
| Example 3 | (1:1) | | | | |
| Comparative | Compound B:Compound 28 | Compound B | Compound 28 | (0.86) | (20) |
| Example 4 | (1:2) | | | | |
| Comparative | Compound J:Compound 20 | Compound J | Compound 20 | (0.50) | (10) |
| Example 5 | (1:1, Co-deposition) | | | | |
| Comparative | Compound B:Compound 28 | Compound B | Compound 28 | (0.86) | (20) |
| Example 6 | (1:2, Co-deposition) | | | | |
| Example 1 | Compound A:Compound | Compound A | Compound 1 | (0.72) | (10) |
| | 2-1 (1:1) | | | | |
| Example 2 | Compound D:Compound | Compound D | Compound 13 | (0.46) | (20) |
| | 2-13 (1:1) | | | | |
| Example 3 | Compound A:Compound | Compound A | Compound 1 | (0.72) | (10) |
| | 2-1 (1:1, Co-deposition) | | | | |
| Example 4 | Compound D:Compound | Compound D | Compound 13 | (0.46) | (20) |
| | 2-13 (1:1, Co-deposition) | | | | |
| Example 5 | Compound F:Compound | Compound F | Compound 20 | (0.80) | (20) |
| | 2-20 (1:1) | | | | |
| Example 6 | Compound I:Compound | Compound I | Compound 28 | (0.89) | (20) |
| | 2-28 (1:1) | | | | |
| Example 7 | Compound T:Compound | Compound T | Compound 38 | (0.82) | (20) |
| | 2-38 (1:1) | | | | |
| Example 8 | Compound V:Compound | Compound V | Compound 41 | (1.08) | (10) |
| | 2-41 (1:1) | | | | |
| Example 9 | Compound W:Compound | Compound W | Compound 46 | (0.96) | (10) |
| | 2-46 (1:1) | | | | |
| Example 1-1 | Compound J:Compound | Compound J | Compound 20 | (0.50) | (10) |
| | 2-20 (1:1) | | | | |
| Example 10 | Compound 1-B:Compound | Compound B | Compound 2 | (1.04) | (20) |
| | 2 (1:1) | | | | |
| Example 11 | Compound 1-F:Compound | Compound F | Compound 8 | (0.55) | (20) |
| | 8 (1:1) | | | | |
| Example 12 | Compound 1-H:Compound | Compound H | Compound 15 | (0.43) | (20) |
| | 15 (1:1) | | | | |
| Example 13 | Compound 1-K:Compound | Compound K | Compound 14 | (0.82) | (10) |
| | 14 (1:1) | | | | |
| Example 14 | Compound 1-A:Compound | Compound A | Compound 1 | (0.72) | (10) |
| | 2-1 (1:1, Co-deposition) | | | | |
| Example 15 | Compound 1-D:Compound | Compound D | Compound 8 | (0.52) | (20) |
| | 2-8 (1:1, Co-deposition) | | | | |
| Example 16 | Compound 1-A:Compound | Compound A | Compound 1 | (0.72) | (10) |
| | 2-1 (1:1) | | | | |
| Example 17 | Compound 1-B:Compound | Compound B | Compound 6 | (0.64) | (10) |
| | 2-6 (1:1) | | | | |
| Example 18 | Compound 1-C:Compound | Compound C | Compound 5 | (1.03) | (0) |
| | 2-5 (1:1) | | | | |
| Example 19 | Compound 1-D:Compound | Compound D | Compound 13 | (1.02) | (20) |
| | 2-13 (1:1) | | | | |
| Example 20 | Compound 1-E:Compound | Compound E | Compound 10 | (0.57) | (0) |
| | 2-10 (1:1) | | | | |
| Example 21 | Compound 1-V:Compound | Compound V | Compound 11 | (0.58) | (0) |
| | 2-11 (1:1) | | | | |
| Example 22 | Compound 1-G:Compound | Compound G | Compound 12 | (0.67) | (20) |
| | 2-12 (1:1) | | | | |
| Example 23 | Compound 1-H:Compound | Compound H | Compound 21 | (0.75) | (20) |
| | 2-21 (1:1) | | | | |
| Example 24 | Compound 1-W:Compound | Compound W | Compound 24 | (0.88) | (10) |
| | 2-24 (1:1) | | | | |
| Example 25 | Compound 1-J:Compound | Compound J | Compound 27 | (0.91) | (20) |
| | 2-27 (1:1) | | | | |
| Example 26 | Compound 1-K:Compound | Compound K | Compound 29 | (0.65) | (20) |
| | 2-29 (1:1) | | | | |
| Example 27 | Compound 1-L:Compound | Compound L | Compound 34 | (0.80) | (20) |
| | 2-34 (1:1) | | | | |
| Example 28 | Compound 1-M:Compound | Compound M | Compound 39 | (0.91) | (10) |
| | 2-39 (1:1) | | | | |
| Example 29 | Compound 1-M:Compound | Compound M | Compound 41 | (1.01) | (10) |
| | 2-41 (1:1) | | | | |
| Example 30 | Compound 1-O:Compound | Compound O | Compound 47 | (1.04) | (20) |
| | 2-47 (1:1) | | | | |
| Example 31 | Compound 1-P:Compound | Compound P | Compound 3 | (1.08) | (10) |
| | 2-3 (1:1) | | | | |
| Example 32 | Compound 1-Q:Compound | Compound Q | Compound 7 | (0.72) | (0) |
| | 2-7 (1:1) | | | | |
| Example 33 | Compound 1-R:Compound | Compound R | Compound 18 | (0.47) | (10) |
| | 2-18 (1:1) | | | | |
| Example 34 | Compound 1-S:Compound | Compound S | Compound 25 | (0.75) | (10) |
| | 2-25 (1:1) | | | | |
| Example 35 | Compound 1-T:Compound | Compound T | Compound 46 | (0.93) | (20) |
| | 2-46 (1:1) | | | | |
| Example 36 | Compound 1-U:Compound | Compound U | Compound 38 | (1.03) | (10) |
| | 2-38 (1:1) | | | | |
| Example 37 | Compound 1-V:Compound | Compound V | Compound 35 | (0.84) | (10) |
| | 2-35 (1:1) | | | | |
| Example 38 | Compound 1-W:Compound | Compound W | Compound 9 | (0.96) | (10) |
| | 2-9 (1:1) | | | | |
| Example 39 | Compound 1-C:Compound | Compound C | Compound 3 | (1.02) | (10) |
| | 2-3 (2:1) | | | | |
| Example 40 | Compound 1-G:Compound | Compound G | Compound 13 | (0.58) | (10) |
| | 2-13 (3:1) | | | | |
| Example 41 | Compound 1-V:Compound | Compound V | Compound 44 | (0.87) | (0) |
| | 2-44 (1:2) | | | | |
| Example 42 | Compound 1-S:Compound | Compound S | Compound 32 | (0.61) | (10) |
| | 2-32 (1:3) | | | | |
| Example 43 | Compound 1-W:Compound | Compound W | Compound 40 | (0.93) | (0) |
| | 2-40 (2:1) | | | | |

For the devices manufactured in Comparative Examples 1 to 6 and Examples 1 to 43, driving voltage, light emission efficiency, color coordinate and time (T95) taken for luminance to become 95% with respect to initial luminance were measured at current density of 20 mA/cm². The results are shown in the following Table 6.

TABLE 6

| | | | Device Result | | | |
|---|---|---|---|---|---|---|
| | | | Voltage | | | Lifetime |
| | Light Emitting Layer | | (V) | Cd/A | Color | (T95, h) |
| Experimental | First Host:Second Host | | (@20 | (@20 | Coordinate | (@20 |
| Example | (Mass Ratio (Deposition Method)) | Dopant | mA/cm²) | mA/cm²) | (x, y) | mA/cm²) |
| Comparative | Compound J:Compound 20 | BD1 | 3.89 | 5.23 | (0.140, | 42.0 |
| Example 1 | (1:1) | | | | 0.050) | |
| Comparative | Compound J:Compound 20 | BD1 | 3.98 | 5.38 | (0.140, | 43.1 |
| Example 2 | (2:1) | | | | 0.049) | |
| Comparative | Compound B:Compound 28 | BD1 | 3.87 | 5.33 | (0.140, | 45.8 |
| Example 3 | (1:1) | | | | 0.050) | |
| Comparative | Compound B:Compound 28 | BD1 | 3.78 | 5.20 | (0.140, | 40.2 |
| Example 4 | (1:2) | | | | 0.050) | |
| Comparative | Compound J:Compound 20 | BD1 | 4.01 | 5.31 | (0.140, | 38.1 |
| Example 5 | (1:1, Co-deposition) | | | | 0.050) | |
| Comparative | Compound B:Compound 28 | BD1 | 3.99 | 5.38 | (0.140, | 35.8 |
| Example 6 | (1:2, Co-deposition) | | | | 0.050) | |
| Example 1 | Compound A:Compound 2-1 | BD1 | 3.88 | 5.40 | (0.140, | 56.1 |
| | (1:1) | | | | 0.050) | |
| Example 2 | Compound D:Compound 2-13 | BD1 | 3.78 | 5.41 | (0.140, | 54.8 |
| | (1:1) | | | | 0.049) | |
| Example 3 | Compound A:Compound 2-1 | BD1 | 3.89 | 5.34 | (0.140, | 50.5 |
| | (1:1, Co-deposition) | | | | 0.050) | |
| Example 4 | Compound D:Compound 2-13 | BD1 | 3.98 | 5.36 | (0.140, | 48.1 |
| | (1:1, Co-deposition) | | | | 0.049) | |
| Example 5 | Compound F:Compound 2-20 | BD1 | 4.01 | 5.44 | (0.140, | 52.1 |
| | (1:1) | | | | 0.049) | |
| Example 6 | Compound I:Compound 2-28 | BD1 | 3.90 | 5.60 | (0.140, | 51.5 |
| | (1:1) | | | | 0.049) | |
| Example 7 | Compound T:Compound 2-38 | BD1 | 3.87 | 5.40 | (0.140, | 53.4 |
| | (1:1) | | | | 0.049) | |
| Example 8 | Compound V:Compound 2-41 | BD1 | 3.77 | 5.44 | (0.140, | 55.1 |
| | (1:1) | | | | 0.050) | |
| Example 9 | Compound W:Compound 2-46 | BD1 | 3.75 | 5.39 | (0.140, | 53.7 |
| | (1:1) | | | | 0.049) | |
| Example 1-1 | Compound J:Compound 2-20 | BD1 | 3.75 | 5.49 | (0.140, | 59.3 |
| | (1:1) | | | | 0.050) | |
| Example 10 | Compound 1-B:Compound 2 | BD1 | 3.80 | 5.54 | (0.140, | 49.8 |
| | (1:1) | | | | 0.049) | |
| Example 11 | Compound 1-F:Compound 8 | BD1 | 3.74 | 5.39 | (0.140, | 55.9 |
| | (1:1) | | | | 0.049) | |
| Example 12 | Compound 1-H:Compound 15 | BD1 | 3.82 | 5.38 | (0.140, | 56.1 |
| | (1:1) | | | | 0.050) | |
| Example 13 | Compound 1-K:Compound 14 | BD1 | 3.79 | 5.47 | (0.140, | 58.1 |
| | (1:1) | | | | 0.049) | |
| Example 14 | Compound 1-A:Compound 2-1 | BD1 | 3.95 | 5.23 | (0.140, | 70.5 |
| | (1:1, Co-deposition) | | | | 0.049) | |
| Example 15 | Compound 1-D:Compound 2-8 | BD1 | 3.90 | 5.37 | (0.140, | 73.1 |
| | (1:1, Co-deposition) | | | | 0.050) | |
| Example 16 | Compound 1-A:Compound 2-1 | BD1 | 3.78 | 5.51 | (0.140, | 79.1 |
| | (1:1) | | | | 0.050) | |
| Example 17 | Compound 1-B:Compound 2-6 | BD1 | 3.80 | 5.50 | (0.140, | 80.5 |
| | (1:1) | | | | 0.050) | |
| Example 18 | Compound 1-C:Compound 2-5 | BD1 | 3.84 | 5.41 | (0.140, | 82.9 |
| | (1:1) | | | | 0.050) | |
| Example 19 | Compound 1-D:Compound 2-13 | BD1 | 3.74 | 5.38 | (0.140, | 85.1 |
| | (1:1) | | | | 0.050) | |
| Example 20 | Compound 1-E:Compound 2-10 | BD1 | 3.77 | 5.40 | (0.140, | 79.5 |
| | (1:1) | | | | 0.050) | |
| Example 21 | Compound 1-V:Compound 2-11 | BD1 | 3.81 | 5.44 | (0.140, | 80.4 |
| | (1:1) | | | | 0.050) | |
| Example 22 | Compound 1-G:Compound 2-12 | BD1 | 3.71 | 5.51 | (0.140, | 81.5 |
| | (1:1) | | | | 0.049) | |
| Example 23 | Compound 1-H:Compound 2-21 | BD1 | 3.88 | 5.55 | (0.140, | 90.1 |
| | (1:1) | | | | 0.050) | |
| Example 24 | Compound 1-W:Compound 2-24 | BD1 | 3.78 | 5.61 | (0.140, | 88.1 |
| | (1:1) | | | | 0.050) | |
| Example 25 | Compound 1-J:Compound 2-27 | BD1 | 3.70 | 5.47 | (0.140, | 83.1 |
| | (1:1) | | | | 0.050) | |
| Example 26 | Compound 1-K:Compound 2-29 | BD1 | 3.80 | 5.39 | (0.140, | 84.6 |
| | (1:1) | | | | 0.050) | |
| Example 27 | Compound 1-L:Compound 2-34 | BD1 | 3.74 | 5.49 | (0.140, | 86.3 |
| | (1:1) | | | | 0.049) | |
| Example 28 | Compound 1-M:Compound 2-39 | BD1 | 3.69 | 5.59 | (0.140, | 84.7 |
| | (1:1) | | | | 0.049) | |
| Example 29 | Compound 1-M:Compound 2-41 | BD1 | 3.70 | 5.52 | (0.140, | 88.1 |
| | (1:1) | | | | 0.049) | |
| Example 30 | Compound 1-O:Compound 2-47 | BD1 | 3.68 | 5.57 | (0.140, | 87.4 |
| | (1:1) | | | | 0.049) | |
| Example 31 | Compound 1-P:Compound 2-3 | BD1 | 3.71 | 5.38 | (0.140, | 90.1 |
| | (1:1) | | | | 0.049) | |
| Example 32 | Compound 1-Q:Compound 2-7 | BD1 | 3.77 | 5.40 | (0.140, | 84.9 |
| | (1:1) | | | | 0.049) | |
| Example 33 | Compound 1-R:Compound 2-18 | BD1 | 3.81 | 5.44 | (0.140, | 88.1 |
| | (1:1) | | | | 0.049) | |
| Example 34 | Compound 1-S:Compound 2-25 | BD1 | 3.84 | 5.39 | (0.140, | 86.5 |
| | (1:1) | | | | 0.050) | |
| Example 35 | Compound 1-T:Compound 2-46 | BD1 | 3.74 | 5.55 | (0.140, | 87.4 |
| | (1:1) | | | | 0.050) | |
| Example 36 | Compound 1-U:Compound 2-38 | BD1 | 3.71 | 5.61 | (0.140, | 88.5 |
| | (1:1) | | | | 0.050) | |
| Example 37 | Compound 1-V:Compound 2-35 | BD1 | 3.78 | 5.70 | (0.140, | 83.9 |
| | (1:1) | | | | 0.050) | |
| Example 38 | Compound 1-W:Compound 2-9 | BD1 | 3.75 | 5.51 | (0.140, | 85.4 |
| | (1:1) | | | | 0.049) | |
| Example 39 | Compound 1-C:Compound 2-3 | BD1 | 3.89 | 5.77 | (0.140, | 83.8 |
| | (2:1) | | | | 0.050) | |
| Example 40 | Compound 1-G:Compound 2-13 | BD1 | 3.91 | 5.80 | (0.140, | 82.5 |
| | (3:1) | | | | 0.050) | |
| Example 41 | Compound 1-V:Compound 2-44 | BD1 | 3.68 | 5.59 | (0.140, | 86.5 |
| | (1:2) | | | | 0.050) | |
| Example 42 | Compound 1-S:Compound 2-32 | BD1 | 3.60 | 5.41 | (0.140, | 88.1 |
| | (1:3) | | | | 0.049) | |
| Example 43 | Compound 1-W:Compound 2-40 | BD1 | 3.71 | 5.45 | (0.140, | 90.8 |
| | (2:1) | | | | 0.050) | |

From the results shown in Table 6, it was identified that Examples 1 to 43 using a mixture including at least one type of the compounds substituted with deuterium (one type: Examples 1 to 13, two types: Examples 14 to 43) as a blue fluorescent host were superior in terms of device properties, particularly lifetime, compared to Comparative Examples 1 to 6 using a mixture of the compounds not substituted with deuterium as a blue fluorescent host. As in existing prior cases, this enables manufacture of a blue light emitting device having significantly superior lifetime by introducing deuterium while increasing possibility of deriving low voltage and high efficiency by using a mixture of anthracene hosts of different series (aryl-based anthracene compound and heteroaryl-based anthracene compound), and proposes that disadvantages of an existing blue device can be improved. In addition, it was identified that Comparative Examples 1 and 4 and Examples 1, 2 and 16 forming the light emitting layer through one deposition source after pre-mixing two types of the host materials before forming the light emitting layer had superior device properties (voltage, efficiency, lifetime) compared to Comparative Examples 5 and 6 and Examples 3, 4 and 14 forming the light emitting layer through co-depositing the same materials.

### <Example 44> Manufacture of OLED

As an anode, a substrate having ITO/Ag/ITO deposited to 70 Å/1000 Å/70 Å was cut to a size of 50 mm×50 mm×0.5 mm, placed in distilled water containing dissolved dispersant, and ultrasonically cleaned. A product of Fischer Co. was used as the dispersant, and as the distilled water, distilled water filtered twice with a filter manufactured by Millipore Co. was used. After the ITO was cleaned for 30 minutes, ultrasonic cleaning was repeated twice using distilled water for 10 minutes. After the cleaning with distilled water was finished, the substrate was ultrasonically cleaned with solvents of isopropyl alcohol, acetone and methanol in this order, and then dried.

On the anode prepared as above, a hole injection layer was formed by thermal vacuum depositing the following compound HI-1 to a thickness of 50 Å, and a hole transfer layer was formed thereon by vacuum depositing the following compound HT1, a material transferring holes, to a thickness of 1150 Å. Subsequently, a hole control layer was formed using the following compound EB1 (150 Å), and then a light emitting layer was formed by vacuum depositing a mixture prepared using the following Compound B synthesized in Preparation Example 1 and Compound 2-3 synthesized in Preparation Example 2, and the following compound BD2 (2 mass %) as dopant to a thickness of 360 Å. After that, an electron control layer was formed by depositing the following compound HB1 to 50 Å, and an electron transfer layer having a thickness of 250 Å was formed by mixing the following compounds ET1 and Liq in a 5:5 mass ratio. Magnesium and lithium fluoride (LiF) having a thickness of 50 Å were consecutively formed to a film as an electron injection layer <EIL>, then magnesium and silver (1:4) were formed to 200 Å as a cathode, and then the following compound CP1 was deposited to 600 Å to complete a device. In the process, the deposition rates of the organic materials were maintained at 1 Å/sec.

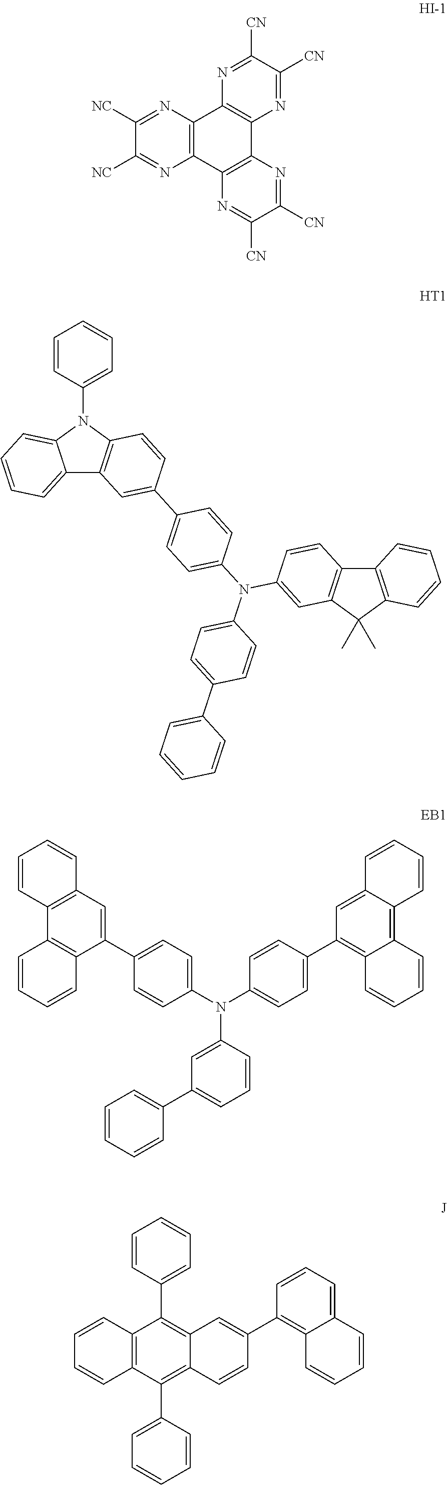

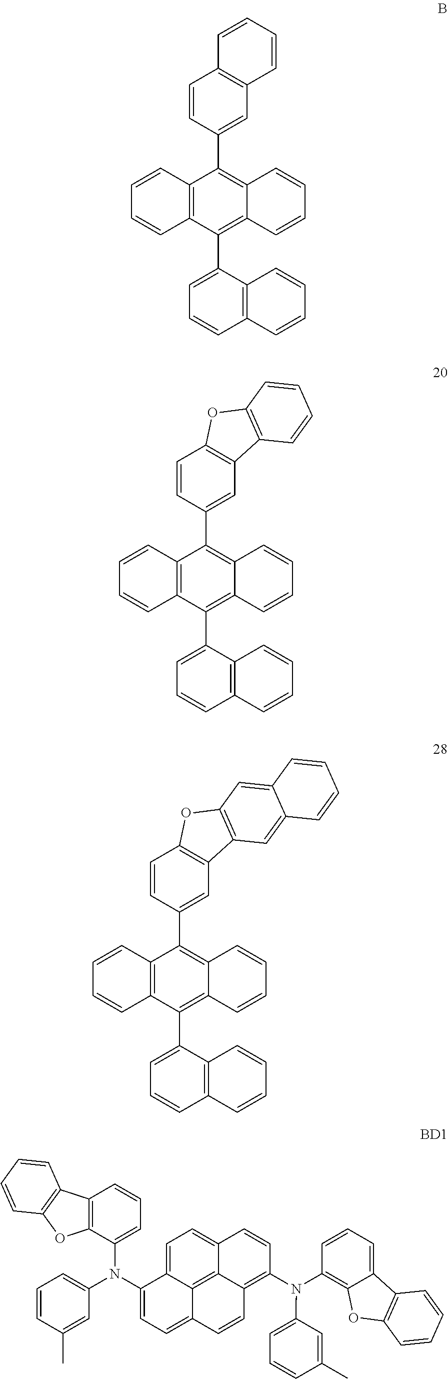

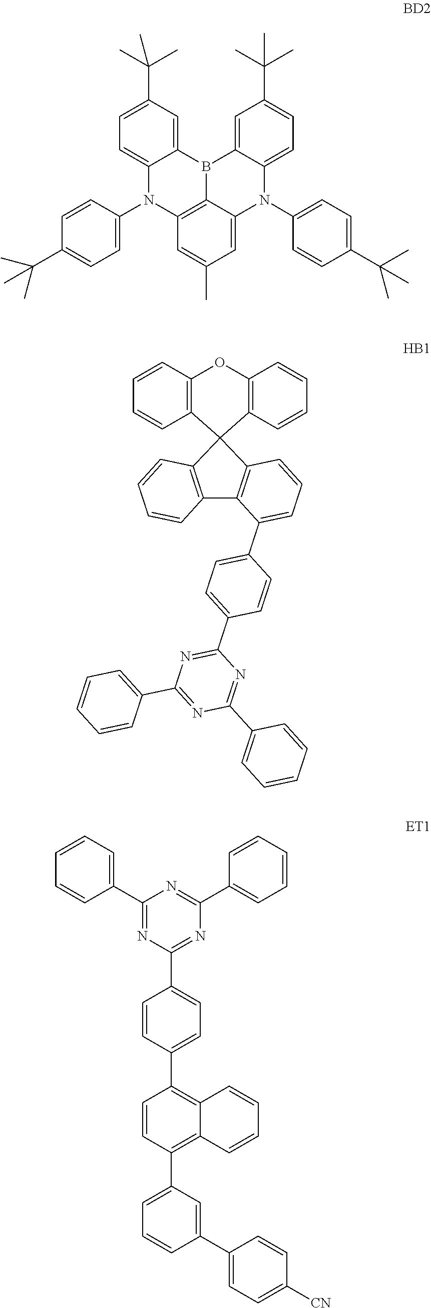 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1 ; c1ccc(-c2nc(-c3ccccc3)nc(-c3ccc(-c4cccc5c4-c4ccccc4C54c5ccccc5Oc5ccccc54)cc3)n2)cc1 ; N#Cc1ccc(-c2cccc(-c3ccc(-c4ccc(-c5nc(-c6ccccc6)nc(-c6ccccc6)n5)cc4)c4ccccc34)c2)cc1]

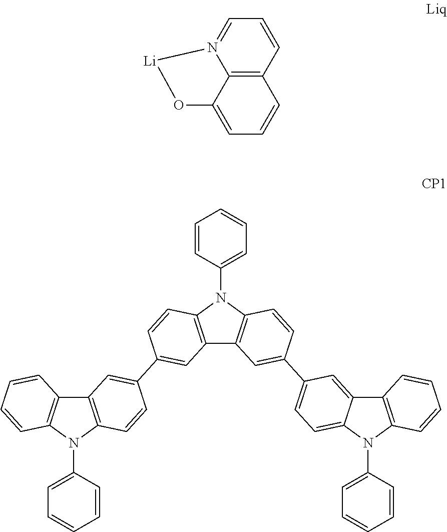

### Examples 45 to 84 and Comparative Examples 7 to 12

Devices of Examples 45 to 84 and Comparative Examples 7 to 12 were manufactured in the same manner as in Example 44, except that materials described in the following Table 8 were used as the light emitting layer material, and a different light emitting layer forming method was used. In Example 44, the light emitting layer was formed by pre-mixing Compound B and Compound 2-3 before forming the layer and through one deposition source as in Experimental Example 1, and in the comparative examples and the examples having the deposition method as co-deposition in the following Table 8, the light emitting layer was formed by depositing the first host, the second host and the dopant each through a different deposition source.

A difference in the dipole moment values and a difference in the evaporation temperatures between the two types of host materials used as the light emitting layer material in Comparative Examples 7 to 12 and Examples 44 to 84 are shown in the following Table 7.

TABLE 7

| | Combination of | Representative | Representative | | Difference in |
|---|---|---|---|---|---|
| | Light Emitting | Structure of | Structure of | | Evaporation |
| | Layer Compound | Chemical | Chemical | Difference | Temperature |
| | (Mass Ratio) | Formula 1 | Formula 2 | in DM (D) | (° C.) |
| Comparative | Compound J:Compound 28 | Compound J | Compound 28 | (0.87) | (20) |
| Example 7 | (1:1) | | | | |
| Comparative | Compound J:Compound 28 | Compound J | Compound 28 | (0.87) | (20) |
| Example 8 | (1:3) | | | | |
| Comparative | Compound B:Compound 20 | Compound B | Compound 20 | (0.49) | (10) |
| Example 9 | (1:1) | | | | |
| Comparative | Compound B:Compound 20 | Compound B | Compound 20 | (0.49) | (10) |
| Example 10 | (2:1) | | | | |
| Comparative | Compound J:Compound 28 | Compound J | Compound 28 | (0.87) | (20) |
| Example 11 | (1:1, Co-deposition) | | | | |
| Comparative | Compound B:Compound 20 | Compound B | Compound 20 | (0.49) | (10) |
| Example 12 | (1:1, Co-deposition) | | | | |
| Example 44 | Compound B:Compound | Compound B | Compound 3 | (1.06) | (20) |
| | 2-3 (1:1) | | | | |
| Example 45 | Compound C:Compound | Compound C | Compound 10 | (0.52) | (0) |
| | 2-10 (1:1) | | | | |
| Example 46 | Compound B:Compound | Compound B | Compound 3 | (1.06) | (20) |
| | 2-3 (1:1, Co-deposition) | | | | |
| Example 47 | Compound C:Compound | Compound C | Compound 10 | (0.52) | (0) |
| | 2-10 (1:1, Co-deposition) | | | | |
| Example 48 | Compound G:Compound | Compound G | Compound 18 | (0.43) | (10) |
| | 2-18 (1:1) | | | | |
| Example 49 | Compound J:Compound | Compound J | Compound 19 | (0.95) | (10) |
| | 2-19 (1:1) | | | | |
| Example 50 | Compound M:Compound | Compound M | Compound 31 | (0.70) | (20) |
| | 2-31 (1:1) | | | | |
| Example 51 | Compound O:Compound | Compound O | Compound 36 | (0.86) | (10) |
| | 2-36 (1:1) | | | | |
| Example 52 | Compound 1-D:Compound | Compound D | Compound 1 | (0.83) | (20) |
| | 1 (1:1) | | | | |
| Example 53 | Compound 1-E:Compound | Compound E | Compound 5 | (1.12) | (0) |
| | 5 (1:1) | | | | |
| Example 54 | Compound 1-R:Compound | Compound R | Compound 13 | (0.62) | (10) |
| | 13 (1:1) | | | | |
| Example 55 | Compound 1-W:Compound | Compound W | Compound 22 | (0.78) | (0) |
| | 22 (1:1) | | | | |
| Example 56 | Compound 1-V:Compound | Compound V | Compound 35 | (0.98) | (10) |
| | 35 (1:1) | | | | |
| Example 57 | Compound 1-Q:Compound | Compound Q | Compound 36 | (1.05) | (0) |
| | 36 (1:1) | | | | |
| Example 58 | Compound 1-S:Compound | Compound S | Compound 1 | (0.71) | (0) |
| | 2-1 (1:1, Co-deposition) | | | | |
| Example 59 | Compound 1-A:Compound | Compound A | Compound 2 | (0.92) | (0) |
| | 2-2 (1:1) | | | | |
| Example 60 | Compound 1-B:Compound | Compound B | Compound 6 | (0.65) | (10) |
| | 2-6 (1:1) | | | | |
| Example 61 | Compound 1-C:Compound | Compound C | Compound 7 | (0.68) | (0) |
| | 2-7 (1:1) | | | | |
| Example 62 | Compound 1-D:Compound | Compound D | Compound 14 | (0.42) | (10) |
| | 2-14 (1:1) | | | | |
| Example 63 | Compound 1-E:Compound | Compound E | Compound 16 | (0.89) | (0) |
| | 2-16 (1:1) | | | | |
| Example 64 | Compound 1-F:Compound | Compound F | Compound 18 | (0.34) | (20) |
| | 2-18 (1:1) | | | | |
| Example 65 | Compound 1-G:Compound | Compound G | Compound 19 | (0.58) | (10) |
| | 2-19 (1:1) | | | | |
| Example 66 | Compound 1-H:Compound | Compound H | Compound 21 | (0.74) | (20) |
| | 2-21 (1:1) | | | | |
| Example 67 | Compound 1-I:Compound | Compound I | Compound 27 | (0.79) | (20) |
| | 2-27 (1:1) | | | | |
| Example 68 | Compound 1-J:Compound | Compound J | Compound 29 | (0.86) | (10) |
| | 2-29 (1:1) | | | | |
| Example 69 | Compound 1-K:Compound | Compound K | Compound 6 | (0.83) | (0) |
| | 2-6 (1:1) | | | | |
| Example 70 | Compound 1-L:Compound | Compound L | Compound 32 | (0.73) | (10) |
| | 2-32 (1:1) | | | | |
| Example 71 | Compound 1-M:Compound | Compound M | Compound 37 | (0.86) | (0) |
| | 2-37 (1:1) | | | | |
| Example 72 | Compound 1-M:Compound | Compound M | Compound 36 | (0.74) | (10) |
| | 2-36 (1:1) | | | | |
| Example 73 | Compound 1-O:Compound | Compound O | Compound 43 | (1.10) | (20) |
| | 2-43 (1:1) | | | | |
| Example 74 | Compound 1-P:Compound | Compound P | Compound 46 | (0.86) | (20) |
| | 2-46 (1:1) | | | | |
| Example 75 | Compound 1-Q:Compound | Compound Q | Compound 20 | (0.49) | (0) |
| | 2-20 (1:1) | | | | |
| Example 76 | Compound 1-R:Compound | Compound R | Compound 11 | (0.71) | (20) |
| | 2-11 (1:1) | | | | |
| Example 77 | Compound 1-S:Compound | Compound S | Compound 12 | (0.71) | (10) |
| | 2-12 (1:1) | | | | |
| Example 78 | Compound 1-T:Compound | Compound T | Compound 18 | (0.41) | (0) |
| | 2-18 (1:1) | | | | |
| Example 79 | Compound 1-U:Compound | Compound U | Compound 21 | (0.83) | (0) |
| | 2-21 (1:1) | | | | |
| Example 80 | Compound 1-V:Compound | Compound V | Compound 33 | (0.84) | (0) |
| | 2-33 (1:1) | | | | |
| Example 81 | Compound 1-W:Compound | Compound W | Compound 44 | (0.77) | (0) |
| | 2-44 (1:1) | | | | |
| Example 82 | Compound 1-E:Compound | Compound E | Compound 15 | (0.51) | (10) |
| | 2-15 (2:1) | | | | |
| Example 83 | Compound 1-T:Compound | Compound T | Compound 28 | (0.95) | (10) |
| | 2-28 (1:2) | | | | |
| Example 84 | Compound 1-V:Compound | Compound V | Compound 45 | (0.87) | (0) |
| | 2-45 (3:1) | | | | |

For the devices manufactured in Comparative Examples 7 to 12 and Examples 44 to 84, driving voltage, light emission efficiency, color coordinate and time (T95) taken for luminance to become 95% with respect to initial luminance were measured at current density of 20 mA/cm². The results are shown in the following Table 8.

TABLE 8

| | | | Device Result | | | |
|---|---|---|---|---|---|---|
| | | | Voltage | | | Lifetime |
| | Light Emitting Layer | | (V) | Cd/A | Color | (T95, h) |
| Experimental | First Host:Second Host | | (@20 | (@20 | Coordinate | (@20 |
| Example | (Mass Ratio (Deposition Method)) | Dopant | mA/cm²) | mA/cm²) | (x, y) | mA/cm²) |
| Comparative | Compound J:Compound 28 | BD2 | 3.90 | 5.89 | (0.129, | 35.3 |
| Example 7 | (1:1) | | | | 0.099) | |
| Comparative | Compound J:Compound 28 | BD2 | 3.81 | 5.94 | (0.131, | 33.4 |
| Example 8 | (1:3) | | | | 0.100) | |
| Comparative | Compound B:Compound 20 | BD2 | 3.84 | 6.01 | (0.129, | 35.1 |
| Example 9 | (1:1) | | | | 0.099) | |
| Comparative | Compound B:Compound 20 | BD2 | 3.88 | 5.97 | (0.130, | 32.4 |
| Example 10 | (2:1) | | | | 0.100) | |
| Comparative | Compound J:Compound 28 | BD2 | 4.05 | 5.81 | (0.129, | 30.1 |
| Example 11 | (1:1, Co-deposition) | | | | 0.099) | |
| Comparative | Compound B:Compound 20 | BD2 | 4.10 | 5.83 | (0.130, | 28.5 |
| Example 12 | (1:1, Co-deposition) | | | | 0.100) | |
| Example 44 | Compound B:Compound 2-3 | BD2 | 3.88 | 6.05 | (0.129, | 45.8 |
| | (1:1) | | | | 0.099) | |
| Example 45 | Compound C:Compound 2-10 | BD2 | 3.91 | 6.02 | (0.130, | 44.9 |
| | (1:1) | | | | 0.100) | |
| Example 46 | Compound B:Compound 2-3 | BD2 | 3.95 | 6.00 | (0.129, | 40.1 |
| | (1:1, Co-deposition) | | | | 0.099) | |
| Example 47 | Compound C:Compound 2-10 | BD2 | 3.99 | 5.91 | (0.129, | 41.8 |
| | (1:1, Co-deposition) | | | | 0.099) | |
| Example 48 | Compound G:Compound 2-18 | BD2 | 3.80 | 6.05 | (0.129, | 49.8 |
| | (1:1) | | | | 0.099) | |
| Example 49 | Compound J:Compound 2-19 | BD2 | 3.74 | 6.01 | (0.129, | 50.1 |
| | (1:1) | | | | 0.099) | |
| Example 50 | Compound M:Compound 2-31 | BD2 | 3.90 | 5.98 | (0.129, | 53.1 |
| | (1:1) | | | | 0.099) | |
| Example 51 | Compound O:Compound 2-36 | BD2 | 3.87 | 6.10 | (0.129, | 50.8 |
| | (1:1) | | | | 0.099) | |
| Example 52 | Compound 1-D:Compound 1 | BD2 | 3.77 | 5.99 | (0.130, | 52.4 |
| | (1:1) | | | | 0.100) | |
| Example 53 | Compound 1-E:Compound 5 | BD2 | 3.81 | 5.94 | (0.129, | 49.5 |
| | (1:1) | | | | 0.099) | |
| Example 54 | Compound 1-R:Compound 13 | BD2 | 3.86 | 6.08 | (0.129, | 49.9 |
| | (1:1) | | | | 0.099) | |
| Example 55 | Compound 1-W:Compound 22 | BD2 | 3.78 | 6.10 | (0.130, | 50.4 |
| | (1:1) | | | | 0.100) | |
| Example 56 | Compound 1-V:Compound 35 | BD2 | 3.77 | 6.01 | (0.129, | 51.4 |
| | (1:1) | | | | 0.099) | |
| Example 57 | Compound 1-Q:Compound 36 | BD2 | 3.70 | 5.87 | (0.129, | 48.7 |
| | (1:1) | | | | 0.099) | |
| Example 58 | Compound 1-S:Compound 2-1 | BD2 | 3.99 | 6.12 | (0.130, | 64.8 |
| | (1:1, Co-deposition) | | | | 0.100) | |
| Example 59 | Compound 1-A:Compound 2-2 | BD2 | 3.85 | 6.08 | (0.129, | 70.5 |
| | (1:1) | | | | 0.099) | |
| Example 60 | Compound 1-B:Compound 2-6 | BD2 | 3.76 | 6.23 | (0.129, | 72.1 |
| | (1:1) | | | | 0.099) | |
| Example 61 | Compound 1-C:Compound 2-7 | BD2 | 3.78 | 6.00 | (0.129, | 73.8 |
| | (1:1) | | | | 0.099) | |
| Example 62 | Compound 1-D:Compound 2-14 | BD2 | 3.80 | 6.08 | (0.129, | 69.5 |
| | (1:1) | | | | 0.099) | |
| Example 63 | Compound 1-E:Compound 2-16 | BD2 | 3.84 | 6.12 | (0.130, | 74.1 |
| | (1:1) | | | | 0.100) | |
| Example 64 | Compound 1-F:Compound 2-18 | BD2 | 3.85 | 5.99 | (0.130, | 70.5 |
| | (1:1) | | | | 0.100) | |
| Example 65 | Compound 1-G:Compound 2-19 | BD2 | 3.79 | 6.02 | (0.129, | 72.8 |
| | (1:1) | | | | 0.099) | |
| Example 66 | Compound 1-H:Compound 2-21 | BD2 | 3.84 | 6.13 | (0.129, | 71.4 |
| | (1:1) | | | | 0.099) | |
| Example 67 | Compound 1-I:Compound 2-27 | BD2 | 3.88 | 6.23 | (0.130, | 76.5 |
| | (1:1) | | | | 0.100) | |
| Example 68 | Compound 1-J:Compound 2-29 | BD2 | 3.84 | 5.98 | (0.129, | 72.8 |
| | (1:1) | | | | 0.099) | |
| Example 69 | Compound 1-K: Compound 2-6 | BD2 | 3.80 | 6.01 | (0.130, | 78.4 |
| | (1:1) | | | | 0.100) | |
| Example 70 | Compound 1-L:Compound 2-32 | BD2 | 3.74 | 6.08 | (0.130, | 77.5 |
| | (1:1) | | | | 0.100) | |
| Example 71 | Compound 1-M: Compound 2-37 | BD2 | 3.72 | 6.06 | (0.130, | 73.6 |
| | (1:1) | | | | 0.100) | |
| Example 72 | Compound 1-M:Compound 2-36 | BD2 | 3.70 | 5.99 | (0.130, | 76.4 |
| | (1:1) | | | | 0.100) | |
| Example 73 | Compound 1-O:Compound 2-43 | BD2 | 3.76 | 6.00 | (0.129, | 75.1 |
| | (1:1) | | | | 0.099) | |
| Example 74 | Compound 1-P:Compound 2-46 | BD2 | 3.71 | 6.07 | (0.130, | 77.8 |
| | (1:1) | | | | 0.100) | |
| Example 75 | Compound 1-Q:Compound 2-20 | BD2 | 3.80 | 6.13 | (0.129, | 78.5 |
| | (1:1) | | | | 0.099) | |
| Example 76 | Compound 1-R:Compound 2-11 | BD2 | 3.89 | 6.17 | (0.129, | 74.2 |
| | (1:1) | | | | 0.099) | |
| Example 77 | Compound l-S:Compound 2-12 | BD2 | 3.76 | 6.04 | (0.130, | 76.8 |
| | (1:1) | | | | 0.100) | |
| Example 78 | Compound 1-T:Compound 2-18 | BD2 | 3.81 | 6.08 | (0.129, | 77.7 |
| | (1:1) | | | | 0.099) | |
| Example 79 | Compound 1-U:Compound 2-21 | BD2 | 3.80 | 5.90 | (0.129, | 71.4 |
| | (1:1) | | | | 0.099) | |
| Example 80 | Compound 1-V:Compound 2-33 | BD2 | 3.80 | 6.16 | (0.130, | 78.6 |
| | (1:1) | | | | 0.100) | |
| Example 81 | Compound 1-W:Compound 2-44 | BD2 | 3.74 | 6.05 | (0.129, | 70.9 |
| | (1:1) | | | | 0.099) | |
| Example 82 | Compound 1-E:Compound 2-15 | BD2 | 3.89 | 6.20 | (0.129, | 70.1 |
| | (2:1) | | | | 0.099) | |
| Example 83 | Compound 1-T:Compound 2-28 | BD2 | 3.70 | 6.01 | (0.129, | 80.5 |
| | (1:2) | | | | 0.099) | |
| Example 84 | Compound 1-V:Compound 2-45 | BD2 | 3.91 | 6.12 | (0.129, | 77.4 |
| | (3:1) | | | | 0.099) | |

Examples 44 to 84 show the same trends as Examples 1 to 43 of Table 6, and it was identified that advantages and properties of dopant performance were able to be retained when using the boron-based blue fluorescent dopant in addition to the pyrene-based blue fluorescent dopant. It was identified that Examples 44 to 84 had superior device properties compared to Comparative Examples 7 to 12 including a mixture of the compounds not substituted with deuterium.

In addition, it was identified that Comparative Examples 7 and 9 and Examples 44 and 45 forming the light emitting layer through one deposition source after pre-mixing two types of the host materials before forming the light emitting layer had superior device properties (voltage, efficiency, lifetime) compared to Comparative Examples 11 and 12 and Examples 46 and 47 forming the light emitting layer through co-depositing the same materials.

1. A method for manufacturing an organic electroluminescent device, the method comprising:
forming a first electrode on a substrate;
forming one or more organic material layers on the first electrode; and
forming a second electrode on the organic material layer,
wherein the forming of the one or more organic material layers includes forming one or more organic material layers using a composition, the composition comprising:
a compound of the following Chemical Formula 1; and
a compound of the following Chemical Formula 2,
wherein at least one of the compound of the following Chemical Formula 1 and the compound of the following Chemical Formula 2 includes at least one deuterium: 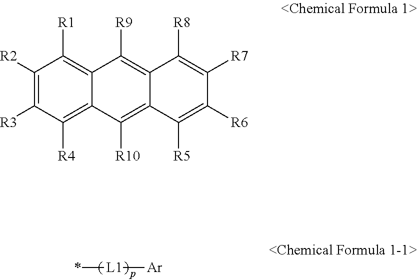
wherein in Chemical Formula 1:
at least one of R1 to R10 bonds to a * site of Chemical Formula 1-1, and the rest are the same as or different from each other and each independently is hydrogen, deuterium, a halogen group, a cyano group, a nitro group, a hydroxyl group, a substituted or unsubstituted alkyl group, a substituted or unsubstituted aryl group, a substituted or unsubstituted cycloalkyl group, a substituted or unsubstituted heteroaryl group, or a substituted or unsubstituted silyl group;
L1 is a direct bond, a substituted or unsubstituted arylene group, or a substituted or unsubstituted heteroarylene group;
Ar is a substituted or unsubstituted aryl group; and
p is an integer of 1 to 5; 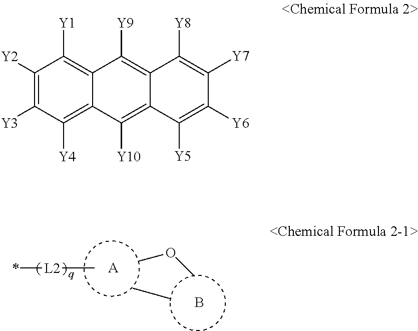
wherein in Chemical Formula 2:
at least one of Y1 to Y10 bonds to a * site of Chemical Formula 2-1, and the rest are the same as or different from each other and each independently is hydrogen, deuterium, a halogen group, a cyano group, a nitro group, a hydroxyl group, a substituted or unsubstituted alkyl group, a substituted or unsubstituted aryl group, a substituted or unsubstituted cycloalkyl group, a substituted or unsubstituted heteroaryl group, or a substituted or unsubstituted silyl group;
A and B are the same as or different from each other, and each independently is a substituted or unsubstituted aromatic hydrocarbon ring or a substituted or unsubstituted aromatic heteroring;
L2 is a direct bond, a substituted or unsubstituted arylene group, or a substituted or unsubstituted heteroarylene group; and
q is an integer of 1 to 5.

2. The method of claim 1, wherein Chemical Formula 1 is any one of the following Chemical Formulae 1-A to 1-C: 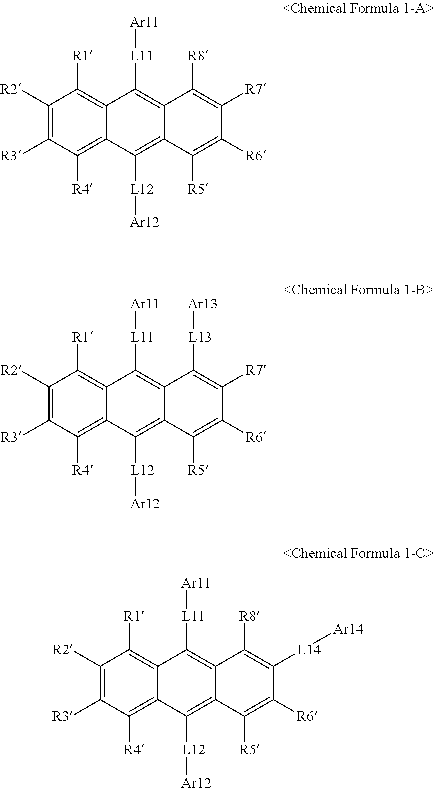
wherein in Chemical Formulae 1-A to 1-C:
R1′ to R8′ are the same as or different from each other, and each independently is hydrogen, deuterium, a halogen group, a cyano group, a nitro group, a hydroxyl group, a substituted or unsubstituted alkyl group, a substituted or unsubstituted aryl group, a substituted or unsubstituted cycloalkyl group, a substituted or unsubstituted heteroaryl group, or a substituted or unsubstituted silyl group;
L11 to L14 are the same as or different from each other, and each independently is a direct bond, a substituted or unsubstituted arylene group, or a substituted or unsubstituted heteroarylene group; and
Ar11 to Ar14 are the same as or different from each other, and each independently is a substituted or unsubstituted aryl group.

3. The method of claim 1, wherein the compound of Chemical Formula 1 and the compound of Chemical Formula 2 satisfy the following Equation 1:
$$\vert D {M}_{host 1} - D {M}_{host 2} \vert > 0. 2 \qquad < Equation 1 >$$
DMₕₒₛₜ₁ is a dipole moment value of the compound of Chemical Formula 1; and
DMₕₒₛₜ₂ is a dipole moment value of the compound of Chemical Formula 2.

4. The method of claim 1, wherein one of the compound of Chemical Formula 1 and the compound of Chemical Formula 2 has a deuterium substitution rate of 10% to 100%.

5. The method of claim 1, wherein two of the compound of Chemical Formula 1 and the compound of Chemical Formula 2 each has a deuterium substitution rate of 10% to 100%.

6. The method of claim 1, wherein a mass ratio of the compound of Chemical Formula 1 to the compound of Chemical Formula 2 is 1:9 to 9:1.

7. The method of claim 1, wherein the compound of Chemical Formula 1 and the compound of Chemical Formula 2 satisfy the following Equation 2:
$$\vert {T}_{sub 1} - {T}_{sub 2} \vert \leq 20 ° C \qquad < Equation 2 >$$
wherein:
T_{sub1} is an evaporation temperature of the compound of Chemical Formula 1; and
T_{sub2} is an evaporation temperature of the compound of Chemical Formula 2.

8. The method of claim 1, wherein the compound of Chemical Formula 1 and the compound of Chemical Formula 2 each has an evaporation temperature of lower than 400° C.

9. The method of claim 1, wherein the compound of Chemical Formula 1 or the compound of Chemical Formula 2 has a concentration of C1 in the composition, and has a concentration of C2 in a film formed by evaporating the composition at a deposition rate of 1 Å/s to 10 Å/s on a surface locating at a determined distance from a place where the composition is evaporated in a high vacuum deposition apparatus having a chamber base pressure of 1×10⁻⁴ torr to 1×10⁻⁹ torr, and satisfies the following Equation 3:
$$\vert ( C 1 - C 2 ) / C 1 \vert < 10 \% . \qquad < Equation 3 >$$

10. An organic electroluminescent device prepared using the method of claim 1.
